(19) United States
(12) Patent Application Publication
(10) Pub. No.: US 2024/0431199 A1
(43) Pub. Date: Dec. 26, 2024

(54) ORGANIC ELECTROLUMINESCENT APPARATUS

(71) Applicant: Merck Patent GmbH, Darmstadt (DE)

(72) Inventors: Amir Hossain PARHAM, Darmstadt (DE); Christian EHRENREICH, Darmstadt (DE); Christian EICKHOFF, Darmstadt (DE); Jonas Valentin KROEBER, Darmstadt (DE)

(21) Appl. No.: 18/695,476

(22) PCT Filed: Sep. 28, 2022
(86) PCT No.: PCT/EP2022/076884

§ 371 Date: Mar. 26, 2024

(30) Foreign Application Priority Data
Sep. 30, 2021 (EP) 21200281.0

(51) Int. Cl. H10K 85/60; C09K 11/02; H10K 50/12

(52) U.S. Cl. CPC H10K 85/654; C09K 11/02; H10K 85/633; H10K 85/6572; H10K 85/6576; H10K 50/12; H10K 85/624; H10K 85/626; H10K 85/6574

(57) ABSTRACT

The present invention relates to an organic electroluminescent apparatus containing a mixture that comprises an electron-transporting host material and a hole-transporting host material, as well as to a formulation containing a mixture of the host materials and to a mixture containing the host materials. The electron-transporting host material corresponds to a compound of formula (1) from the class of compounds containing a pyridine, pyrimidine or triazine unit substituted by a dibenzofuran or dibenzothiophene and the hole-transporting host material corresponds to a deuterated monoamine of formula (2).

### TECHNICAL FIELD

The present invention relates to an organic electroluminescent device comprising a mixture comprising an electron-transporting host material and a hole-transporting host material, and to a formulation comprising a mixture of the host materials and to a mixture comprising the host materials. The electron-transporting host material corresponds to a compound of the formula (1) from the class of compounds containing a pyridine, pyrimidine or triazine unit substituted by a dibenzofuran or dibenzothiophene, and the hole-transporting host material corresponds to a deuterated monoamine of the formula (2).

### STATE OF THE ART

The structure of organic electroluminescent devices (e.g. OLEDs—organic light-emitting diodes or OLECs—organic light-emitting electrochemical cells) in which organic semiconductors are used as functional materials has long been known. Emitting materials used here, aside from fluorescent emitters, are increasingly organometallic complexes which exhibit phosphorescence rather than fluorescence. For quantum-mechanical reasons, up to a fourfold increase in energy efficiency and power efficiency is possible using organometallic compounds as phosphorescent emitters. In general terms, however, there is still a need for improvement in OLEDs, especially also in OLEDs which exhibit triplet emission (phosphorescence), for example with regard to efficiency, operating voltage and lifetime.

The properties of organic electroluminescent devices are not only determined by the emitters used. Also of particular significance here are especially the other materials used, such as host and matrix materials, hole blocker materials, electron transport materials, hole transport materials and electron or exciton blocker materials, and among these especially the host or matrix materials. Improvements to these materials can lead to distinct improvements to electroluminescent devices.

Host materials for use in organic electronic devices are well known to the person skilled in the art. The term “matrix material” is also frequently used in the prior art when what is meant is a host material for phosphorescent emitters. This use of the term is also applicable to the present invention. In the meantime, a multitude of host materials has been developed both for fluorescent and for phosphorescent electronic devices.

A further means of improving the performance data of electronic devices, especially of organic electroluminescent devices, is to use combinations of two or more materials, especially host materials or matrix materials. It has become established practice in the art to use a mixture consisting of an electron transport material, a hole transport material and a phosphorescent emitter in the emission layer of an OLED, where the emission layer may also contain further materials.

According to WO2015169412 and WO2016015810, it is possible to use triazine-dibenzofuran-carbazole derivatives and triazine-dibenzothiophene-carbazole derivatives, for example, in a light-emitting layer as host materials.

WO17204556 and WO19190101 each describe specific aryldiamines, which may be unsubstituted or partly deuterated, and the use thereof in an electroluminescent device, especially in an emitting auxiliary layer.

US2017186969 describes an organic light-emitting device, wherein specific monoarylamines that are present in the organic layer may be unsubstituted or partly deuterated, and are especially present in an emitting auxiliary layer.

WO18026197, WO19151682, WO20226300, WO20231197 and WO21096228 each describe an organic light-emitting device, where two classes of compounds are present in the organic layer, selected from respectively specific monoarylamines, which may be unsubstituted or partly deuterated, and specific triazines.

Specific monoarylamines that may be unsubstituted or partly deuterated are described in published specifications WO2015022051, WO2017148564, WO2018083053 CN112375053, WO2021156323 and WO21107728.

However, there is still need for improvement in the case of use of these materials or in the case of use of mixtures of the materials, especially in relation to efficiency, operating voltage and/or lifetime of the organic electroluminescent device.

The problem addressed by the present invention is therefore that of providing a combination of host materials which are suitable for use in an organic electroluminescent device, especially in a fluorescent or phosphorescent OLED, and lead to good device properties, especially with regard to an improved lifetime, and that of providing the corresponding electroluminescent device.

It has now been found that this problem is solved, and the disadvantages from the prior art are eliminated, by the combination of at least one compound of the formula (1) as first host material and at least one hole-transporting compound of the formula (2) as second host material in a light-emitting layer of an organic electroluminescent device. The use of such a material combination for production of the light-emitting layer in an organic electroluminescent device leads to very good properties of these devices, especially with regard to lifetime, especially with equal or improved efficiency and/or operating voltage. The advantages are especially also apparent in the presence of a light-emitting component in the emission layer, especially in the case of combination with emitters of the formulae (IIIa) and (I) to (VIII), at concentrations between 2% and 15% by weight. The advantages are especially apparent in the presence of a light-emitting component of the formula (IIIa) as described below at concentrations between 2% and 15% by weight.

### SUMMARY OF THE INVENTION

The present invention therefore first provides an organic electroluminescent device comprising an anode, a cathode and at least one organic layer containing at least one light-emitting layer, wherein the at least one light-emitting layer contains at least one compound of the formula (1) as host material 1 and at least one compound of the formula (2) as host material 2:

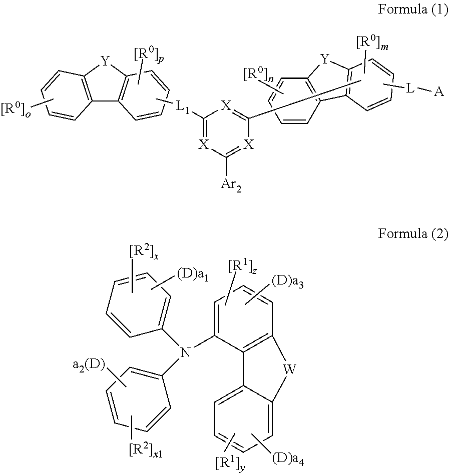

where the symbols and indices used are as follows:
A is

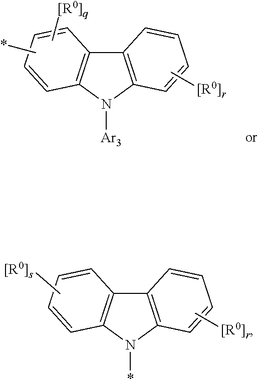

X is the same or different at each instance and is CR⁰ or N, where at least one symbol X is N;
Y is the same or different at each instance and is selected from O and S;
indicates the binding site to the formula (1);
L and L₁ are the same or different at each instance and are a single bond or an aromatic or heteroaromatic ring system having 5 to 30 aromatic ring atoms;
W is O, S or C(R)₂;
R is in each case independently a straight-chain or branched alkyl group which has 1 to 4 carbon atoms and may be partly or fully deuterated, or an unsubstituted or partly or fully deuterated aromatic ring system having 6 to 18 carbon atoms, where two substituents R together with the carbon atom to which they are bonded may form a mono- or polycyclic, aliphatic or aromatic or heteroaromatic, unsubstituted, partly deuterated or fully deuterated ring system which may be substituted by one or more substituents R³, with the condition that the ring system and substituents bonded thereto do not contain a carbazole group;
R⁰ at each instance is independently D, an unsubstituted or partly or fully deuterated aromatic ring system having 6 to 18 carbon atoms or an unsubstituted or partly or fully deuterated dibenzofuran, dibenzothiophene, or C-bonded N-arylcarbazole;
Ar₁ is the same or different at each instance and is an aromatic or heteroaromatic ring system which has 5 to 30 aromatic ring atoms and may be substituted by one or more nonaromatic R³ radicals; at the same time, two Ar₁ radicals bonded to the same nitrogen atom, phosphorus atom or boron atom may also be bridged to one another by a single bond or a bridge selected from C(R³)₂, O and S;
Ar₂ at each instance is independently an aryl or heteroaryl group which has 5 to 40 aromatic ring atoms and may be substituted by one or more R′ radicals;
Ar₃ at each instance is independently an aromatic ring system having 6 to 40 aromatic ring atoms or a heteroaromatic ring system having 5 to 40 aromatic ring atoms, which may be substituted by one or more R′ radicals;
aryl is the same or different at each instance and is an aromatic or heteroaromatic ring system which has 5 to 30 aromatic ring atoms and may be substituted by one or more nonaromatic R radicals;
R′ is the same or different at each instance and is selected from the group consisting of D, F, Cl, Br, I, CN, NO₂, N(Ar₁)₂, NH₂, N(R³)₂, C(═O)Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R′ to form a monocyclic or polycyclic, aliphatic, aromatic or heteroaromatic ring system which may be substituted by one or more R³ radicals;
R¹ is the same or different at each instance and is selected from the group consisting of F, Cl, Br, I, CN, NO₂, C(═O)R′, P(═O)(Ar₁)₂, P(Ar₁)₂, B(Ar₁)₂, Si(Ar₁)₃, Si(R′)₃, a straight-chain alkyl, alkoxy or thioalkyl group having 1 to 20 carbon atoms and a branched or cyclic alkyl, alkoxy or thioalkyl group having 3 to 20 carbon atoms and an alkenyl group having 2 to 20 carbon atoms, each of which may be substituted by one or more R′ radicals, where one or more nonadjacent CH₂ groups may be replaced by R′C═CR′, Si(R′)₂, C═O, C═S, C═NR′, P(═O)(R′), SO, SO₂, NR′, O, S or CONR′ and where one or more hydrogen atoms may be replaced by D, F, Cl, Br, I, CN or NO₂;
R² is the same or different at each instance and is selected from the group consisting of F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R² to form a monocyclic or polycyclic, aliphatic, aromatic or heteroaromatic ring system which may be substituted by one or more R³ radicals, with the condition that R² and substituents bonded thereto do not contain a carbazole group;
R³ is the same or different at each instance and is selected from the group consisting of D, F, CN, an aliphatic hydrocarbyl radical having 1 to 20 carbon atoms, and an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, it is possible for two or more adjacent R³ substituents together to form a mono- or polycyclic, aliphatic ring system;
n, m, p, q are each independently 0, 1, 2 or 3;
o, r, s are each independently 0, 1, 2, 3 or 4;
x, x1 at each instance are independently 0, 1, 2, 3 or 4;
y, z are each independently 0, 1 or 2;
a1, a2 are each independently 1, 2, 3, 4 or 5;
a3 is 0, 1, 2 or 3;
a4 is 0, 1, 2, 3 or 4; and
a1+a2+a3+a4 is 3, 4, 5, 6, 7, 8, 9, 10, 11, 12, 13, 14, 15, 16 or 17.

The invention further provides a process for producing the organic electroluminescent devices and mixtures comprising at least one compound of the formula (1) and at least one compound of the formula (2), specific material combinations and formulations that contain such mixtures or material combinations. The corresponding preferred embodiments as described hereinafter likewise form part of the subject-matter of the present invention. The surprising and advantageous effects are achieved through specific selection of the compounds of the formula (1) and the compounds of the formula (2).

### DESCRIPTION OF THE INVENTION

The organic electroluminescent device of the invention is, for example, an organic light-emitting transistor (OLET), an organic field quench device (OFQD), an organic light-emitting electrochemical cell (OLEC, LEC, LEEC), an organic laser diode (O-laser) or an organic light-emitting diode (OLED). The organic electroluminescent device of the invention is especially an organic light-emitting diode or an organic light-emitting electrochemical cell. The device of the invention is more preferably an OLED.

The organic layer of the device of the invention that contains the light-emitting layer containing the material combination of at least one compound of the formula (1) and at least one compound of the formula (2) as described above or described hereinafter preferably comprises, in addition to this light-emitting layer (EML), a hole injection layer (HIL), a hole transport layer (HTL), an electron transport layer (ETL), an electron injection layer (EIL) and/or a hole blocker layer (HBL). It is also possible for the device of the invention to include multiple layers from this group selected from EML, HIL, HTL, ETL, EIL and HBL.

However, the device may also comprise inorganic materials or else layers formed entirely from inorganic materials.

It is preferable that the light-emitting layer containing at least one compound of the formula (1) and at least one compound of the formula (2) is a phosphorescent layer which is characterized in that it comprises, in addition to the host material combination of the compounds of the formula (1) and formula (2) as described above, at least one phosphorescent emitter. A suitable selection of emitters and preferred emitters is described hereinafter.

In the present patent application, “D” or “D atom” means deuterium.

An aryl group in the context of this invention contains 6 to 40 aromatic ring atoms, preferably carbon atoms. A heteroaryl group in the context of this invention contains 5 to 40 aromatic ring atoms, where the ring atoms include carbon atoms and at least one heteroatom, with the proviso that the sum total of carbon atoms and heteroatoms adds up to at least 5. The heteroatoms are preferably selected from N, O and/or S. An aryl group or heteroaryl group is understood here to mean either a simple aromatic cycle, i.e. phenyl, derived from benzene, or a simple heteroaromatic cycle, for example derived from pyridine, pyrimidine or thiophene, or a fused aryl or heteroaryl group, for example derived from naphthalene, anthracene, phenanthrene, quinoline or isoquinoline. An aryl group having 6 to 18 carbon atoms is therefore preferably phenyl, naphthyl, phenanthryl or triphenylenyl, with no restriction in the attachment of the aryl group as substituent. The aryl or heteroaryl group in the context of this invention may bear one or more R′ radicals, where the substituent R′ is described below.

An aromatic ring system in the context of this invention contains 6 to 40 carbon atoms in the ring system. The aromatic ring system also includes aryl groups as described above. An aromatic ring system having 6 to 18 carbon atoms is preferably selected from phenyl, fully deuterated phenyl, biphenyl, naphthyl, phenanthryl and triphenylenyl.

A heteroaromatic ring system in the context of this invention contains 5 to 40 ring atoms and at least one heteroatom. A preferred heteroaromatic ring system has 10 to 40 ring atoms and at least one heteroatom. The heteroaromatic ring system also includes heteroaryl groups as described above. The heteroatoms in the heteroaromatic ring system are preferably selected from N, O and/or S.

An aromatic or heteroaromatic ring system in the context of this invention is understood to mean a system which does not necessarily contain only aryl or heteroaryl groups, but in which it is also possible for a plurality of aryl or heteroaryl groups to be interrupted by a nonaromatic unit (preferably less than 10% of the atoms other than H), for example a carbon or oxygen atom or a carbonyl group. For example, systems such as 9,9′-spirobifluorene, 9,9-diarylfluorene, diaryl ethers, stilbene, etc. shall thus also be regarded as aromatic or heteroaromatic ring systems in the context of this invention, and likewise systems in which two or more aryl groups are interrupted, for example, by a linear or cyclic alkyl group or by a silyl group. In addition, systems in which two or more aryl or heteroaryl groups are bonded directly to one another, for example biphenyl, terphenyl, quaterphenyl or bipyridine, are likewise encompassed by the definition of the aromatic or heteroaromatic ring system.

An aromatic or heteroaromatic ring system which has 5-40 aromatic ring atoms and may be joined to the aromatic or heteroaromatic system via any desired positions is understood to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The abbreviation Ar₁ is the same or different at each instance and denotes an aromatic or heteroaromatic ring system which has 5 to 40 aromatic ring atoms and may be substituted by one or more nonaromatic R³ radicals; at the same time, two Ar₁ radicals bonded to the same nitrogen atom, phosphorus atom or boron atom may also be bridged to one another by a single bond or a bridge selected from C(R³)₂, O and S, where the R³ radical or the substituents R³ has/have a definition as described above or hereinafter. A preferred definition of Ar₁ is described hereinafter.

The abbreviation “aryl” is the same or different at each instance and denotes an aromatic or heteroaromatic ring system which has 5 to 40 aromatic ring atoms and may be substituted by one or more nonaromatic R′ radicals, where the R′ radical or the substituents R′ is/are defined as described above or hereinafter. A preferred definition of “aryl” is described hereinafter.

The abbreviation Ar₂ in each case independently at each instance denotes an aryl or heteroaryl group which has 5 to 40 aromatic ring atoms and may be substituted by one or more R′ radicals, where the R′ radical or the substituents R′ has/have a definition as described above or hereinafter. The details given for the aryl and heteroaryl groups having to 40 aromatic ring atoms apply here correspondingly.

The abbreviation Ar₃ in each case independently at each instance denotes an aromatic ring system having 6 to 40 aromatic ring atoms or a heteroaromatic ring system having 5 to 40 aromatic ring atoms, which may be substituted by one or more R′ radicals, where the R′ radical or the substituents R′ has/have a definition as described above or hereinafter. The details given for the aryl and heteroaryl groups having 5 to 40 aromatic ring atoms apply here correspondingly.

A cyclic alkyl, alkoxy or thioalkyl group in the context of this invention is understood to mean a monocyclic, bicyclic or polycyclic group.

In the context of the present invention, a straight-chain, branched or cyclic C₁- to C₂₀-alkyl group is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals.

A straight-chain or branched C₁- to C₂₀-alkoxy group is understood to mean, for example, methoxy, trifluoromethoxy, ethoxy, n-propoxy, i-propoxy, n-butoxy, i-butoxy, s-butoxy, t-butoxy or 2-methylbutoxy.

A straight-chain C₁- to C₂₀-thioalkyl group is understood to mean, for example, S-alkyl groups, for example thiomethyl, 1-thioethyl, 1-thio-i-propyl, 1-thio-n-propyl, 1-thio-i-butyl, 1-thio-n-butyl or 1-thio-t-butyl.

An aryloxy or heteroaryloxy group having 5 to 40 aromatic ring atoms means O-aryl or O-heteroaryl and means that the aryl or heteroaryl group is bonded via an oxygen atom, where the aryl or heteroaryl group is defined as described above.

A phosphorescent emitter in the context of the present invention is a compound that exhibits luminescence from an excited state with higher spin multiplicity, i.e. a spin state>1, especially from an excited triplet state. In the context of this application, all luminescent complexes with transition metals or lanthanides are to be regarded as phosphorescent emitters. A more exact definition is given hereinafter.

When the host materials of the light-emitting layer comprising at least one compound of the formula (1) as described above or described as preferred hereinafter and at least one compound of the formula (2) as described above or described hereinafter are used for a phosphorescent emitter, it is preferable when the triplet energy thereof is not significantly less than the triplet energy of the phosphorescent emitter. In respect of the triplet level, it is preferably the case that T₁ (emitter)−T₁ (matrix)≤0.2 eV, more preferably ≤0.15 eV, most preferably ≤0.1 eV. T₁ (matrix) here is the triplet level of the matrix material in the emission layer, this condition being applicable to each of the two matrix materials, and T₁ (emitter) is the triplet level of the phosphorescent emitter. If the emission layer contains more than two matrix materials, the abovementioned relationship is preferably also applicable to every further matrix material.

There follows a description of the host material 1 and its preferred embodiments that is/are present in the device of the invention. The preferred embodiments of the host material 1 of the formula (1) are also applicable to the mixture and/or formulation of the invention.

Preferred compounds of the formula (1) are the compounds (1A), (1B), (1C), (1D), (1E), (1F), (1G) and (1H):

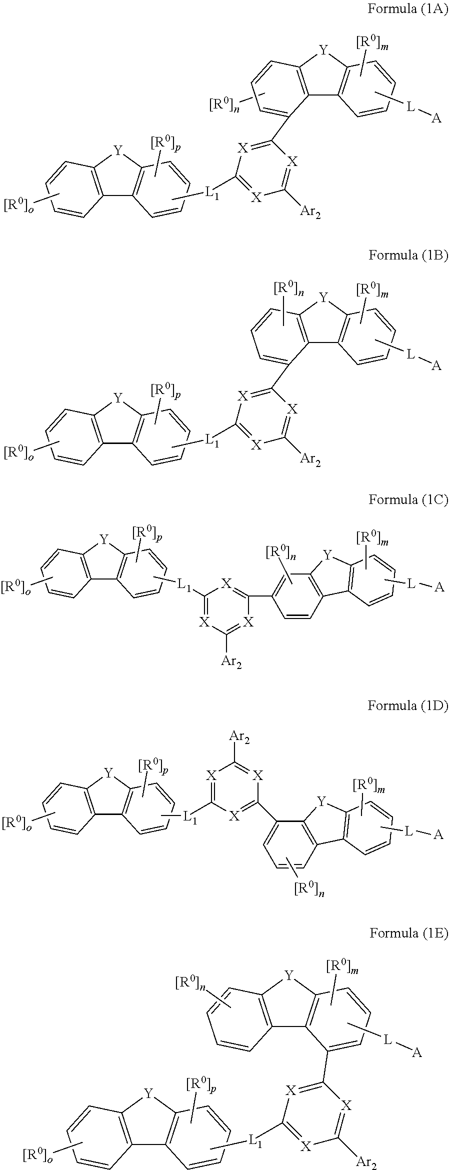

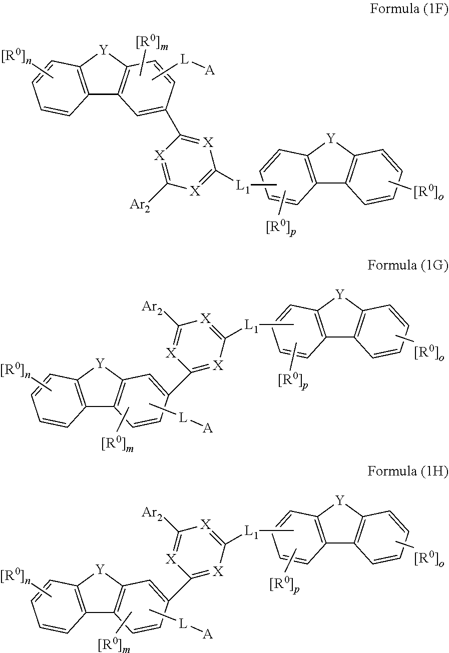

where A, L, L₁, Y, X, Ar₂, R⁰, n, m, o and p have a definition given above or a definition given with preference hereinafter.

In compounds of the formula (1) or preferred compounds of the formula (1) as described above, especially of the formula (1A), the symbol L as linker represents a single bond or an aromatic or heteroaromatic ring system having 5 to 30 aromatic ring atoms.

In compounds of the formula (1) or preferred compounds of the formula (1) as described above, especially of the formula (1A), the symbol L is preferably a bond or a linker selected from the group of L-1 to L-33:

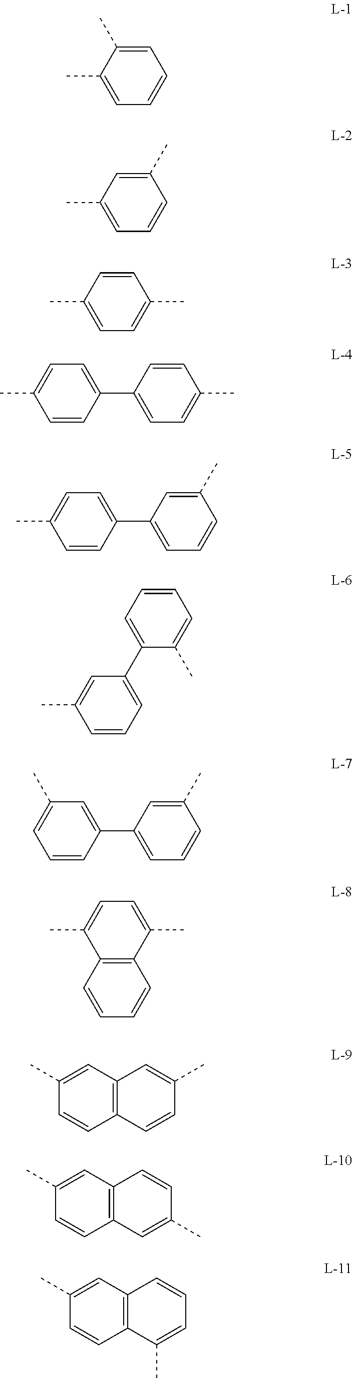

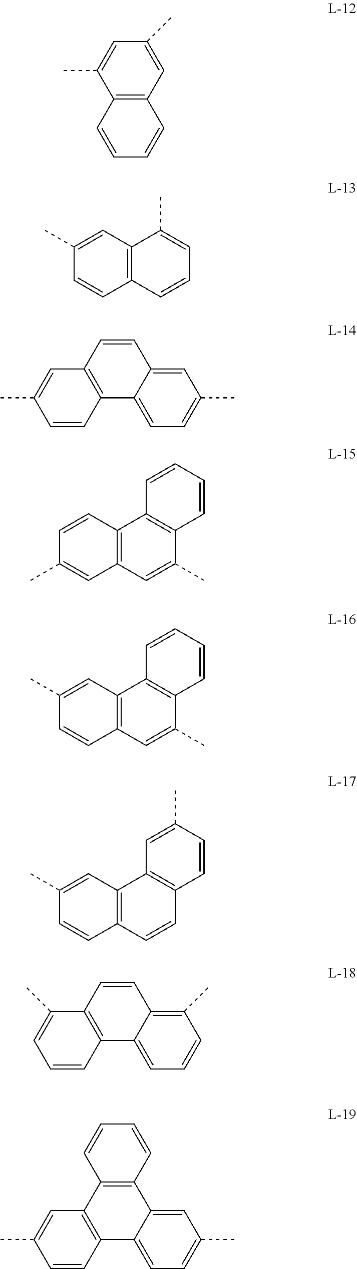

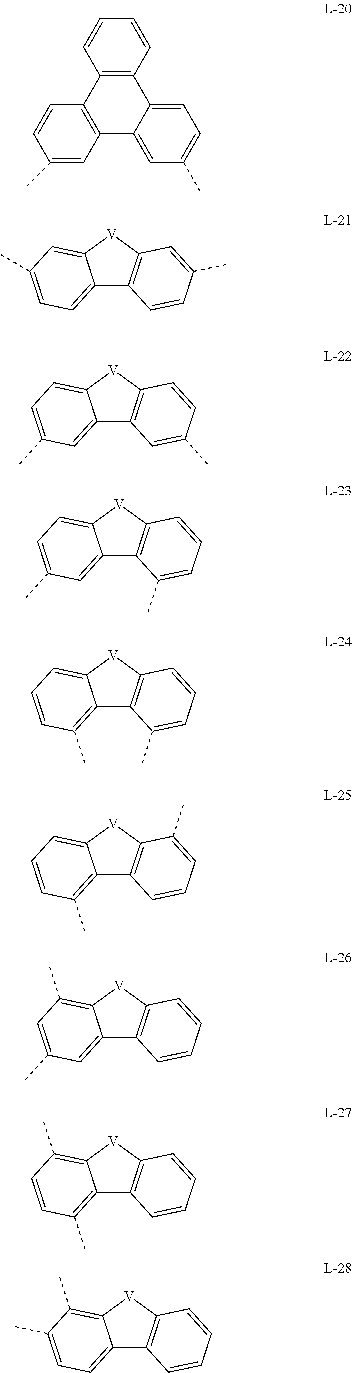

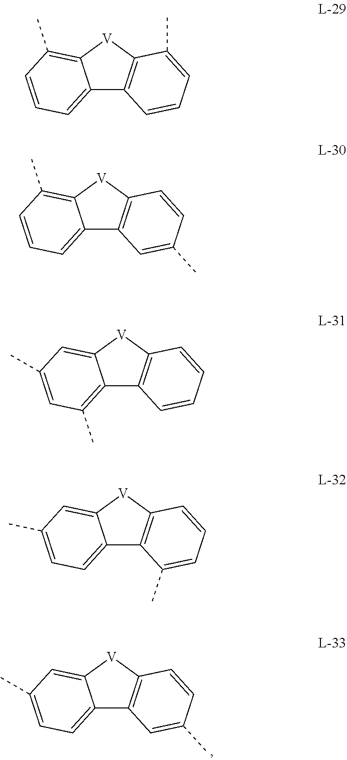

where V is in each case independently O or S.

The invention therefore further provides the electroluminescent device as described above, wherein the linker L in the host material 1 is selected from a bond and the linkers from the group of L-1 to L-33 as described above.

In compounds of the formula (1) or preferred compounds of the formula (1) as described above, especially of the formula (1A), the symbol L in one embodiment is more preferably a bond or a linker selected from L-1 to L-3, L-7, L-21, L-22, L-23, L-25 to L-27 and L-30 to L-33, where V is in each case independently O or S. V is more preferably O. In compounds of the formula (1), the symbol L in a further embodiment is more preferably a bond or a linker selected from L-2 to L-20, preferably L-2 and L-3. L is most preferably a single bond.

Compounds of the formula (1A) in which L is preferably a single bond can be described by the formula (1a):

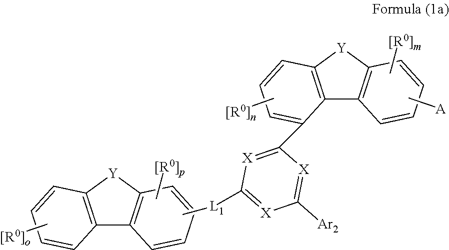

where Y, A, L₁, X, Ar₂, R⁰, n, m, o and p have a definition given above or definition given with preference hereinafter.

In compounds of the formula (1) or preferred compounds of the formula (1) as described above, especially of the formula (1A), the symbol L₁ as linker represents a single bond or an aromatic or heteroaromatic ring system having 5 to 30 aromatic ring atoms.

In compounds of the formula (1) or preferred compounds of the formula (1) as described above, especially of the formula (1A), the symbol L₁ preferably represents a single bond or a linker selected from the group of L-1 to L-33 as described above. In compounds of the formula (1) or preferred compounds of the formula (1) as described above, especially in compounds of the formula (1A) or (1a), the symbol L₁ is preferably a single bond or a linker L-2 or L-3 as described above, or more preferably a single bond.

Compounds of the formula (1A) in which L₁ is preferably a single bond can be described by the formula (1b):

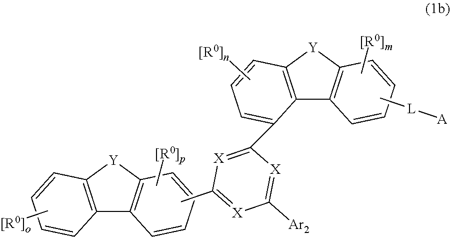

where Y, A, L, X, Ar₂, R⁰, n, m, o and p have a definition given above or definition given with preference hereinafter.

The invention therefore further provides an electroluminescent device as described above, wherein L₁ in the host material 1 is a single bond.

In a preferred embodiment of the invention, in compounds of the formulae (1), (1A), (1B), (1C), (1D), (1E), (1F), (1G), (1H), (1a) and (1b) or preferred embodiments of the host material of the formulae (1), (1A), (1B), (1C), (1D), (1E), (1F), (1G), (1H), (1a) and (1b) as described above or hereinafter, the abbreviation A is

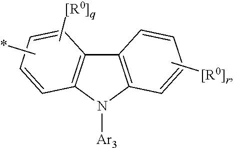

where Ar₃, R⁰, q and r and the identifier * have a definition given above or definition given with preference hereinafter.

In a particularly preferred embodiment of the invention, in compounds of the formulae (1), (1A), (1B), (1C), (1D), (1E), (1F), (1G), (1H), (1a) and (1b) or preferred embodiments of the host material of the formulae (1), (1A), (1B), (1C), (1D), (1E), (1F), (1G), (1H), (1a) and (1b) as described above or hereinafter, the abbreviation A is

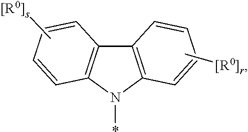

where R⁰, s and r and the identifier * have a definition given above or definition given with preference hereinafter.

In compounds of the formulae (1), (1A), (1B), (1C), (1D), (1E), (1F), (1G), (1H), (1a) and (1b) or preferred embodiments of the host material of the formulae (1), (1A), (1B), (1C), (1D), (1E), (1F), (1G), (1H), (1a) and (1b), the symbol X is CR⁰ or N, where at least one X group is N.

The substituent

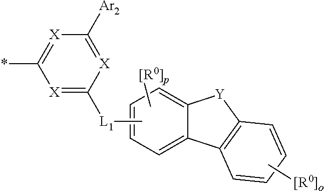

therefore has the following definitions, where * indicates the bonding site to the dibenzofuran or dibenzothiophene and L₁, R⁰, o, p, Y and Ar₂ have a definition given above or a definition given as preferred:

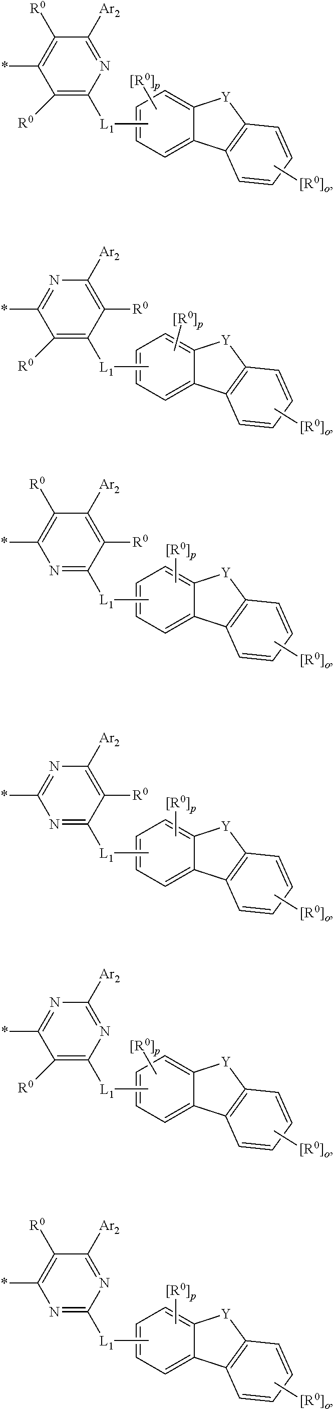

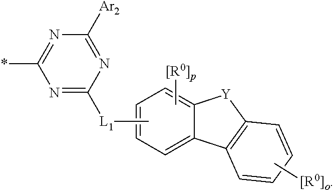

In these aforementioned substituents, Y is preferably O.

In host material 1, X is preferably N at two instances and one X is CR⁰, or all X are N. In host material 1, all X are more preferably N, where R⁰ has a definition given above or given hereinafter.

Preferred host materials 1 accordingly correspond to the compounds of the formulae (1), (1A), (18), (1C), (1D), (1E), (1F), (1G), (1H), (1a), (1b), (1c), (1d), (1e) and (1f):

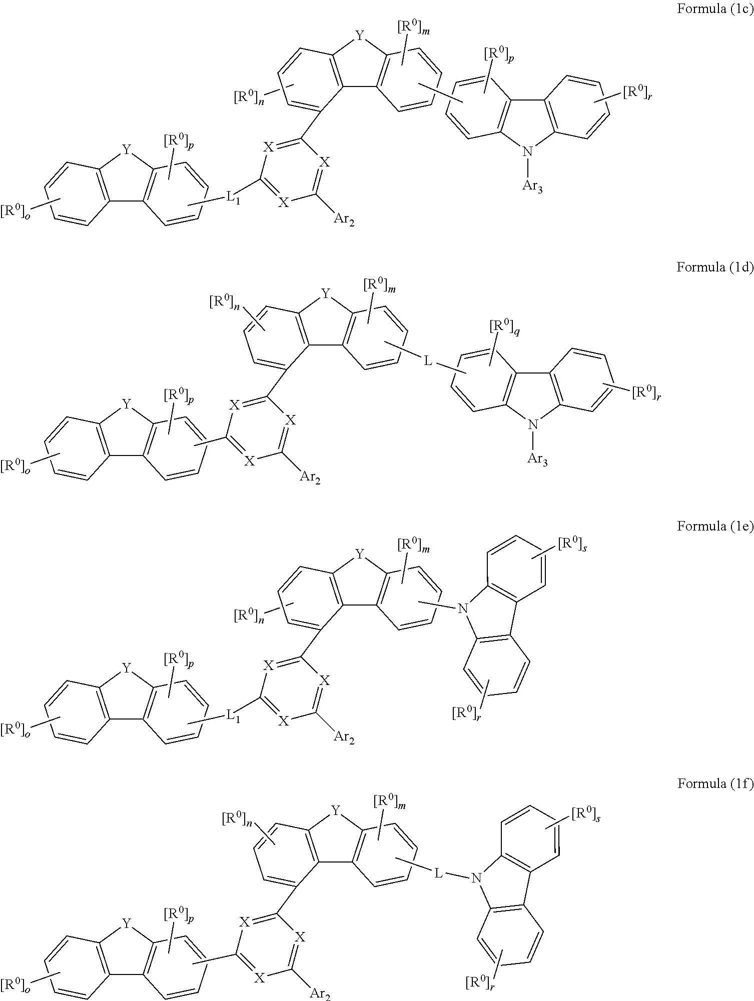

where Y, L, L₁, X, X₁, Ar₂, R⁰, Ar₃, o, p, n, m, q, r and s have a definition given above or definition given with preference above or hereinafter. In compounds of the formulae (1), (1A), (1B), (1C), (1D), (1E), (1F), (1G), (1H), (1a), (1b), (1c), (1d), (1e) and (1f), all X are preferably N. Compounds of the formulae (1e) and (1f) are particularly preferred.

R⁰ at each instance is independently D, an unsubstituted or partly or fully deuterated aromatic ring system having 6 to 18 carbon atoms or an unsubstituted or partly or fully deuterated dibenzofuran, dibenzothiophene, or C-bonded N-arylcarbazole, where “aryl” has a definition given above or hereinafter.

R⁰ at each instance is preferably D or an unsubstituted or partly or fully deuterated aromatic ring system having 6 to 18 carbon atoms. R⁰ at each instance is more preferably D.

In the C-bonded N-arylcarbazole, “aryl” preferably denotes an aromatic ring system having 6 to 30 aromatic ring atoms or a heteroaromatic ring system which has 5 to 30 aromatic ring atoms and may be substituted by one or more R′ radicals. More preferably, “aryl” is unsubstituted, partly deuterated, singly substituted by a substituent R′ other than H and D, or fully deuterated and is selected from the preferred Ar-1 to Ar-12 groups as described hereinafter, where R′ has a definition specified above or specified with preference hereinafter.

More preferably, “aryl” in the C-bonded N-arylcarbazole is Ar-1 to Ar-4, where R′ has a definition specified above or specified with preference hereinafter.

In compounds of the formulae (1), (1A), (1B), (1C), (1D), (1E), (1F), (1G), (1H), (1a), (1b), (1c), (1d), (1e) and (1f), o is preferably 4 when R⁰ is D. When R⁰ has a different definition than D, as described above, o is preferably 1 or 2, more preferably 1. In a preferred embodiment in which o is 4, three substituents R⁰ are preferably D and one substituent R⁰ is an unsubstituted or partly or fully deuterated aromatic ring system having 6 to 18 carbon atoms.

In a further embodiment of the invention, o is preferably 0.

In a further embodiment of the invention, o is preferably 1, 2 or 3, where R⁰ has a definition specified above or specified as preferred.

In compounds of the formulae (1), (1A), (1B), (1C), (1D), (1E), (1F), (1G), (1H), (1a), (1b), (1c), (1d), (1e) and (1f), p is preferably 3 when R⁰ is D. When R⁰ has a different definition than D, as described above, p is preferably 1. In a preferred embodiment in which p is 3, two substituents R⁰ are preferably D and one substituent R⁰ is an unsubstituted or partly or fully deuterated aromatic ring system having 6 to 18 carbon atoms.

In a further embodiment of the invention, p is preferably 0.

In a further embodiment of the invention, p is preferably 1 or 2, where R⁰ has a definition specified above or specified as preferred.

In compounds of the formulae (1), (1A), (1B), (1C), (1D), (1E), (1F), (1G), (1H), (1a), (1b), (1c), (1d), (1e) and (1f), m is preferably 3 when R⁰ is D. When R⁰ has a different definition than D, as described above, m is preferably 1. In a preferred embodiment in which m is 3, two substituents R⁰ are preferably D and one substituent R⁰ is an unsubstituted or partly or fully deuterated aromatic ring system having 6 to 18 carbon atoms.

In a further embodiment of the invention, m is preferably 0.

In a further embodiment of the invention, m is preferably 1 or 2, where R⁰ has a definition specified above or specified as preferred.

In compounds of the formulae (1), (1A), (1B), (1C), (1D), (1E), (1F), (1G), (1H), (1a), (1b), (1c), (1d), (1e) and (1f), n is preferably 3 when R⁰ is D. When R⁰ has a different definition than D, as described above, n is preferably 1. In a preferred embodiment in which n is 3, two substituents R⁰ are preferably D and one substituent R⁰ is an unsubstituted or partly or fully deuterated aromatic ring system having 6 to 18 carbon atoms.

In a further embodiment of the invention, n is preferably 0.

In a further embodiment of the invention, n is preferably 1 or 2, where R⁰ has a definition specified above or specified as preferred.

In compounds of the formulae (1), (1A), (1B), (1C), (1D), (1E), (1F), (1G), (1H), (1a), (1b), (1c) and (1d), q is preferably 3 when R⁰ is D. When R⁰ has a different definition than D, as described above, q is preferably 1. In a preferred embodiment in which q is 3, two substituents R⁰ are preferably D and one substituent R⁰ is an unsubstituted or partly or fully deuterated aromatic ring system having 6 to 18 carbon atoms or an unsubstituted or partly or fully deuterated dibenzofuran, dibenzothiophene, or C-bonded N-arylcarbazole, where “aryl” has a definition given above.

In a further embodiment of the invention, q is preferably 0.

In a further embodiment of the invention, q is preferably 1 or 2, where R⁰ has a definition specified above or specified as preferred.

In compounds of the formulae (1), (1A), (1B), (1C), (1D), (1E), (1F), (1G), (1H), (1a), (1b), (1c), (1d), (1e) and (1f), r is preferably 4 when R⁰ is D. When R⁰ has a different definition than D, as described above, r is preferably 1. In a preferred embodiment in which r is 4, three substituents R⁰ are preferably D and one substituent R⁰ is an unsubstituted or partly or fully deuterated aromatic ring system having 6 to 18 carbon atoms or an unsubstituted or partly or fully deuterated dibenzofuran, dibenzothiophene, or C-bonded N-arylcarbazole, where “aryl” has a definition given above.

In a further embodiment of the invention, r is preferably 0.

In a further embodiment of the invention, r is preferably 1, 2 or 3, where R⁰ has a definition specified above or specified as preferred.

In compounds of the formulae (1), (1A), (1B), (1C), (1D), (1E), (1F), (1G), (1H), (1a), (1b), (1e) and (1f), s is preferably 4 when R⁰ is D. When R⁰ has a different definition than D, as described above, s is preferably 1. In a preferred embodiment in which r is 4, three substituents R⁰ are preferably D and one substituent R⁰ is an unsubstituted or partly or fully deuterated aromatic ring system having 6 to 18 carbon atoms or an unsubstituted or partly or fully deuterated dibenzofuran, dibenzothiophene, or C-bonded N-arylcarbazole, where “aryl” has a definition given above.

In a further embodiment of the invention, s is preferably 0.

In a further embodiment of the invention, s is preferably 1, 2 or 3, where R⁰ has a definition specified above or specified as preferred.

In compounds of the formulae (1), (1A), (1B), (1C), (1D), (1E), (1F), (1G), (1H), (1a), (1b), (1c), (1d), (1e) and (1f), the sum of o+p+m+n is preferably 0, 1, 2 or 3, more preferably 0, 1 or 2. In a preferred embodiment, the sum of o+p+m+n+q+r is 20 and the substituents R⁰ are each D.

In a further embodiment of the invention, the sum of o+p+m+n+q+r is preferably 0, 1, 2 or 3, preferably 0 or 3.

In a preferred embodiment, the sum of o+p+m+n+r+s is 21 and the substituents R⁰ are each D.

In a further embodiment of the invention, the sum of o+p+m+n+r+s is preferably 0, 1, 2 or 3, preferably 0 or 3.

In compounds of the formulae (1), (1A), (1B), (1C), (1D), (1E), (1F), (1G), (1H), (1a), (1b), (1c), (1d), (1e) and (1f), both symbols Y are preferably O.

In compounds of the formulae (1), (1A), (1B), (1C), (1D), (1E), (1F), (1G), (1H), (1a), (1b), (1c), (1d), (1e) and (1f), or compounds of the formulae (1), (1A), (1B), (1C), (1D), (1E), (1F), (1G), (1H), (1a), (1b), (1c), (1d), (1e) and (1f) that are described as preferred, each Ar₂ is preferably independently an aryl group having 6 to 40 aromatic ring atoms, as described above or described as preferred, which may be substituted by one or more R′ radicals, or is a heteroaryl group having 10 to 40 aromatic ring atoms, as described above, which may be substituted by one or more R′ radicals. It is possible here for two or more R′ radicals bonded to the same carbon atom or to adjacent carbon atoms to form a monocyclic or polycyclic, aliphatic, aromatic or heteroaromatic ring system which may be substituted by one or more R³ radicals. The linkage of the aryl group or heteroaryl group is not limited here, and may be via a carbon atom or via a heteroatom, for example a nitrogen atom.

Ar₂ may preferably be selected from the following groups Ar-1 to Ar-17, where R′ and Ar₁ have a definition specified above or specified as preferred, and wherein direct linkage of two heteroatoms to one another by R′ or Ar₁ is ruled out:

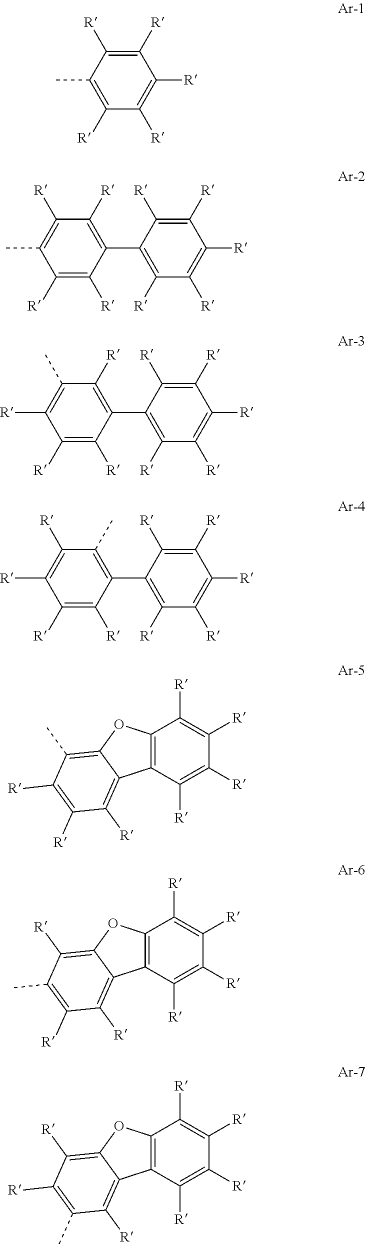

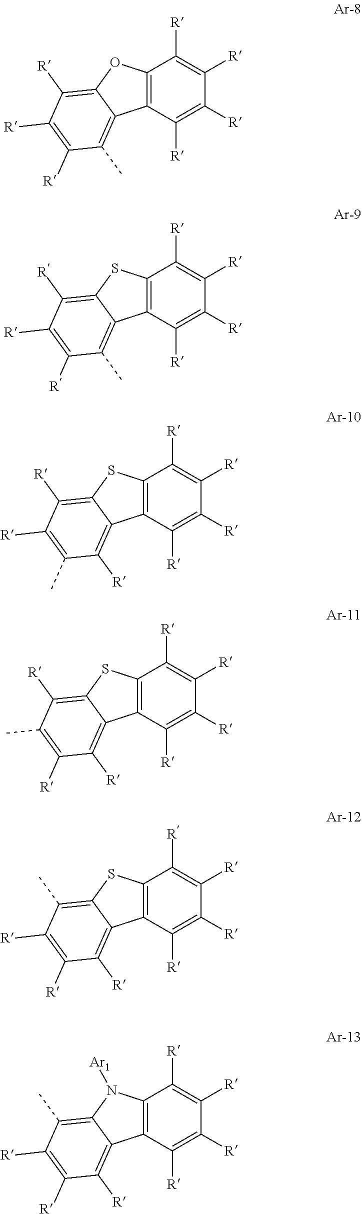

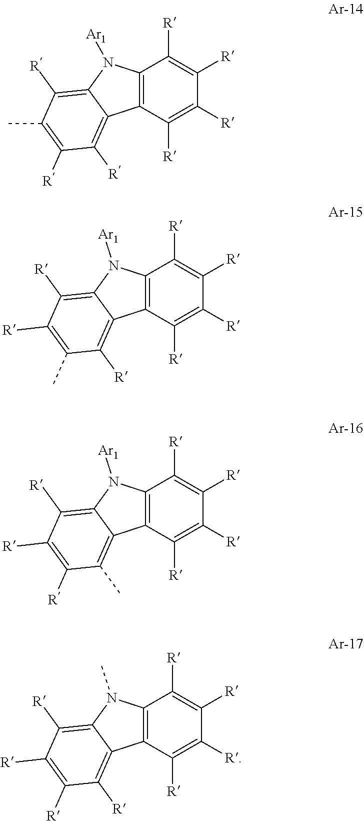

The dotted line indicates the bonding site to the rest of the formulae (1), (1A), (1B), (1C), (1D), (1E), (1F), (1G), (1H), (1a), (1b), (1c), (1d), (1e) and (1f).

More preferably, Ar₂ is Ar-1, Ar-5, Ar-6, Ar-9, Ar-17, more preferably Ar-1, where R′ has a definition specified above or specified with preference hereinafter.

R′ in substituents of the formulae Ar-1 to Ar-17 as described above is preferably selected from the group of H, D, CN, and an aromatic or heteroaromatic ring system which has 5 to 40 aromatic ring atoms and may be substituted in each case by one or more R³ radicals. Ar₁ in substituents of the formulae Ar-13 to Ar-16 as described above is preferably phenyl or deuterated phenyl.

More preferably, Ar₂ is unsubstituted, partly deuterated, singly substituted by a substituent R′ other than H and D, or fully deuterated.

The linkage of the dibenzofuran or dibenzothiophene group bonded via the linker L₁ in the compounds of the formulae (1), (1A), (1B), (1C), (1D), (1E), (1F), (1G), (1H), (1a), (1b), (1c), (1d), (1e) and (1f) or preferred compounds of the formulae (1), (1A), (1B), (1C), (1D), (1E), (1F), (1G), (1H), (1a), (1b), (1c), (1d), (1e) and (1f) is not limited here and may be via any carbon atom. More preferably, the dibenzofuran or dibenzothiophene group in position 2, 3 or 4 is bonded via the linker L₁ to the rest of the formulae (1), (1A), (1B), (1C), (1D), (1E), (1F), (1G), (1H), (1a), (1b), (1c), (1d), (1e) and (1f). Most preferably, the dibenzofuran or dibenzothiophene group in position 3 is bonded via the linker L₁ to the rest of the formulae (1), (1A), (1B), (1C), (1D), (1E), (1F), (1G), (1H), (1a), (1b), (1c), (1d), (1e) and (1f).

In compounds of the formulae (1), (1A), (1B), (1C), (1D), (1E), (1F), (1G), (1H), (1a), (1b), (1c) and (1d), or compounds of the formulae (1), (1A), (1B), (1C), (1D), (1E), (1F), (1G), (1H), (1a), (1b), (1c) and (1d) that are described as preferred, each Ar₃ is preferably independently an aryl group having 6 to 40 aromatic ring atoms, as described above or described as preferred, which may be substituted by one or more R′ radicals, or is a heteroaryl group having 10 to 40 aromatic ring atoms, as described above, which may be substituted by one or more R′ radicals.

In compounds of the formulae (1), (1A), (1B), (1C), (1D), (1E), (1F), (1G), (1H), (1a), (1b), (1c) and (1d), or compounds of the formulae (1), (1A), (1B), (1C), (1D), (1E), (1F), (1G), (1H), (1a), (1b), (1c) and (1d) that are described as preferred, each Ar₃ is preferably independently an aryl group having 6 to 18 aromatic ring atoms, as described above or described as preferred, which may be substituted by one or more R′ radicals, or is a heteroaryl group having 10 to 40 carbon atoms and containing an oxygen atom or a sulfur atom, as described above, which may be substituted by one or more R′ radicals.

The linkage of the aryl group or the heteroaryl group is not limited here, but is preferably via a carbon atom.

More preferably, Ar₃ is unsubstituted, partly deuterated, singly substituted by a substituent R′ other than H and D, or fully deuterated and is selected from the preferred Ar-1 to Ar-12 groups, where R′ has a definition specified above or specified with preference hereinafter. More preferably, Ar₃ is Ar-1 to Ar-4, where R′ has a definition specified above or specified as preferred hereinafter.

R′ in substituents of the formulae Ar-1 to Ar-12 for Ar₃ as described above is preferably selected from the group of H, D, CN, and an aromatic or heteroaromatic ring system which has 5 to 40 aromatic ring atoms and may be substituted in each case by one or more R³ radicals. More preferably, Ar₃ is unsubstituted and partly or fully deuterated.

R³ in compounds of the formulae (1), (1A), (1B), (1C), (1D), (1E), (1F), (1G), (1H), (1a), (1b), (1c), (1d), (1e) and (1f) as described above or described as preferred is preferably selected independently at each instance from the group of H, CN, an aromatic or heteroaromatic ring system having 5 to 40 aromatic ring atoms in which one or more hydrogen atoms may be replaced by D or CN. R³ in compounds of the formulae (1), (1A), (1B), (1C), (1D), (1E), (1F), (1G), (1H), (1a), (1b), (1c), (1d), (1e) and (1f) as described above or described as preferred is more preferably selected independently at each instance from H, D, phenyl and deuterated phenyl.

Examples of suitable host materials of the formulae (1), (1A), (1B), (1C), (1D), (1E), (1F), (1G), (1H), (1a), (1b), (1c), (1d), (1e) and (1f) that are selected in accordance with the invention and are preferably used in combination with at least one compound of the formula (2) in the electroluminescent device of the invention are the structures given below in table 1.

TABLE 1

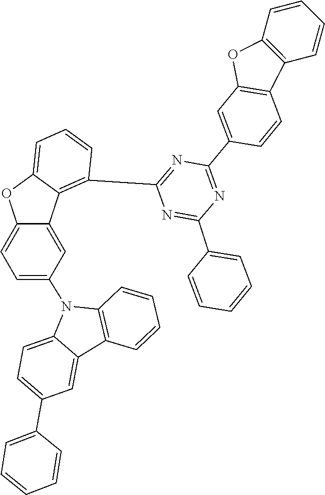 [SMILES: c1ccc(-c2ccc3c(c2)c2ccccc2n3-c2ccc3oc4cccc(-c5nc(-c6ccccc6)nc(-c6ccc7c(c6)oc6ccccc67)n5)c4c3c2)cc1]

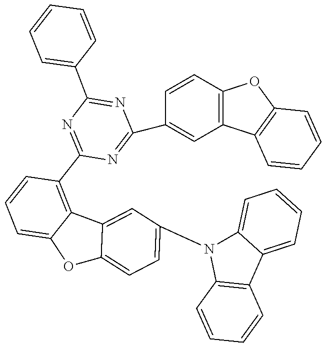 [SMILES: c1ccc(-c2nc(-c3ccc4oc5ccccc5c4c3)nc(-c3cccc4oc5ccc(-n6c7ccccc7c7ccccc76)cc5c34)n2)cc1]

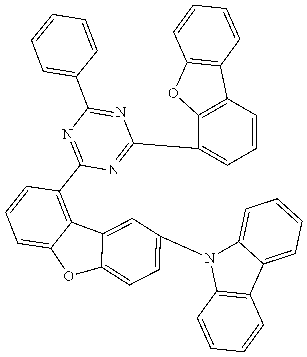 [SMILES: c1ccc(-c2nc(-c3cccc4c3oc3ccccc34)nc(-c3cccc4oc5ccc(-n6c7ccccc7c7ccccc76)cc5c34)n2)cc1]

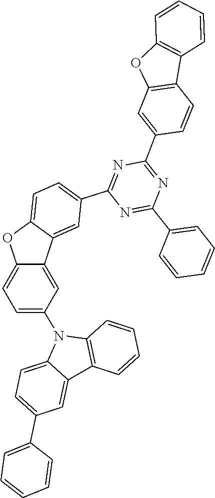 [SMILES: c1ccc(-c2ccc3c(c2)c2ccccc2n3-c2ccc3oc4ccc(-c5nc(-c6ccccc6)nc(-c6ccc7c(c6)oc6ccccc67)n5)cc4c3c2)cc1]

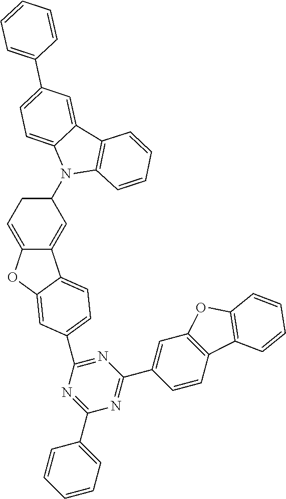 [SMILES: C1=c2oc3cc(-c4nc(-c5ccccc5)nc(-c5ccc6c(c5)oc5ccccc56)n4)ccc3c2=CC(n2c3ccccc3c3cc(-c4ccccc4)ccc32)C1]

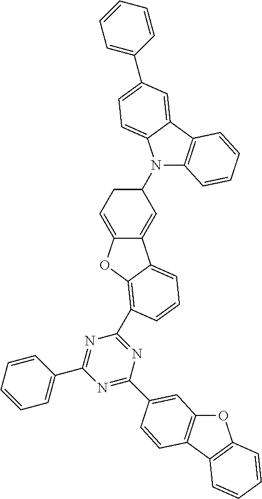 [SMILES: C1=c2oc3c(-c4nc(-c5ccccc5)nc(-c5ccc6c(c5)oc5ccccc56)n4)cccc3c2=CC(n2c3ccccc3c3cc(-c4ccccc4)ccc32)C1]

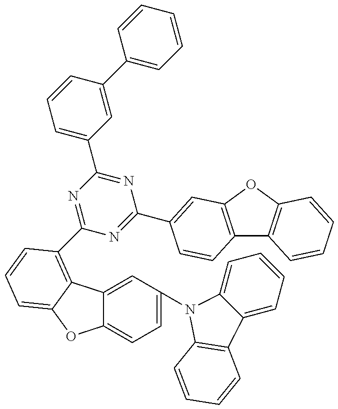 [SMILES: c1ccc(-c2cccc(-c3nc(-c4ccc5c(c4)oc4ccccc45)nc(-c4cccc5oc6ccc(-n7c8ccccc8c8ccccc87)cc6c45)n3)c2)cc1]

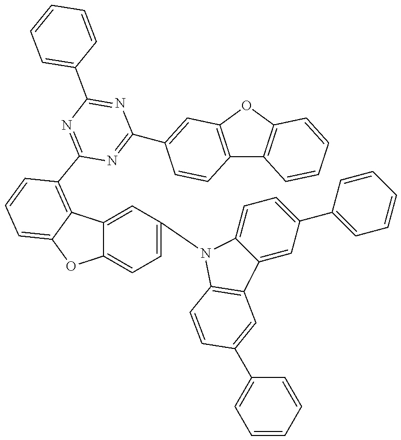 [SMILES: c1ccc(-c2ccc3c(c2)c2cc(-c4ccccc4)ccc2n3-c2ccc3oc4cccc(-c5nc(-c6ccccc6)nc(-c6ccc7c(c6)oc6ccccc67)n5)c4c3c2)cc1]

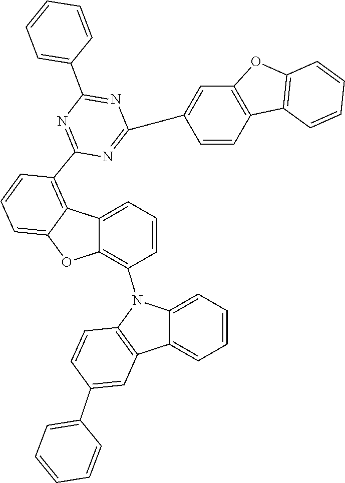 [SMILES: c1ccc(-c2ccc3c(c2)c2ccccc2n3-c2cccc3c2oc2cccc(-c4nc(-c5ccccc5)nc(-c5ccc6c(c5)oc5ccccc56)n4)c23)cc1]

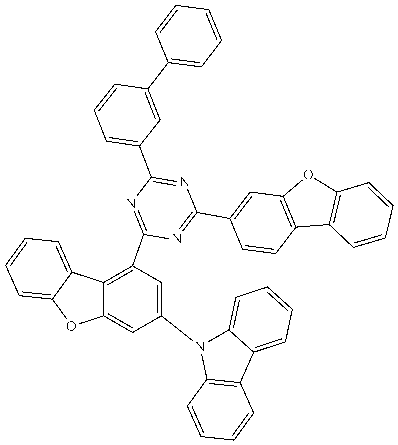 [SMILES: c1ccc(-c2cccc(-c3nc(-c4ccc5c(c4)oc4ccccc45)nc(-c4cc(-n5c6ccccc6c6ccccc65)cc5oc6ccccc6c45)n3)c2)cc1]

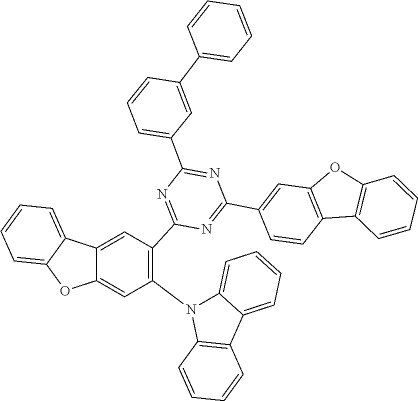 [SMILES: c1ccc(-c2cccc(-c3nc(-c4ccc5c(c4)oc4ccccc45)nc(-c4cc5c(cc4-n4c6ccccc6c6ccccc64)oc4ccccc45)n3)c2)cc1]

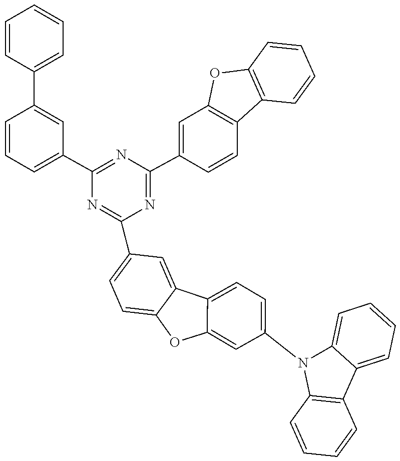 [SMILES: c1ccc(-c2cccc(-c3nc(-c4ccc5c(c4)oc4ccccc45)nc(-c4ccc5oc6cc(-n7c8ccccc8c8ccccc87)ccc6c5c4)n3)c2)cc1]

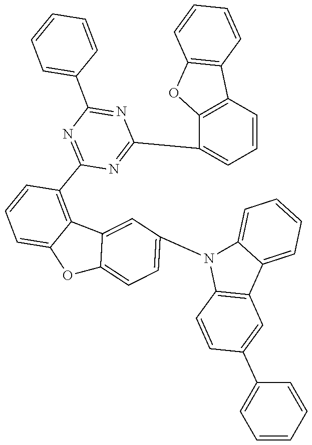 [SMILES: c1ccc(-c2ccc3c(c2)c2ccccc2n3-c2ccc3oc4cccc(-c5nc(-c6ccccc6)nc(-c6cccc7c6oc6ccccc67)n5)c4c3c2)cc1]

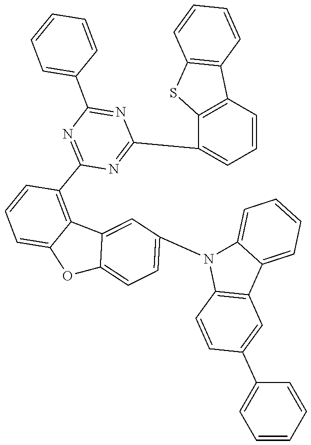 [SMILES: c1ccc(-c2ccc3c(c2)c2ccccc2n3-c2ccc3oc4cccc(-c5nc(-c6ccccc6)nc(-c6cccc7c6sc6ccccc67)n5)c4c3c2)cc1]

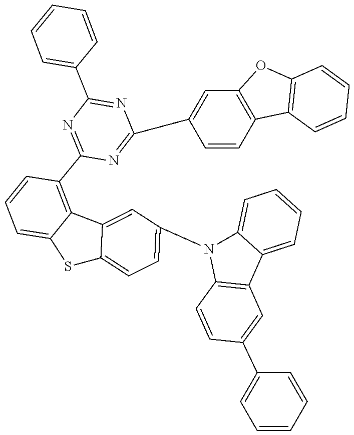 [SMILES: c1ccc(-c2ccc3c(c2)c2ccccc2n3-c2ccc3sc4cccc(-c5nc(-c6ccccc6)nc(-c6ccc7c(c6)oc6ccccc67)n5)c4c3c2)cc1]

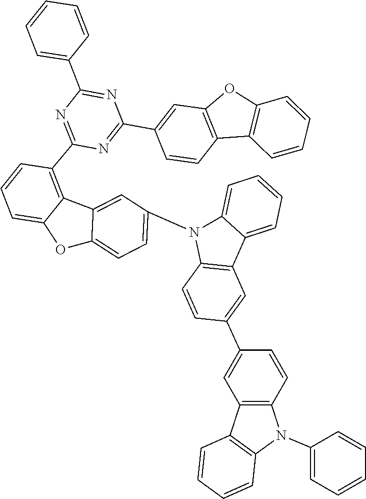 [SMILES: c1ccc(-c2nc(-c3ccc4c(c3)oc3ccccc34)nc(-c3cccc4oc5ccc(-n6c7ccccc7c7cc(-c8ccc9c(c8)c8ccccc8n9-c8ccccc8)ccc76)cc5c34)n2)cc1]

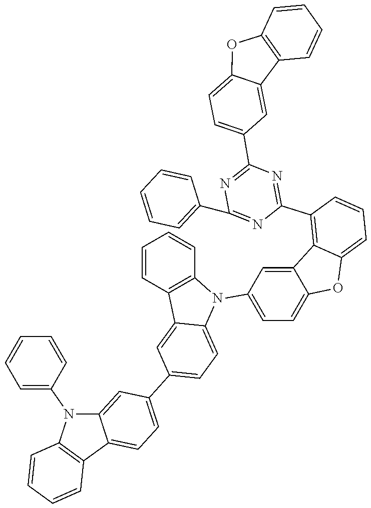 [SMILES: c1ccc(-c2nc(-c3ccc4oc5ccccc5c4c3)nc(-c3cccc4oc5ccc(-n6c7ccccc7c7cc(-c8ccc9c%10ccccc%10n(-c%10ccccc%10)c9c8)ccc76)cc5c34)n2)cc1]

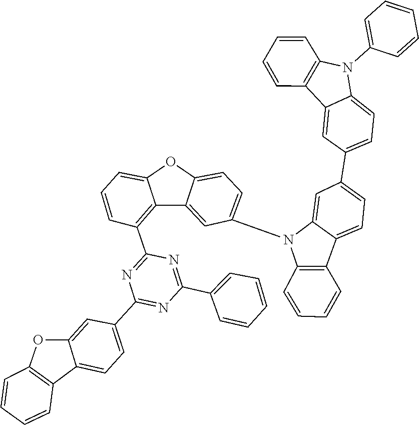 [SMILES: c1ccc(-c2nc(-c3ccc4c(c3)oc3ccccc34)nc(-c3cccc4oc5ccc(-n6c7ccccc7c7ccc(-c8ccc9c(c8)c8ccccc8n9-c8ccccc8)cc76)cc5c34)n2)cc1]

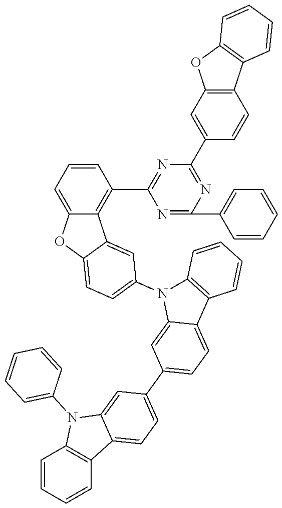 [SMILES: c1ccc(-c2nc(-c3ccc4c(c3)oc3ccccc34)nc(-c3cccc4oc5ccc(-n6c7ccccc7c7ccc(-c8ccc9c%10ccccc%10n(-c%10ccccc%10)c9c8)cc76)cc5c34)n2)cc1]

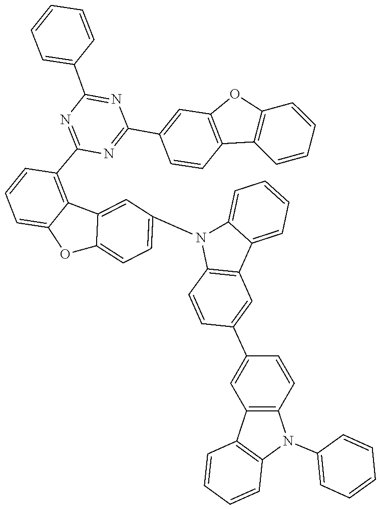 [SMILES: c1ccc(-c2nc(-c3ccc4c(c3)oc3ccccc34)nc(-c3cccc4oc5ccc(-n6c7ccccc7c7cc(-c8ccc9c(c8)c8ccccc8n9-c8ccccc8)ccc76)cc5c34)n2)cc1]

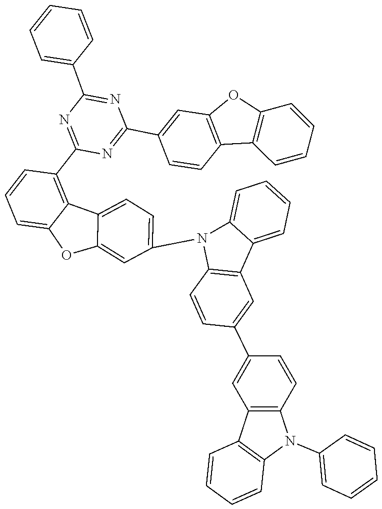 [SMILES: c1ccc(-c2nc(-c3ccc4c(c3)oc3ccccc34)nc(-c3cccc4oc5cc(-n6c7ccccc7c7cc(-c8ccc9c(c8)c8ccccc8n9-c8ccccc8)ccc76)ccc5c34)n2)cc1]

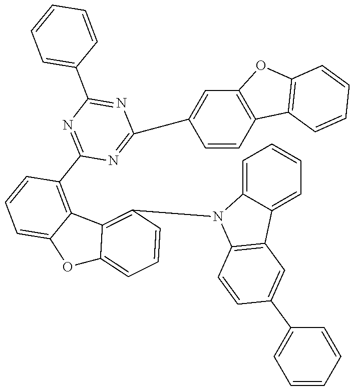 [SMILES: c1ccc(-c2ccc3c(c2)c2ccccc2n3-c2cccc3oc4cccc(-c5nc(-c6ccccc6)nc(-c6ccc7c(c6)oc6ccccc67)n5)c4c23)cc1]

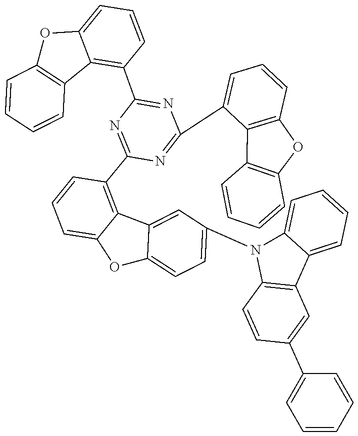 [SMILES: c1ccc(-c2ccc3c(c2)c2ccccc2n3-c2ccc3oc4cccc(-c5nc(-c6cccc7oc8ccccc8c67)nc(-c6cccc7oc8ccccc8c67)n5)c4c3c2)cc1]

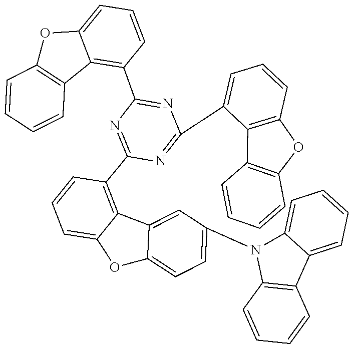 [SMILES: c1ccc2c(c1)oc1cccc(-c3nc(-c4cccc5oc6ccccc6c45)nc(-c4cccc5oc6ccc(-n7c8ccccc8c8ccccc87)cc6c45)n3)c12]

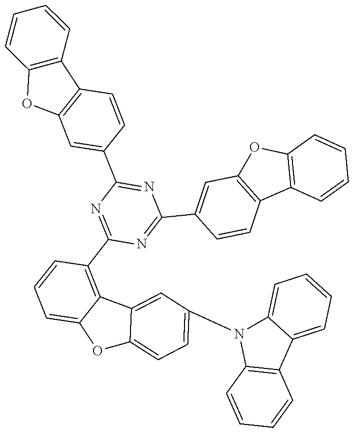 [SMILES: c1ccc2c(c1)oc1cc(-c3nc(-c4ccc5c(c4)oc4ccccc45)nc(-c4cccc5oc6ccc(-n7c8ccccc8c8ccccc87)cc6c45)n3)ccc12]

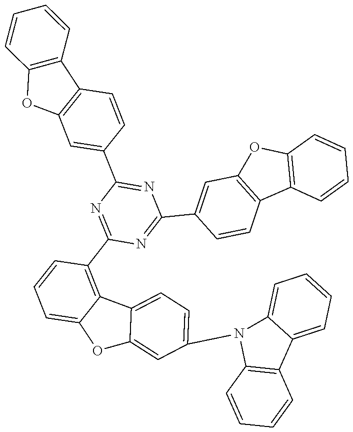 [SMILES: c1ccc2c(c1)oc1cc(-c3nc(-c4ccc5c(c4)oc4ccccc45)nc(-c4cccc5oc6cc(-n7c8ccccc8c8ccccc87)ccc6c45)n3)ccc12]

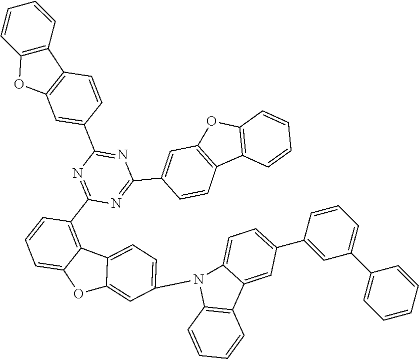 [SMILES: c1ccc(-c2cccc(-c3ccc4c(c3)c3ccccc3n4-c3ccc4c(c3)oc3cccc(-c5nc(-c6ccc7c(c6)oc6ccccc67)nc(-c6ccc7c(c6)oc6ccccc67)n5)c34)c2)cc1]

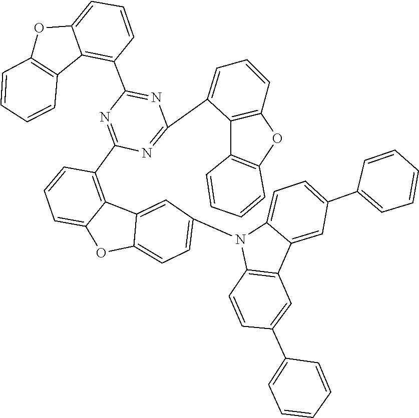 [SMILES: c1ccc(-c2ccc3c(c2)c2cc(-c4ccccc4)ccc2n3-c2ccc3oc4cccc(-c5nc(-c6cccc7oc8ccccc8c67)nc(-c6cccc7oc8ccccc8c67)n5)c4c3c2)cc1]

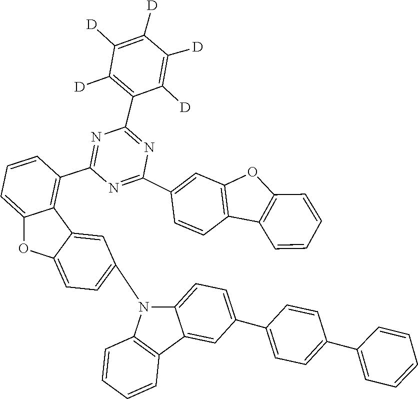 [SMILES: [2H]c1c([2H])c([2H])c(-c2nc(-c3ccc4c(c3)oc3ccccc34)nc(-c3cccc4oc5ccc(-n6c7ccccc7c7cc(-c8ccc(-c9ccccc9)cc8)ccc76)cc5c34)n2)c([2H])c1[2H]]

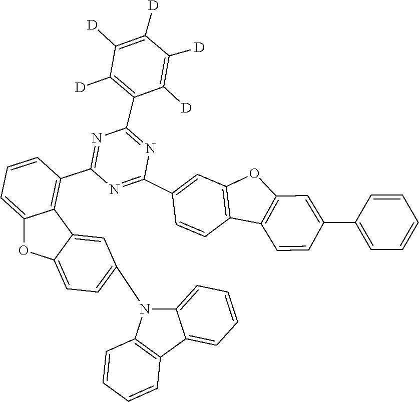 [SMILES: [2H]c1c([2H])c([2H])c(-c2nc(-c3ccc4c(c3)oc3cc(-c5ccccc5)ccc34)nc(-c3cccc4oc5ccc(-n6c7ccccc7c7ccccc76)cc5c34)n2)c([2H])c1[2H]]

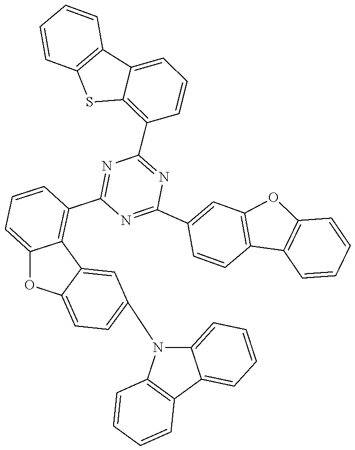 [SMILES: c1ccc2c(c1)oc1cc(-c3nc(-c4cccc5c4sc4ccccc45)nc(-c4cccc5oc6ccc(-n7c8ccccc8c8ccccc87)cc6c45)n3)ccc12]

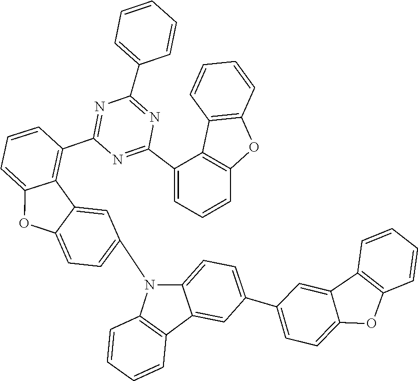 [SMILES: c1ccc(-c2nc(-c3cccc4oc5ccccc5c34)nc(-c3cccc4oc5ccc(-n6c7ccccc7c7cc(-c8ccc9oc%10ccccc%10c9c8)ccc76)cc5c34)n2)cc1]

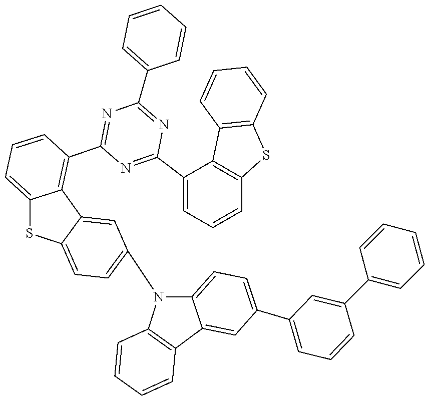 [SMILES: c1ccc(-c2cccc(-c3ccc4c(c3)c3ccccc3n4-c3ccc4sc5cccc(-c6nc(-c7ccccc7)nc(-c7cccc8sc9ccccc9c78)n6)c5c4c3)c2)cc1]

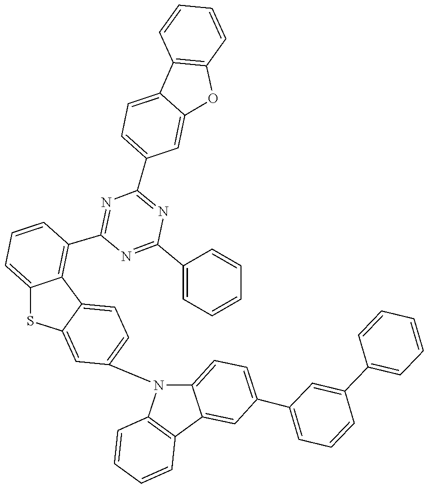 [SMILES: c1ccc(-c2cccc(-c3ccc4c(c3)c3ccccc3n4-c3ccc4c(c3)sc3cccc(-c5nc(-c6ccccc6)nc(-c6ccc7c(c6)oc6ccccc67)n5)c34)c2)cc1]

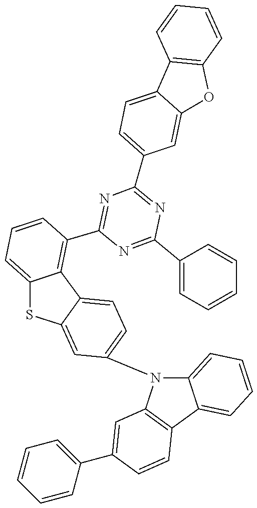 [SMILES: c1ccc(-c2ccc3c4ccccc4n(-c4ccc5c(c4)sc4cccc(-c6nc(-c7ccccc7)nc(-c7ccc8c(c7)oc7ccccc78)n6)c45)c3c2)cc1]

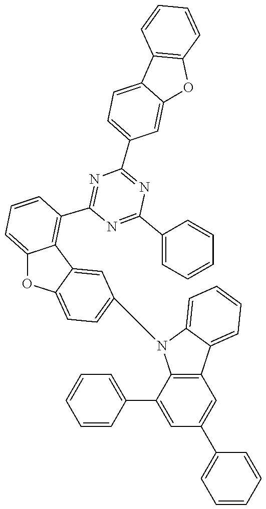 [SMILES: c1ccc(-c2cc(-c3ccccc3)c3c(c2)c2ccccc2n3-c2ccc3oc4cccc(-c5nc(-c6ccccc6)nc(-c6ccc7c(c6)oc6ccccc67)n5)c4c3c2)cc1]

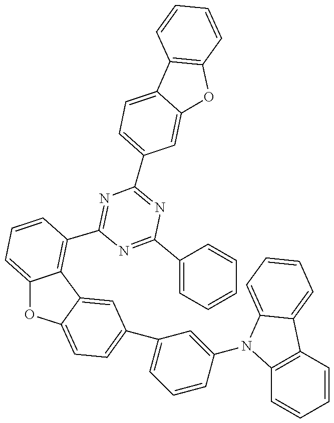 [SMILES: c1ccc(-c2nc(-c3ccc4c(c3)oc3ccccc34)nc(-c3cccc4oc5ccc(-c6cccc(-n7c8ccccc8c8ccccc87)c6)cc5c34)n2)cc1]

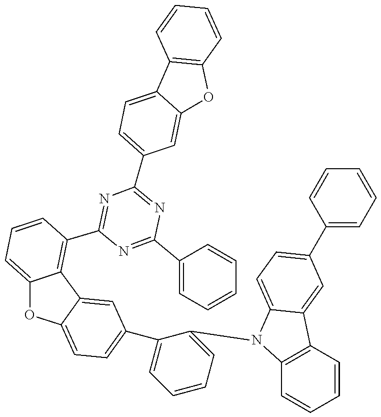 [SMILES: c1ccc(-c2ccc3c(c2)c2ccccc2n3-c2ccccc2-c2ccc3oc4cccc(-c5nc(-c6ccccc6)nc(-c6ccc7c(c6)oc6ccccc67)n5)c4c3c2)cc1]

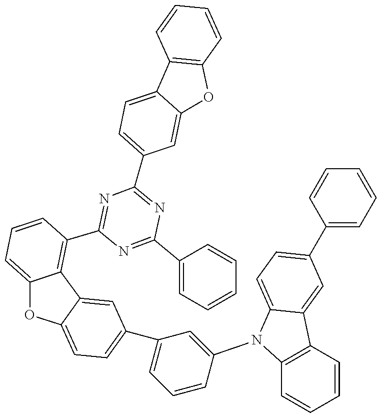 [SMILES: c1ccc(-c2ccc3c(c2)c2ccccc2n3-c2cccc(-c3ccc4oc5cccc(-c6nc(-c7ccccc7)nc(-c7ccc8c(c7)oc7ccccc78)n6)c5c4c3)c2)cc1]

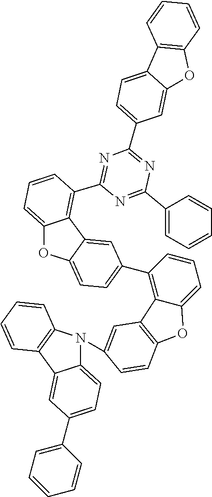 [SMILES: c1ccc(-c2ccc3c(c2)c2ccccc2n3-c2ccc3oc4cccc(-c5ccc6oc7cccc(-c8nc(-c9ccccc9)nc(-c9ccc%10c(c9)oc9ccccc9%10)n8)c7c6c5)c4c3c2)cc1]

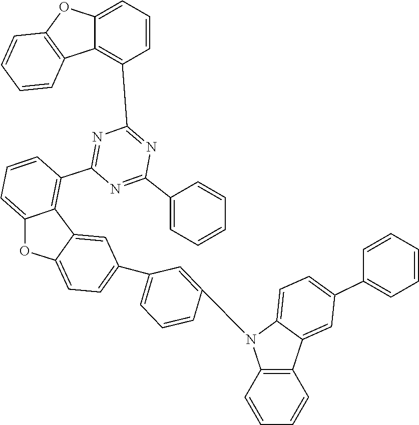 [SMILES: c1ccc(-c2ccc3c(c2)c2ccccc2n3-c2cccc(-c3ccc4oc5cccc(-c6nc(-c7ccccc7)nc(-c7cccc8oc9ccccc9c78)n6)c5c4c3)c2)cc1]

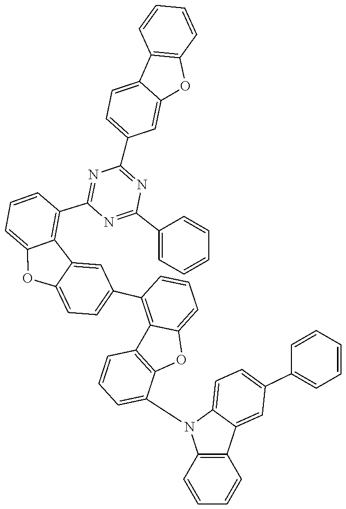 [SMILES: c1ccc(-c2ccc3c(c2)c2ccccc2n3-c2cccc3c2oc2cccc(-c4ccc5oc6cccc(-c7nc(-c8ccccc8)nc(-c8ccc9c(c8)oc8ccccc89)n7)c6c5c4)c23)cc1]

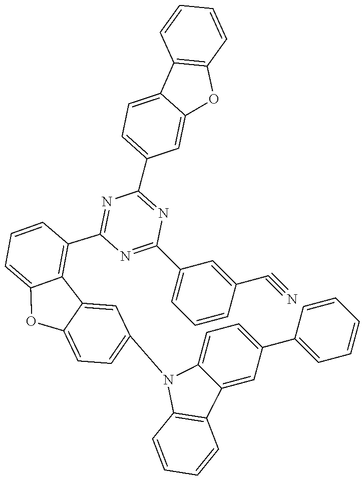 [SMILES: N#Cc1cccc(-c2nc(-c3ccc4c(c3)oc3ccccc34)nc(-c3cccc4oc5ccc(-n6c7ccccc7c7cc(-c8ccccc8)ccc76)cc5c34)n2)c1]

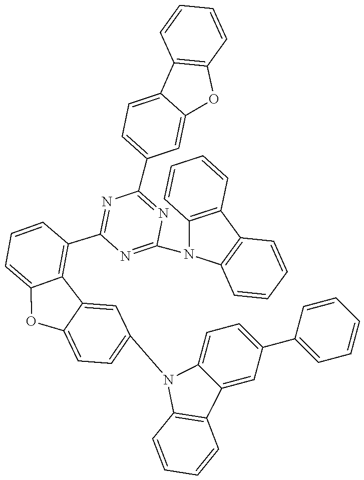 [SMILES: c1ccc(-c2ccc3c(c2)c2ccccc2n3-c2ccc3oc4cccc(-c5nc(-c6ccc7c(c6)oc6ccccc67)nc(-n6c7ccccc7c7ccccc76)n5)c4c3c2)cc1]

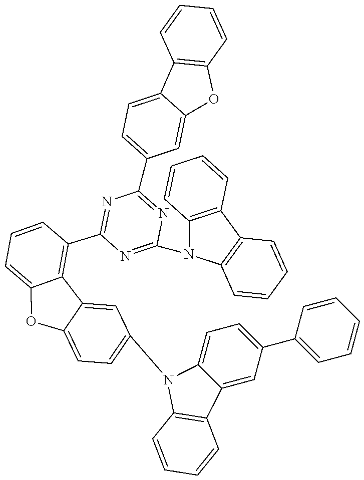 [SMILES: c1ccc(-c2ccc3c(c2)c2ccccc2n3-c2ccc3oc4cccc(-c5nc(-c6ccc7c(c6)oc6ccccc67)nc(-n6c7ccccc7c7ccccc76)n5)c4c3c2)cc1]

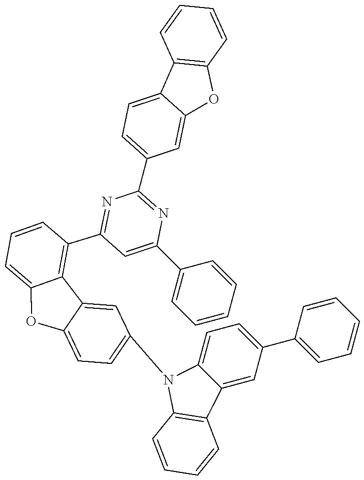 [SMILES: c1ccc(-c2ccc3c(c2)c2ccccc2n3-c2ccc3oc4cccc(-c5cc(-c6ccccc6)nc(-c6ccc7c(c6)oc6ccccc67)n5)c4c3c2)cc1]

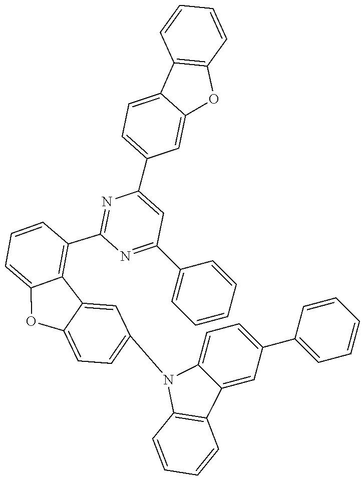 [SMILES: c1ccc(-c2ccc3c(c2)c2ccccc2n3-c2ccc3oc4cccc(-c5nc(-c6ccccc6)cc(-c6ccc7c(c6)oc6ccccc67)n5)c4c3c2)cc1]

The host material 1 as described above or described as preferred above or hereinafter is preferably partly deuterated or fully deuterated.

Particularly suitable compounds of the formulae (1), (1a), (1b), (1c), (1d), (1e) and (1f) that are used with preference in combination with at least one compound of the formula (2) in the electroluminescent device of the invention are the compounds E1 to E51 in table 2.

TABLE 2

| | |
|---|---|
| 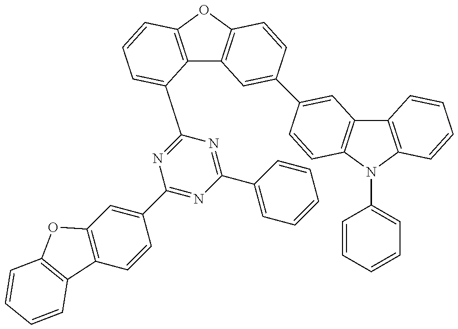 [SMILES: c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1] | E1 |
| 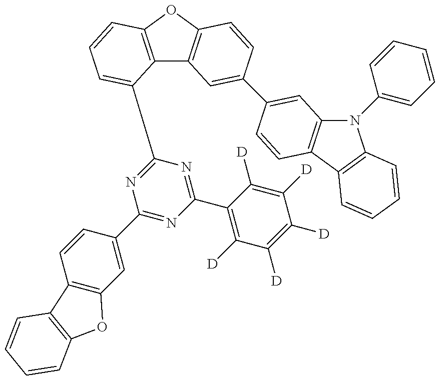 [SMILES: [2H]c1c([2H])c([2H])c(-c2nc(-c3ccc4c(c3)oc3ccccc34)nc(-c3cccc4oc5ccc(-c6ccc7c8ccccc8n(-c8ccccc8)c7c6)cc5c34)n2)c([2H])c1[2H]] | E2 |
| 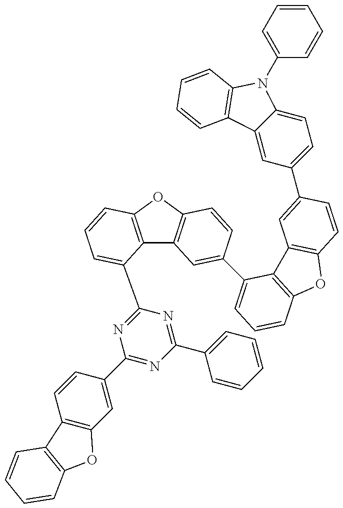 [SMILES: c1ccc(-c2nc(-c3ccc4c(c3)oc3ccccc34)nc(-c3cccc4oc5ccc(-c6cccc7oc8ccc(-c9ccc%10c(c9)c9ccccc9n%10-c9ccccc9)cc8c67)cc5c34)n2)cc1] | E3 |
| 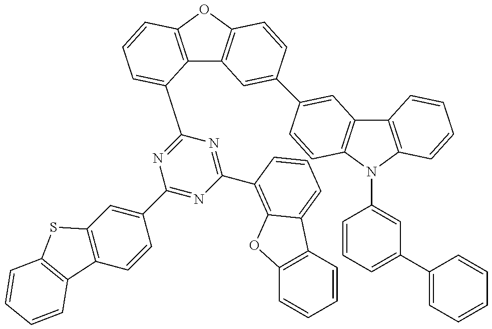 [SMILES: c1ccc(-c2cccc(-n3c4ccccc4c4cc(-c5ccc6oc7cccc(-c8nc(-c9ccc%10c(c9)sc9ccccc9%10)nc(-c9cccc%10c9oc9ccccc9%10)n8)c7c6c5)ccc43)c2)cc1] | E4 |
| 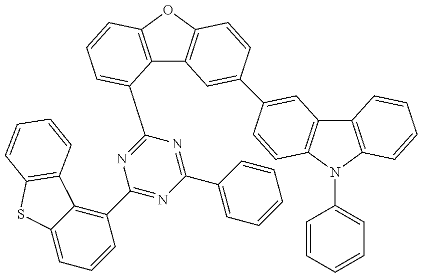 [SMILES: c1ccc(-c2nc(-c3cccc4oc5ccc(-c6ccc7c(c6)c6ccccc6n7-c6ccccc6)cc5c34)nc(-c3cccc4sc5ccccc5c34)n2)cc1] | E5 |
| 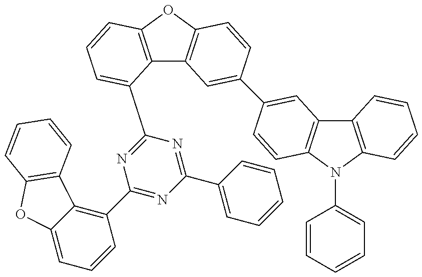 [SMILES: c1ccc(-c2nc(-c3cccc4oc5ccccc5c34)nc(-c3cccc4oc5ccc(-c6ccc7c(c6)c6ccccc6n7-c6ccccc6)cc5c34)n2)cc1] | E6 |
| 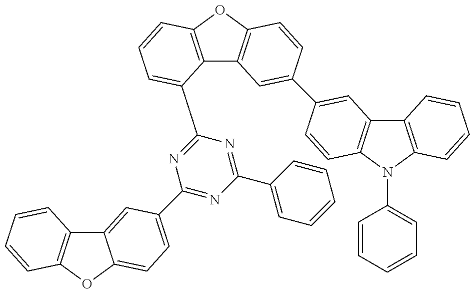 [SMILES: c1ccc(-c2nc(-c3ccc4oc5ccccc5c4c3)nc(-c3cccc4oc5ccc(-c6ccc7c(c6)c6ccccc6n7-c6ccccc6)cc5c34)n2)cc1] | E7 |
| 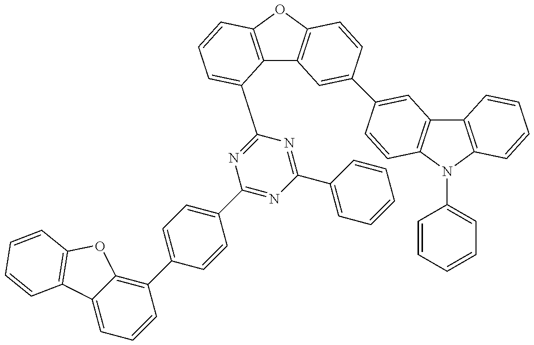 [SMILES: c1ccc(-c2nc(-c3ccc(-c4cccc5c4oc4ccccc45)cc3)nc(-c3cccc4oc5ccc(-c6ccc7c(c6)c6ccccc6n7-c6ccccc6)cc5c34)n2)cc1] | E8 |
| 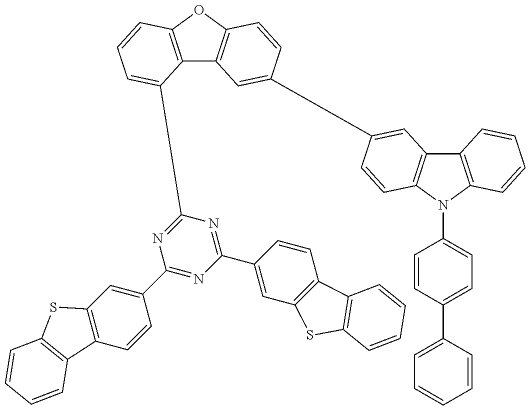 [SMILES: c1ccc(-c2ccc(-n3c4ccccc4c4cc(-c5ccc6oc7cccc(-c8nc(-c9ccc%10c(c9)sc9ccccc9%10)nc(-c9ccc%10c(c9)sc9ccccc9%10)n8)c7c6c5)ccc43)cc2)cc1] | E9 |
| 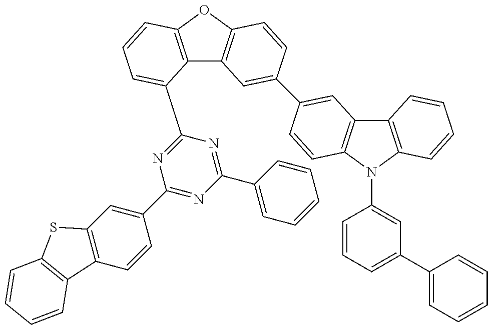 [SMILES: c1ccc(-c2cccc(-n3c4ccccc4c4cc(-c5ccc6oc7cccc(-c8nc(-c9ccccc9)nc(-c9ccc%10c(c9)sc9ccccc9%10)n8)c7c6c5)ccc43)c2)cc1] | E10 |
| 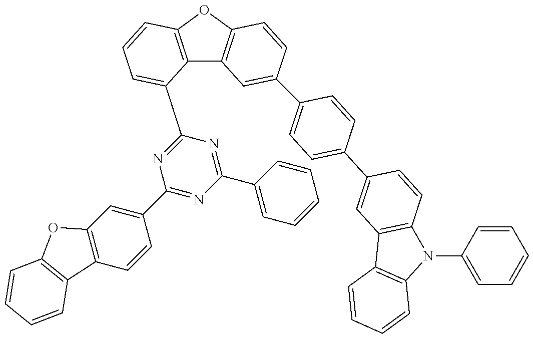 [SMILES: c1ccc(-c2nc(-c3ccc4c(c3)oc3ccccc34)nc(-c3cccc4oc5ccc(-c6ccc(-c7ccc8c(c7)c7ccccc7n8-c7ccccc7)cc6)cc5c34)n2)cc1] | E11 |
| 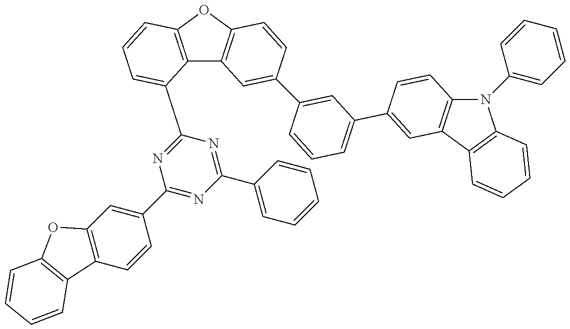 [SMILES: c1ccc(-c2nc(-c3ccc4c(c3)oc3ccccc34)nc(-c3cccc4oc5ccc(-c6cccc(-c7ccc8c(c7)c7ccccc7n8-c7ccccc7)c6)cc5c34)n2)cc1] | E12 |
| 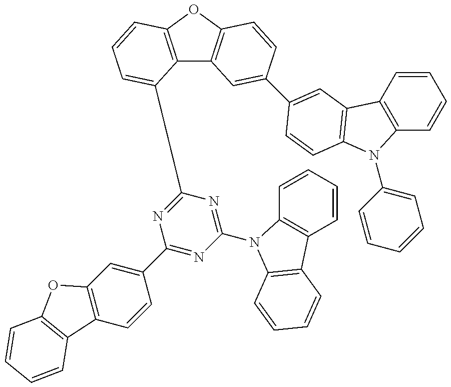 [SMILES: c1ccc(-n2c3ccccc3c3cc(-c4ccc5oc6cccc(-c7nc(-c8ccc9c(c8)oc8ccccc89)nc(-n8c9ccccc9c9ccccc98)n7)c6c5c4)ccc32)cc1] | E13 |
| 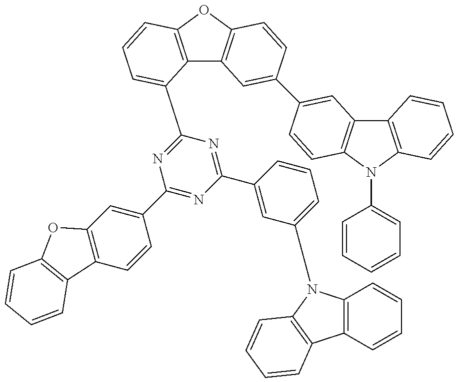 [SMILES: c1ccc(-n2c3ccccc3c3cc(-c4ccc5oc6cccc(-c7nc(-c8cccc(-n9c%10ccccc%10c%10ccccc%109)c8)nc(-c8ccc9c(c8)oc8ccccc89)n7)c6c5c4)ccc32)cc1] | E14 |
| 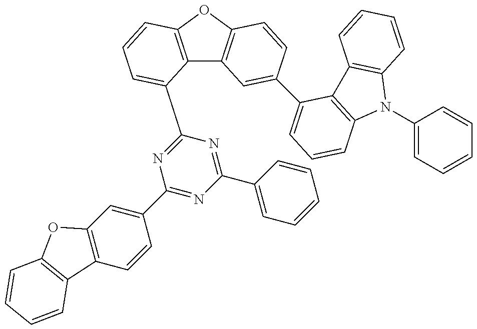 [SMILES: c1ccc(-c2nc(-c3ccc4c(c3)oc3ccccc34)nc(-c3cccc4oc5ccc(-c6cccc7c6c6ccccc6n7-c6ccccc6)cc5c34)n2)cc1] | E15 |
| 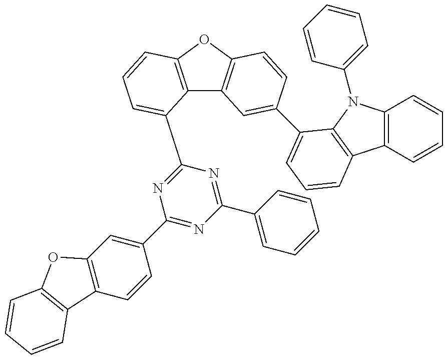 [SMILES: c1ccc(-c2nc(-c3ccc4c(c3)oc3ccccc34)nc(-c3cccc4oc5ccc(-c6cccc7c8ccccc8n(-c8ccccc8)c67)cc5c34)n2)cc1] | E16 |
| 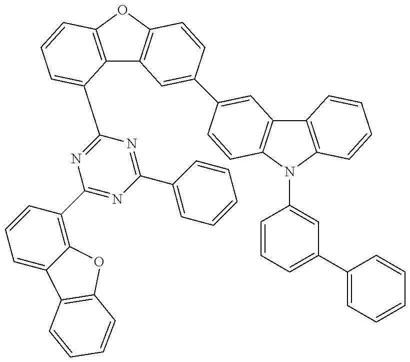 [SMILES: c1ccc(-c2cccc(-n3c4ccccc4c4cc(-c5ccc6oc7cccc(-c8nc(-c9ccccc9)nc(-c9cccc%10c9oc9ccccc9%10)n8)c7c6c5)ccc43)c2)cc1] | E17 |
| 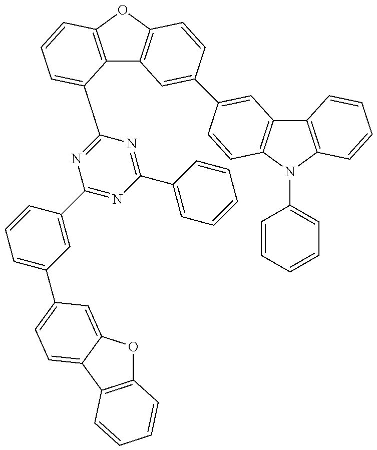 [SMILES: c1ccc(-c2nc(-c3cccc(-c4ccc5c(c4)oc4ccccc45)c3)nc(-c3cccc4oc5ccc(-c6ccc7c(c6)c6ccccc6n7-c6ccccc6)cc5c34)n2)cc1] | E18 |
| 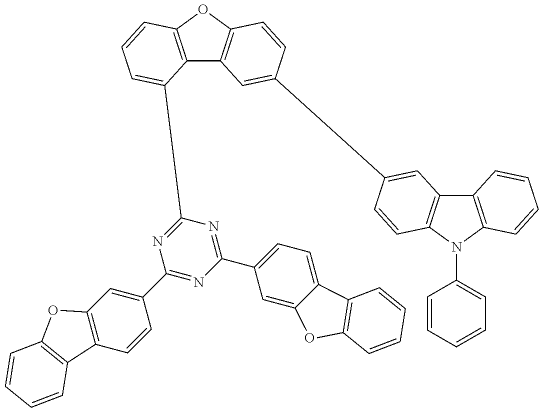 [SMILES: c1ccc(-n2c3ccccc3c3cc(-c4ccc5oc6cccc(-c7nc(-c8ccc9c(c8)oc8ccccc89)nc(-c8ccc9c(c8)oc8ccccc89)n7)c6c5c4)ccc32)cc1] | E19 |
| 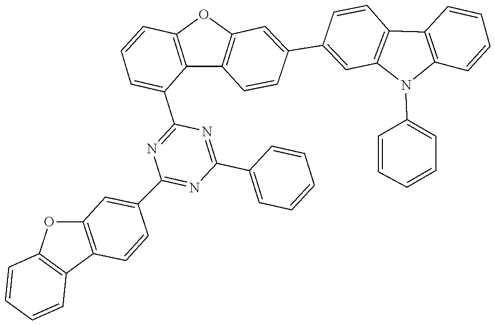 [SMILES: c1ccc(-c2nc(-c3ccc4c(c3)oc3ccccc34)nc(-c3cccc4oc5cc(-c6ccc7c8ccccc8n(-c8ccccc8)c7c6)ccc5c34)n2)cc1] | E20 |
| 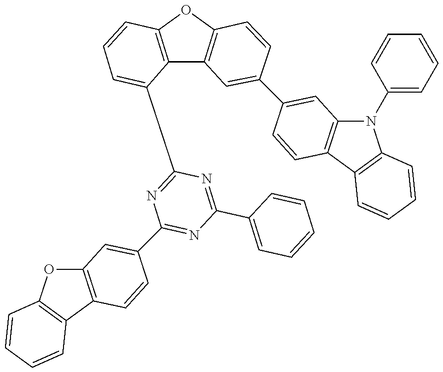 [SMILES: c1ccc(-c2nc(-c3ccc4c(c3)oc3ccccc34)nc(-c3cccc4oc5ccc(-c6ccc7c8ccccc8n(-c8ccccc8)c7c6)cc5c34)n2)cc1] | E21 |
| 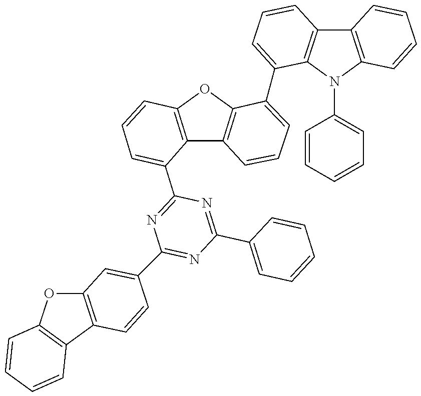 [SMILES: c1ccc(-c2nc(-c3ccc4c(c3)oc3ccccc34)nc(-c3cccc4oc5c(-c6cccc7c8ccccc8n(-c8ccccc8)c67)cccc5c34)n2)cc1] | E22 |
| 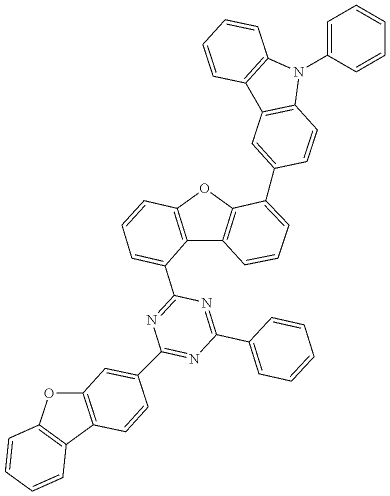 [SMILES: c1ccc(-c2nc(-c3ccc4c(c3)oc3ccccc34)nc(-c3cccc4oc5c(-c6ccc7c(c6)c6ccccc6n7-c6ccccc6)cccc5c34)n2)cc1] | E23 |
| 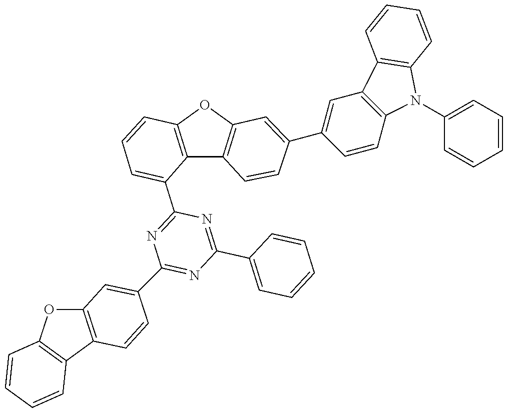 [SMILES: c1ccc(-c2nc(-c3ccc4c(c3)oc3ccccc34)nc(-c3cccc4oc5cc(-c6ccc7c(c6)c6ccccc6n7-c6ccccc6)ccc5c34)n2)cc1] | E24 |
| 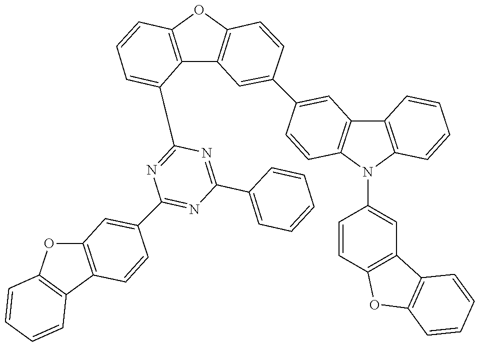 [SMILES: c1ccc(-c2nc(-c3ccc4c(c3)oc3ccccc34)nc(-c3cccc4oc5ccc(-c6ccc7c(c6)c6ccccc6n7-c6ccc7oc8ccccc8c7c6)cc5c34)n2)cc1] | E25 |
| 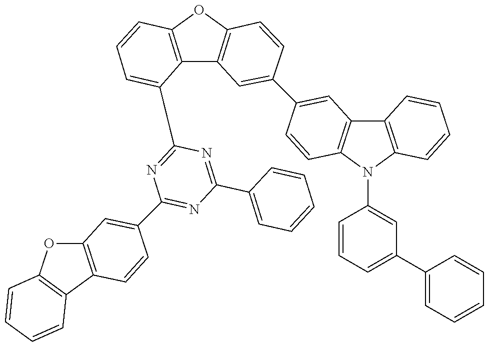 [SMILES: c1ccc(-c2cccc(-n3c4ccccc4c4cc(-c5ccc6oc7cccc(-c8nc(-c9ccccc9)nc(-c9ccc%10c(c9)oc9ccccc9%10)n8)c7c6c5)ccc43)c2)cc1] | E26 |
| 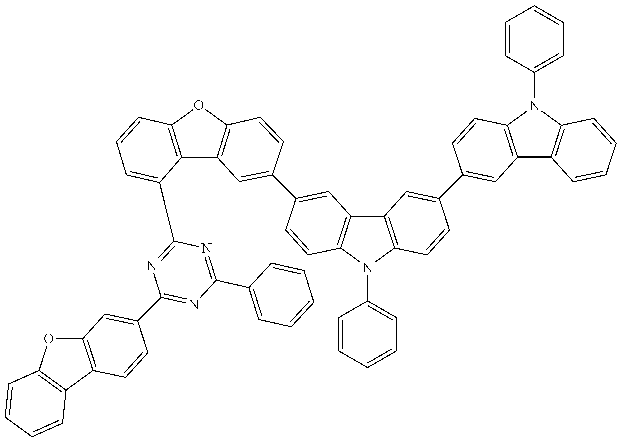 [SMILES: c1ccc(-c2nc(-c3ccc4c(c3)oc3ccccc34)nc(-c3cccc4oc5ccc(-c6ccc7c(c6)c6cc(-c8ccc9c(c8)c8ccccc8n9-c8ccccc8)ccc6n7-c6ccccc6)cc5c34)n2)cc1] | E27 |
| 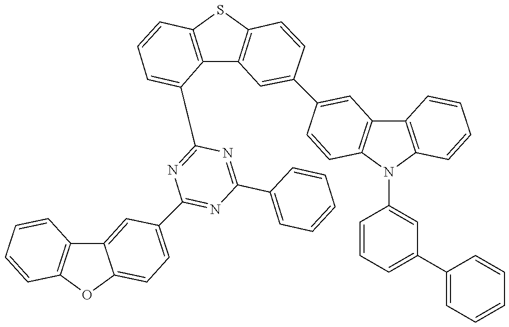 [SMILES: c1ccc(-c2cccc(-n3c4ccccc4c4cc(-c5ccc6sc7cccc(-c8nc(-c9ccccc9)nc(-c9ccc%10oc%11ccccc%11c%10c9)n8)c7c6c5)ccc43)c2)cc1] | E28 |
| 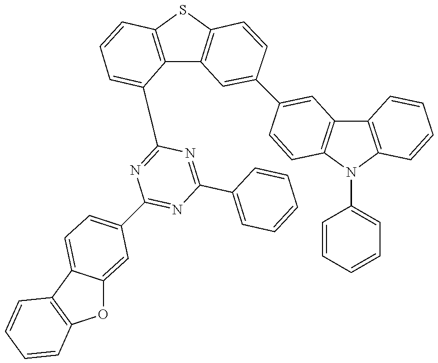 [SMILES: c1ccc(-c2nc(-c3ccc4c(c3)oc3ccccc34)nc(-c3cccc4sc5ccc(-c6ccc7c(c6)c6ccccc6n7-c6ccccc6)cc5c34)n2)cc1] | E29 |
| 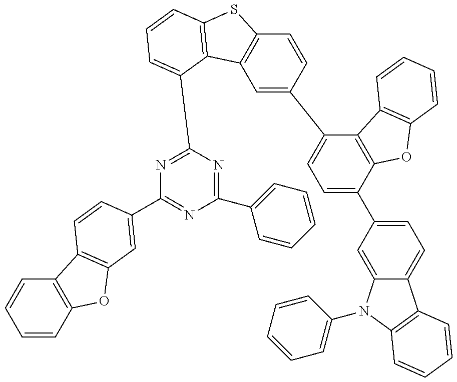 [SMILES: c1ccc(-c2nc(-c3ccc4c(c3)oc3ccccc34)nc(-c3cccc4sc5ccc(-c6ccc(-c7ccc8c9ccccc9n(-c9ccccc9)c8c7)c7oc8ccccc8c67)cc5c34)n2)cc1] | E30 |
| 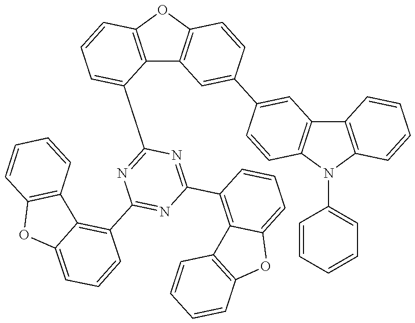 [SMILES: c1ccc(-n2c3ccccc3c3cc(-c4ccc5oc6cccc(-c7nc(-c8cccc9oc%10ccccc%10c89)nc(-c8cccc9oc%10ccccc%10c89)n7)c6c5c4)ccc32)cc1] | E31 |
| 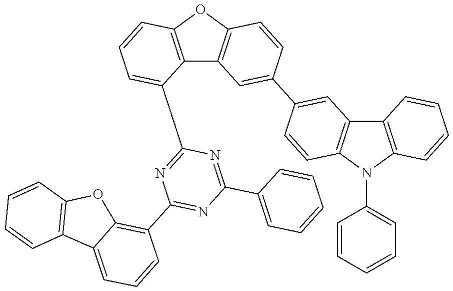 [SMILES: c1ccc(-c2nc(-c3cccc4c3oc3ccccc34)nc(-c3cccc4oc5ccc(-c6ccc7c(c6)c6ccccc6n7-c6ccccc6)cc5c34)n2)cc1] | E32 |
| 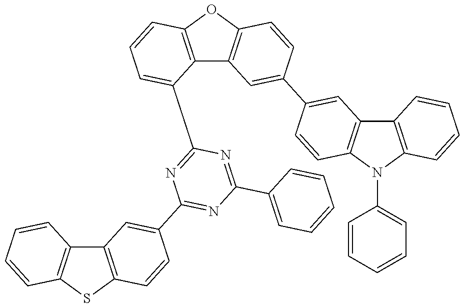 [SMILES: c1ccc(-c2nc(-c3ccc4sc5ccccc5c4c3)nc(-c3cccc4oc5ccc(-c6ccc7c(c6)c6ccccc6n7-c6ccccc6)cc5c34)n2)cc1] | E33 |
| 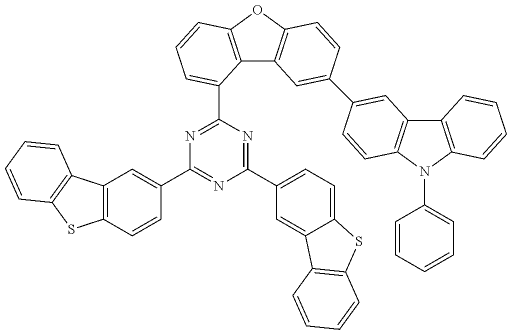 [SMILES: c1ccc(-n2c3ccccc3c3cc(-c4ccc5oc6cccc(-c7nc(-c8ccc9sc%10ccccc%10c9c8)nc(-c8ccc9sc%10ccccc%10c9c8)n7)c6c5c4)ccc32)cc1] | E34 |
| 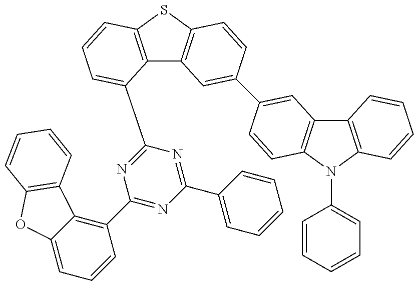 [SMILES: c1ccc(-c2nc(-c3cccc4oc5ccccc5c34)nc(-c3cccc4sc5ccc(-c6ccc7c(c6)c6ccccc6n7-c6ccccc6)cc5c34)n2)cc1] | E35 |
| 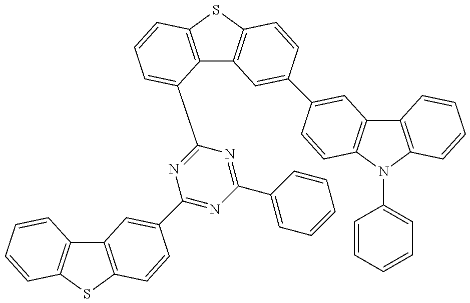 [SMILES: c1ccc(-c2nc(-c3ccc4sc5ccccc5c4c3)nc(-c3cccc4sc5ccc(-c6ccc7c(c6)c6ccccc6n7-c6ccccc6)cc5c34)n2)cc1] | E36 |
| 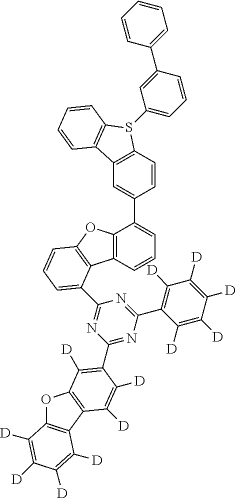 | E37 |
| 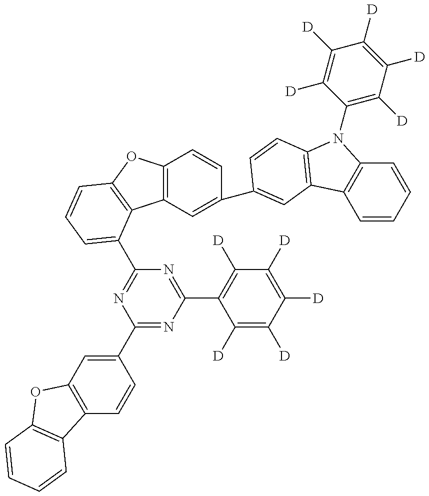 [SMILES: [2H]c1c([2H])c([2H])c(-c2nc(-c3ccc4c(c3)oc3ccccc34)nc(-c3cccc4oc5ccc(-c6ccc7c(c6)c6ccccc6n7-c6c([2H])c([2H])c([2H])c([2H])c6[2H])cc5c34)n2)c([2H])c1[2H]] | E38 |
| 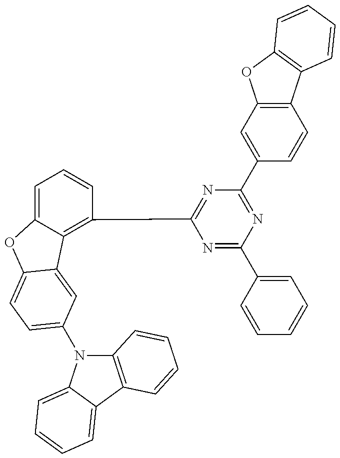 [SMILES: c1ccc(-c2nc(-c3ccc4c(c3)oc3ccccc34)nc(-c3cccc4oc5ccc(-n6c7ccccc7c7ccccc76)cc5c34)n2)cc1] | E39 |
| 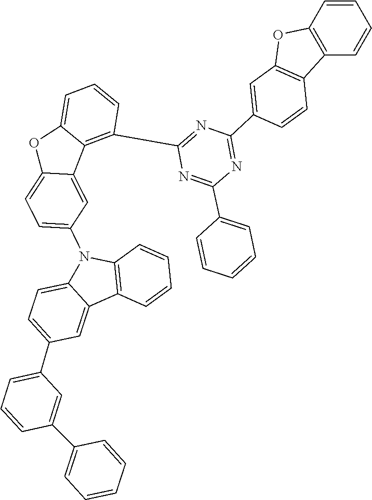 [SMILES: c1ccc(-c2cccc(-c3ccc4c(c3)c3ccccc3n4-c3ccc4oc5cccc(-c6nc(-c7ccccc7)nc(-c7ccc8c(c7)oc7ccccc78)n6)c5c4c3)c2)cc1] | E40 |
| 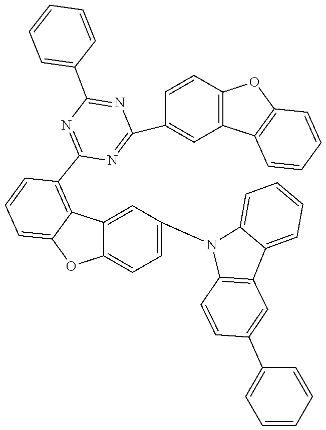 [SMILES: c1ccc(-c2ccc3c(c2)c2ccccc2n3-c2ccc3oc4cccc(-c5nc(-c6ccccc6)nc(-c6ccc7oc8ccccc8c7c6)n5)c4c3c2)cc1] | E41 |
| 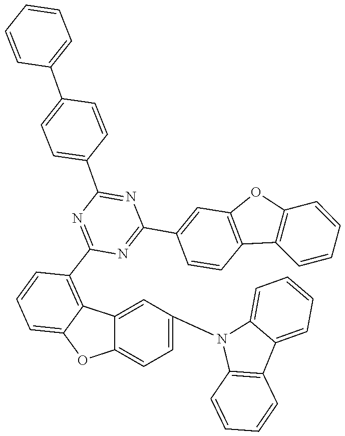 [SMILES: c1ccc(-c2ccc(-c3nc(-c4ccc5c(c4)oc4ccccc45)nc(-c4cccc5oc6ccc(-n7c8ccccc8c8ccccc87)cc6c45)n3)cc2)cc1] | E42 |
| 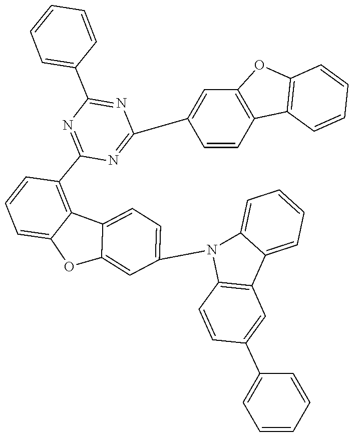 [SMILES: c1ccc(-c2ccc3c(c2)c2ccccc2n3-c2ccc3c(c2)oc2cccc(-c4nc(-c5ccccc5)nc(-c5ccc6c(c5)oc5ccccc56)n4)c23)cc1] | E43 |
| 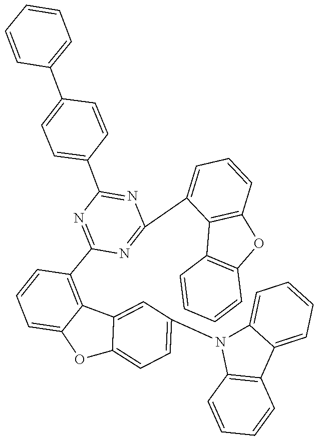 [SMILES: c1ccc(-c2ccc(-c3nc(-c4cccc5oc6ccccc6c45)nc(-c4cccc5oc6ccc(-n7c8ccccc8c8ccccc87)cc6c45)n3)cc2)cc1] | E44 |
| 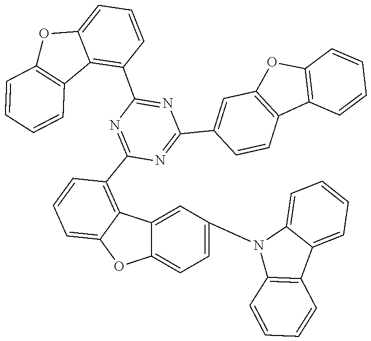 [SMILES: c1ccc2c(c1)oc1cc(-c3nc(-c4cccc5oc6ccccc6c45)nc(-c4cccc5oc6ccc(-n7c8ccccc8c8ccccc87)cc6c45)n3)ccc12] | E45 |
| 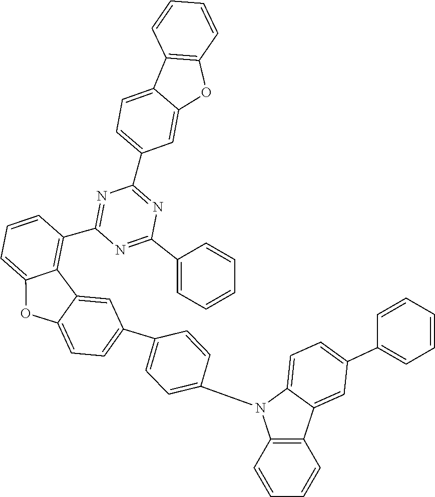 [SMILES: c1ccc(-c2ccc3c(c2)c2ccccc2n3-c2ccc(-c3ccc4oc5cccc(-c6nc(-c7ccccc7)nc(-c7ccc8c(c7)oc7ccccc78)n6)c5c4c3)cc2)cc1] | E46 |
| 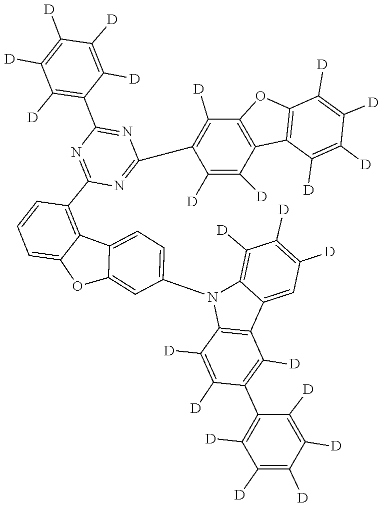 [SMILES: [2H]c1cc2c3c([2H])c(-c4c([2H])c([2H])c([2H])c([2H])c4[2H])c([2H])c([2H])c3n(-c3ccc4c(c3)oc3cccc(-c5nc(-c6c([2H])c([2H])c([2H])c([2H])c6[2H])nc(-c6c([2H])c([2H])c7c(oc8c([2H])c([2H])c([2H])c([2H])c87)c6[2H])n5)c34)c2c([2H])c1[2H]] | E47 |
| 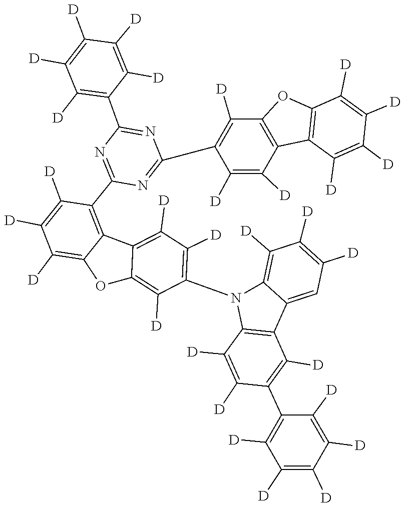 [SMILES: [2H]c1cc2c3c([2H])c(-c4c([2H])c([2H])c([2H])c([2H])c4[2H])c([2H])c([2H])c3n(-c3c([2H])c([2H])c4c(oc5c([2H])c([2H])c([2H])c(-c6nc(-c7c([2H])c([2H])c([2H])c([2H])c7[2H])nc(-c7c([2H])c([2H])c8c(oc9c([2H])c([2H])c([2H])c([2H])c98)c7[2H])n6)c54)c3[2H])c2c([2H])c1[2H]] | E48 |
| 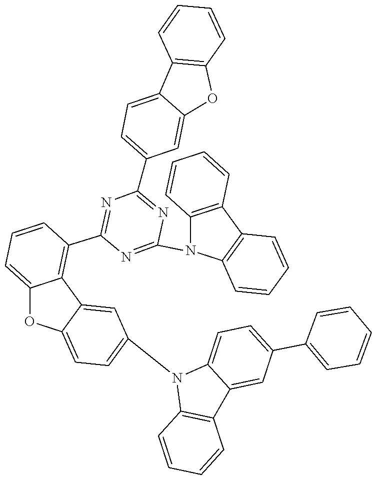 [SMILES: c1ccc(-c2ccc3c(c2)c2ccccc2n3-c2ccc3oc4cccc(-c5nc(-c6ccc7c(c6)oc6ccccc67)nc(-n6c7ccccc7c7ccccc76)n5)c4c3c2)cc1] | E49 |
| 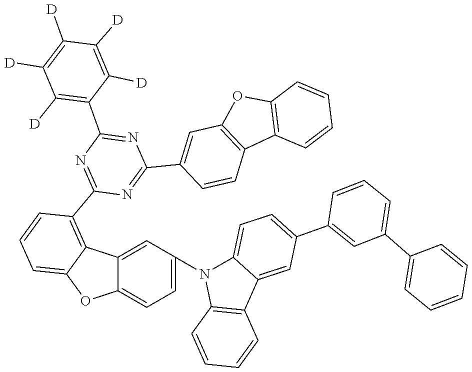 [SMILES: [2H]c1c([2H])c([2H])c(-c2nc(-c3ccc4c(c3)oc3ccccc34)nc(-c3cccc4oc5ccc(-n6c7ccccc7c7cc(-c8cccc(-c9ccccc9)c8)ccc76)cc5c34)n2)c([2H])c1[2H]] | E50 |
| 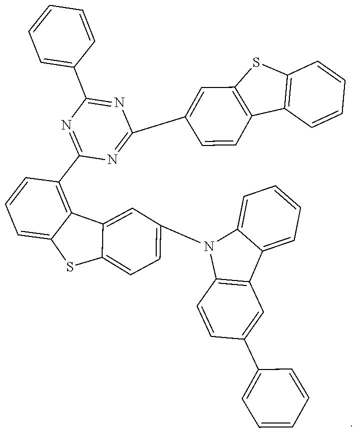 [SMILES: c1ccc(-c2ccc3c(c2)c2ccccc2n3-c2ccc3sc4cccc(-c5nc(-c6ccccc6)nc(-c6ccc7c(c6)sc6ccccc67)n5)c4c3c2)cc1] | E51 |

The preparation of the compounds of the formula (1) or of the preferred compounds from table 1 and of the compounds E1 to E51 is known to those skilled in the art. The compounds can be prepared by synthesis steps known to those skilled in the art, for example bromination, Suzuki coupling, Ullmann coupling, Hartwig-Buchwald coupling, etc. A suitable synthesis method is shown in general in schemes 1, 2 and 3 below, where the symbols and indices used have the meanings given above, except omitting, for simplification, the representation of possible substituents R⁰ as described in the compounds of the formulae (1), (1A), (1B), (1C), (1D), (1E), (1F), (1G), (1H), (1a), (1b), (1c), (1d), (1e) and (1f). It will present no difficulties to the person skilled in the art to adapt the teaching of the preparation to these compounds of the formulae (1), (1A), (1B), (1C), (1D), (1E), (1F), (1G), (1H), (1a), (1b), (1c), (1d), (1e) and (1f).

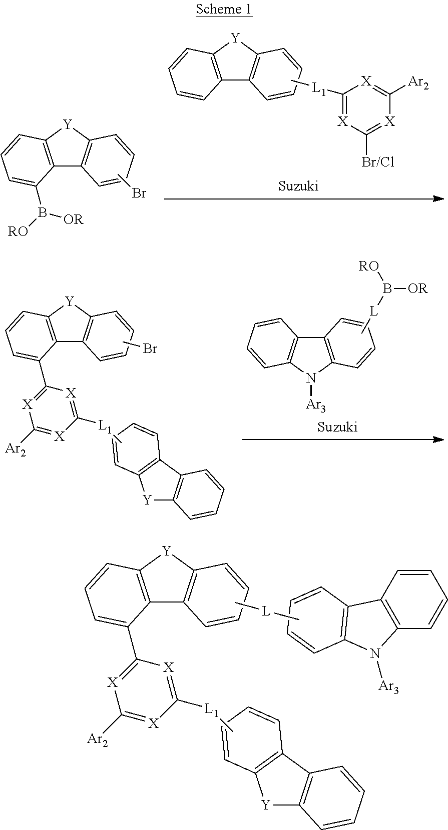

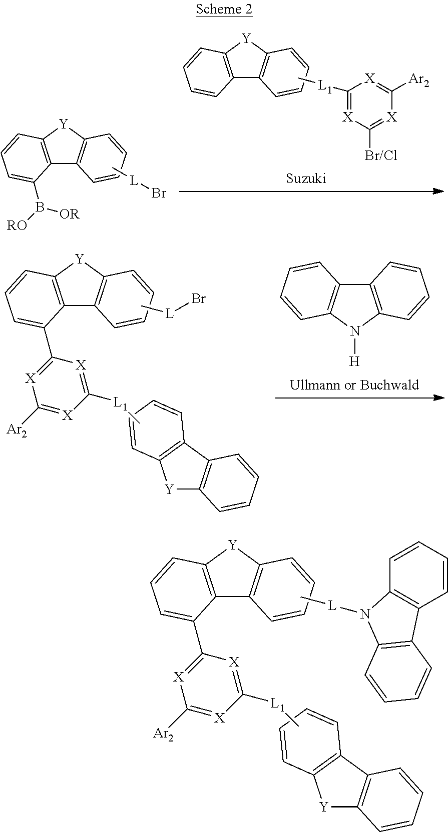

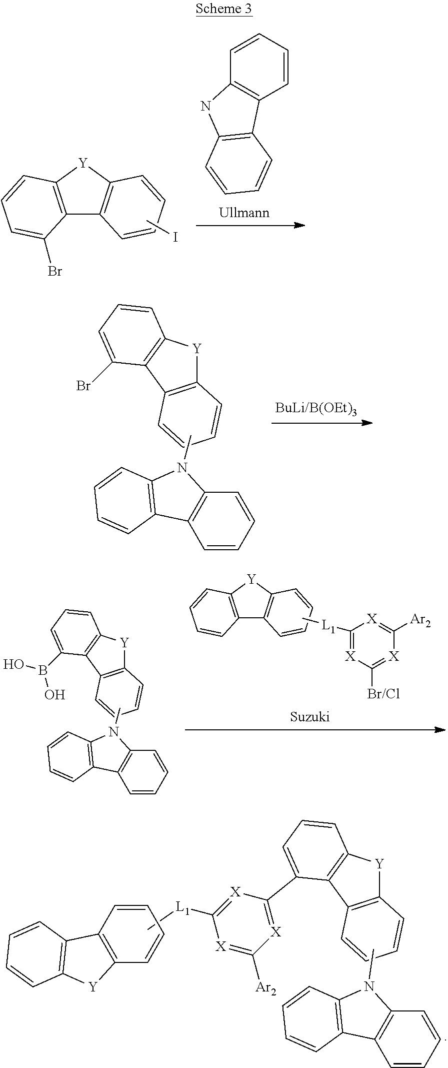

There follows a description of the host material 2 and its preferred embodiments that is/are present in the device of the invention. The preferred embodiments of the host material 2 of the formula (2) are also applicable to the mixture and/or formulation of the invention.

In one embodiment of the invention, for the device of the invention, compounds of the formula (2) as described above are selected, and these are used in the light-emitting layer with compounds of the formula (1) as described above or described as preferred or with the compounds from table 1 or the compounds E1 to E51.

In compounds of the formula (2) as described above, the sum of the indices a1+a2+a3+a4 is selected from 3, 4, 5, 6, 7, 8, 9, 10, 11, 12, 13, 14, 15, 16 and 17. The host material 2 is accordingly at least partly deuterated on each N-bonded substituent. In a preferred embodiment, two of the N-bonded substituents in host material 2 are partly deuterated and the third N-bonded substituent is fully deuterated. In a further preferred embodiment, two of the N-bonded substituents in host material 2 are fully deuterated and the third N-bonded substituent is partly deuterated. In a further preferred embodiment, each N-bonded substituent in host material 2 is fully deuterated.

In a preferred embodiment of the host material 2, the host material 2 is a mixture of deuterated compounds of the formula (2) as described above or described as preferred hereinafter, where the degree of deuteration of the compounds of the formula (2) is at least 50% to 90%, preferably 70% to 100%. Corresponding deuteration methods are described hereinafter.

The invention accordingly further provides an organic luminescent device as described above or described as preferred, wherein the host material 2 as described above or described as preferred hereinafter is fully deuterated.

In compounds of the formula (2), or the compounds of the formulae (2a), (2b), (2c), (2d) and (2e) disclosed hereinafter, x is preferably 1 or 2, where R² is the same or different at each instance and is preferably selected from the group consisting of F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more Ra radicals, or a combination of these systems, where it is optionally possible for two or more adjacent substituents R² to form a monocyclic or polycyclic, aliphatic, aromatic or heteroaromatic ring system which may be substituted by one or more R³ radicals, with the condition that R² and substituents bonded thereto do not contain a carbazole group.

If, in compounds of the formula (2), or the compounds of the formulae (2a), (2b), (2c), (2d) and (2e) disclosed hereinafter, x is 1 and a₁ is 1, 2, 3 or 4, the substituent R² is preferably selected from the group of the following substituents R2-1 to R2-221, where the substituents R2-1 to R2-221 may also be partly deuterated or fully deuterated, if not already described as such:

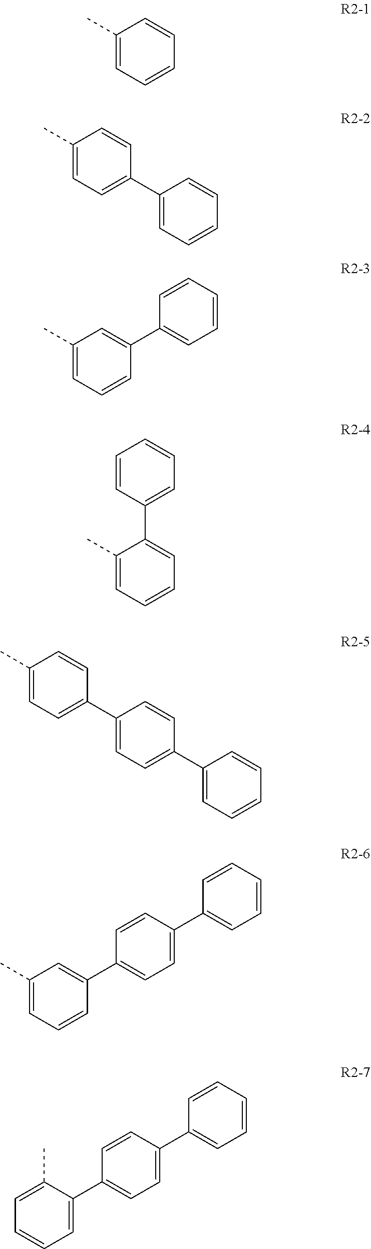

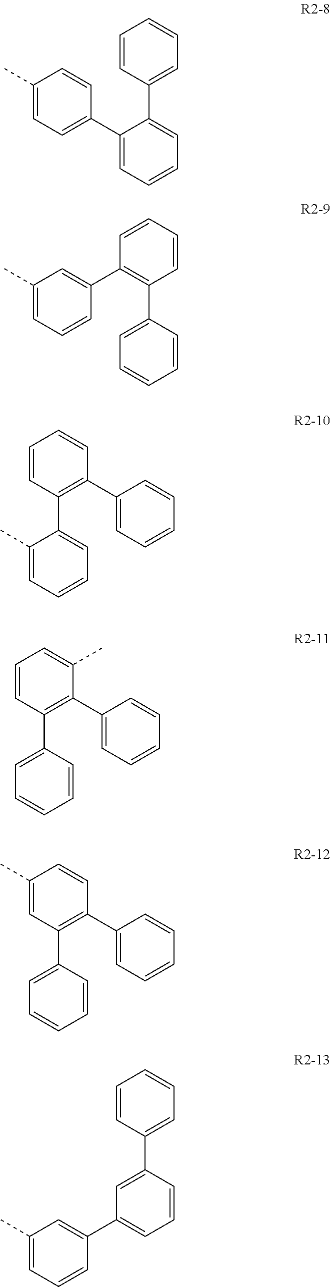

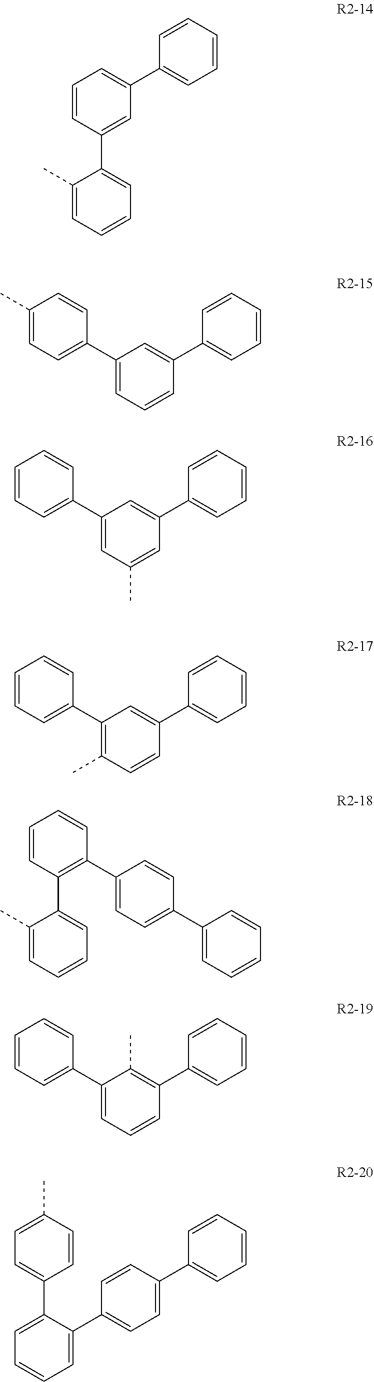

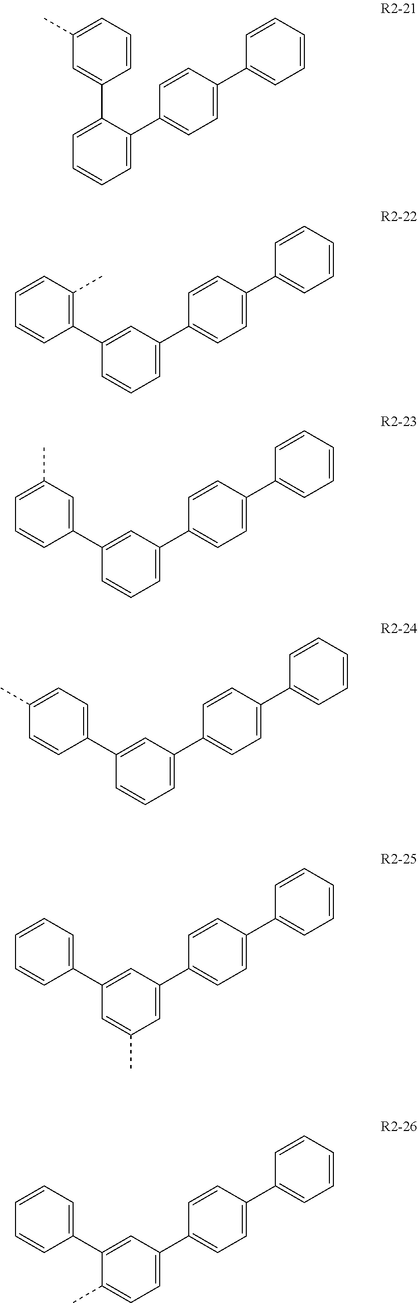

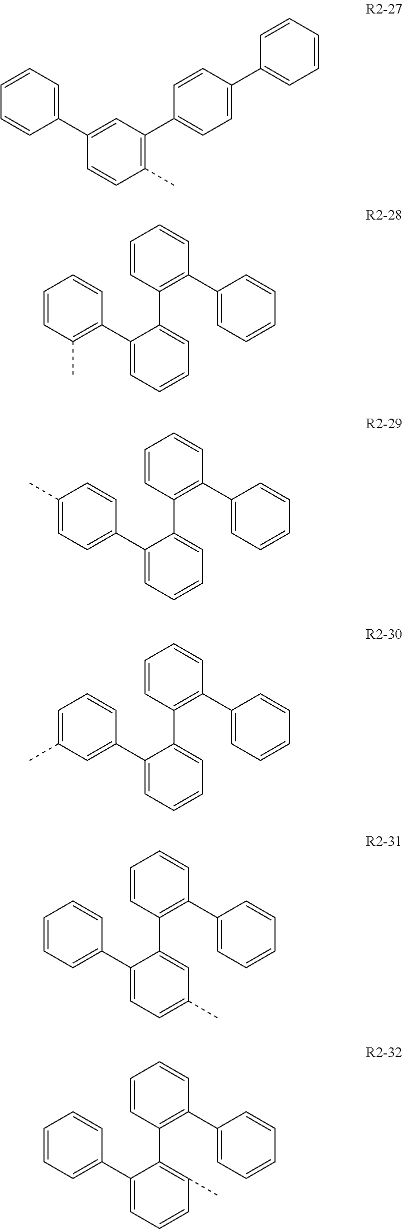

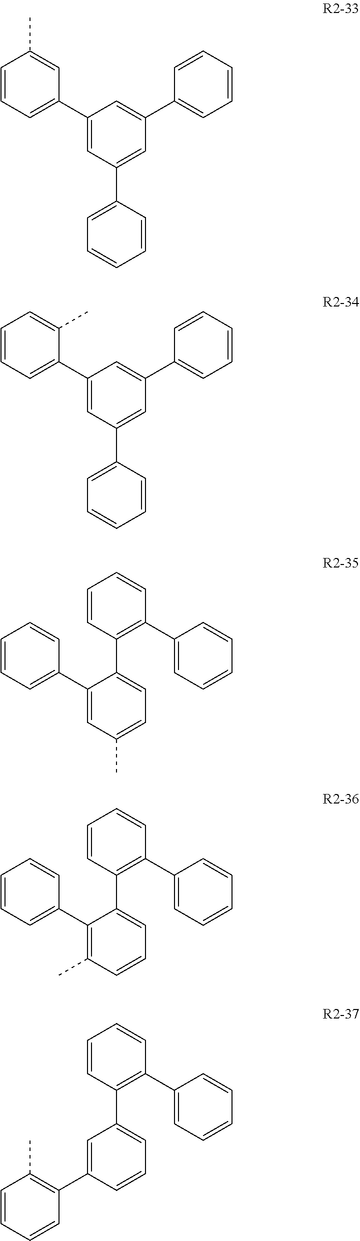

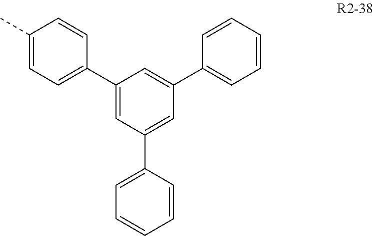

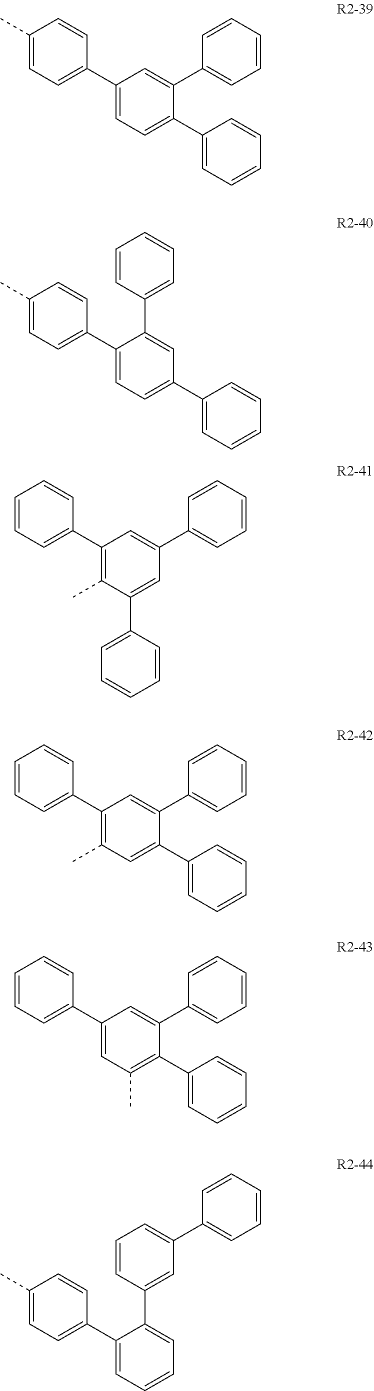

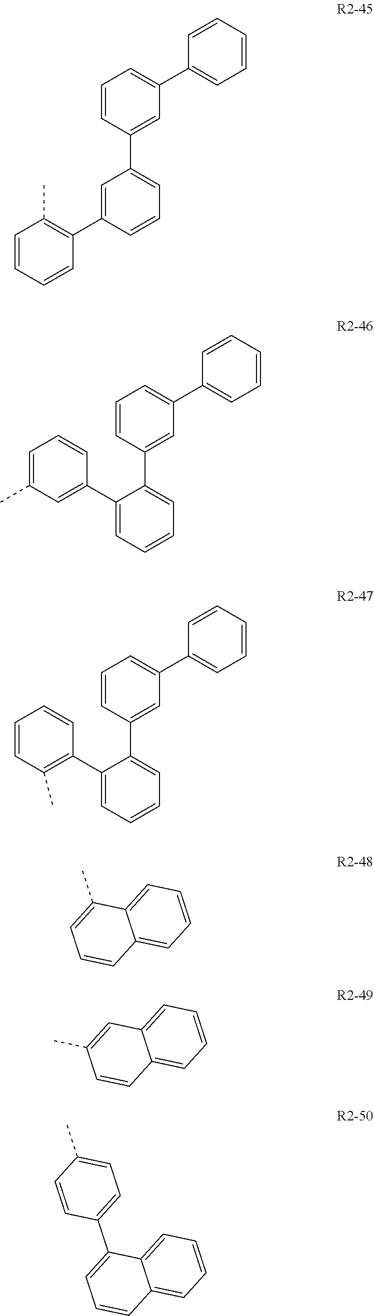

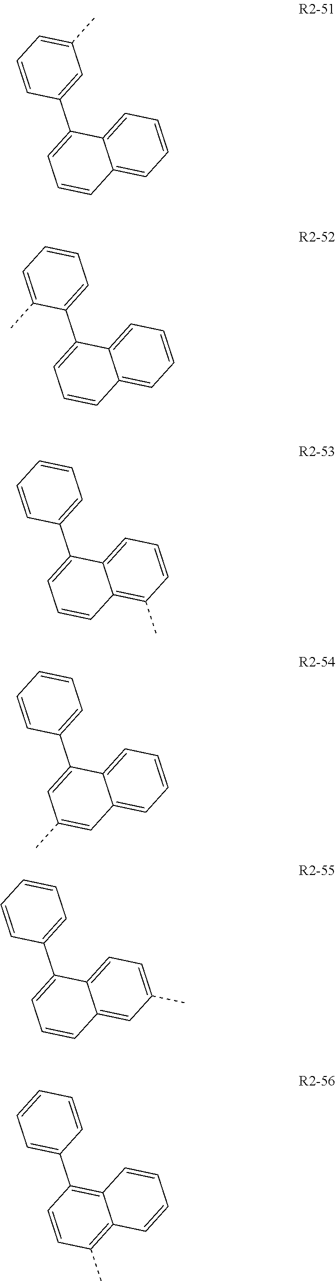

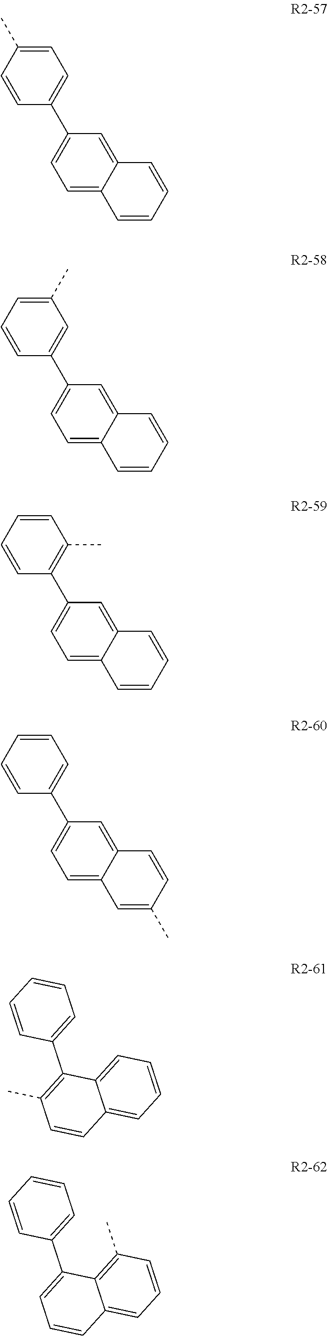

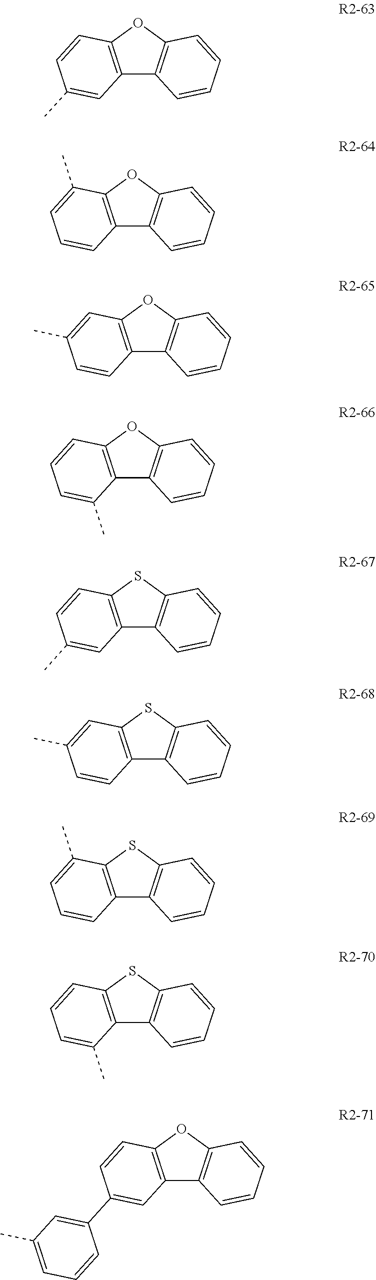

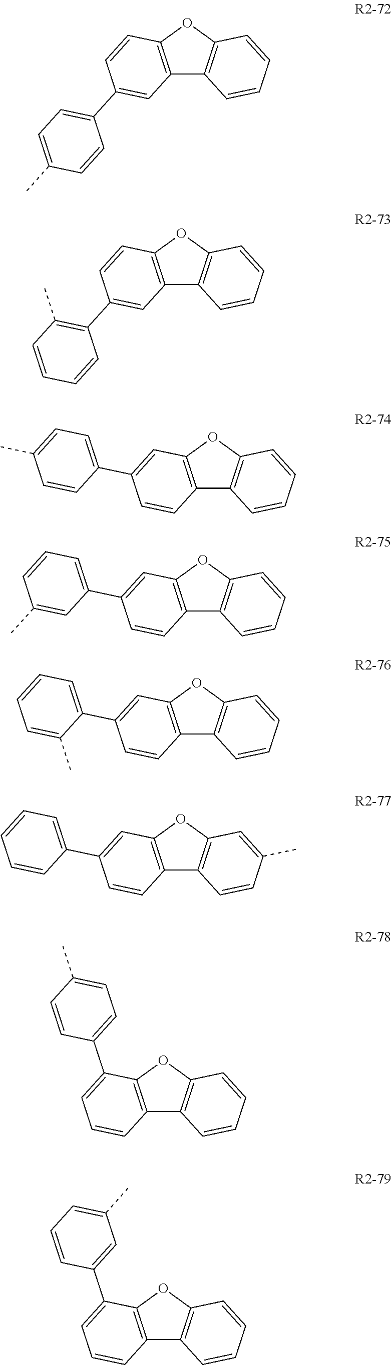

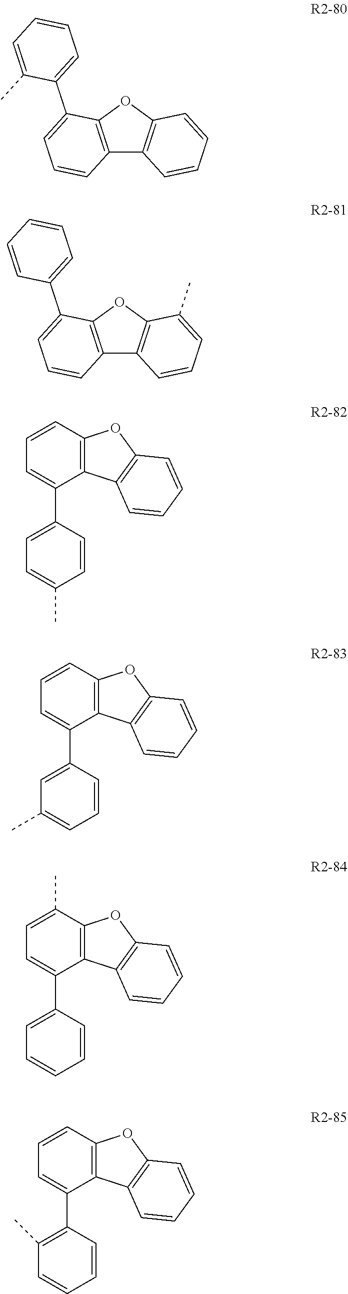

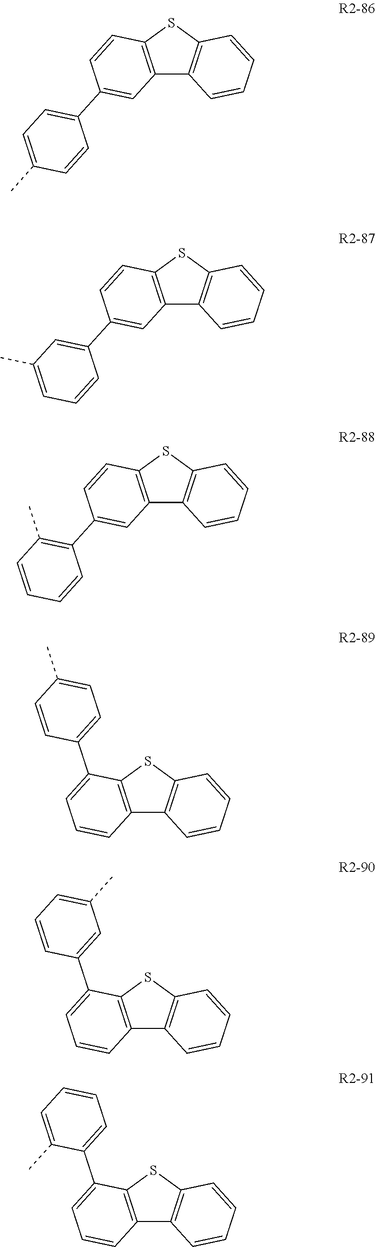

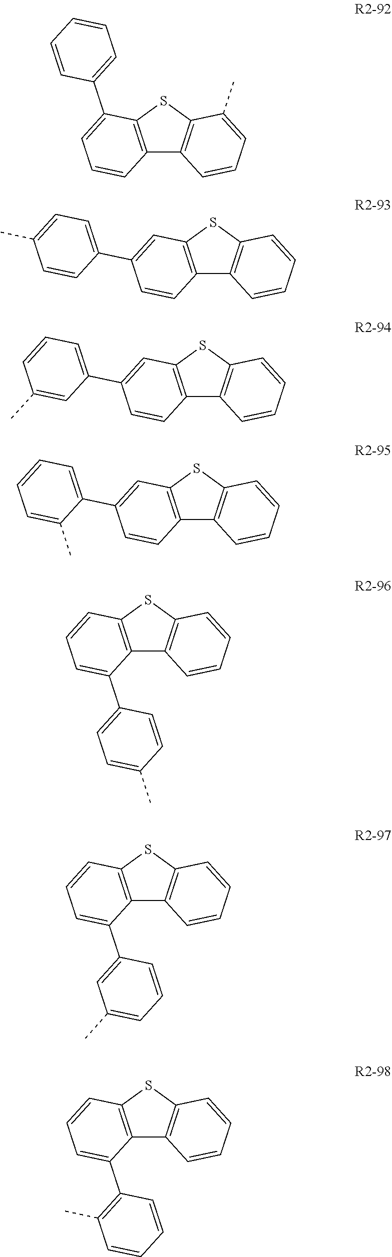

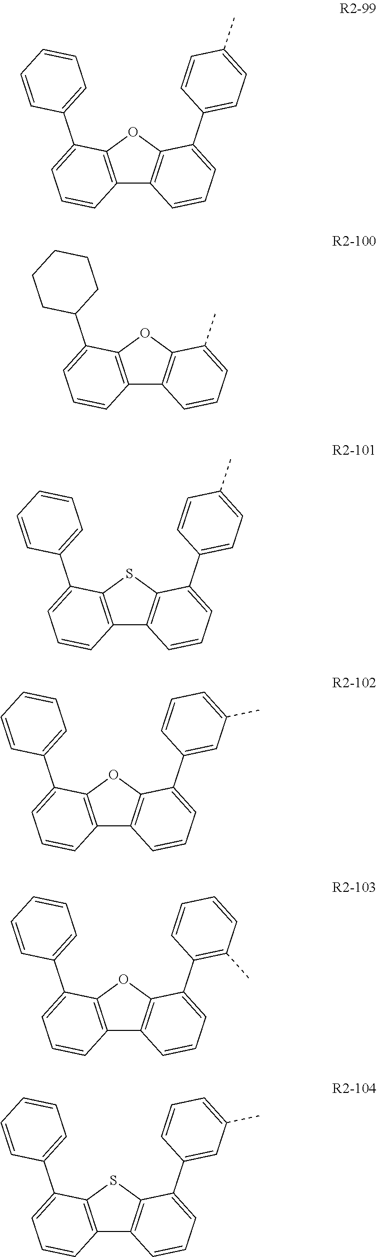

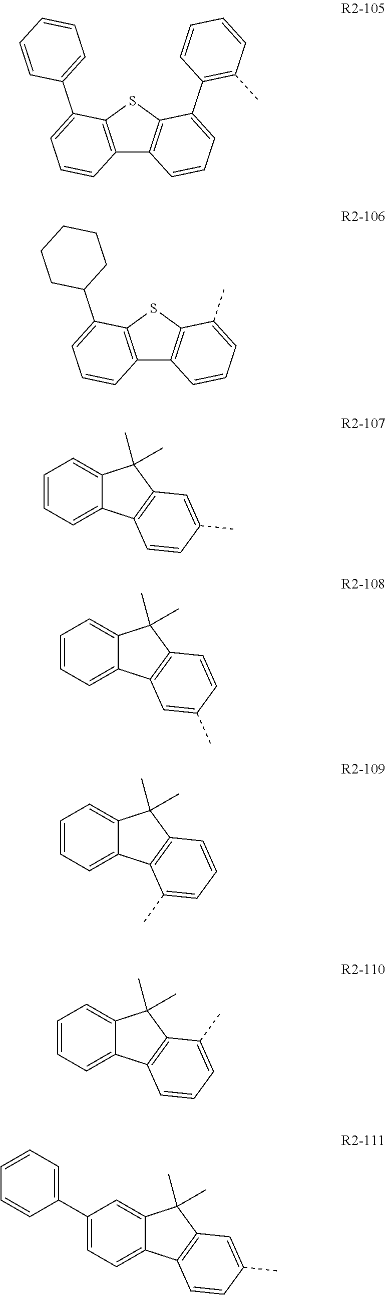

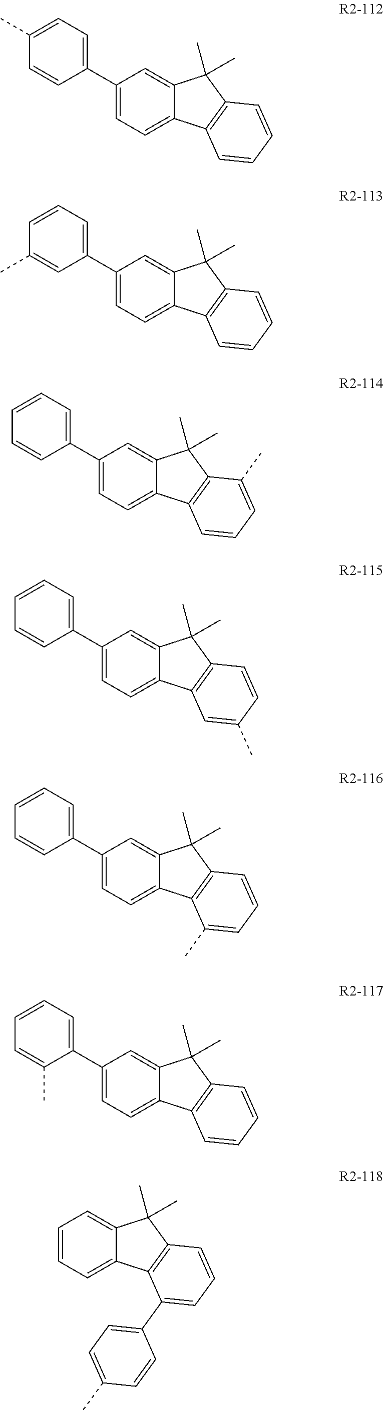

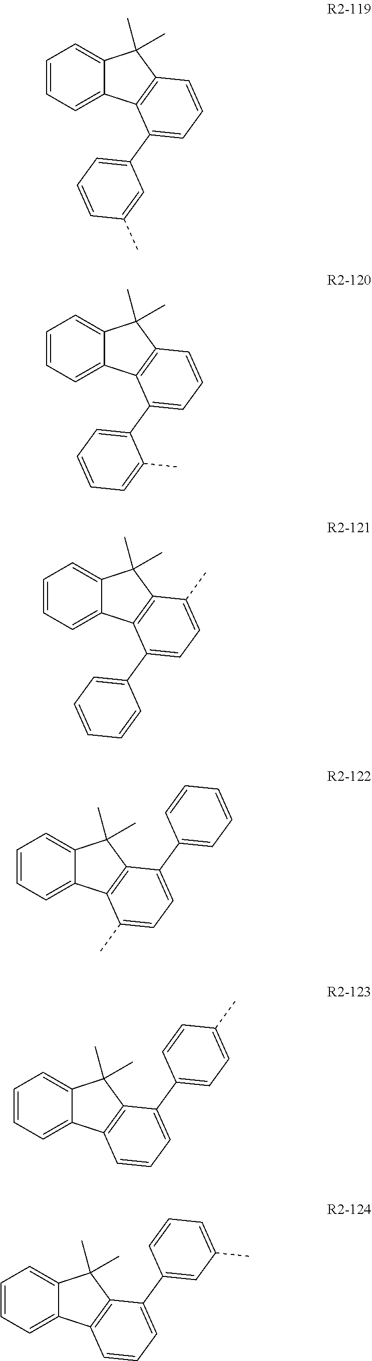

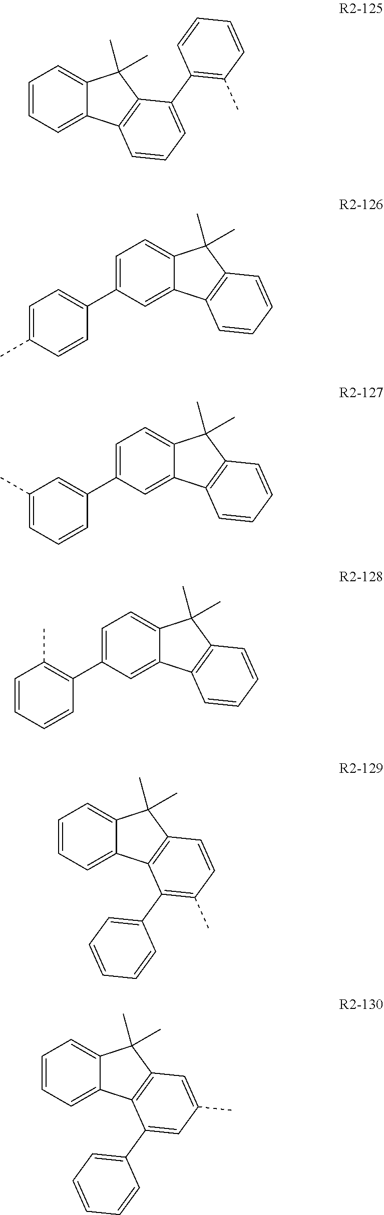

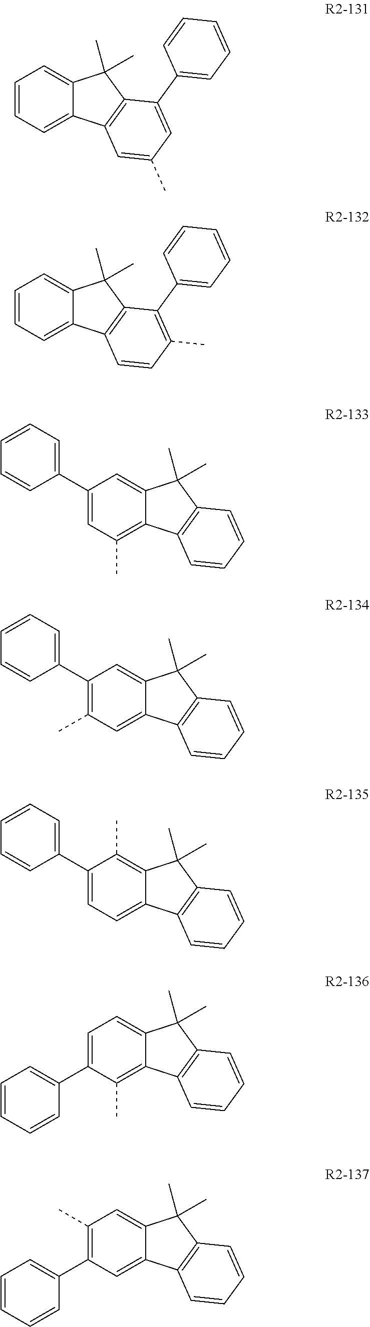

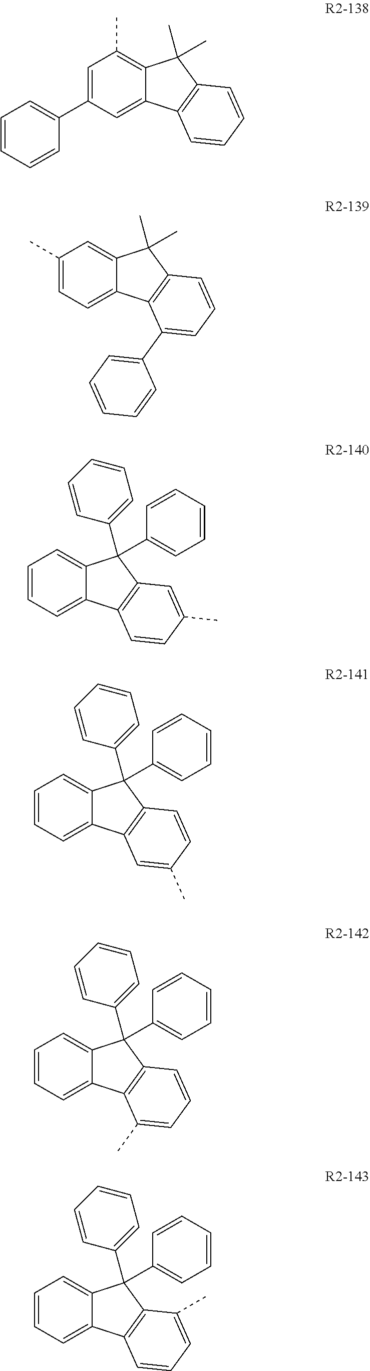

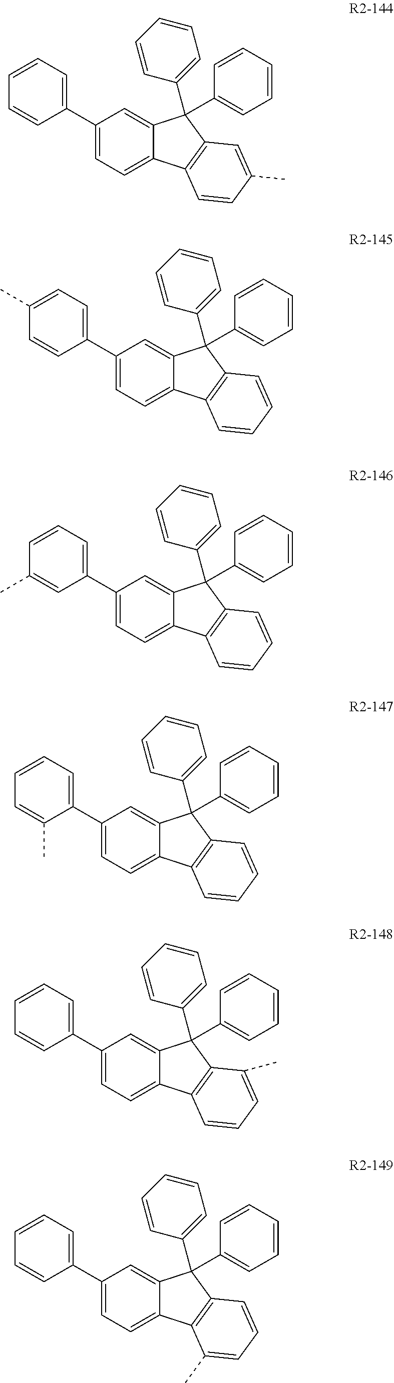

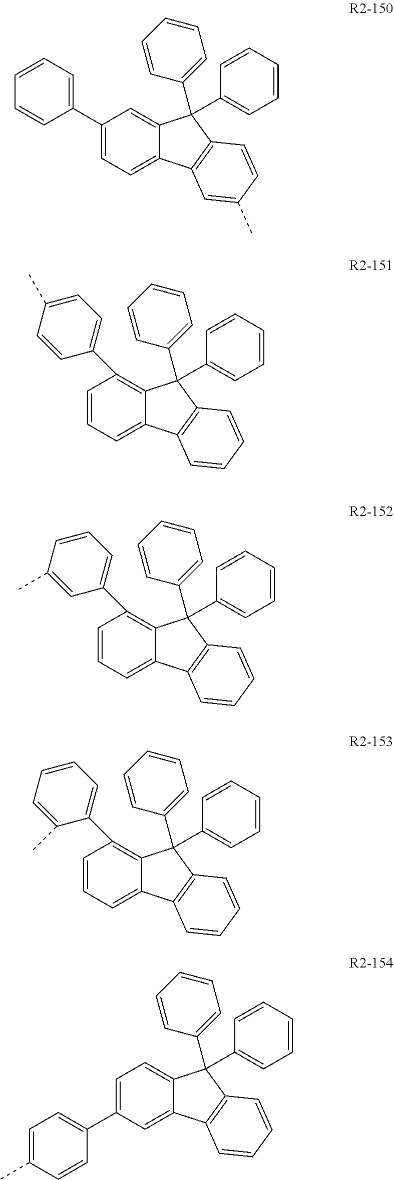

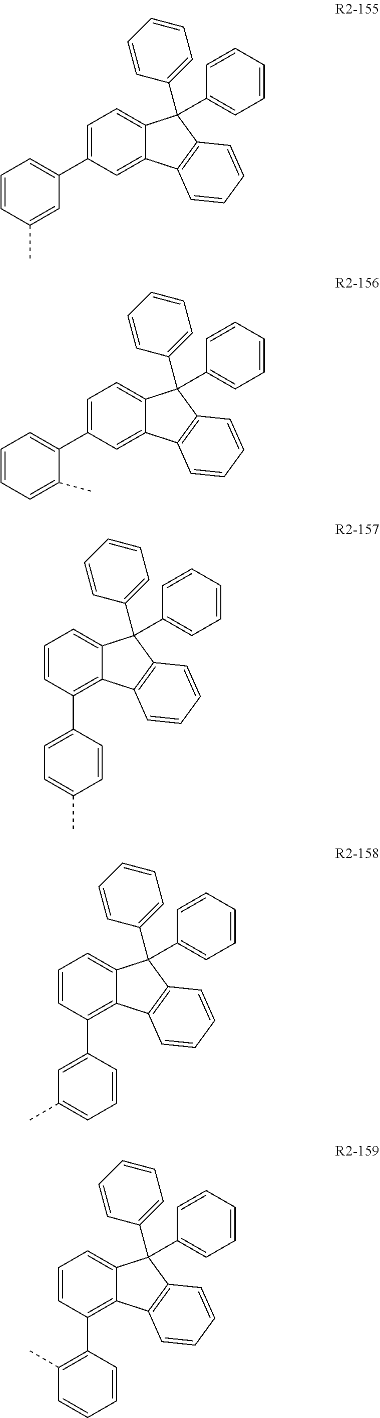

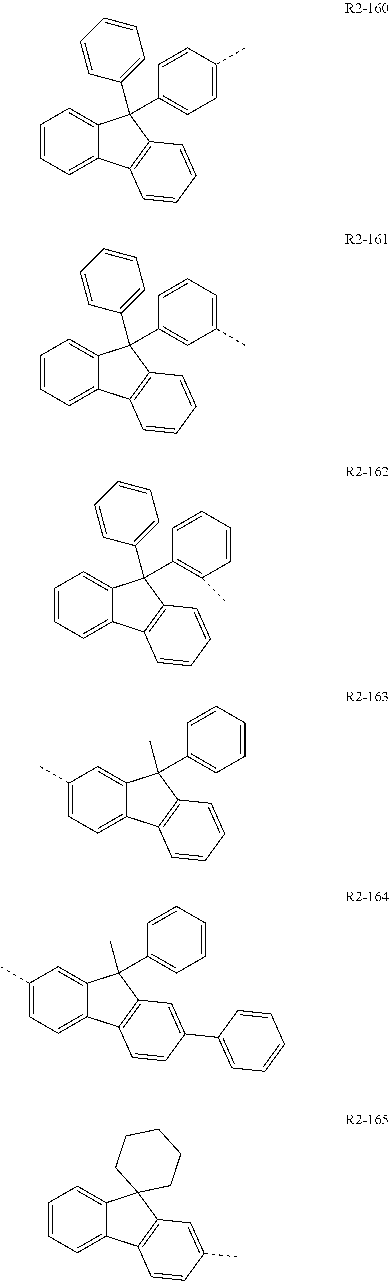

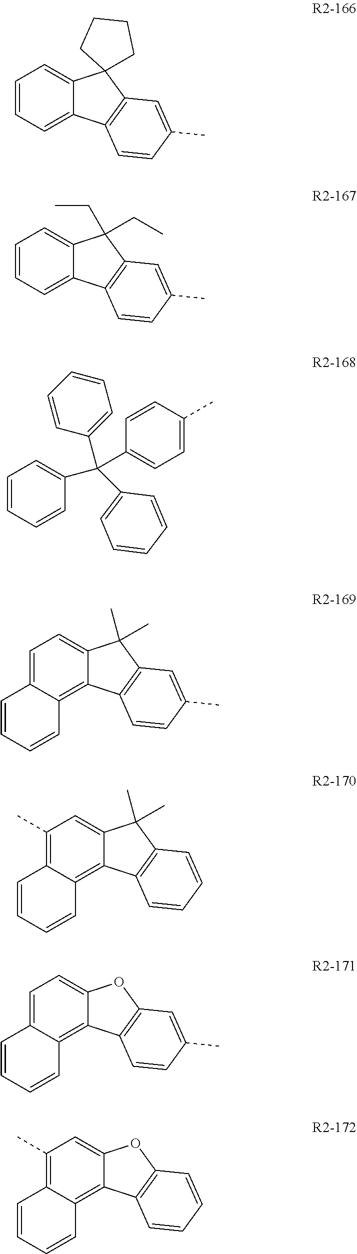

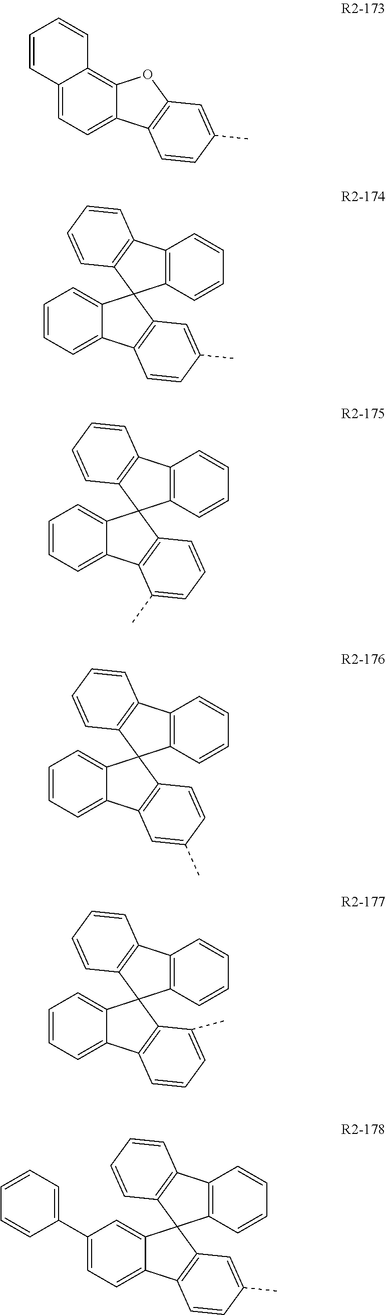

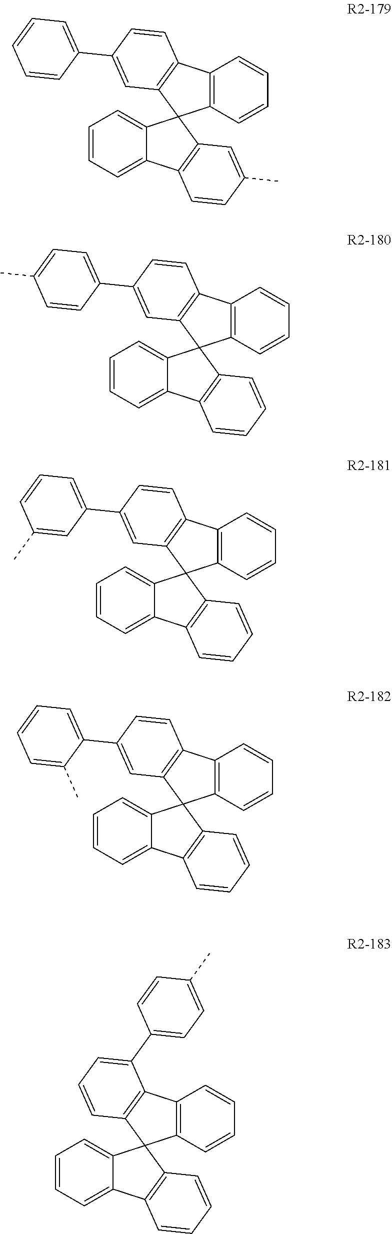

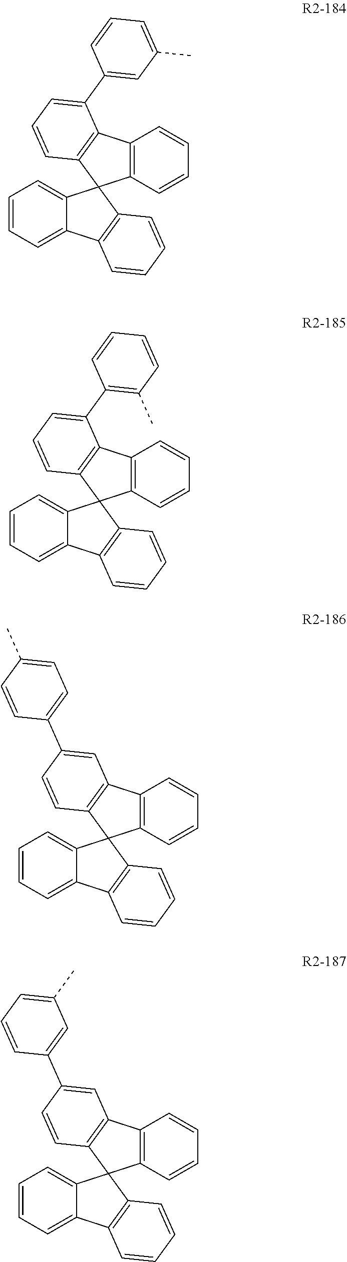

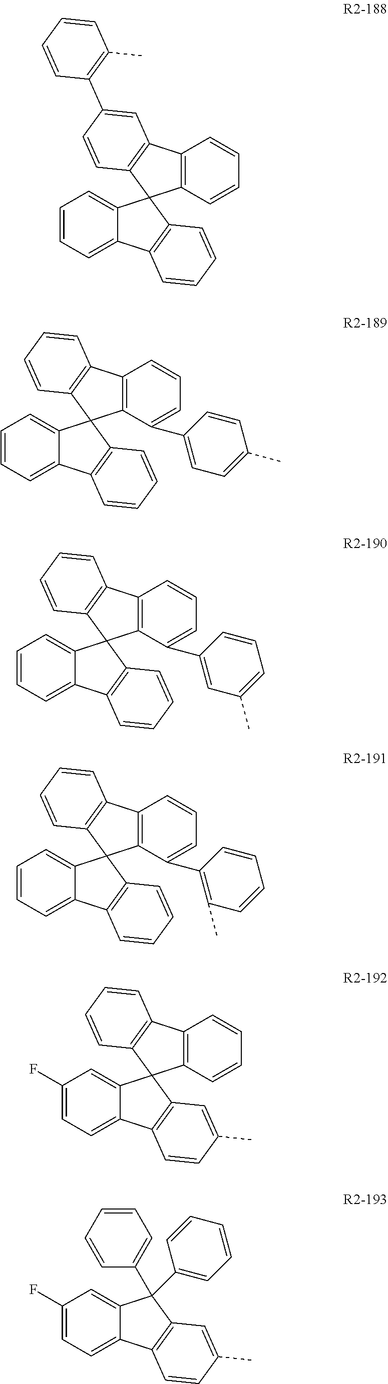

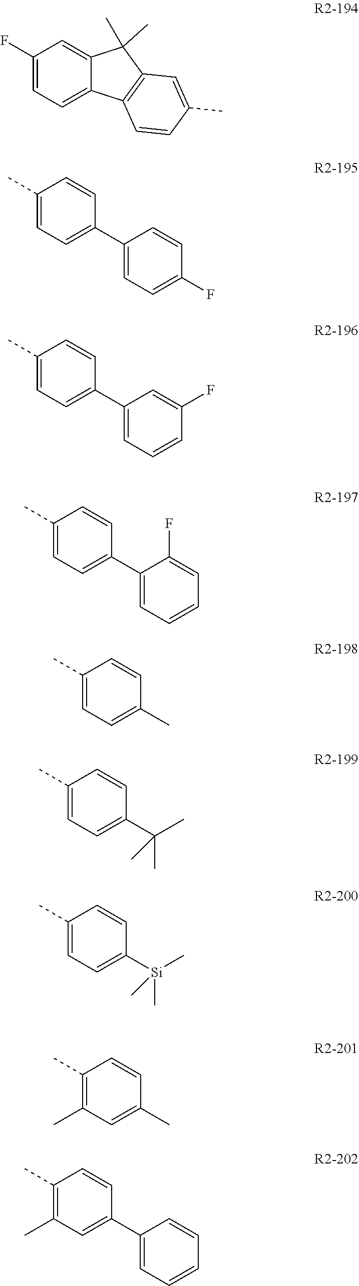

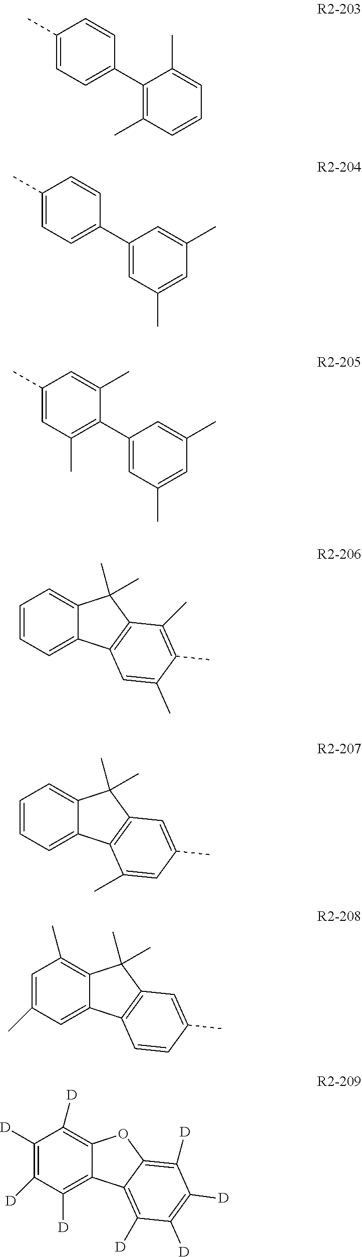

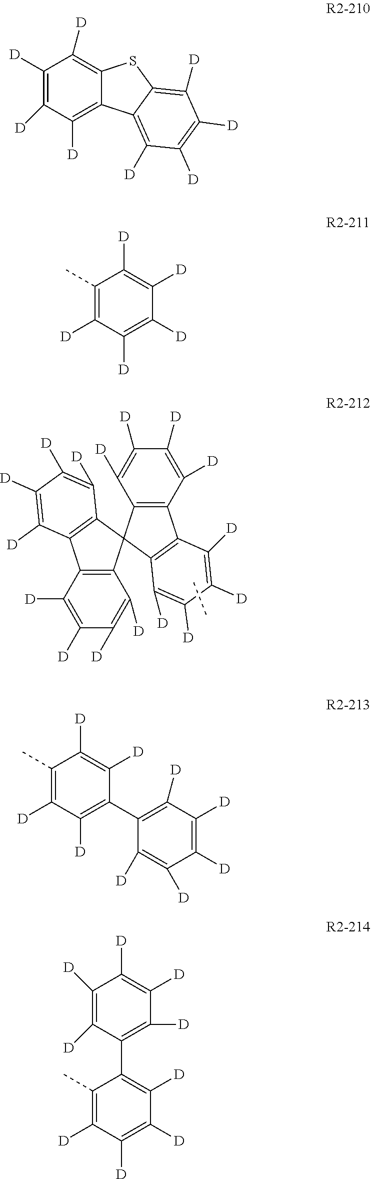

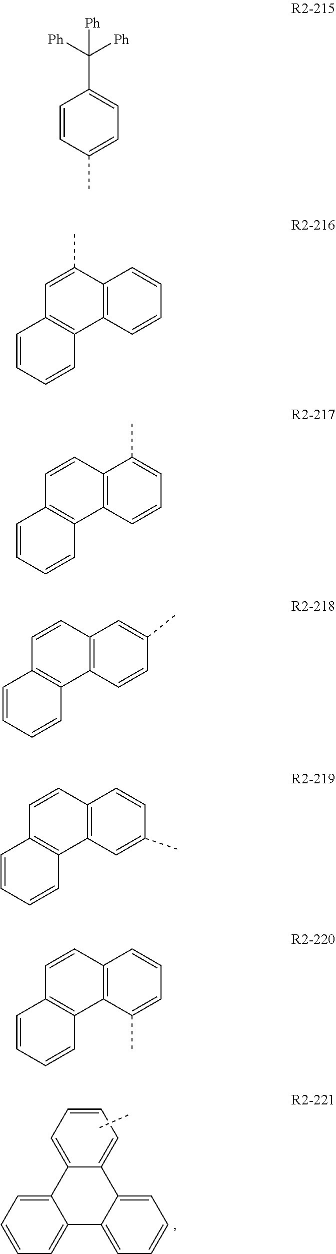

where the dotted line represents the bond to the rest of the formula (2). The substituents R2-1 to R2-221 are preferably partly deuterated or fully deuterated.

If, in compounds of the formula (2), x is 2 and a₁ is 1, 2 or 3, the two substituents R², in a preferred embodiment, form a monocyclic or polycyclic, aliphatic, aromatic or heteroaromatic ring system that may be substituted by one or more R³ radicals, with the condition that the ring system and substituents bonded thereto do not contain a carbazole group.

In a preferred embodiment, the host material 2 of the formula (2) is at least one compound of the formula (3):

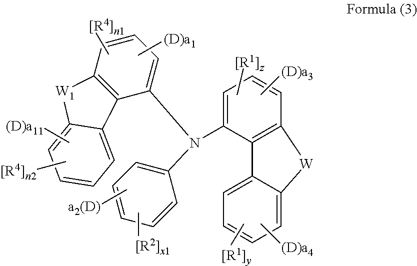

where W, R¹, R², a1, a2, a3, a4, x, x1, y and z have a definition given above or given hereinafter and the symbols and indices used are as follows:
W₁ is O, S or C(R)₂, where R has a definition given above;
R⁴ is the same or different at each instance and is selected from the group consisting of F, Cl, Br, I, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br or I, an aromatic or heteroaromatic ring system which has 5 to 60 aromatic ring atoms and may be substituted in each case by one or more R³ radicals, where it is optionally possible for two or more adjacent substituents R⁴ to form a monocyclic or polycyclic, aliphatic, aromatic or heteroaromatic ring system which may be substituted by one or more R³ radicals, with the condition that R⁴ and substituents bonded thereto do not contain a carbazole group;
a₁₁ is 0, 1, 2, 3 or 4;
n1 is 0, 1 or 2; and
n2 is 0, 1, 2, 3 or 4.

In compounds of the formula (3), a11 is preferably 1, 2, 3 or 4.

In compounds of the formula (3), a1+a2+a3+a4+a11 is preferably selected from 3, 4, 5, 6, 7, 8, 9, 10, 11, 12, 13, 14, 15, 16, 17, 18 or 19.

In compounds of the formula (3), n1 is preferably 0 or 1.

In compounds of the formula (3), n2 is preferably 0 or 1.

In compounds of the formula (3), n1+n2 is preferably 0 or 1.

In compounds of the formula (3), n1+n2 is preferably 0.

When the substituent R⁴ occurs in compounds of the formula (3) as described above, or in compounds of the formulae (3a), (3b), (3c), (3d) and (3e) as described hereinafter, it is preferably selected from the group of F, a straight-chain or branched alkyl group having 1 to 20 carbon atoms, each of which may be substituted by one or more R³ radicals, and the substituents R2-1 to R2-221 as described above, where the substituents R2-1 to R2-221 may also be partly deuterated or fully deuterated, if not already described as such, and where the dotted line represents the bond to the rest of the formulae (3), (3a), (3b), (3c), (3d) or (3e), or two or more adjacent substituents R⁴ form a monocyclic or polycyclic, aromatic or heteroaromatic ring system that may be substituted by one or more R³ radicals, with the condition that R³ and substituents bonded thereto do not contain a carbazole group.

When the substituent R⁴ occurs in compounds of the formulae (3), (3a), (3b), (3c), (3d) and (3e) as described above or hereinafter, it is more preferably selected from the group of F, a straight-chain or branched alkyl group having 1 to 10 carbon atoms, each of which may be substituted by one or more Ra radicals, and the substituents R2-1 to R2-3, R2-63 to R2-70, R2-107 to R2-111, R2-114 to R2-116, R2-122, R2-129 to R2-139 and R2-206 to R2-215 and R2-221 as described above, which are partly deuterated or fully deuterated.

The invention accordingly further provides an organic luminescent device as described above or described as preferred, wherein the host material 2 corresponds to at least one compound of the formula (3) as described above.

In compounds of the formula (2) or (3) as described above or described as preferred, W is O, S or C(R)₂ where each R is independently a straight-chain or branched alkyl group which has 1 to 4 carbon atoms and may be partly or fully deuterated, or an unsubstituted or partly or fully deuterated aromatic ring system having 6 to 18 carbon atoms, where two substituents R together with the carbon atom to which they are bonded may form a mono- or polycyclic, aliphatic or aromatic or heteroaromatic, unsubstituted, partly deuterated or fully deuterated ring system which may be substituted by one or more substituents R³, with the condition that the ring system and substituents bonded thereto do not contain a carbazole group. W is preferably O or C(R)₂. W is more preferably C(R)₂ where R has a definition given above or given as preferred hereinafter.

In compounds of the formula (2) or (3) as described above or described as preferred, R is preferably a methyl or phenyl group that may be partly or fully deuterated, or two substituents R together with the carbon atom to which they are bonded form a mono- or polycyclic, aliphatic or aromatic or heteroaromatic, unsubstituted, partly deuterated or fully deuterated ring system which may be substituted by one or more substituents R³, with the condition that the ring system and substituents bonded thereto do not contain a carbazole group.

Preferred compounds of the formula (2) or (3) are represented by the formulae (2a) to (2e) and (3a) to (3e):

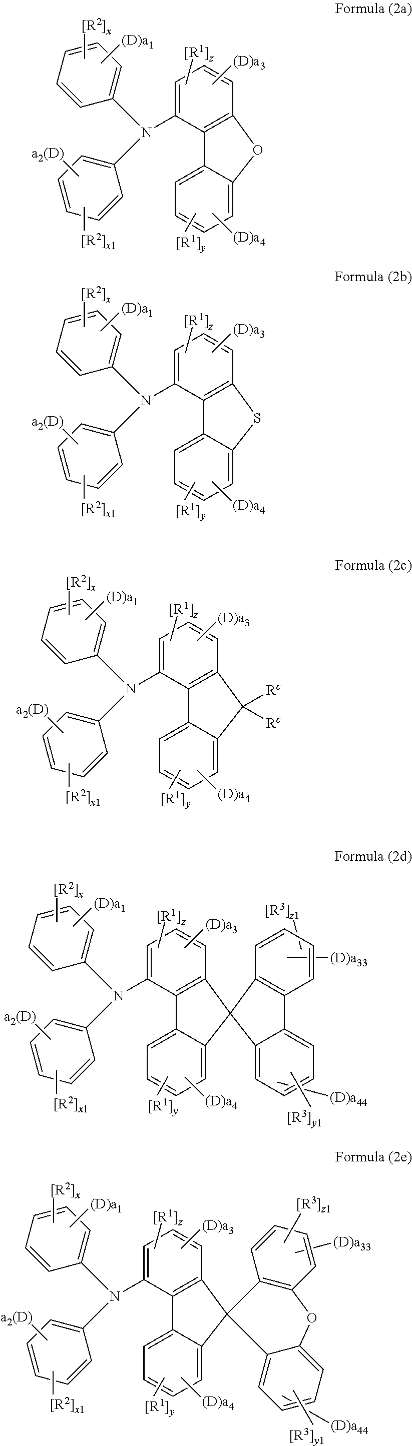

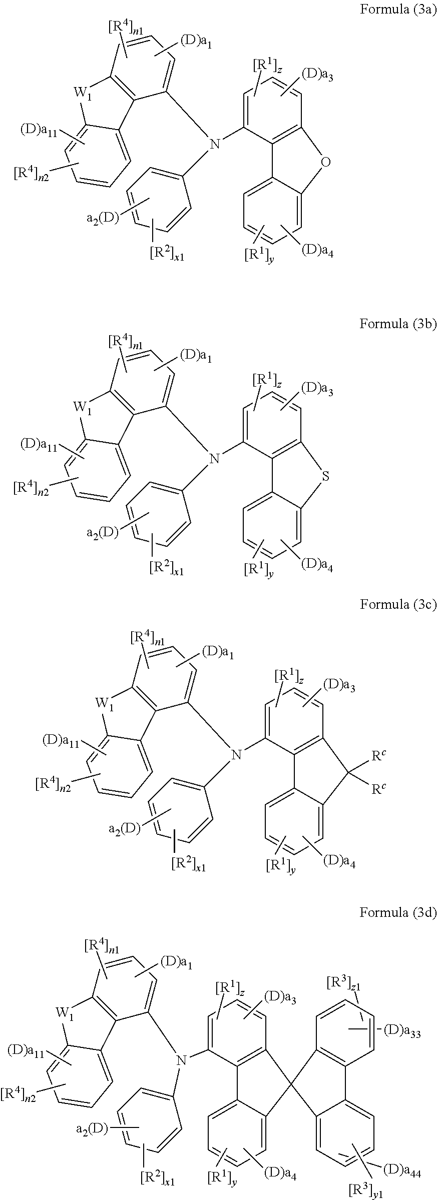

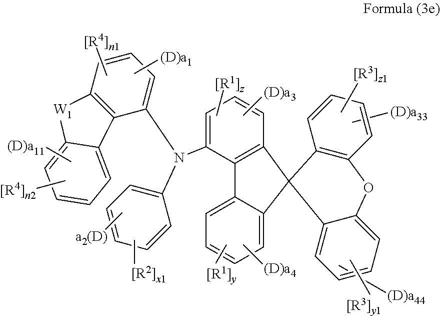

where a1, a2, a3, a4, a11, R², x, x1, y, z, R¹, R³, R⁴ and W₁ have a definition given above or a definition given as preferred above or hereinafter, and
R^{c} is in each case independently a straight-chain or branched alkyl group which has 1 to 4 carbon atoms and may be partly or fully deuterated, or an unsubstituted or partly or fully deuterated aromatic ring system having 6 to 18 carbon atoms;
y1, z1 are each independently 0, 1 or 2; and
a₃₃, a₄₄ are each independently 0, 1, 2, 3 or 4, with the condition that R³ and substituents bonded thereto do not contain a carbazole group.

In compounds of the formulae (2c) and (3c) as described above, or in compounds of the formulae (3h), (3l), (3n), (3o), (4) and (5) as described hereinafter, R^{c} is preferably the same and is a straight-chain or branched alkyl group having 1 to 4 carbon atoms that may be partly or fully deuterated, or an unsubstituted or partly or fully deuterated phenyl. In compounds of the formulae (2c) and (3c) as described above, or in compounds of the formulae (3h), (3l), (3n), (3o), (4) and (5) as described hereinafter, R^{c} is preferably the same and is in each case CD₃.

In compounds of the formulae (2d) and (2e), a33 is preferably 1, 2, 3 or 4. In compounds of the formulae (2d) and (2e), a₄₄ is preferably 1, 2, 3 or 4. In compounds of the formulae (2d) and (2e), y1 and z1 are preferably 0.

In compounds of the formulae (2d) and (2e), a1+a2+a3+a4+a33+a44 is preferably selected from 3, 4, 5, 6, 7, 8, 9, 10, 11, 12, 13, 14, 15, 16, 17, 18, 19, 20, 21, 22, 23, 24 or 25.

In compounds of the formulae (3a), (3b), (3c), (3d) and (3e) and the compounds of the formulae (3f), (3g), (3h), (3i), (3j), (3k), (3l), (3m), (3n), (3o), (4), (5), (6), (7), (8) and (9) specified below, a11 is preferably 1, 2, 3 or 4.

In compounds of the formulae (3d) and (3e) and the compounds of the formulae (6), (7), (8) and (9) specified below, a33 is preferably 1, 2, 3 or 4. In compounds of the formulae (3d) and (3e) and the compounds of the formulae (6), (7), (8) and (9) specified below, a44 is preferably 1, 2, 3 or 4. In compounds of the formulae (3d) and (3f), y1 and z1 are preferably 0.

In compounds of the formulae (3a), (3b) and (3c), a1+a2+a3+a4+a11 is preferably selected from 3, 4, 5, 6, 7, 8, 9, 10, 11, 12, 13, 14, 15, 16, 17, 18 or 19. In compounds of the formulae (3d) and (3e), a1+a2+a3+a4+a11+a33+a44 is preferably selected from 3, 4, 5, 6, 7, 8, 9, 10, 11, 12, 13, 14, 15, 16, 17, 18, 19, 20, 21, 22, 23, 24, 25, 26 or 27.

When the substituent R³ occurs in compounds of the formulae (2d), (2e), (3d) and (3e) as described above, or in compounds of the formulae (3i), (3m), (5), (6), (7), (8) and (9) as described hereinafter, it is preferably selected from the group of F, a straight-chain or branched alkyl group having 1 to 20 carbon atoms in which one or more hydrogen atoms may be replaced by D, F, Cl, Br, I or CN, and the substituents R2-1 to R2-221 as described above, where the substituents R2-1 to R2-221 may also be partly deuterated or fully deuterated, if not already described as such, and where the dotted line represents the bond to the rest of the formulae (2d), (2e), (3d), (3e), (3i), (3m), (5), (6), (7), (8) and (9).

When the substituent R³ occurs in compounds of the formulae (2d), (2e), (3d) and (3e) as described above, or in compounds of the formulae (3i), (3m), (5), (6), (7), (8) and (9) as described hereinafter, it is more preferably selected from the group of F, a straight-chain or branched alkyl group having 1 to 10 carbon atoms in which one or more hydrogen atoms is/are replaced by D, and the substituents R2-1 to R2-3, R2-63 to R2-70, R2-107 to R2-111, R2-114 to R2-116, R2-122, R2-129 to R2-139 and R2-206 to R2-215 and R2-221 as described above, which may be partly deuterated or fully deuterated, if not already described as such.

In a preferred embodiment of the compounds of the formulae (3), (3a), (3b), (3c), (3d) and (3e) as described above or described as preferred, W₁ is O, S or C(R)₂ where each R is independently a straight-chain or branched alkyl group which has 1 to 4 carbon atoms and may be partly or fully deuterated, or an unsubstituted or partly or fully deuterated aromatic ring system having 6 to 18 carbon atoms, where two substituents R together with the carbon atom to which they are bonded may form a mono- or polycyclic, aliphatic or aromatic or heteroaromatic, unsubstituted, partly deuterated or fully deuterated ring system which may be substituted by one or more substituents R³, with the condition that the ring system and substituents bonded thereto do not contain a carbazole group. W₁ is preferably O or C(R)₂. W₁ is more preferably C(R)₂ where R has a definition given above or given as preferred above.

Preferred compounds of the formulae (3), (3a), (3b), (3c) and (3d) are represented by the formulae (3f), (3g), (3h), (3i), (3j), (3k), (3l), (3m), (3n), (3o), (4), (5), (6), (7), (8) and (9):

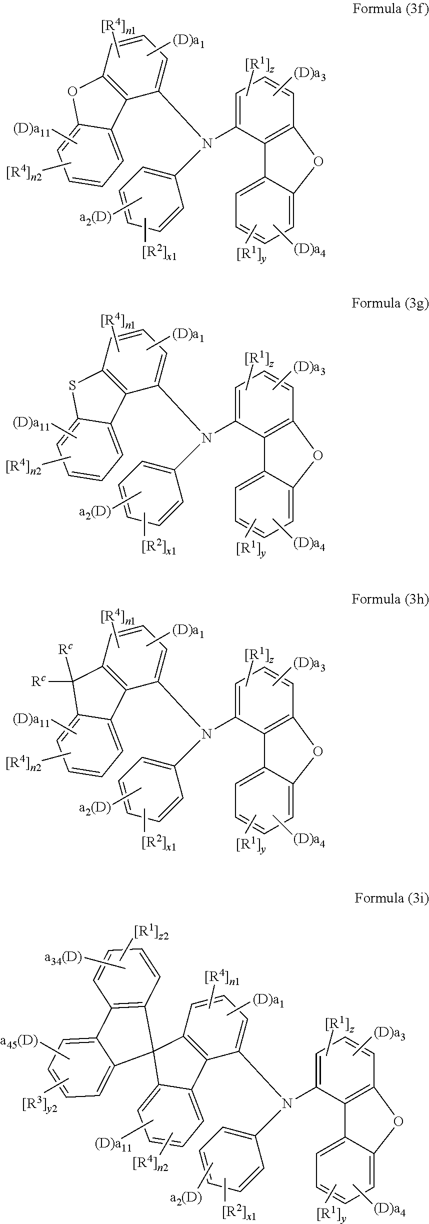

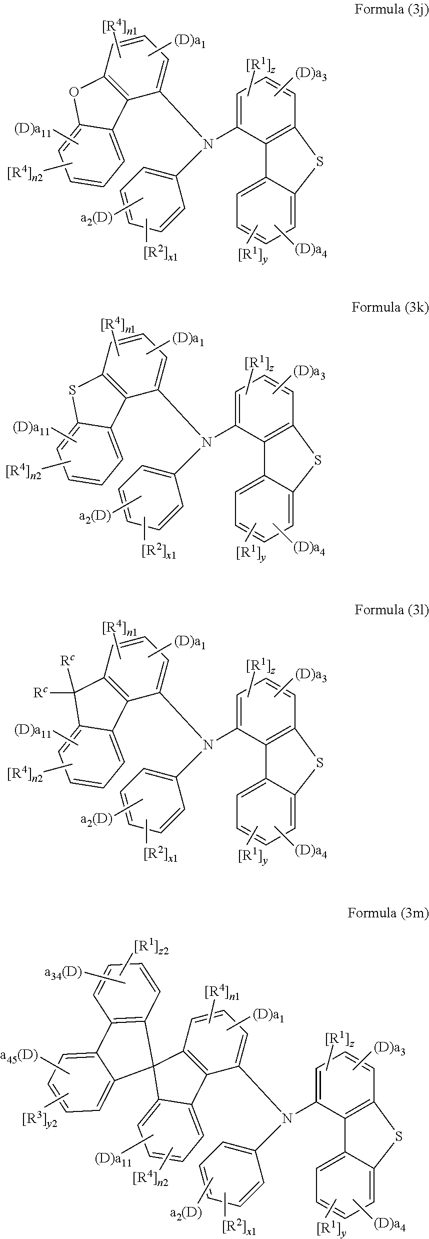

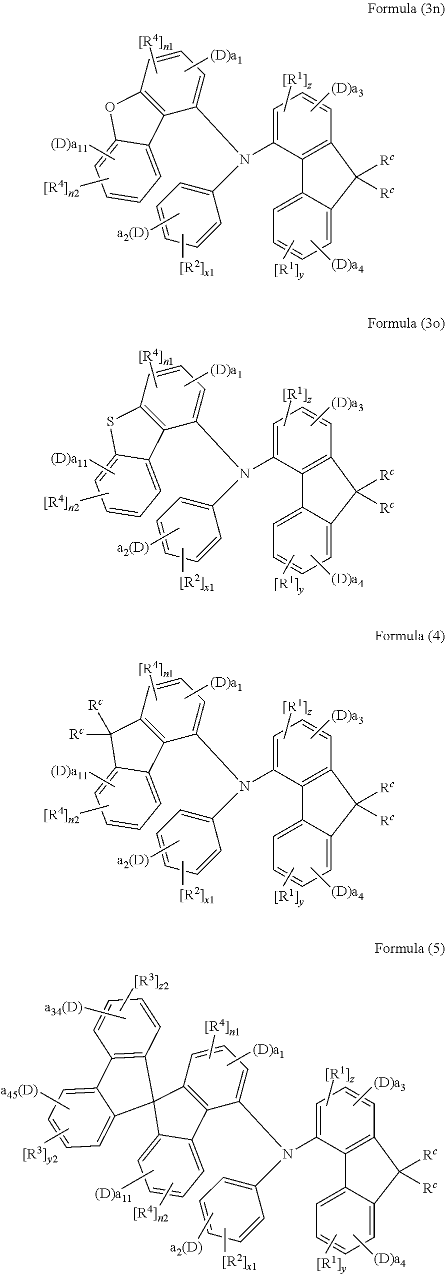

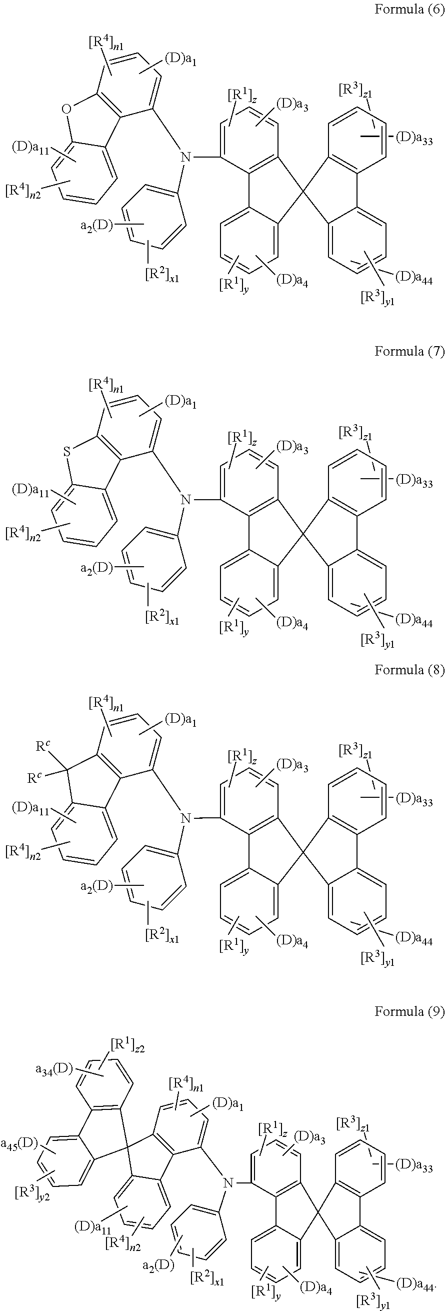

where a₁, a₂, a₃, a₄, a₁₁, a₃₃, a₄₄, R², x, x1, y, y1, z, z1, R¹, R³, R^{c} and R⁴ have a definition given above or a definition given as preferred above or hereinafter, and
y2, z2 are each independently 0, 1 or 2; and
a34, a45 are each independently 0, 1, 2, 3 or 4.

In compounds of the formulae (3f), (3g), (3h), (3j), (3k), (3l), (3n), (3o) and (4), a1+a2+a3+a4+a11 is preferably selected from 3, 4, 5, 6, 7, 8, 9, 10, 11, 12, 13, 14, 15, 16, 17, 18 or 19. In compounds of the formulae (6), (7) and (8), a₁+a₂+a₃+a₄+a₁₁+a₃₃+a₄₄ is preferably selected from 3, 4, 5, 6, 7, 8, 9, 10, 11, 12, 13, 14, 15, 16, 17, 18, 19, 20, 21, 22, 23, 24, 25, 26 or 27.

In compounds of the formulae (3i), (3m) and (5), a₁+a₂+a₃+a₄+a₁₁+a₃₄+a₄₅ is preferably selected from 3, 4, 5, 6, 7, 8, 9, 10, 11, 12, 13, 14, 15, 16, 17, 18, 19, 20, 21, 22, 23, 24, 25, 26 or 27.

In compounds of the formulae (9), a₁+a₂+a₃+a₄+a₁₁+a₃₃+a₄₄+a₃₄+a₄₅ is preferably selected from 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34 or 35.

In compounds of the formulae (3i), (3m), (5) and (9), y2 and z2 are preferably 0.

In compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9), y is preferably 0 or 1. In compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9), z is preferably 0 or 1. In compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9), y+z is preferably 0 or 1. In a preferred embodiment of the compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9), y+z is preferably 0.

When the substituent R¹ occurs in compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) as described above, it is preferably selected from the group of F and a straight-chain, branched or cyclic alkyl group having 1 to 20 carbon atoms in which one or more hydrogen atoms may be replaced by D, F, Cl, Br, I or CN.

When the substituent R¹ occurs in compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) as described above, it is more preferably selected from the group of F and a straight-chain or branched alkyl group having 1 to 10 carbon atoms in which one or more hydrogen atoms may be replaced by D.

When the substituent R¹ occurs in compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) as described above, it is most preferably selected from the group of a straight-chain or branched alkyl group having 1 to 10 carbon atoms in which one or more hydrogen atoms is/are replaced by D.

Particular preference is given to using compounds of the formulae (4), (5), (6), (7), (8) and (9) as host material 2 in the device of the invention, where the symbols and indices mentioned have a definition given above or respectively given as preferred above or a definition respectively given as preferred hereinafter.

Very particular preference is given to using compounds of the formulae (5), (8) and (9) as host material 2 in the device of the invention, where the symbols and indices mentioned have a definition given above or respectively given as preferred above or a definition respectively given as preferred hereinafter.

The invention accordingly further provides an organic electroluminescent device as described above or described as preferred, wherein the at least one compound of the formula (2) corresponds to a compound of the formula (5), (8) or (9).

In compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9), x1 is preferably 1 or 2, where R² is the same or different at each instance and is preferably selected from the group consisting of F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br, I, CN or NO₂, an aromatic or heteroaromatic ring system which has 5 to 60 aromatic ring atoms and may be substituted in each case by one or more Ra radicals, an aryloxy or heteroaryloxy group which has 5 to 60 aromatic ring atoms and may be substituted by one or more R³ radicals, or a combination of these systems, where it is optionally possible for two or more adjacent substituents R² to form a monocyclic or polycyclic, aliphatic, aromatic or heteroaromatic ring system which may be substituted by one or more R³ radicals, with the condition that R² and substituents bonded thereto do not contain a carbazole group.

If, in compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9), x1 is 1 and a₁ is 1, 2, 3 or 4, the substituent R² is preferably selected from the group of substituents R2-1 to R2-221, where the substituents R2-1 to R2-221 in this case may be substituted by one or more R⁵ radicals in which one or more hydrogen atoms or deuterium atoms would be replaced by R⁵, where R⁵ is the same or different at each instance and is selected from the group consisting of F, CN, N(Ar₁)₂, an aliphatic hydrocarbyl radical having 1 to 20 carbon atoms and an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; it is possible here for two or more adjacent substituents R⁵ together to form a mono- or polycyclic, aliphatic, aromatic or heteroaromatic ring system, with the condition that the ring system and substituents bonded thereto do not contain a carbazole group.

When the substituent R⁵ occurs in substituents R2-1 to R2-221 of compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) as described above, it is preferably selected from the group of F, N(Ar₁)₂, a straight-chain or branched alkyl group having 1 to 10 carbon atoms in which one or more hydrogen atoms may be replaced by D and an aromatic or heteroaromatic ring system having 5 to 18 aromatic ring atoms in which one or more hydrogen atoms may be replaced by D, where Ar₁ has a definition given above, with the condition that the ring system and substituents bonded thereto do not contain a carbazole group, or two or more adjacent substituents R⁵ together form a mono- or polycyclic, aliphatic, aromatic or heteroaromatic ring system, with the condition that the ring system and substituents bonded thereto do not contain a carbazole group.

In the case that the substituent N(Ar₁)₂ occurs, each Ar₁ is independently preferably selected from the group of R2-1 to R2-221 as described above, which may be partly deuterated or fully deuterated, and with the condition that the ring system and substituents bonded thereto do not contain a carbazole group, where the dotted line binds to the nitrogen atom.

In a preferred embodiment of the host material 2, represented by the compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) as described above, the N-bonded substituent of the part-formula (2-0):

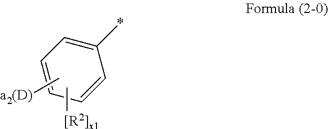

is selected from the group of substituents R2-1 to R2-221, where at least one hydrogen atom in the substituents R2-1 to R2-221 is replaced by D, where the substituents R2-1 to R2-221 in this case may be substituted by one or more R⁵ radicals in which one or more hydrogen atoms or deuterium atoms, but not the at least one deuterium atom, would be replaced by R⁵, where R⁵ has a definition given above or given as preferred, with the condition that the ring system and substituents bonded thereto do not contain a carbazole group and * denotes the attachment to the radical of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9).

In this embodiment, it is preferable when the N-bonded substituent of the part-formula (2-0) is selected from the group of substituents R2-2 to R2-47, R2-63 to R2-98, R2-107 to R2-139, R2-174 to R2-197, R2-206 to R2-214 and R2-221, where at least one hydrogen atom is replaced by D, i.e. the substituents are partly deuterated or fully deuterated, where the substituents mentioned in this case may be substituted by one or more R⁵ radicals in which one or more hydrogen atoms or deuterium atoms, but not the at least one deuterium atom, would be replaced by R⁵, where R⁵ has a definition given above or given as preferred, with the condition that the ring system and substituents bonded thereto do not contain a carbazole group and the dotted line denotes the attachment to the radical of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9).

In this embodiment, it is particularly preferable when the N-bonded substituent of the part-formula (2-0) is selected from the group of substituents R2-174 to R2-197 and R2-212, where at least one hydrogen atom is replaced by D, i.e. the substituents are partly deuterated or fully deuterated, where the substituents R2-174 to R2-197 and R2-212 in this case may be substituted by one or more R⁵ radicals in which one or more hydrogen atoms or deuterium atoms, but not the at least one deuterium atom, would be replaced by R⁵, where R⁵ has a definition given above or given as preferred, with the condition that the ring system and substituents bonded thereto do not contain a carbazole group and the dotted line denotes the attachment to the radical of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9). The substituents R2-1 to R2-221 as part-formula (2-0) are preferably partly deuterated or fully deuterated.

Examples of suitable host materials of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) that are selected in accordance with the invention and are preferably used in combination with at least one compound of the formula (1) in the electroluminescent device of the invention are the structures given below in table 3:

TABLE 3

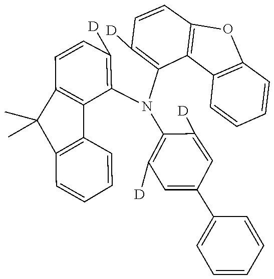 [SMILES: [2H]c1cc(-c2ccccc2)cc([2H])c1N(c1c([2H])ccc2c1-c1ccccc1C2(C)C)c1c([2H])ccc2oc3ccccc3c12]

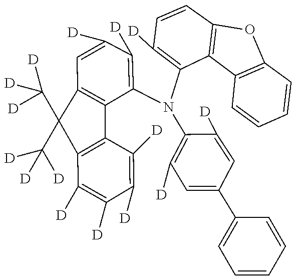 [SMILES: [2H]c1cc2c(c(N(c3c([2H])cc(-c4ccccc4)cc3[2H])c3c([2H])ccc4oc5ccccc5c34)c1[2H])-c1c([2H])c([2H])c([2H])c([2H])c1C2(C([2H])([2H])[2H])C([2H])([2H])[2H]]

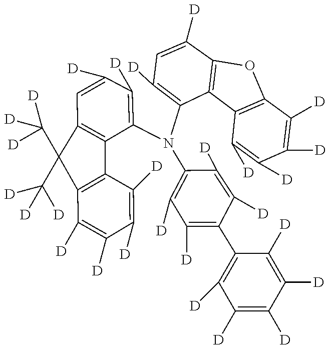 [SMILES: [2H]c1cc2c(c(N(c3c([2H])c([2H])c(-c4c([2H])c([2H])c([2H])c([2H])c4[2H])c([2H])c3[2H])c3c([2H])cc([2H])c4oc5c([2H])c([2H])c([2H])c([2H])c5c34)c1[2H])-c1c([2H])c([2H])c([2H])c([2H])c1C2(C([2H])([2H])[2H])C([2H])([2H])[2H]]

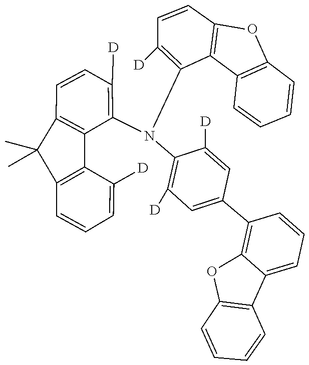 [SMILES: [2H]c1cccc2c1-c1c(ccc([2H])c1N(c1c([2H])cc(-c3cccc4c3oc3ccccc34)cc1[2H])c1c([2H])ccc3oc4ccccc4c13)C2(C)C]

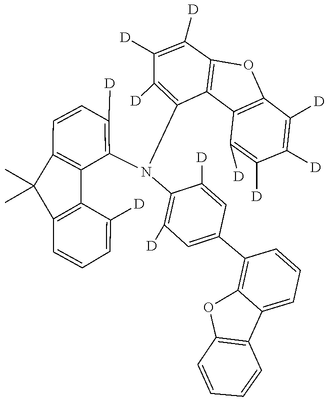 [SMILES: [2H]c1cccc2c1-c1c(ccc([2H])c1N(c1c([2H])cc(-c3cccc4c3oc3ccccc34)cc1[2H])c1c([2H])c([2H])c([2H])c3oc4c([2H])c([2H])c([2H])c([2H])c4c13)C2(C)C]

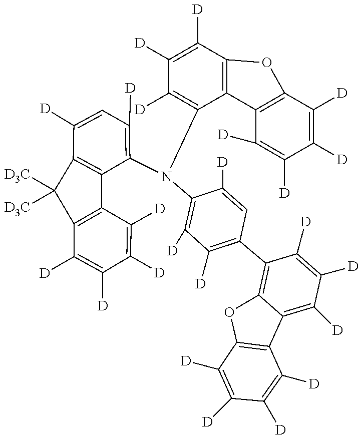 [SMILES: [2H]c1cc(-c2c([2H])c([2H])c([2H])c3c2oc2c([2H])c([2H])c([2H])c([2H])c23)c([2H])c([2H])c1N(c1c([2H])cc([2H])c2c1-c1c([2H])c([2H])c([2H])c([2H])c1C2(C([2H])([2H])[2H])C([2H])([2H])[2H])c1c([2H])c([2H])c([2H])c2oc3c([2H])c([2H])c([2H])c([2H])c3c12]

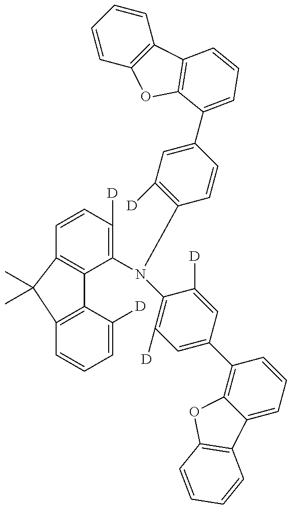 [SMILES: [2H]c1cc(-c2cccc3c2oc2ccccc23)ccc1N(c1c([2H])cc(-c2cccc3c2oc2ccccc23)cc1[2H])c1c([2H])ccc2c1-c1c([2H])cccc1C2(C)C]

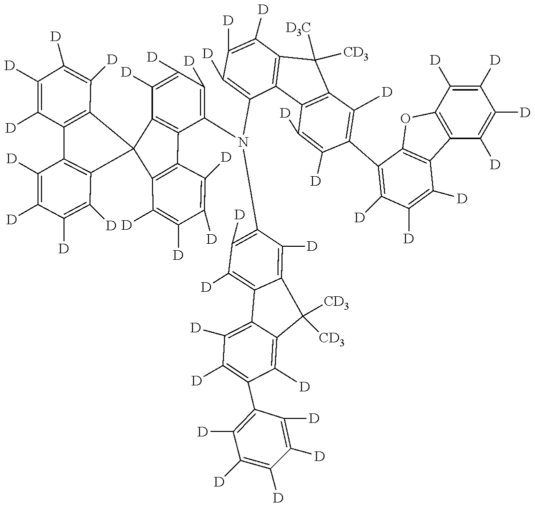 [SMILES: [2H]c1c([2H])c([2H])c(-c2c([2H])c([2H])c3c(c2[2H])C(C([2H])([2H])[2H])(C([2H])([2H])[2H])c2c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c(-c6c([2H])c([2H])c([2H])c7c6oc6c([2H])c([2H])c([2H])c([2H])c67)c([2H])c4C5(C([2H])([2H])[2H])C([2H])([2H])[2H])c([2H])c([2H])c2-3)c([2H])c1[2H]]

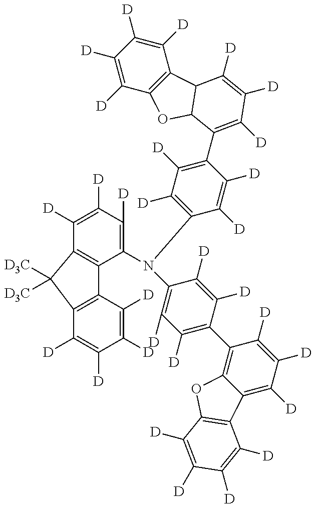 [SMILES: [2H]C1=C(c2c([2H])c([2H])c(N(c3c([2H])c([2H])c(-c4c([2H])c([2H])c([2H])c5c4oc4c([2H])c([2H])c([2H])c([2H])c45)c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c2[2H])C2Oc3c([2H])c([2H])c([2H])c([2H])c3C2C([2H])=C1[2H]]

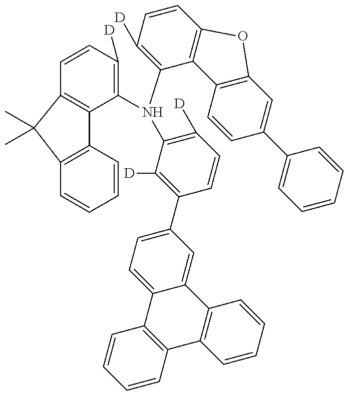 [SMILES: [2H]c1ccc(-c2ccc3c4ccccc4c4ccccc4c3c2)c([2H])c1N(c1c([2H])ccc2c1-c1ccccc1C2(C)C)c1c([2H])ccc2oc3cc(-c4ccccc4)ccc3c12]

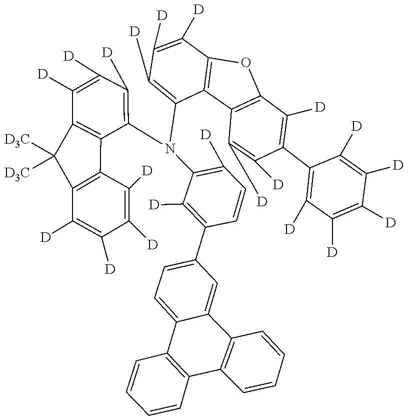 [SMILES: [2H]c1ccc(-c2ccc3c4ccccc4c4ccccc4c3c2)c([2H])c1N(c1c([2H])c([2H])c([2H])c2c1-c1c([2H])c([2H])c([2H])c([2H])c1C2(C([2H])([2H])[2H])C([2H])([2H])[2H])c1c([2H])c([2H])c([2H])c2oc3c([2H])c(-c4c([2H])c([2H])c([2H])c([2H])c4[2H])c([2H])c([2H])c3c12]

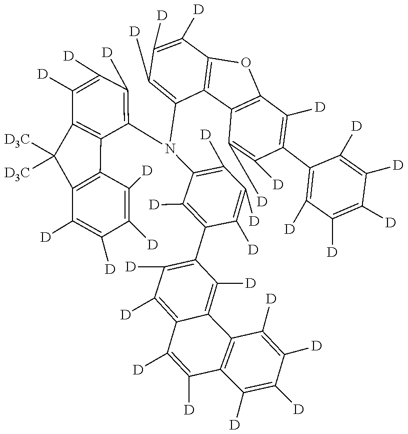 [SMILES: [2H]c1c([2H])c([2H])c(-c2c([2H])c([2H])c3c(oc4c([2H])c([2H])c([2H])c(N(c5c([2H])c([2H])c([2H])c(-c6c([2H])c([2H])c7c([2H])c([2H])c8c([2H])c([2H])c([2H])c([2H])c8c7c6[2H])c5[2H])c5c([2H])c([2H])c([2H])c6c5-c5c([2H])c([2H])c([2H])c([2H])c5C6(C([2H])([2H])[2H])C([2H])([2H])[2H])c43)c2[2H])c([2H])c1[2H]]

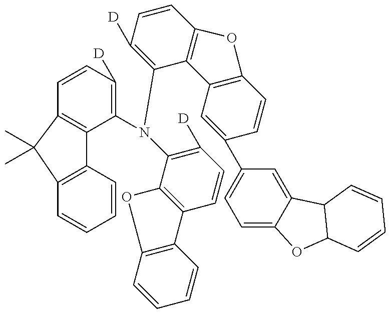 [SMILES: [2H]c1ccc2c(c1N(c1c([2H])ccc3c1oc1ccccc13)c1c([2H])ccc3oc4ccc(-c5ccc6c(c5)C5C=CC=CC5O6)cc4c13)-c1ccccc1C2(C)C]

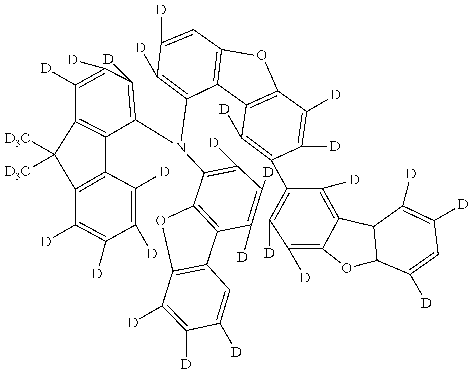 [SMILES: [2H]C1=CC([2H])=C([2H])C2c3c([2H])c(-c4c([2H])c([2H])c5oc6cc([2H])c([2H])c(N(c7c([2H])c([2H])c([2H])c8c7-c7c([2H])c([2H])c([2H])c([2H])c7C8(C([2H])([2H])[2H])C([2H])([2H])[2H])c7c([2H])c([2H])c([2H])c8c7oc7c([2H])c([2H])c([2H])cc78)c6c5c4[2H])c([2H])c([2H])c3OC12]

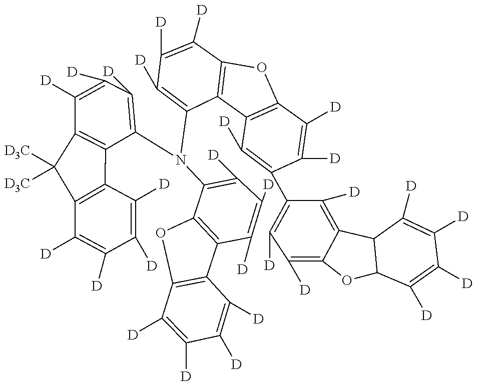 [SMILES: [2H]C1=C([2H])C2Oc3c([2H])c([2H])c(-c4c([2H])c([2H])c5oc6c([2H])c([2H])c([2H])c(N(c7c([2H])c([2H])c([2H])c8c7-c7c([2H])c([2H])c([2H])c([2H])c7C8(C([2H])([2H])[2H])C([2H])([2H])[2H])c7c([2H])c([2H])c([2H])c8c7oc7c([2H])c([2H])c([2H])c([2H])c78)c6c5c4[2H])c([2H])c3C2C([2H])=C1[2H]]

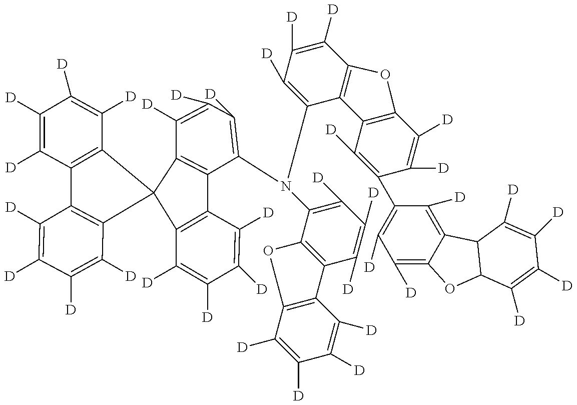 [SMILES: [2H]C1=C([2H])C2Oc3c([2H])c([2H])c(-c4c([2H])c([2H])c5oc6c([2H])c([2H])c([2H])c(N(c7c([2H])c([2H])c([2H])c8c7-c7c([2H])c([2H])c([2H])c([2H])c7C87c8c([2H])c([2H])c([2H])c([2H])c8-c8c([2H])c([2H])c([2H])c([2H])c87)c7c([2H])c([2H])c([2H])c8c7oc7c([2H])c([2H])c([2H])c([2H])c78)c6c5c4[2H])c([2H])c3C2C([2H])=C1[2H]]

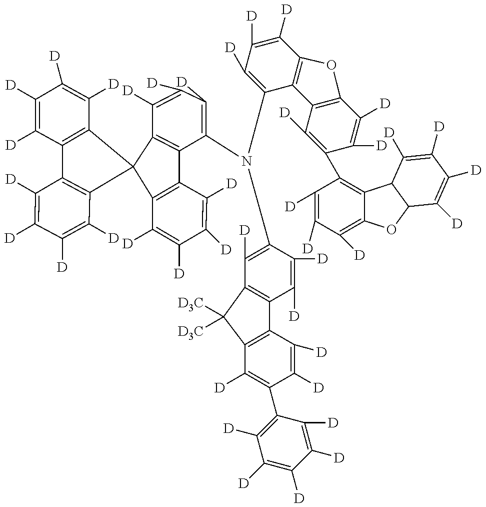 [SMILES: [2H]C1=C([2H])C2Oc3c([2H])c([2H])c([2H])c(-c4c([2H])c([2H])c5oc6c([2H])c([2H])c([2H])c(N(c7c([2H])c([2H])c8c(c7[2H])C(C([2H])([2H])[2H])(C([2H])([2H])[2H])c7c([2H])c(-c9c([2H])c([2H])c([2H])c([2H])c9[2H])c([2H])c([2H])c7-8)c7c([2H])c([2H])c([2H])c8c7-c7c([2H])c([2H])c([2H])c([2H])c7C87c8c([2H])c([2H])c([2H])c([2H])c8-c8c([2H])c([2H])c([2H])c([2H])c87)c6c5c4[2H])c3C2C([2H])=C1[2H]]

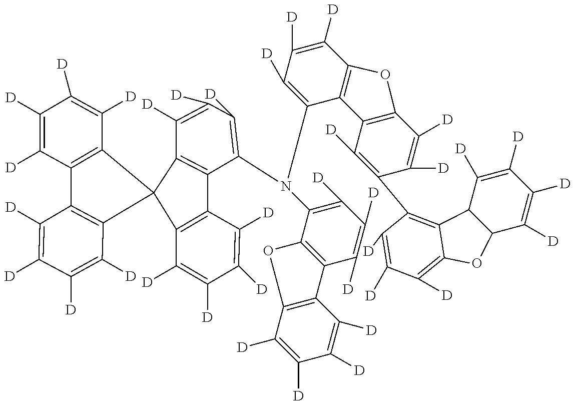 [SMILES: [2H]C1=C([2H])C2Oc3c([2H])c([2H])c([2H])c(-c4c([2H])c([2H])c5oc6c([2H])c([2H])c([2H])c(N(c7c([2H])c([2H])c([2H])c8c7-c7c([2H])c([2H])c([2H])c([2H])c7C87c8c([2H])c([2H])c([2H])c([2H])c8-c8c([2H])c([2H])c([2H])c([2H])c87)c7c([2H])c([2H])c([2H])c8c7oc7c([2H])c([2H])c([2H])c([2H])c78)c6c5c4[2H])c3C2C([2H])=C1[2H]]

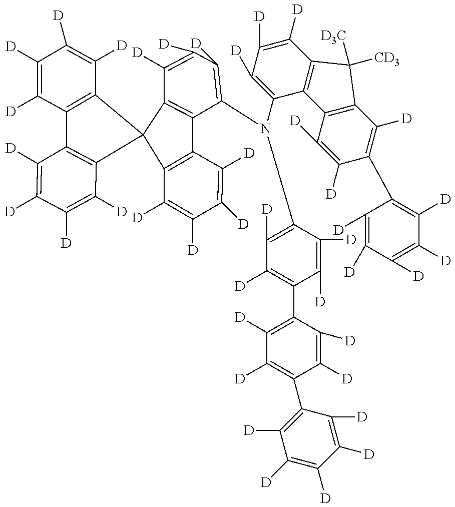 [SMILES: [2H]c1c([2H])c([2H])c(-c2c([2H])c([2H])c(-c3c([2H])c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c(-c6c([2H])c([2H])c([2H])c([2H])c6[2H])c([2H])c4C5(C([2H])([2H])[2H])C([2H])([2H])[2H])c([2H])c3[2H])c([2H])c2[2H])c([2H])c1[2H]]

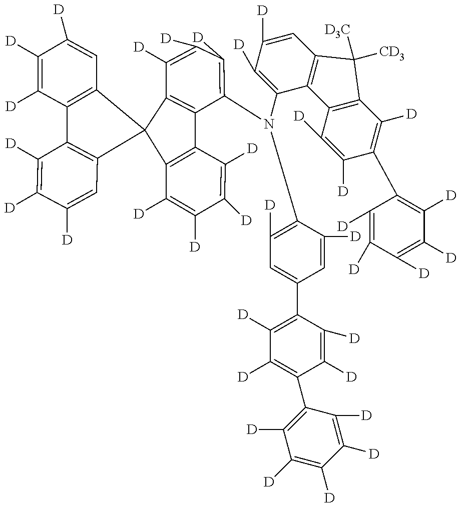 [SMILES: [2H]c1cc2c(c([2H])c1[2H])-c1c(cc([2H])c([2H])c1[2H])C21c2c([2H])c([2H])c([2H])c([2H])c2-c2c(N(c3c([2H])cc(-c4c([2H])c([2H])c(-c5c([2H])c([2H])c([2H])c([2H])c5[2H])c([2H])c4[2H])cc3[2H])c3c([2H])c([2H])cc4c3-c3c([2H])c([2H])c(-c5c([2H])c([2H])c([2H])c([2H])c5[2H])c([2H])c3C4(C([2H])([2H])[2H])C([2H])([2H])[2H])c([2H])c([2H])c([2H])c21]

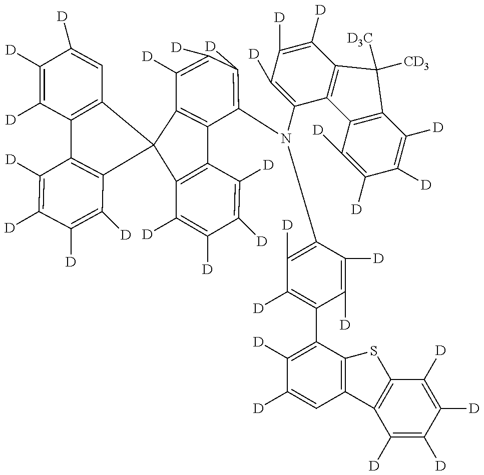 [SMILES: [2H]c1cc2c(c([2H])c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])cc5c4sc4c([2H])c([2H])c([2H])c([2H])c45)c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

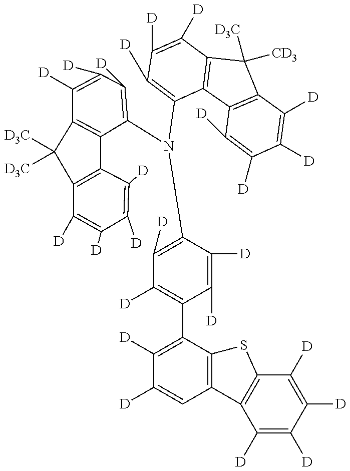 [SMILES: [2H]c1cc2c(sc3c([2H])c([2H])c([2H])c([2H])c32)c(-c2c([2H])c([2H])c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c2[2H])c1[2H]]

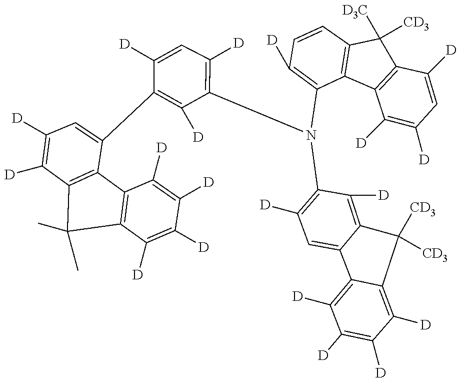 [SMILES: [2H]c1cc([2H])c2c(c1[2H])-c1c(ccc([2H])c1N(c1c([2H])cc([2H])c(-c3cc([2H])c([2H])c4c3-c3c([2H])c([2H])c([2H])c([2H])c3C4(C)C)c1[2H])c1c([2H])cc3c(c1[2H])C(C([2H])([2H])[2H])(C([2H])([2H])[2H])c1c([2H])c([2H])c([2H])c([2H])c1-3)C2(C([2H])([2H])[2H])C([2H])([2H])[2H]]

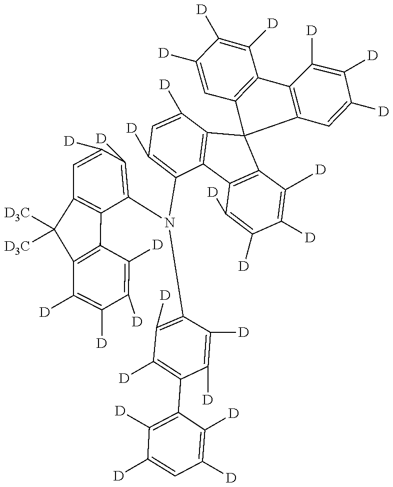 [SMILES: [2H]c1cc2c(c([2H])c1[2H])-c1c(cc([2H])c([2H])c1[2H])C21c2c([2H])cc([2H])c(N(c3c([2H])c([2H])c(-c4c([2H])c([2H])cc([2H])c4[2H])c([2H])c3[2H])c3c([2H])c([2H])cc4c3-c3c([2H])c([2H])c([2H])c([2H])c3C4(C([2H])([2H])[2H])C([2H])([2H])[2H])c2-c2c([2H])c([2H])c([2H])c([2H])c21]

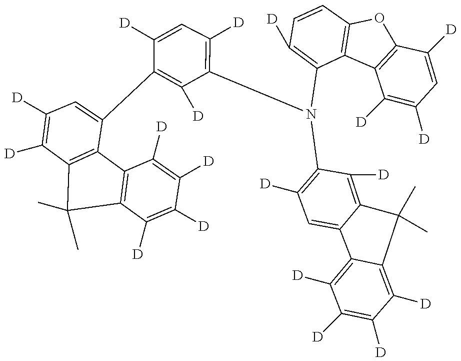 [SMILES: [2H]c1cc(-c2c([2H])cc([2H])c(N(c3c([2H])cc4c(c3[2H])C(C)(C)c3c([2H])c([2H])c([2H])c([2H])c3-4)c3c([2H])ccc4oc5c([2H])cc([2H])c([2H])c5c34)c2[2H])c2c(c1[2H])C(C)(C)c1c([2H])c([2H])c([2H])c([2H])c1-2]

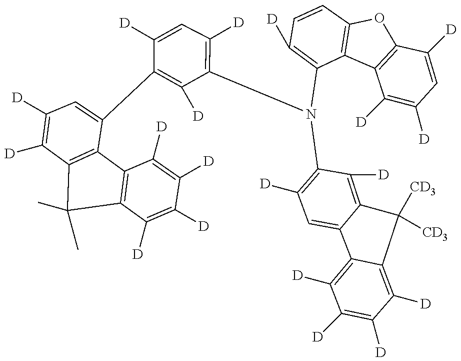 [SMILES: [2H]c1cc(-c2c([2H])cc([2H])c(N(c3c([2H])cc4c(c3[2H])C(C([2H])([2H])[2H])(C([2H])([2H])[2H])c3c([2H])c([2H])c([2H])c([2H])c3-4)c3c([2H])ccc4oc5c([2H])cc([2H])c([2H])c5c34)c2[2H])c2c(c1[2H])C(C)(C)c1c([2H])c([2H])c([2H])c([2H])c1-2]

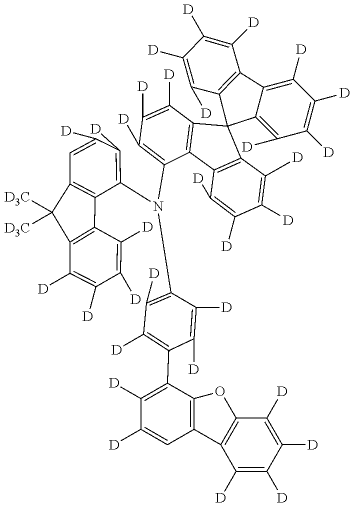 [SMILES: [2H]c1cc2c(c(N(c3c([2H])c([2H])c(-c4c([2H])c([2H])cc5c4oc4c([2H])c([2H])c([2H])c([2H])c45)c([2H])c3[2H])c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c1[2H])-c1c([2H])c([2H])c([2H])c([2H])c1C2(C([2H])([2H])[2H])C([2H])([2H])[2H]]

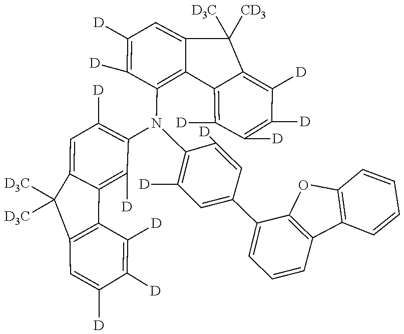 [SMILES: [2H]c1cc2c(c([2H])c1[2H])-c1c(cc([2H])c(N(c3c([2H])cc(-c4cccc5c4oc4ccccc45)cc3[2H])c3c([2H])c([2H])cc4c3-c3c([2H])c([2H])c([2H])c([2H])c3C4(C([2H])([2H])[2H])C([2H])([2H])[2H])c1[2H])C2(C([2H])([2H])[2H])C([2H])([2H])[2H]]

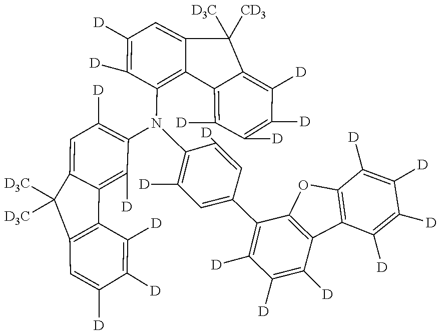 [SMILES: [2H]c1cc2c(c([2H])c1[2H])-c1c(cc([2H])c(N(c3c([2H])cc(-c4c([2H])c([2H])c([2H])c5c4oc4c([2H])c([2H])c([2H])c([2H])c45)cc3[2H])c3c([2H])c([2H])cc4c3-c3c([2H])c([2H])c([2H])c([2H])c3C4(C([2H])([2H])[2H])C([2H])([2H])[2H])c1[2H])C2(C([2H])([2H])[2H])C([2H])([2H])[2H]]

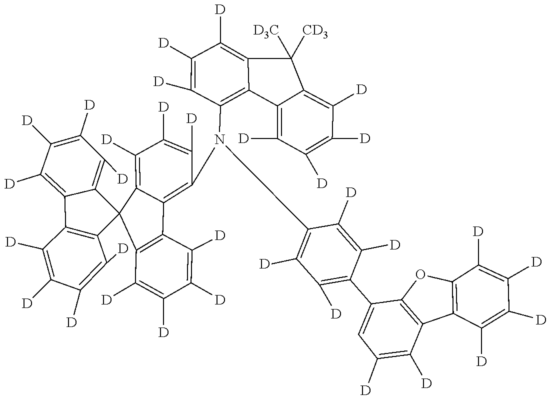 [SMILES: [2H]c1cc(-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c2[2H])c2oc3c([2H])c([2H])c([2H])c([2H])c3c2c1[2H]]

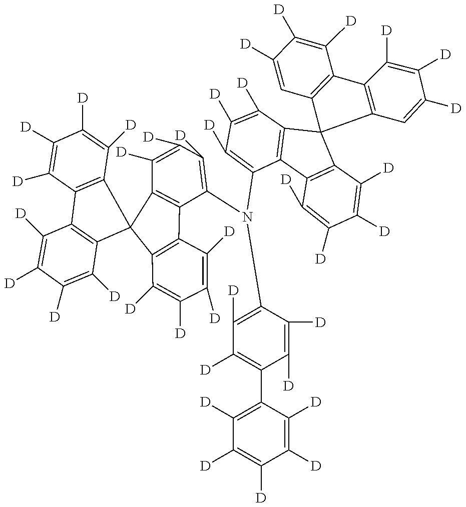 [SMILES: [2H]c1cc2c(c([2H])c1[2H])-c1c(cc([2H])c([2H])c1[2H])C21c2c([2H])c([2H])c([2H])c([2H])c2-c2c(N(c3c([2H])c([2H])c(-c4c([2H])c([2H])c([2H])c([2H])c4[2H])c([2H])c3[2H])c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c([2H])c([2H])c([2H])c21]

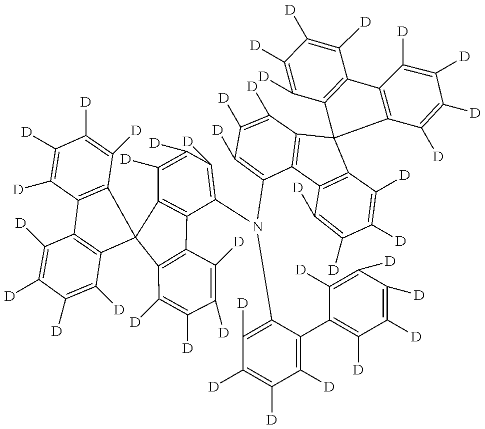 [SMILES: [2H]c1c([2H])c([2H])c(-c2c([2H])c([2H])c([2H])c([2H])c2N(c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c([2H])c1[2H]]

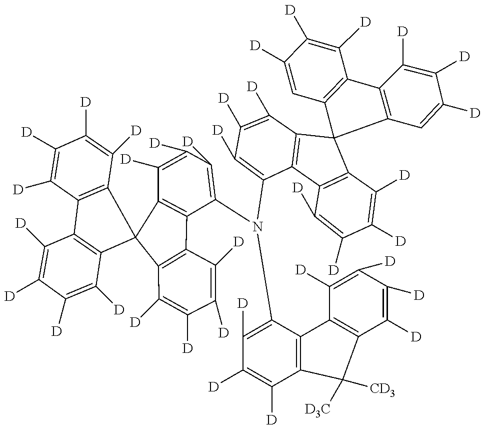 [SMILES: [2H]c1cc2c(c([2H])c1[2H])-c1c(cc([2H])c([2H])c1[2H])C21c2c([2H])c([2H])c([2H])c([2H])c2-c2c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

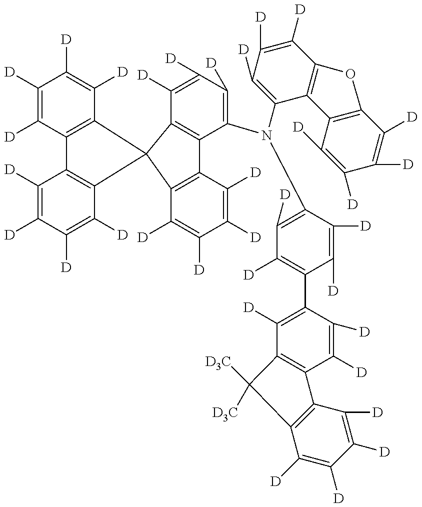 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])c5c(c4[2H])C(C([2H])([2H])[2H])(C([2H])([2H])[2H])c4c([2H])c([2H])c([2H])c([2H])c4-5)c([2H])c3[2H])c3c([2H])c([2H])c([2H])c4oc5c([2H])c([2H])c([2H])c([2H])c5c34)c([2H])c([2H])c([2H])c21]

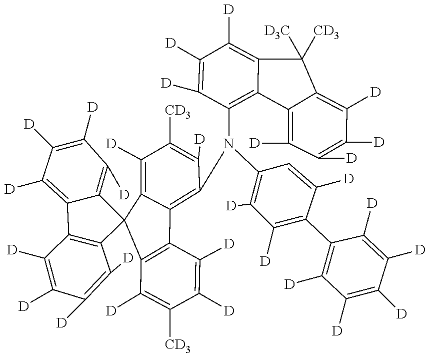 [SMILES: [2H]c1cc(N(c2c([2H])c(C([2H])([2H])[2H])c([2H])c3c2-c2c([2H])c([2H])c(C([2H])([2H])[2H])c([2H])c2C32c3c([2H])c([2H])c([2H])c([2H])c3-c3c([2H])c([2H])c([2H])c([2H])c32)c2c([2H])c([2H])c([2H])c3c2-c2c([2H])c([2H])c([2H])c([2H])c2C3(C([2H])([2H])[2H])C([2H])([2H])[2H])c([2H])c([2H])c1-c1c([2H])c([2H])c([2H])c([2H])c1[2H]]

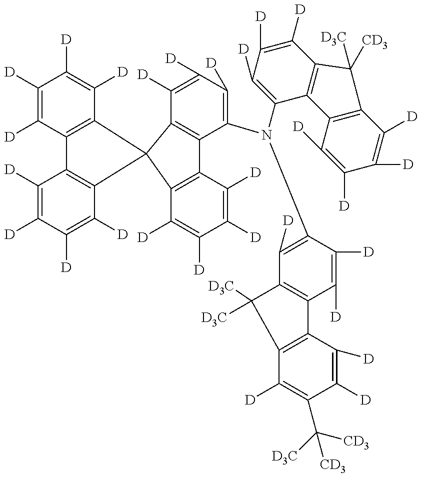 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c(C(C([2H])([2H])[2H])(C([2H])([2H])[2H])C([2H])([2H])[2H])c([2H])c([2H])c3-4)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

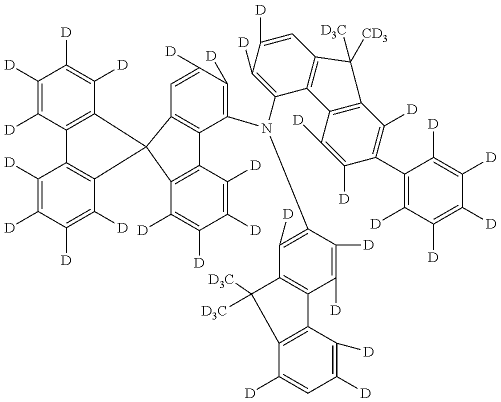 [SMILES: [2H]c1cc([2H])c2c(c1[2H])-c1c([2H])c([2H])c(N(c3c([2H])c([2H])cc4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])cc4c3-c3c([2H])c([2H])c(-c5c([2H])c([2H])c([2H])c([2H])c5[2H])c([2H])c3C4(C([2H])([2H])[2H])C([2H])([2H])[2H])c([2H])c1C2(C([2H])([2H])[2H])C([2H])([2H])[2H]]

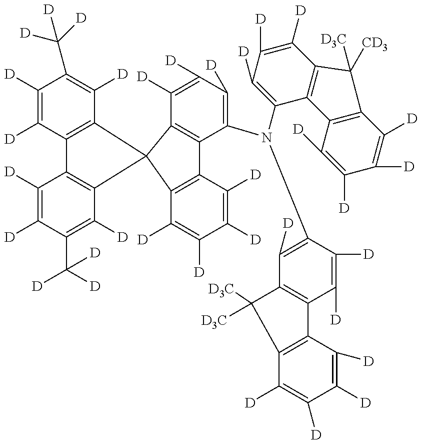 [SMILES: [2H]c1c([2H])c([2H])c2c(c1[2H])-c1c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C21c2c([2H])c(C([2H])([2H])[2H])c([2H])c([2H])c2-c2c([2H])c([2H])c(C([2H])([2H])[2H])c([2H])c21]

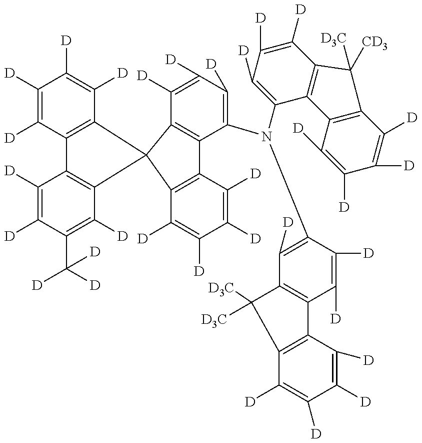 [SMILES: [2H]c1c([2H])c([2H])c2c(c1[2H])-c1c([2H])c([2H])c(C([2H])([2H])[2H])c([2H])c1C21c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

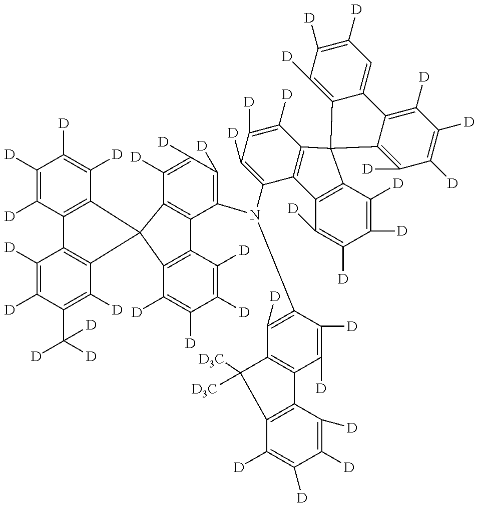 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C43c4c([2H])c([2H])c([2H])c([2H])c4-c4c([2H])c([2H])c(C([2H])([2H])[2H])c([2H])c43)c([2H])c([2H])c([2H])c21]

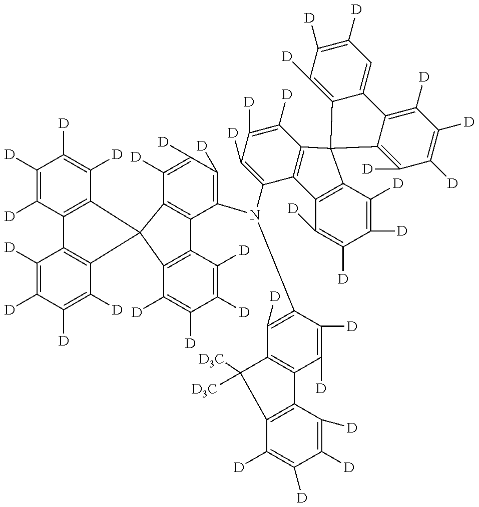 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c([2H])c([2H])c([2H])c21]

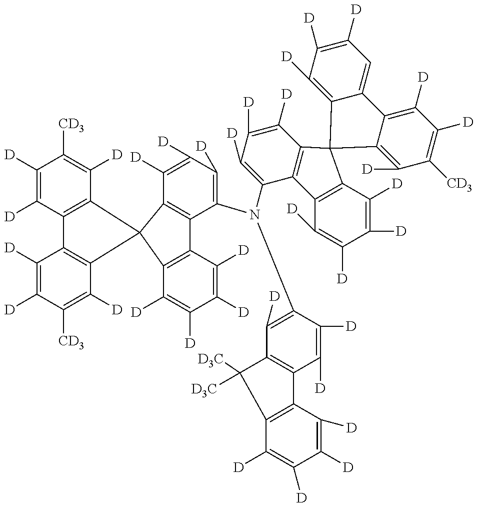 [SMILES: [2H]c1cc2c(c([2H])c1[2H])C1(c3c([2H])c(C([2H])([2H])[2H])c([2H])c([2H])c3-2)c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c([2H])c([2H])c([2H])c21]

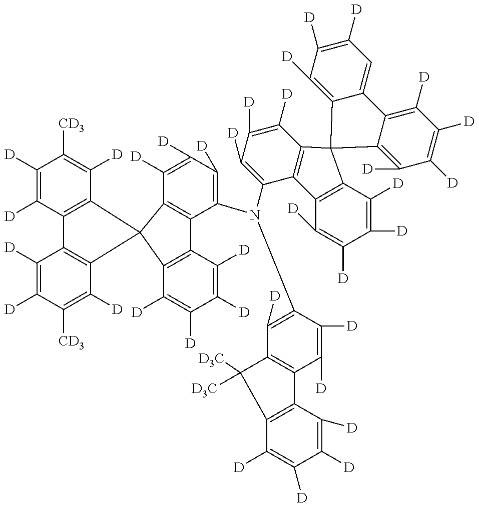 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c([2H])c([2H])c([2H])c21]

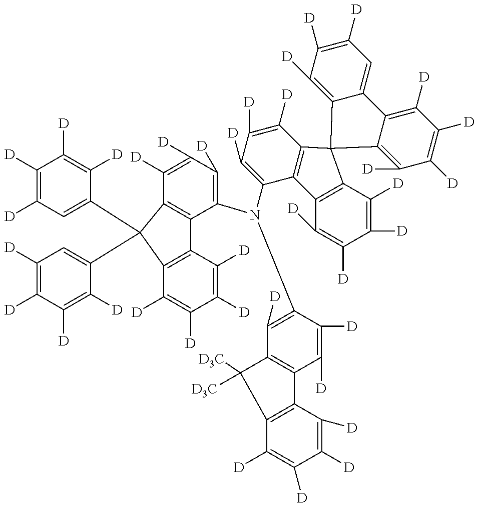 [SMILES: [2H]c1cc(C2(c3cc([2H])c([2H])c([2H])c3[2H])c3c([2H])c([2H])c([2H])c([2H])c3-c3c(N(c4c([2H])c([2H])c5c(c4[2H])C(C([2H])([2H])[2H])(C([2H])([2H])[2H])c4c([2H])c([2H])c([2H])c([2H])c4-5)c4c([2H])c([2H])c([2H])c5c4-c4c([2H])c([2H])c([2H])c([2H])c4C54c5c(cc([2H])c([2H])c5[2H])-c5c([2H])c([2H])c([2H])c([2H])c54)c([2H])c([2H])c([2H])c32)c([2H])c([2H])c1[2H]]

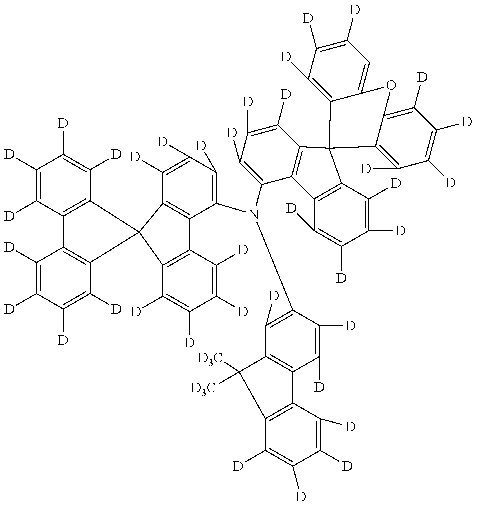 [SMILES: [2H]c1cc2c(c([2H])c1[2H])C1(c3c([2H])c([2H])c([2H])c([2H])c3O2)c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c([2H])c([2H])c([2H])c21]

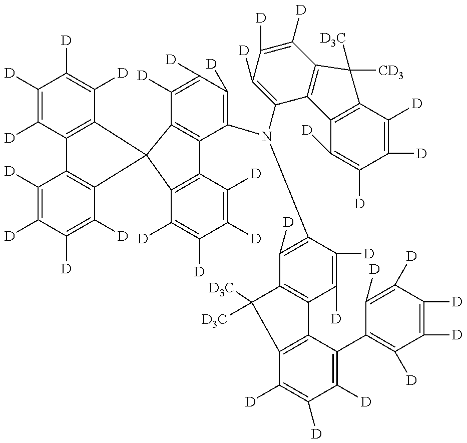 [SMILES: [2H]c1c([2H])c([2H])c(-c2c([2H])c([2H])c([2H])c3c2-c2c([2H])c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c([2H])c([2H])c4C5(C([2H])([2H])[2H])C([2H])([2H])[2H])c([2H])c2C3(C([2H])([2H])[2H])C([2H])([2H])[2H])c([2H])c1[2H]]

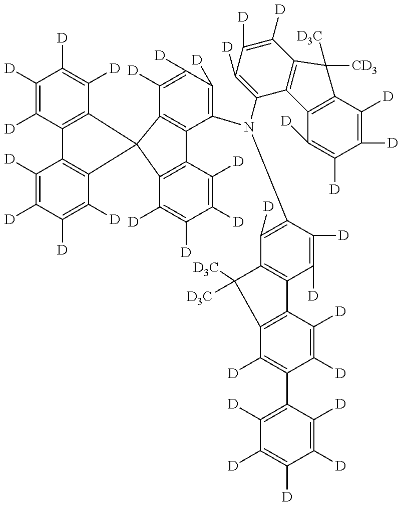 [SMILES: [2H]c1c([2H])c([2H])c(-c2c([2H])c([2H])c3c(c2[2H])C(C([2H])([2H])[2H])(C([2H])([2H])[2H])c2c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c([2H])c([2H])c4C5(C([2H])([2H])[2H])C([2H])([2H])[2H])c([2H])c([2H])c2-3)c([2H])c1[2H]]

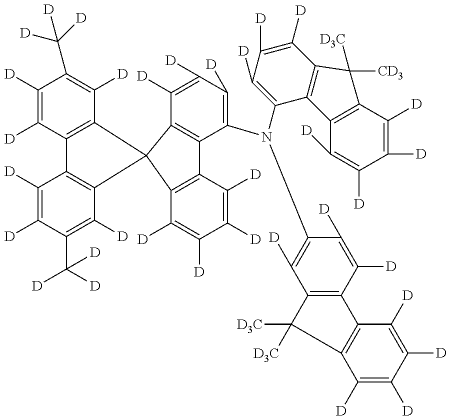 [SMILES: [2H]c1c([2H])c([2H])c2c(c1[2H])-c1c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C21c2c([2H])c(C([2H])([2H])[2H])c([2H])c([2H])c2-c2c([2H])c([2H])c(C([2H])([2H])[2H])c([2H])c21]

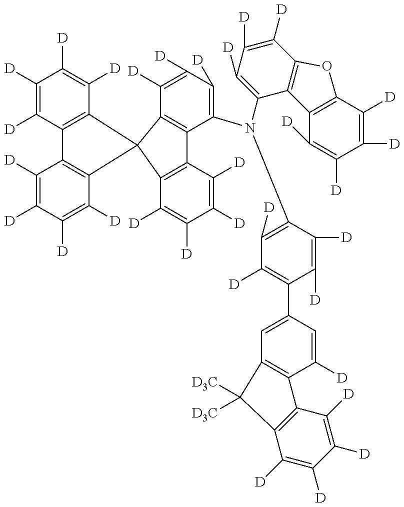 [SMILES: [2H]c1cc(-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4oc5c([2H])c([2H])c([2H])c([2H])c5c34)c([2H])c2[2H])cc2c1-c1c([2H])c([2H])c([2H])c([2H])c1C2(C([2H])([2H])[2H])C([2H])([2H])[2H]]

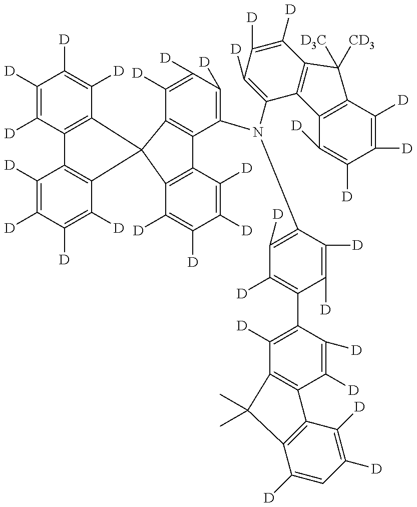 [SMILES: [2H]c1cc([2H])c2c(c1[2H])-c1c([2H])c([2H])c(-c3c([2H])c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c([2H])c([2H])c4C5(C([2H])([2H])[2H])C([2H])([2H])[2H])c([2H])c3[2H])c([2H])c1C2(C)C]

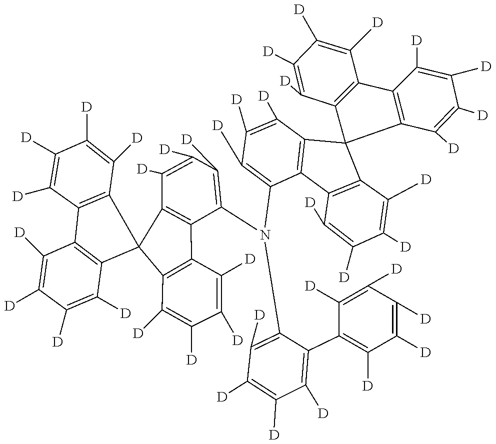 [SMILES: [2H]c1c([2H])c([2H])c(-c2c([2H])c([2H])c([2H])c([2H])c2N(c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c([2H])c1[2H]]

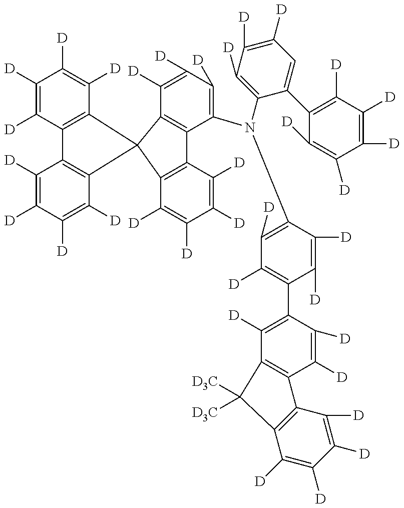 [SMILES: [2H]c1cc(-c2c([2H])c([2H])c([2H])c([2H])c2[2H])c(N(c2c([2H])c([2H])c(-c3c([2H])c([2H])c4c(c3[2H])C(C([2H])([2H])[2H])(C([2H])([2H])[2H])c3c([2H])c([2H])c([2H])c([2H])c3-4)c([2H])c2[2H])c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c([2H])c1[2H]]

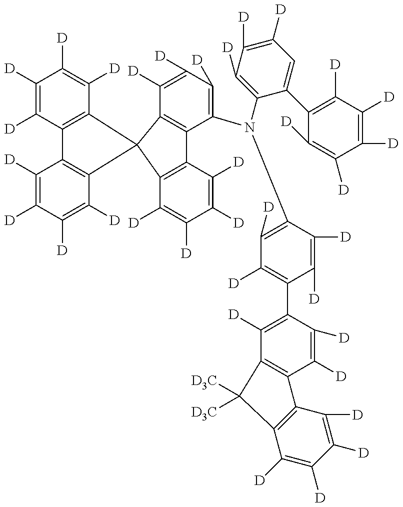 [SMILES: [2H]c1cc(-c2c([2H])c([2H])c([2H])c([2H])c2[2H])c(N(c2c([2H])c([2H])c(-c3c([2H])c([2H])c4c(c3[2H])C(C([2H])([2H])[2H])(C([2H])([2H])[2H])c3c([2H])c([2H])c([2H])c([2H])c3-4)c([2H])c2[2H])c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c([2H])c1[2H]]

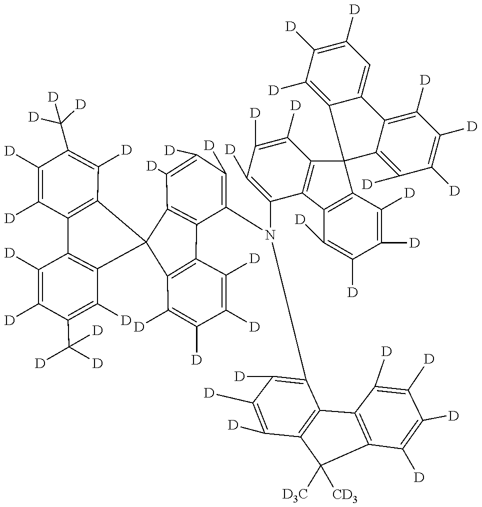 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

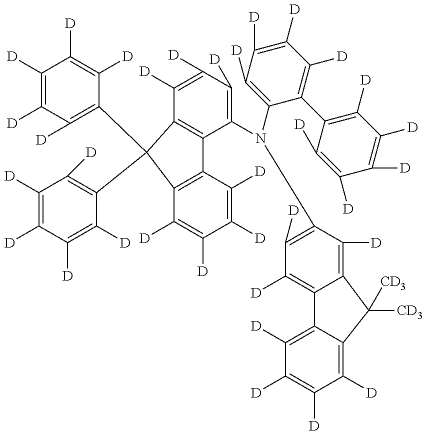 [SMILES: [2H]c1c([2H])c([2H])c(-c2c([2H])c([2H])c([2H])c([2H])c2N(c2c([2H])c([2H])c3c(c2[2H])C(C([2H])([2H])[2H])(C([2H])([2H])[2H])c2c([2H])c([2H])c([2H])c([2H])c2-3)c2c([2H])c([2H])c([2H])c3c2-c2c([2H])c([2H])c([2H])c([2H])c2C3(c2c([2H])c([2H])c([2H])c([2H])c2[2H])c2c([2H])c([2H])c([2H])c([2H])c2[2H])c([2H])c1[2H]]

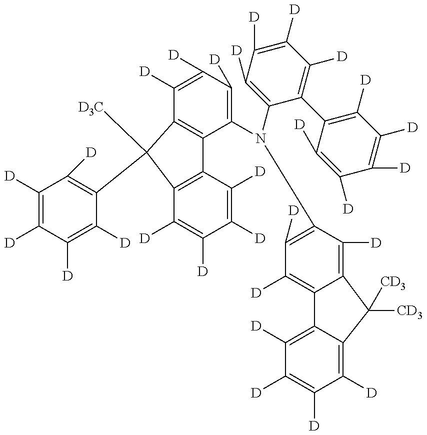 [SMILES: [2H]c1c([2H])c([2H])c(-c2c([2H])c([2H])c([2H])c([2H])c2N(c2c([2H])c([2H])c3c(c2[2H])C(C([2H])([2H])[2H])(C([2H])([2H])[2H])c2c([2H])c([2H])c([2H])c([2H])c2-3)c2c([2H])c([2H])c([2H])c3c2-c2c([2H])c([2H])c([2H])c([2H])c2C3(c2c([2H])c([2H])c([2H])c([2H])c2[2H])C([2H])([2H])[2H])c([2H])c1[2H]]

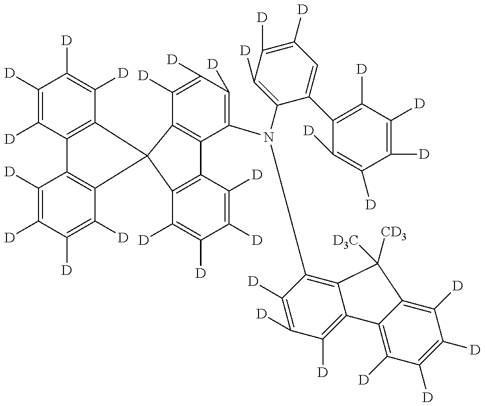 [SMILES: [2H]c1cc(-c2c([2H])c([2H])c([2H])c([2H])c2[2H])c(N(c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c2c([2H])c([2H])c([2H])c3c2C(C([2H])([2H])[2H])(C([2H])([2H])[2H])c2c([2H])c([2H])c([2H])c([2H])c2-3)c([2H])c1[2H]]

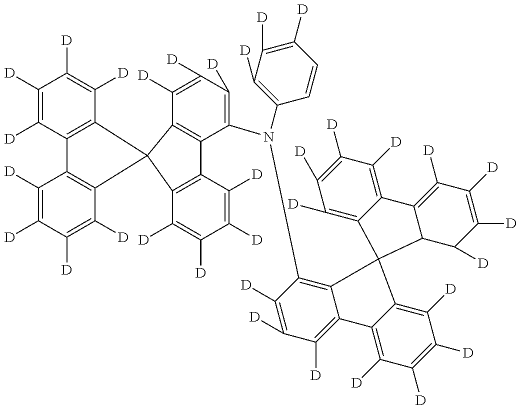 [SMILES: [2H]C1=C([2H])C([2H])C2C(=C1[2H])c1c([2H])c([2H])c([2H])c([2H])c1C21c2c([2H])c([2H])c([2H])c([2H])c2-c2c([2H])c([2H])c([2H])c(N(c3ccc([2H])c([2H])c3[2H])c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c21]

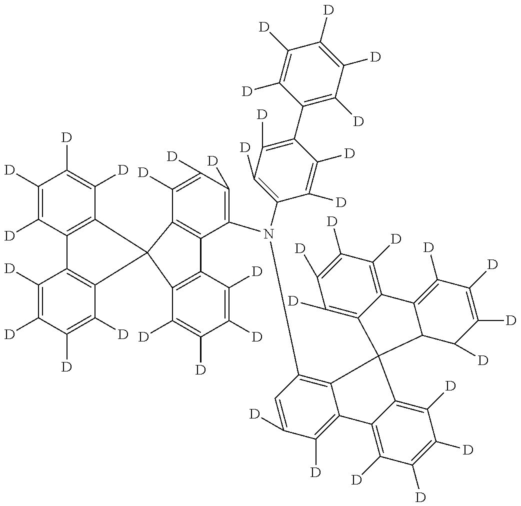 [SMILES: [2H]C1=C([2H])C([2H])C2C(=C1[2H])c1c([2H])c([2H])c([2H])c([2H])c1C21c2c(N(c3c([2H])c([2H])c(-c4c([2H])c([2H])c([2H])c([2H])c4[2H])c([2H])c3[2H])c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)cc([2H])c([2H])c2-c2c([2H])c([2H])c([2H])c([2H])c21]

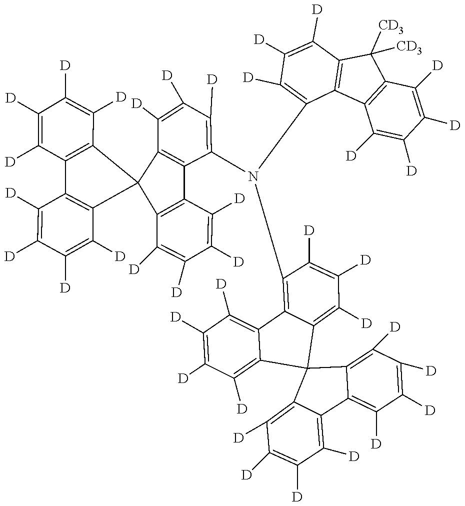 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

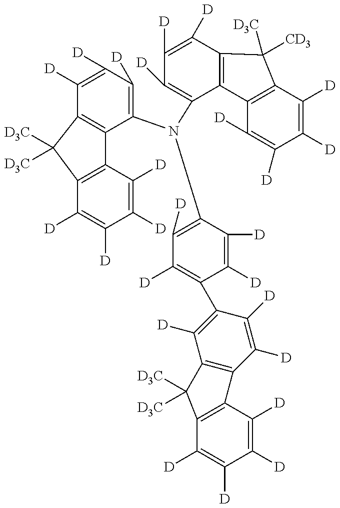 [SMILES: [2H]c1c([2H])c([2H])c2c(c1[2H])-c1c([2H])c([2H])c(-c3c([2H])c([2H])c(N(c4c([2H])c([2H])c([2H])c5c4-c4c([2H])c([2H])c([2H])c([2H])c4C5(C([2H])([2H])[2H])C([2H])([2H])[2H])c4c([2H])c([2H])c([2H])c5c4-c4c([2H])c([2H])c([2H])c([2H])c4C5(C([2H])([2H])[2H])C([2H])([2H])[2H])c([2H])c3[2H])c([2H])c1C2(C([2H])([2H])[2H])C([2H])([2H])[2H]]

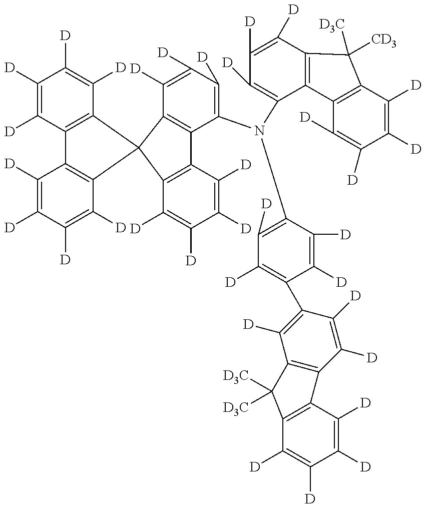 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])c5c(c4[2H])C(C([2H])([2H])[2H])(C([2H])([2H])[2H])c4c([2H])c([2H])c([2H])c([2H])c4-5)c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

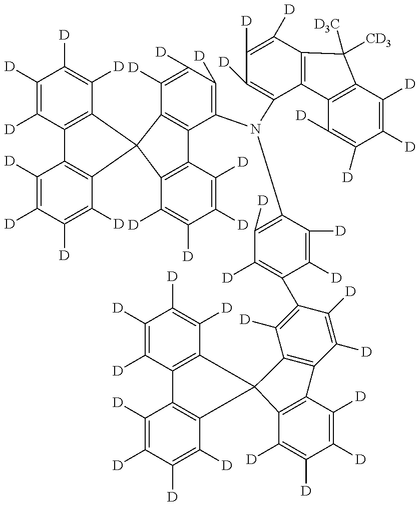 [SMILES: [2H]c1c([2H])c([2H])c2c(c1[2H])-c1c([2H])c([2H])c([2H])c([2H])c1C21c2c([2H])c([2H])c([2H])c([2H])c2-c2c([2H])c([2H])c(-c3c([2H])c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c([2H])c([2H])c4C5(C([2H])([2H])[2H])C([2H])([2H])[2H])c([2H])c3[2H])c([2H])c21]

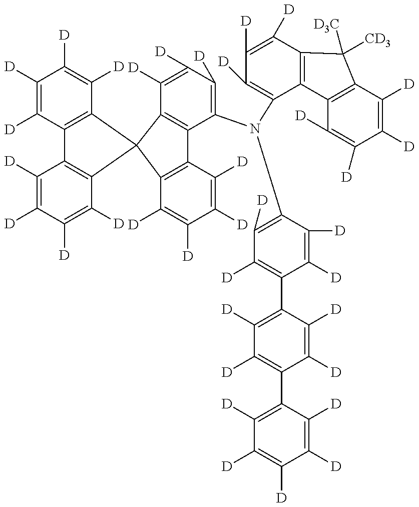 [SMILES: [2H]c1c([2H])c([2H])c(-c2c([2H])c([2H])c(-c3c([2H])c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c([2H])c([2H])c4C5(C([2H])([2H])[2H])C([2H])([2H])[2H])c([2H])c3[2H])c([2H])c2[2H])c([2H])c1[2H]]

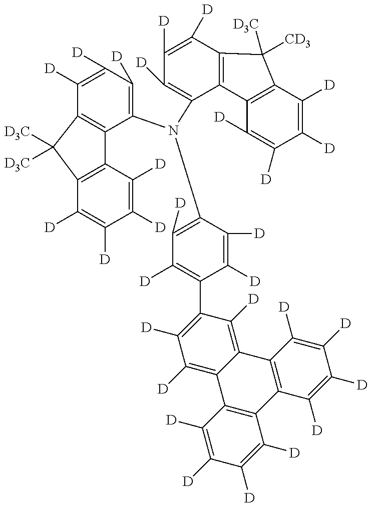 [SMILES: [2H]c1c([2H])c([2H])c2c(c1[2H])-c1c(N(c3c([2H])c([2H])c(-c4c([2H])c([2H])c5c6c([2H])c([2H])c([2H])c([2H])c6c6c([2H])c([2H])c([2H])c([2H])c6c5c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(C([2H])([2H])[2H])C([2H])([2H])[2H]]

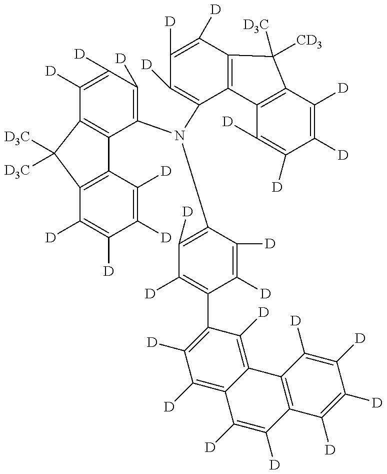 [SMILES: [2H]c1c([2H])c([2H])c2c(c1[2H])-c1c(N(c3c([2H])c([2H])c(-c4c([2H])c([2H])c5c([2H])c([2H])c6c([2H])c([2H])c([2H])c([2H])c6c5c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(C([2H])([2H])[2H])C([2H])([2H])[2H]]

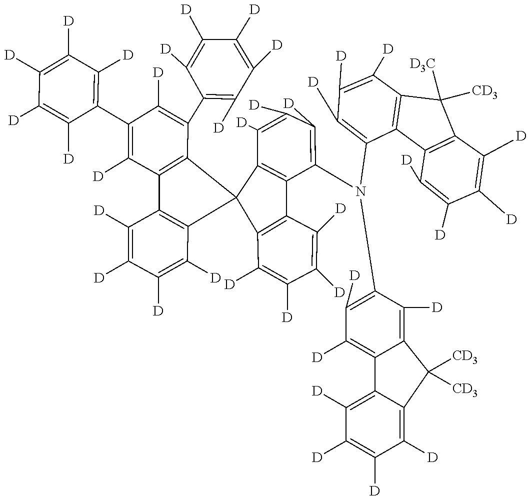 [SMILES: [2H]C1=C([2H])C2=C(C(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C43c4c([2H])c([2H])c([2H])c([2H])c4-c4c([2H])c(-c5c([2H])c([2H])c([2H])c([2H])c5[2H])c([2H])c(-c5c([2H])c([2H])c([2H])c([2H])c5[2H])c43)=C([2H])C1)c1c([2H])c([2H])c([2H])c([2H])c1C2(C([2H])([2H])[2H])C([2H])([2H])[2H]]

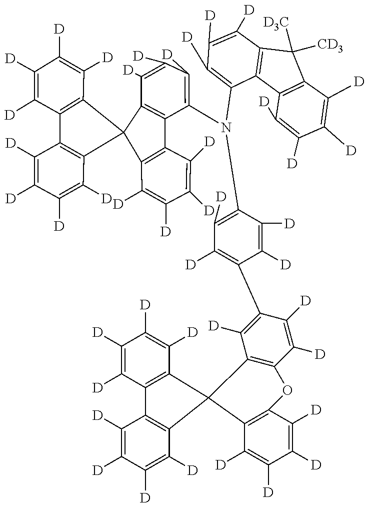 [SMILES: [2H]C1=C([2H])C2=C(C(N(c3c([2H])c([2H])c(-c4c([2H])c([2H])c5c(c4[2H])C4(c6c([2H])c([2H])c([2H])c([2H])c6O5)c5c([2H])c([2H])c([2H])c([2H])c5-c5c([2H])c([2H])c([2H])c([2H])c54)c([2H])c3[2H])c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)=C([2H])C1)c1c([2H])c([2H])c([2H])c([2H])c1C2(C([2H])([2H])[2H])C([2H])([2H])[2H]]

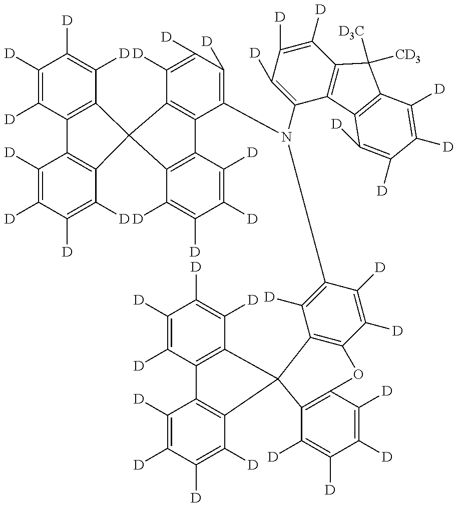 [SMILES: [2H]c1c([2H])c([2H])c2c(c1[2H])Oc1c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c1C21c2c([2H])c([2H])c([2H])c([2H])c2-c2c([2H])c([2H])c([2H])c([2H])c21]

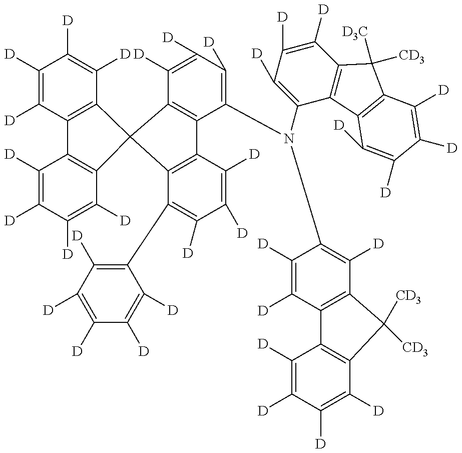 [SMILES: [2H]c1c([2H])c([2H])c(-c2c([2H])c([2H])c([2H])c3c2C2(c4c([2H])c([2H])c([2H])c([2H])c4-c4c([2H])c([2H])c([2H])c([2H])c42)c2c([2H])c([2H])c([2H])c(N(c4c([2H])c([2H])c5c(c4[2H])C(C([2H])([2H])[2H])(C([2H])([2H])[2H])c4c([2H])c([2H])c([2H])c([2H])c4-5)c4c([2H])c([2H])c([2H])c5c4-c4c([2H])c([2H])c([2H])c([2H])c4C5(C([2H])([2H])[2H])C([2H])([2H])[2H])c2-3)c([2H])c1[2H]]

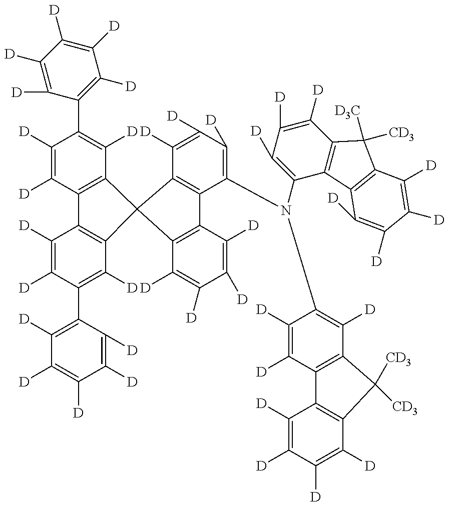 [SMILES: [2H]c1c([2H])c([2H])c(-c2c([2H])c([2H])c3c(c2[2H])C2(c4c([2H])c(-c5c([2H])c([2H])c([2H])c([2H])c5[2H])c([2H])c([2H])c4-3)c3c([2H])c([2H])c([2H])c([2H])c3-c3c(N(c4c([2H])c([2H])c5c(c4[2H])C(C([2H])([2H])[2H])(C([2H])([2H])[2H])c4c([2H])c([2H])c([2H])c([2H])c4-5)c4c([2H])c([2H])c([2H])c5c4-c4c([2H])c([2H])c([2H])c([2H])c4C5(C([2H])([2H])[2H])C([2H])([2H])[2H])c([2H])c([2H])c([2H])c32)c([2H])c1[2H]]

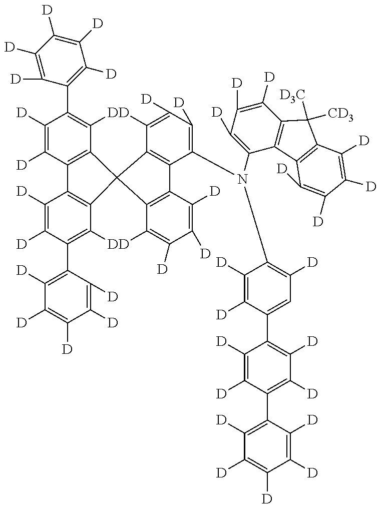 [SMILES: [2H]c1cc(-c2c([2H])c([2H])c(-c3c([2H])c([2H])c([2H])c([2H])c3[2H])c([2H])c2[2H])c([2H])c([2H])c1N(c1c([2H])c([2H])c([2H])c2c1-c1c([2H])c([2H])c([2H])c([2H])c1C21c2c([2H])c(-c3c([2H])c([2H])c([2H])c([2H])c3[2H])c([2H])c([2H])c2-c2c([2H])c([2H])c(-c3c([2H])c([2H])c([2H])c([2H])c3[2H])c([2H])c21)c1c([2H])c([2H])c([2H])c2c1-c1c([2H])c([2H])c([2H])c([2H])c1C2(C([2H])([2H])[2H])C([2H])([2H])[2H]]

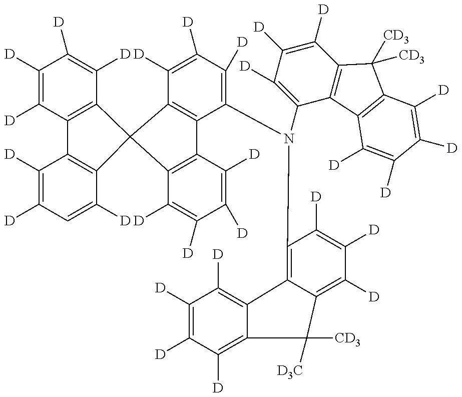 [SMILES: [2H]c1cc([2H])c2c(c1[2H])-c1c([2H])c([2H])c([2H])c([2H])c1C21c2c([2H])c([2H])c([2H])c([2H])c2-c2c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

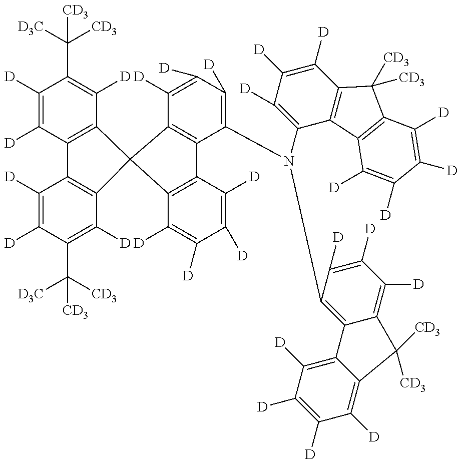 [SMILES: [2H]c1c([2H])c([2H])c2c(c1[2H])-c1c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C21c2c([2H])c(C(C([2H])([2H])[2H])(C([2H])([2H])[2H])C([2H])([2H])[2H])c([2H])c([2H])c2-c2c([2H])c([2H])c(C(C([2H])([2H])[2H])(C([2H])([2H])[2H])C([2H])([2H])[2H])c([2H])c21]

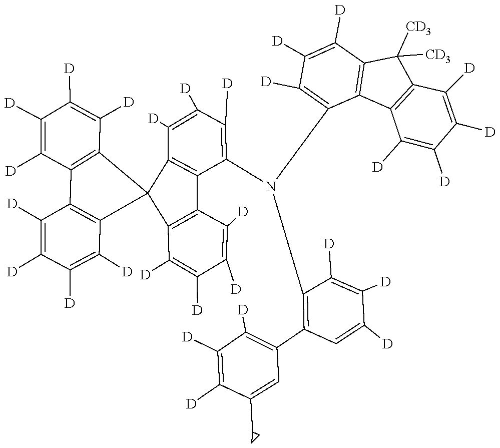 [SMILES: [2H]c1cc(-c2cc(C3=CC3)c([2H])c([2H])c2[2H])c(N(c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c2c([2H])c([2H])c([2H])c3c2-c2c([2H])c([2H])c([2H])c([2H])c2C3(C([2H])([2H])[2H])C([2H])([2H])[2H])c([2H])c1[2H]]

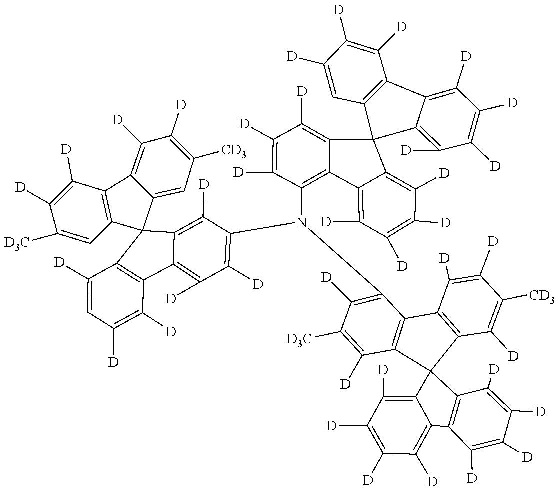 [SMILES: [2H]c1cc2c(c([2H])c1[2H])-c1c([2H])c([2H])c([2H])c([2H])c1C21c2c([2H])c([2H])c([2H])c([2H])c2-c2c(N(c3c([2H])c([2H])c4c(c3[2H])C3(c5cc(C([2H])([2H])[2H])c([2H])c([2H])c5-c5c3cc(C([2H])([2H])[2H])c([2H])c5[2H])c3c([2H])cc([2H])c([2H])c3-4)c3c([2H])c(C([2H])([2H])[2H])c([2H])c4c3-c3c([2H])c([2H])c(C([2H])([2H])[2H])c([2H])c3C43c4c([2H])c([2H])c([2H])c([2H])c4-c4c([2H])c([2H])c([2H])c([2H])c43)c([2H])c([2H])c([2H])c21]

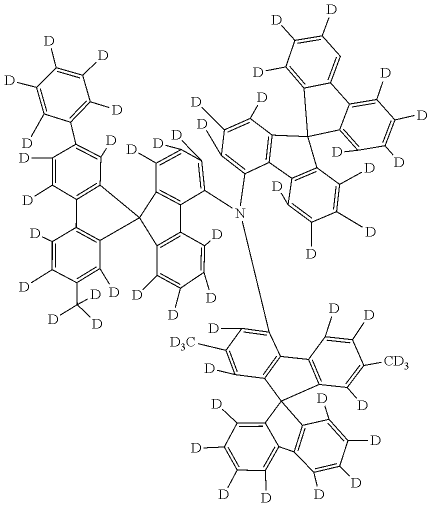 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(-c5c([2H])c([2H])c([2H])c([2H])c5[2H])c([2H])c([2H])c4-c4c([2H])c([2H])c(C([2H])([2H])[2H])c([2H])c43)c3c([2H])c(C([2H])([2H])[2H])c([2H])c4c3-c3c([2H])c([2H])c(C([2H])([2H])[2H])c([2H])c3C43c4c([2H])c([2H])c([2H])c([2H])c4-c4c([2H])c([2H])c([2H])c([2H])c43)c([2H])c([2H])c([2H])c21]

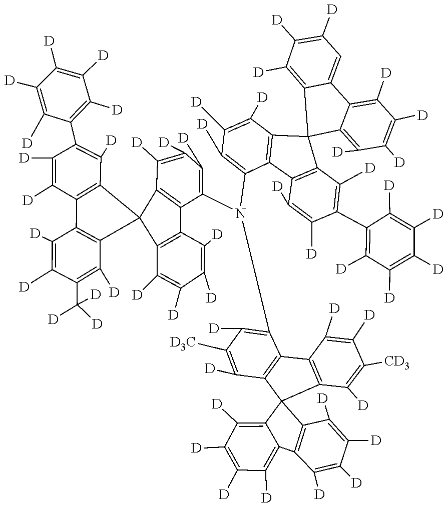 [SMILES: [2H]c1cc2c(c([2H])c1[2H])C1(c3c([2H])c([2H])c([2H])c([2H])c3-2)c2c([2H])c(-c3c([2H])c([2H])c([2H])c([2H])c3[2H])c([2H])c([2H])c2-c2c(N(c3c([2H])c([2H])c([2H])c4c3-c3c([2H])c([2H])c([2H])c([2H])c3C43c4c([2H])c(-c5c([2H])c([2H])c([2H])c([2H])c5[2H])c([2H])c([2H])c4-c4c([2H])c([2H])c(C([2H])([2H])[2H])c([2H])c43)c3c([2H])c(C([2H])([2H])[2H])c([2H])c4c3-c3c([2H])c([2H])c(C([2H])([2H])[2H])c([2H])c3C43c4c([2H])c([2H])c([2H])c([2H])c4-c4c([2H])c([2H])c([2H])c([2H])c43)c([2H])c([2H])c([2H])c21]

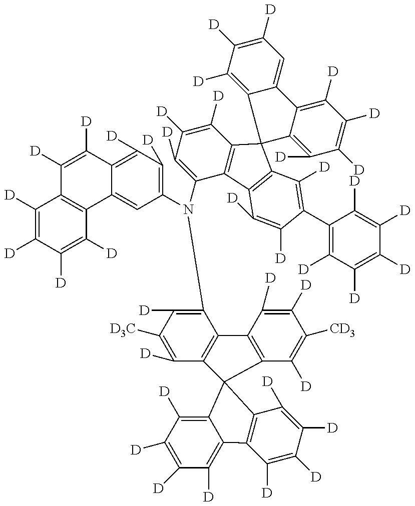 [SMILES: [2H]c1cc2c(c([2H])c1[2H])C1(c3c([2H])c([2H])c([2H])c([2H])c3-2)c2c([2H])c(-c3c([2H])c([2H])c([2H])c([2H])c3[2H])c([2H])c([2H])c2-c2c(N(c3cc4c(c([2H])c3[2H])c([2H])c([2H])c3c([2H])c([2H])c([2H])c([2H])c34)c3c([2H])c(C([2H])([2H])[2H])c([2H])c4c3-c3c([2H])c([2H])c(C([2H])([2H])[2H])c([2H])c3C43c4c([2H])c([2H])c([2H])c([2H])c4-c4c([2H])c([2H])c([2H])c([2H])c43)c([2H])c([2H])c([2H])c21]

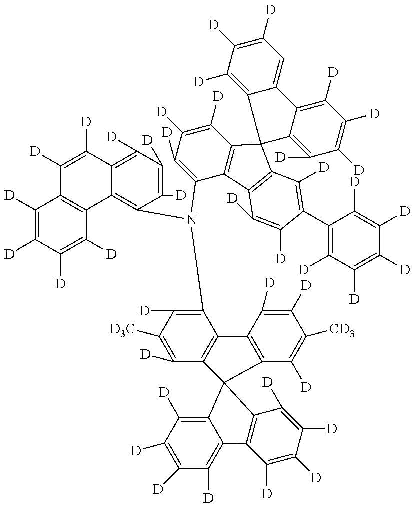 [SMILES: [2H]c1cc2c(c([2H])c1[2H])C1(c3c([2H])c([2H])c([2H])c([2H])c3-2)c2c([2H])c(-c3c([2H])c([2H])c([2H])c([2H])c3[2H])c([2H])c([2H])c2-c2c(N(c3c([2H])c(C([2H])([2H])[2H])c([2H])c4c3-c3c([2H])c([2H])c(C([2H])([2H])[2H])c([2H])c3C43c4c([2H])c([2H])c([2H])c([2H])c4-c4c([2H])c([2H])c([2H])c([2H])c43)c3c([2H])c([2H])c([2H])c4c([2H])c([2H])c5c([2H])c([2H])c([2H])c([2H])c5c34)c([2H])c([2H])c([2H])c21]

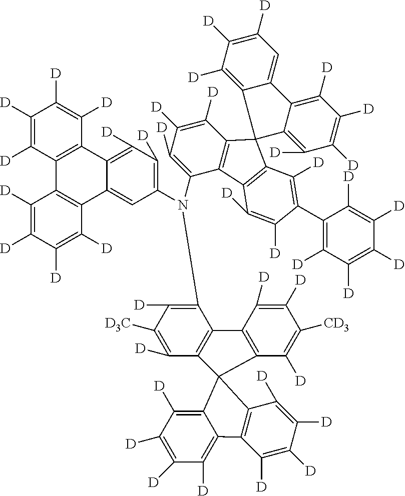 [SMILES: [2H]c1cc2c(c([2H])c1[2H])C1(c3c([2H])c([2H])c([2H])c([2H])c3-2)c2c([2H])c(-c3c([2H])c([2H])c([2H])c([2H])c3[2H])c([2H])c([2H])c2-c2c(N(c3cc4c(c([2H])c3[2H])c3c([2H])c([2H])c([2H])c([2H])c3c3c([2H])c([2H])c([2H])c([2H])c43)c3c([2H])c(C([2H])([2H])[2H])c([2H])c4c3-c3c([2H])c([2H])c(C([2H])([2H])[2H])c([2H])c3C43c4c([2H])c([2H])c([2H])c([2H])c4-c4c([2H])c([2H])c([2H])c([2H])c43)c([2H])c([2H])c([2H])c21]

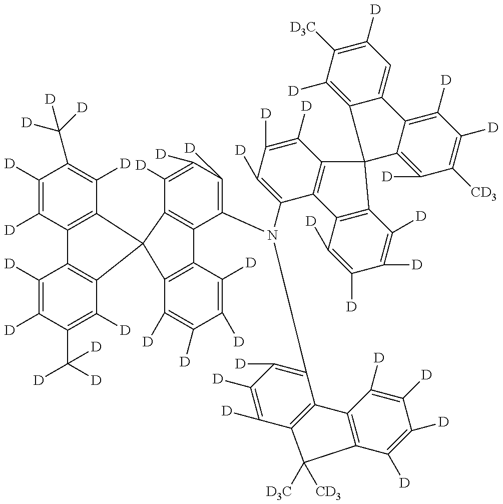 [SMILES: [2H]c1cc2c(c([2H])c1C([2H])([2H])[2H])C1(c3c([2H])c(C([2H])([2H])[2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

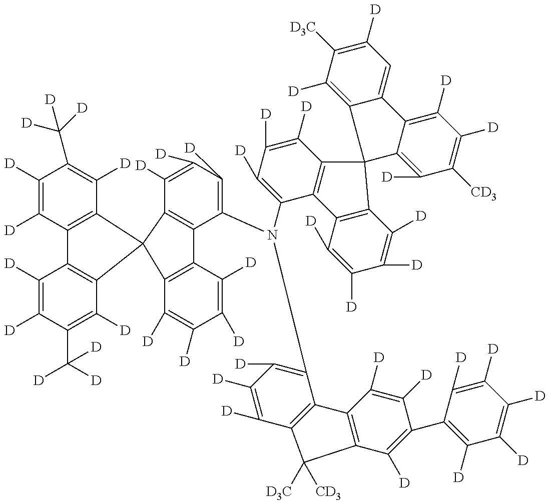 [SMILES: [2H]c1cc2c(c([2H])c1C([2H])([2H])[2H])C1(c3c([2H])c(C([2H])([2H])[2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c3c([2H])c([2H])c([2H])c4c3-c3c([2H])c([2H])c(-c5c([2H])c([2H])c([2H])c([2H])c5[2H])c([2H])c3C4(C([2H])([2H])[2H])C([2H])([2H])[2H])c([2H])c([2H])c([2H])c21]

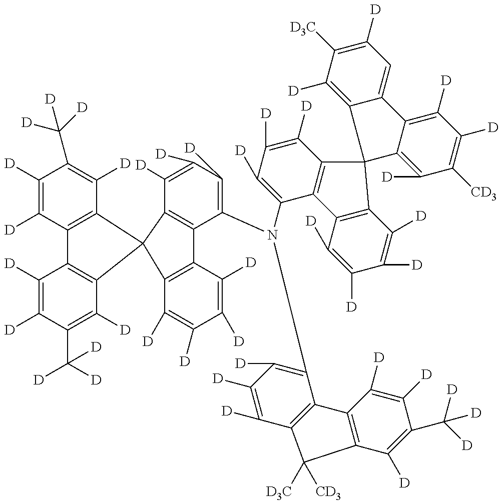 [SMILES: [2H]c1cc2c(c([2H])c1C([2H])([2H])[2H])C1(c3c([2H])c(C([2H])([2H])[2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c3c([2H])c([2H])c([2H])c4c3-c3c([2H])c([2H])c(C([2H])([2H])[2H])c([2H])c3C4(C([2H])([2H])[2H])C([2H])([2H])[2H])c([2H])c([2H])c([2H])c21]

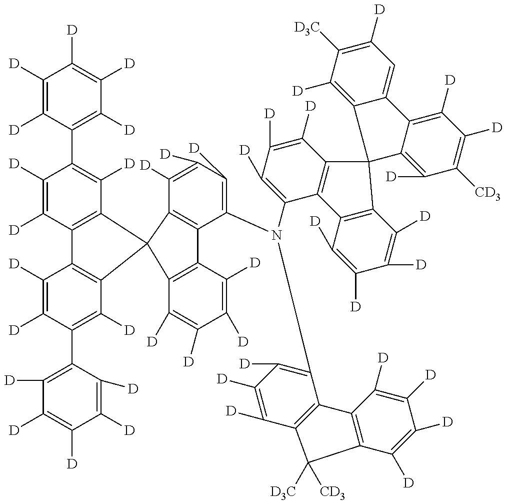 [SMILES: [2H]c1cc2c(c([2H])c1C([2H])([2H])[2H])C1(c3c([2H])c(C([2H])([2H])[2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(-c5c([2H])c([2H])c([2H])c([2H])c5[2H])c([2H])c([2H])c4-c4c([2H])c([2H])c(-c5c([2H])c([2H])c([2H])c([2H])c5[2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

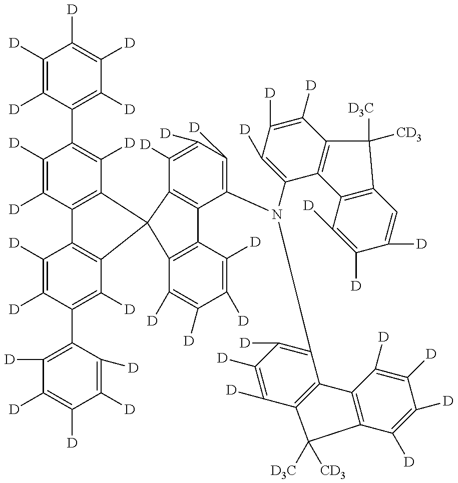 [SMILES: [2H]c1cc2c(c([2H])c1[2H])-c1c(N(c3c([2H])c([2H])c([2H])c4c3-c3c([2H])c([2H])c([2H])c([2H])c3C43c4c([2H])c(-c5c([2H])c([2H])c([2H])c([2H])c5[2H])c([2H])c([2H])c4-c4c([2H])c([2H])c(-c5c([2H])c([2H])c([2H])c([2H])c5[2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(C([2H])([2H])[2H])C([2H])([2H])[2H]]

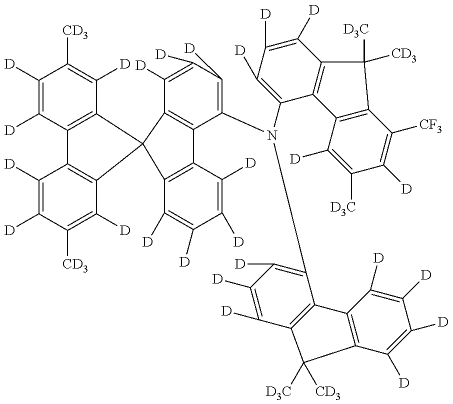 [SMILES: [2H]c1c([2H])c([2H])c2c(c1[2H])-c1c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c(C([2H])([2H])[2H])c([2H])c(C(F)(F)F)c3C4(C([2H])([2H])[2H])C([2H])([2H])[2H])c([2H])c([2H])c([2H])c1C21c2c([2H])c(C([2H])([2H])[2H])c([2H])c([2H])c2-c2c([2H])c([2H])c(C([2H])([2H])[2H])c([2H])c21]

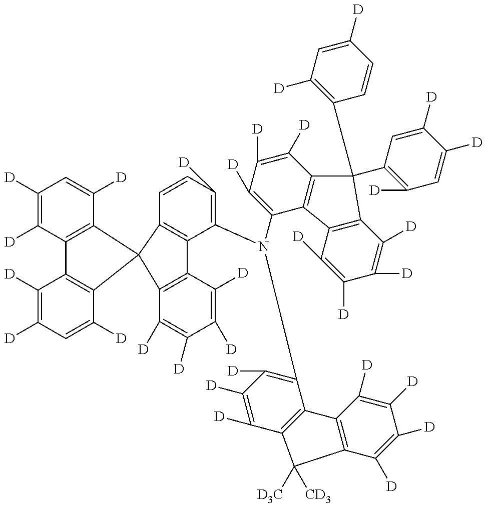 [SMILES: [2H]c1ccc(C2(c3cc([2H])c([2H])cc3[2H])c3c([2H])c([2H])c([2H])c([2H])c3-c3c(N(c4c([2H])ccc5c4-c4c([2H])c([2H])c([2H])c([2H])c4C54c5c([2H])cc([2H])c([2H])c5-c5c([2H])c([2H])cc([2H])c54)c4c([2H])c([2H])c([2H])c5c4-c4c([2H])c([2H])c([2H])c([2H])c4C5(C([2H])([2H])[2H])C([2H])([2H])[2H])c([2H])c([2H])c([2H])c32)c([2H])c1]

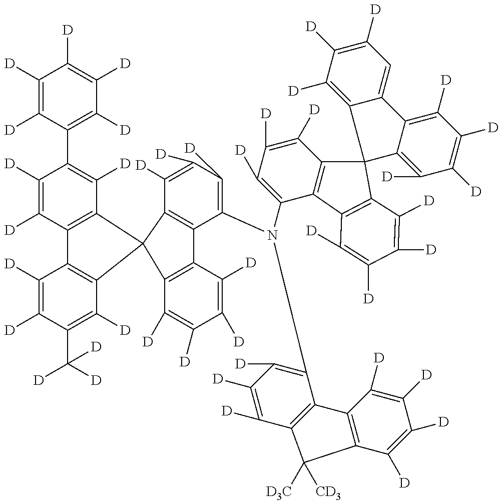 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(-c5c([2H])c([2H])c([2H])c([2H])c5[2H])c([2H])c([2H])c4-c4c([2H])c([2H])c(C([2H])([2H])[2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

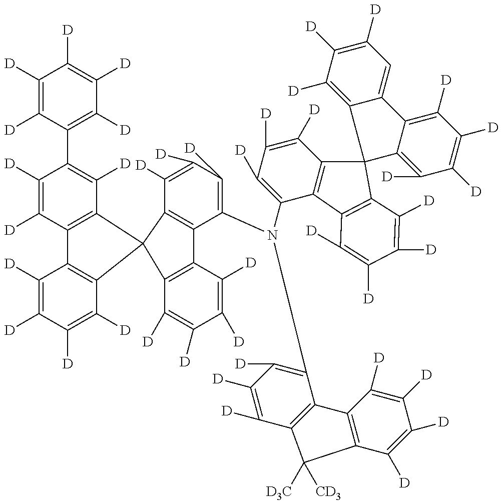 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c(-c5c([2H])c([2H])c([2H])c([2H])c5[2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

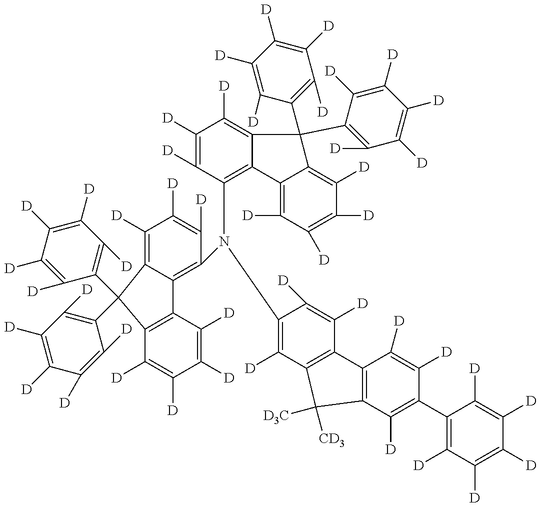 [SMILES: [2H]c1c([2H])c([2H])c(-c2c([2H])c([2H])c3c(c2[2H])C(C([2H])([2H])[2H])(C([2H])([2H])[2H])c2c([2H])c(N(c4c([2H])c([2H])c([2H])c5c4-c4c([2H])c([2H])c([2H])c([2H])c4C5(c4c([2H])c([2H])c([2H])c([2H])c4[2H])c4c([2H])c([2H])c([2H])c([2H])c4[2H])c4c([2H])c([2H])c([2H])c5c4-c4c([2H])c([2H])c([2H])c([2H])c4C5(c4c([2H])c([2H])c([2H])c([2H])c4[2H])c4c([2H])c([2H])c([2H])c([2H])c4[2H])c([2H])c([2H])c2-3)c([2H])c1[2H]]

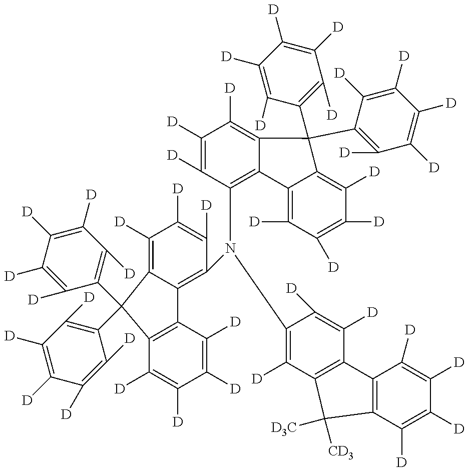 [SMILES: [2H]c1c([2H])c([2H])c(C2(c3c([2H])c([2H])c([2H])c([2H])c3[2H])c3c([2H])c([2H])c([2H])c([2H])c3-c3c(N(c4c([2H])c([2H])c5c(c4[2H])C(C([2H])([2H])[2H])(C([2H])([2H])[2H])c4c([2H])c([2H])c([2H])c([2H])c4-5)c4c([2H])c([2H])c([2H])c5c4-c4c([2H])c([2H])c([2H])c([2H])c4C5(c4c([2H])c([2H])c([2H])c([2H])c4[2H])c4c([2H])c([2H])c([2H])c([2H])c4[2H])c([2H])c([2H])c([2H])c32)c([2H])c1[2H]]

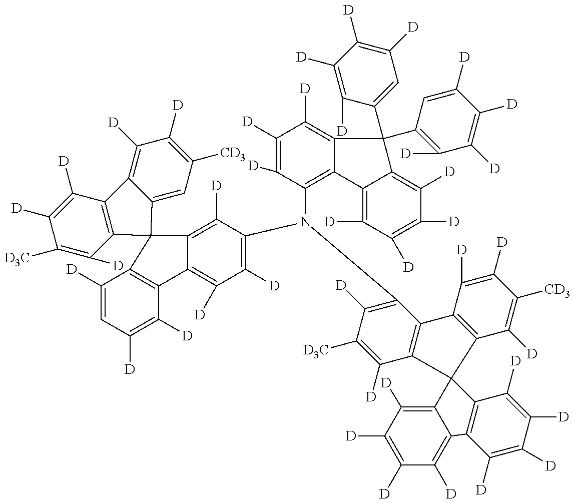 [SMILES: [2H]c1cc(C2(c3cc([2H])c([2H])c([2H])c3[2H])c3c([2H])c([2H])c([2H])c([2H])c3-c3c(N(c4c([2H])c([2H])c5c(c4[2H])C4(c6cc(C([2H])([2H])[2H])c([2H])c([2H])c6-c6c([2H])c([2H])c(C([2H])([2H])[2H])c([2H])c64)c4c([2H])cc([2H])c([2H])c4-5)c4c([2H])c(C([2H])([2H])[2H])c([2H])c5c4-c4c([2H])c([2H])c(C([2H])([2H])[2H])c([2H])c4C54c5c([2H])c([2H])c([2H])c([2H])c5-c5c([2H])c([2H])c([2H])c([2H])c54)c([2H])c([2H])c([2H])c32)c([2H])c([2H])c1[2H]]

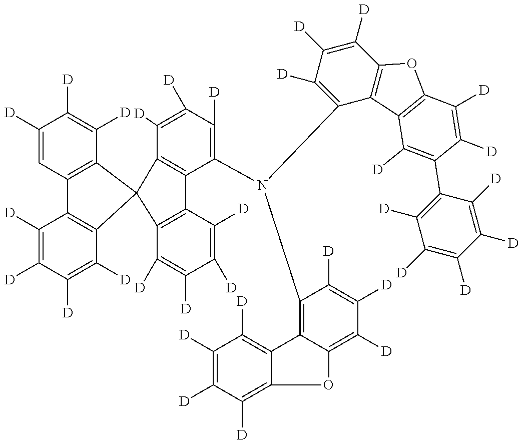 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c([2H])c4oc5c([2H])c([2H])c([2H])c([2H])c5c34)c3c([2H])c([2H])c([2H])c4oc5c([2H])c([2H])c(-c6c([2H])c([2H])c([2H])c([2H])c6[2H])c([2H])c5c34)c([2H])c([2H])c([2H])c21]

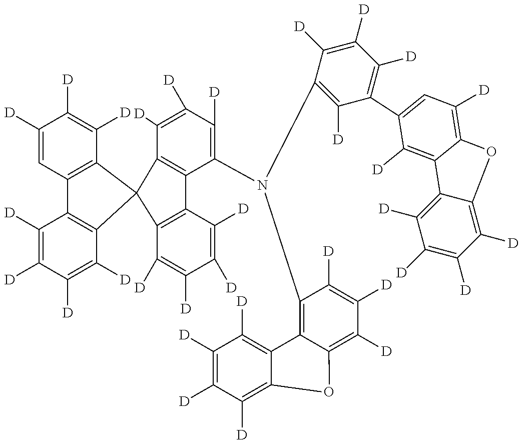 [SMILES: [2H]c1cc2c(c([2H])c1[2H])C1(c3c([2H])c([2H])c([2H])c([2H])c3-2)c2c([2H])c([2H])c([2H])c([2H])c2-c2c(N(c3c([2H])c([2H])c([2H])c(-c4cc([2H])c5oc6c([2H])c([2H])c([2H])c([2H])c6c5c4[2H])c3[2H])c3c([2H])c([2H])c([2H])c4oc5c([2H])c([2H])c([2H])c([2H])c5c34)c([2H])c([2H])c([2H])c21]

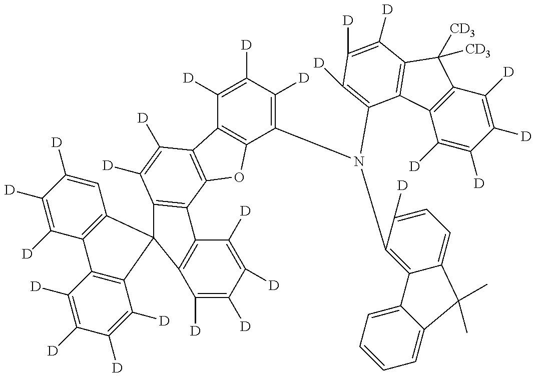 [SMILES: [2H]c1cc2c(c([2H])c1[2H])-c1c([2H])c([2H])c([2H])c([2H])c1C21c2c([2H])c([2H])c([2H])c([2H])c2-c2c1c([2H])c([2H])c1c2oc2c(N(c3c([2H])ccc4c3-c3ccccc3C4(C)C)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

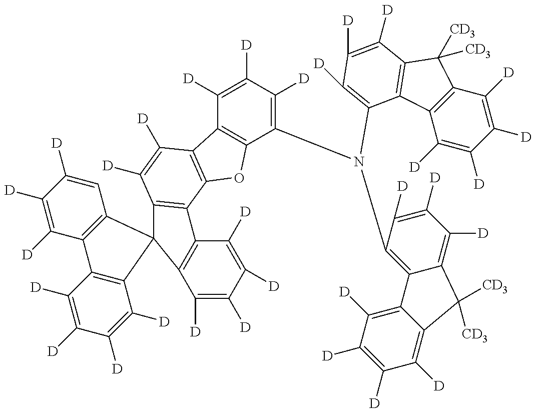 [SMILES: [2H]c1cc2c(c([2H])c1[2H])-c1c([2H])c([2H])c([2H])c([2H])c1C21c2c([2H])c([2H])c([2H])c([2H])c2-c2c1c([2H])c([2H])c1c2oc2c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

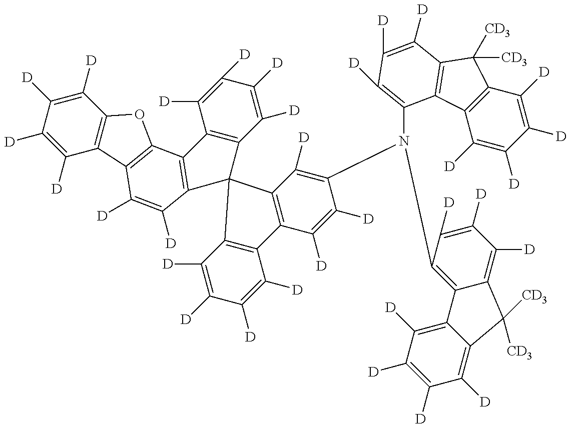 [SMILES: [2H]c1c([2H])c([2H])c2c(c1[2H])-c1c([2H])c([2H])c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c1C21c2c([2H])c([2H])c([2H])c([2H])c2-c2c1c([2H])c([2H])c1c2oc2c([2H])c([2H])c([2H])c([2H])c21]

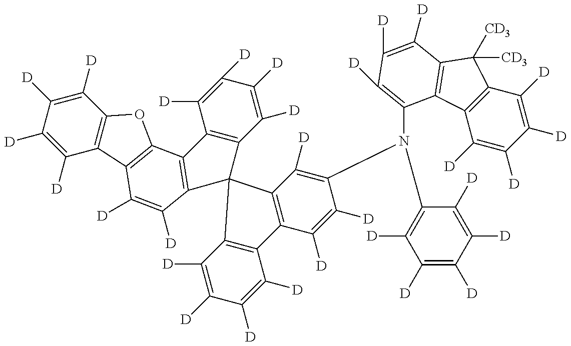 [SMILES: [2H]c1c([2H])c([2H])c(N(c2c([2H])c([2H])c3c(c2[2H])C2(c4c([2H])c([2H])c([2H])c([2H])c4-3)c3c([2H])c([2H])c([2H])c([2H])c3-c3c2c([2H])c([2H])c2c3oc3c([2H])c([2H])c([2H])c([2H])c32)c2c([2H])c([2H])c([2H])c3c2-c2c([2H])c([2H])c([2H])c([2H])c2C3(C([2H])([2H])[2H])C([2H])([2H])[2H])c([2H])c1[2H]]

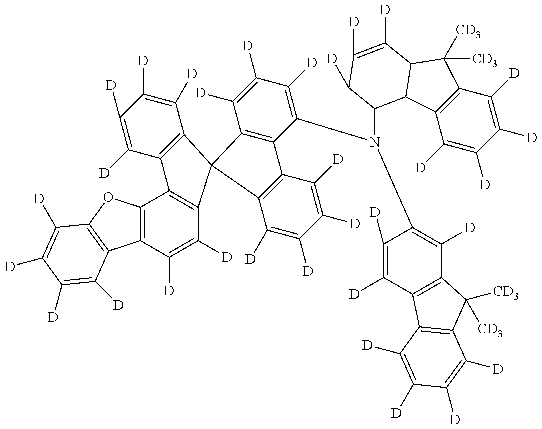 [SMILES: [2H]C1=C([2H])C2C(c3c([2H])c([2H])c([2H])c([2H])c3C2(C([2H])([2H])[2H])C([2H])([2H])[2H])C(N(c2c([2H])c([2H])c3c(c2[2H])C(C([2H])([2H])[2H])(C([2H])([2H])[2H])c2c([2H])c([2H])c([2H])c([2H])c2-3)c2c([2H])c([2H])c([2H])c3c2-c2c([2H])c([2H])c([2H])c([2H])c2C32c3c([2H])c([2H])c([2H])c([2H])c3-c3c2c([2H])c([2H])c2c3oc3c([2H])c([2H])c([2H])c([2H])c32)C1[2H]]

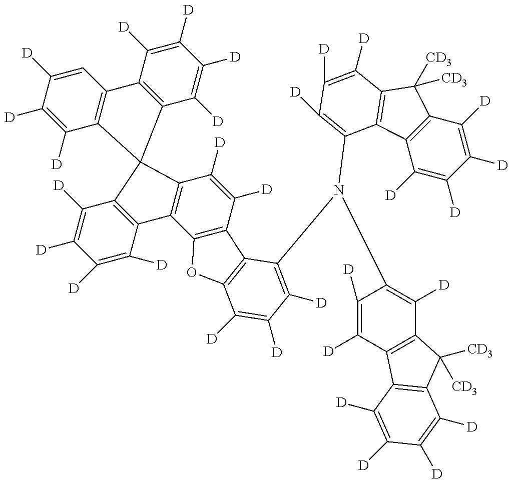 [SMILES: [2H]c1cc2c(c([2H])c1[2H])C1(c3c([2H])c([2H])c([2H])c([2H])c3-2)c2c([2H])c([2H])c([2H])c([2H])c2-c2c1c([2H])c([2H])c1c2oc2c([2H])c([2H])c([2H])c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C4(C([2H])([2H])[2H])C([2H])([2H])[2H])c21]

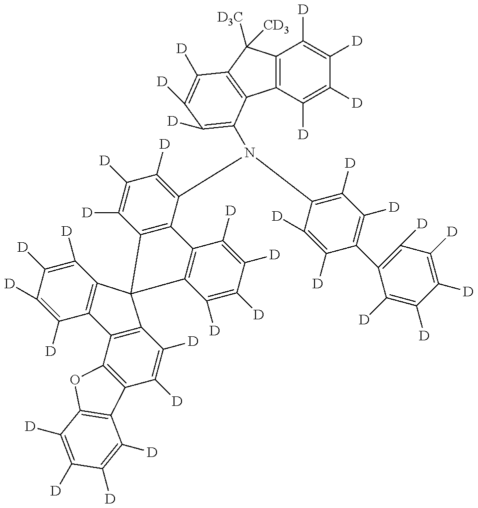 [SMILES: [2H]c1c([2H])c([2H])c(-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c3c([2H])c([2H])c3c4oc4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c2[2H])c([2H])c1[2H]]

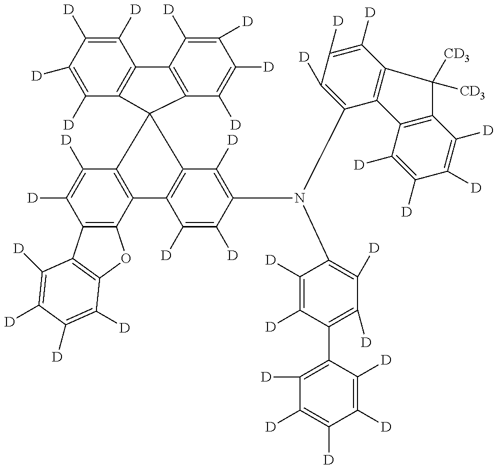 [SMILES: [2H]c1c([2H])c([2H])c(-c2c([2H])c([2H])c(N(c3c([2H])c([2H])c4c(c3[2H])C3(c5c([2H])c([2H])c([2H])c([2H])c5-c5c([2H])c([2H])c([2H])c([2H])c53)c3c([2H])c([2H])c5c(oc6c([2H])c([2H])c([2H])c([2H])c65)c3-4)c3c([2H])c([2H])c([2H])c4c3-c3c([2H])c([2H])c([2H])c([2H])c3C4(C([2H])([2H])[2H])C([2H])([2H])[2H])c([2H])c2[2H])c([2H])c1[2H]]

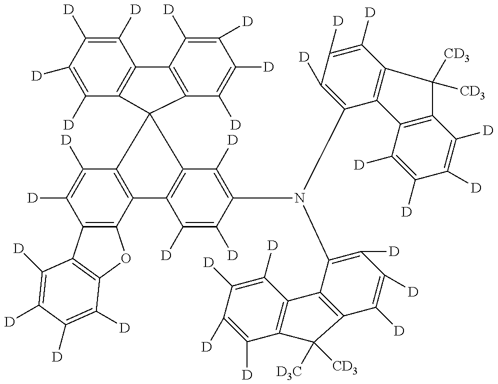 [SMILES: [2H]c1c([2H])c([2H])c2c(c1[2H])-c1c([2H])c([2H])c([2H])c([2H])c1C21c2c([2H])c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c2-c2c1c([2H])c([2H])c1c2oc2c([2H])c([2H])c([2H])c([2H])c21]

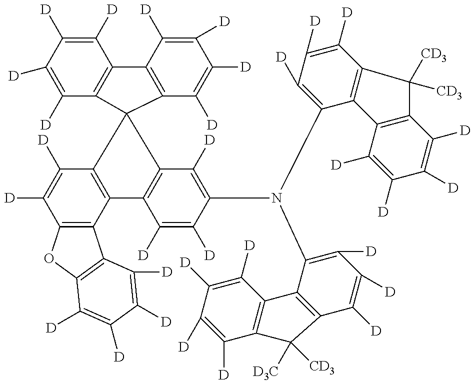 [SMILES: [2H]c1c([2H])c([2H])c2c(c1[2H])-c1c([2H])c([2H])c([2H])c([2H])c1C21c2c([2H])c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c2-c2c1c([2H])c([2H])c1oc3c([2H])c([2H])c([2H])c([2H])c3c21]

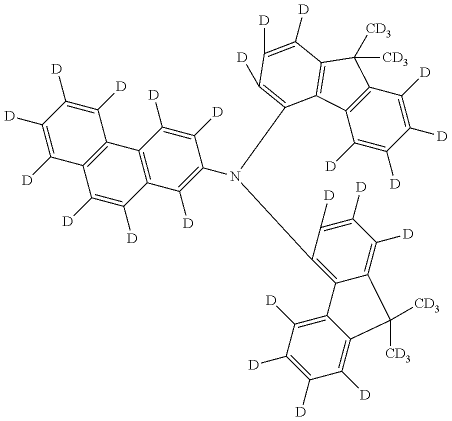 [SMILES: [2H]c1c([2H])c([2H])c2c(c1[2H])-c1c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c4c(c3[2H])c([2H])c([2H])c3c([2H])c([2H])c([2H])c([2H])c34)c([2H])c([2H])c([2H])c1C2(C([2H])([2H])[2H])C([2H])([2H])[2H]]

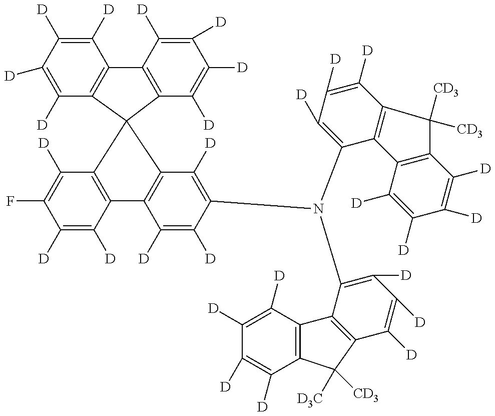 [SMILES: [2H]c1c([2H])c([2H])c2c(c1[2H])-c1c([2H])c([2H])c([2H])c([2H])c1C21c2c([2H])c(F)c([2H])c([2H])c2-c2c([2H])c([2H])c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3-c3c([2H])c([2H])c([2H])c([2H])c3C4(C([2H])([2H])[2H])C([2H])([2H])[2H])c([2H])c21]

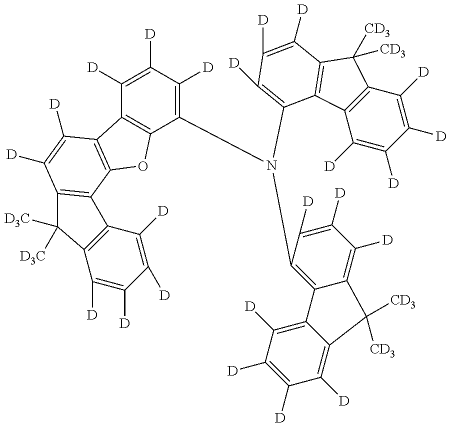 [SMILES: [2H]c1c([2H])c([2H])c2c(c1[2H])-c1c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c([2H])c4c3oc3c5c(c([2H])c([2H])c34)C(C([2H])([2H])[2H])(C([2H])([2H])[2H])c3c([2H])c([2H])c([2H])c([2H])c3-5)c([2H])c([2H])c([2H])c1C2(C([2H])([2H])[2H])C([2H])([2H])[2H]]

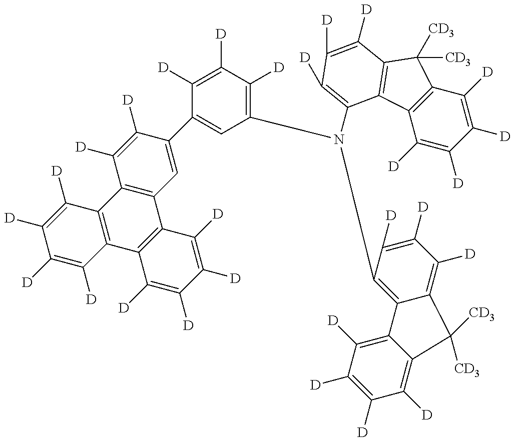 [SMILES: [2H]c1c(-c2cc3c(c([2H])c2[2H])c2c([2H])c([2H])c([2H])c([2H])c2c2c([2H])c([2H])c([2H])c([2H])c32)cc(N(c2c([2H])c([2H])c([2H])c3c2-c2c([2H])c([2H])c([2H])c([2H])c2C3(C([2H])([2H])[2H])C([2H])([2H])[2H])c2c([2H])c([2H])c([2H])c3c2-c2c([2H])c([2H])c([2H])c([2H])c2C3(C([2H])([2H])[2H])C([2H])([2H])[2H])c([2H])c1[2H]]

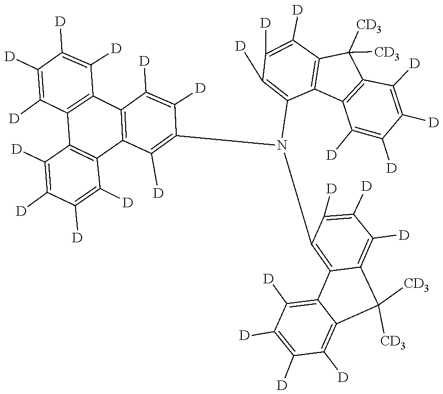 [SMILES: [2H]c1c([2H])c([2H])c2c(c1[2H])-c1c(N(c3c([2H])c([2H])c([2H])c4c3-c3c([2H])c([2H])c([2H])c([2H])c3C4(C([2H])([2H])[2H])C([2H])([2H])[2H])c3c([2H])c([2H])c4c5c([2H])c([2H])c([2H])c([2H])c5c5c([2H])c([2H])c([2H])c([2H])c5c4c3[2H])c([2H])c([2H])c([2H])c1C2(C([2H])([2H])[2H])C([2H])([2H])[2H]]

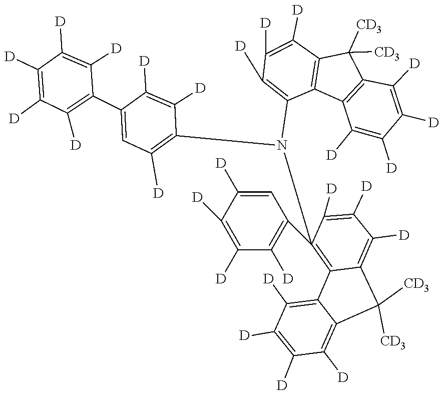

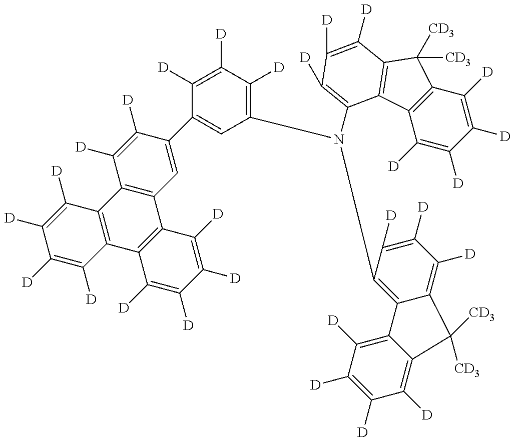 [SMILES: [2H]c1c(-c2cc3c(c([2H])c2[2H])c2c([2H])c([2H])c([2H])c([2H])c2c2c([2H])c([2H])c([2H])c([2H])c32)cc(N(c2c([2H])c([2H])c([2H])c3c2-c2c([2H])c([2H])c([2H])c([2H])c2C3(C([2H])([2H])[2H])C([2H])([2H])[2H])c2c([2H])c([2H])c([2H])c3c2-c2c([2H])c([2H])c([2H])c([2H])c2C3(C([2H])([2H])[2H])C([2H])([2H])[2H])c([2H])c1[2H]]

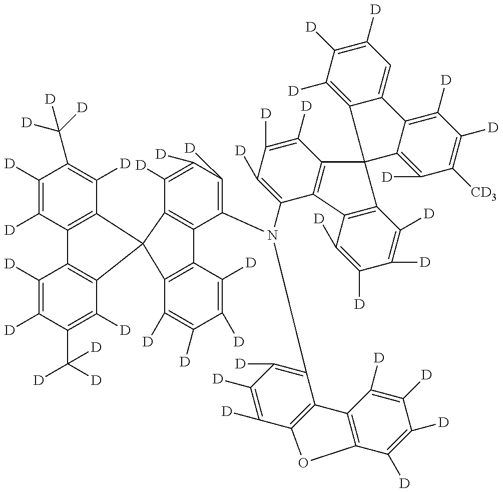 [SMILES: [2H]c1cc2c(c([2H])c1[2H])C1(c3c([2H])c(C([2H])([2H])[2H])c([2H])c([2H])c3-2)c2c([2H])c([2H])c([2H])c([2H])c2-c2c(N(c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c3c([2H])c([2H])c([2H])c4oc5c([2H])c([2H])c([2H])c([2H])c5c34)c([2H])c([2H])c([2H])c21]

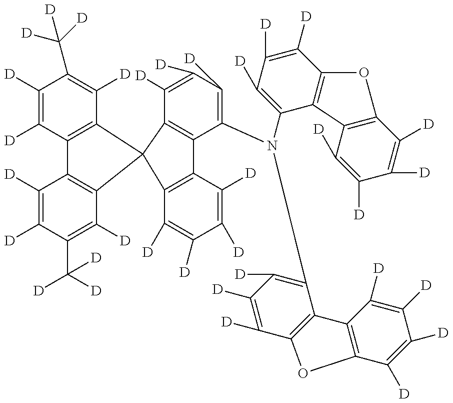 [SMILES: [2H]c1c([2H])c([2H])c2c(c1[2H])-c1c(N(c3c([2H])c([2H])c([2H])c4oc5c([2H])c([2H])c([2H])c([2H])c5c34)c3c([2H])c([2H])c([2H])c4oc5c([2H])c([2H])c([2H])c([2H])c5c34)c([2H])c([2H])c([2H])c1C21c2c([2H])c(C([2H])([2H])[2H])c([2H])c([2H])c2-c2c([2H])c([2H])c(C([2H])([2H])[2H])c([2H])c21]

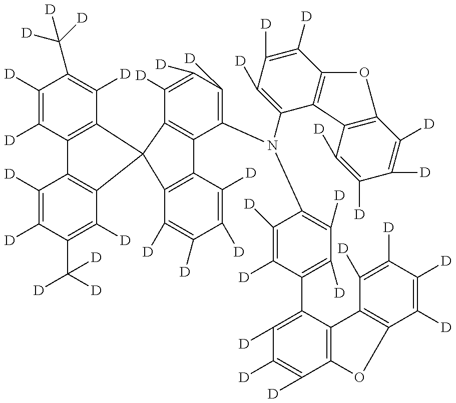 [SMILES: [2H]c1c([2H])c([2H])c2c(c1[2H])-c1c(N(c3c([2H])c([2H])c(-c4c([2H])c([2H])c([2H])c5oc6c([2H])c([2H])c([2H])c([2H])c6c45)c([2H])c3[2H])c3c([2H])c([2H])c([2H])c4oc5c([2H])c([2H])c([2H])c([2H])c5c34)c([2H])c([2H])c([2H])c1C21c2c([2H])c(C([2H])([2H])[2H])c([2H])c([2H])c2-c2c([2H])c([2H])c(C([2H])([2H])[2H])c([2H])c21]

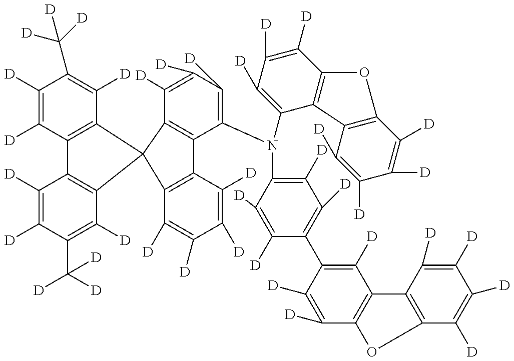 [SMILES: [2H]c1c([2H])c([2H])c2c(c1[2H])-c1c(N(c3c([2H])c([2H])c(-c4c([2H])c([2H])c5oc6c([2H])c([2H])c([2H])c([2H])c6c5c4[2H])c([2H])c3[2H])c3c([2H])c([2H])c([2H])c4oc5c([2H])c([2H])c([2H])c([2H])c5c34)c([2H])c([2H])c([2H])c1C21c2c([2H])c(C([2H])([2H])[2H])c([2H])c([2H])c2-c2c([2H])c([2H])c(C([2H])([2H])[2H])c([2H])c21]

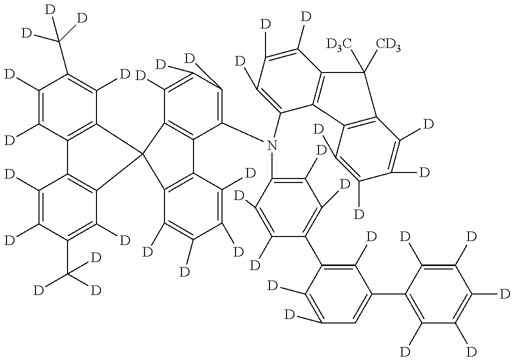 [SMILES: [2H]c1cc(-c2c([2H])c([2H])c([2H])c([2H])c2[2H])c([2H])c(-c2c([2H])c([2H])c(N(c3c([2H])c([2H])c([2H])c4c3-c3c([2H])c([2H])c([2H])c([2H])c3C43c4c([2H])c(C([2H])([2H])[2H])c([2H])c([2H])c4-c4c([2H])c([2H])c(C([2H])([2H])[2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c2[2H])c1[2H]]

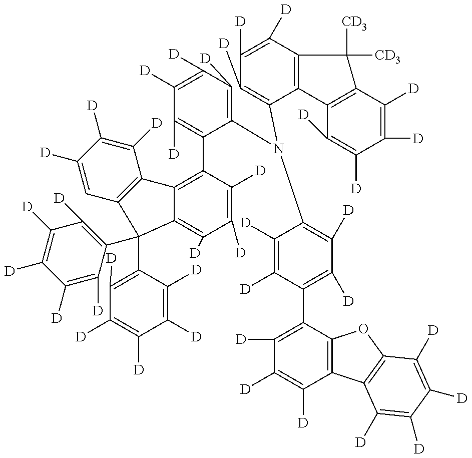 [SMILES: [2H]c1cc2c(c([2H])c1[2H])-c1c(-c3c([2H])c([2H])c([2H])c([2H])c3N(c3c([2H])c([2H])c(-c4c([2H])c([2H])c([2H])c5c4oc4c([2H])c([2H])c([2H])c([2H])c45)c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(c1c([2H])c([2H])c([2H])c([2H])c1[2H])c1c([2H])c([2H])c([2H])c([2H])c1[2H]]

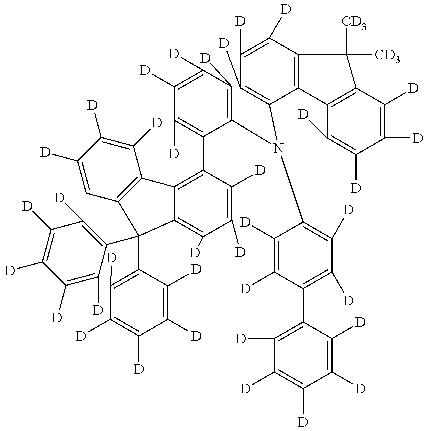 [SMILES: [2H]c1cc2c(c([2H])c1[2H])-c1c(-c3c([2H])c([2H])c([2H])c([2H])c3N(c3c([2H])c([2H])c(-c4c([2H])c([2H])c([2H])c([2H])c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(c1c([2H])c([2H])c([2H])c([2H])c1[2H])c1c([2H])c([2H])c([2H])c([2H])c1[2H]]

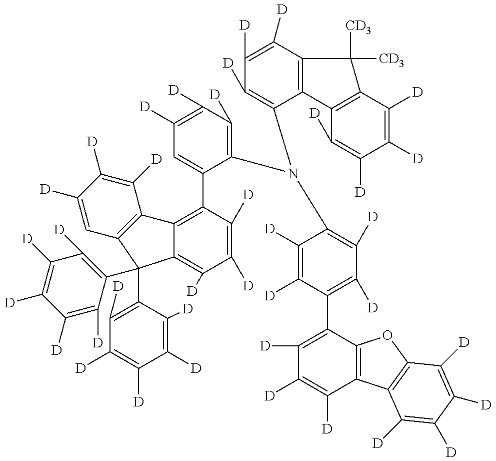 [SMILES: [2H]c1cc2c(c([2H])c1[2H])-c1c(-c3cc([2H])c([2H])c([2H])c3N(c3c([2H])c([2H])c(-c4c([2H])c([2H])c([2H])c5c4oc4c([2H])c([2H])c([2H])c([2H])c45)c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(c1c([2H])c([2H])c([2H])c([2H])c1[2H])c1c([2H])c([2H])c([2H])c([2H])c1[2H]]

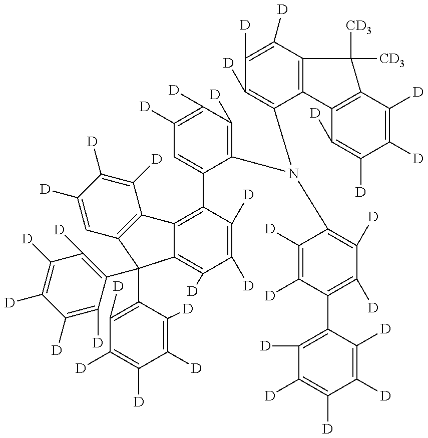 [SMILES: [2H]c1cc2c(c([2H])c1[2H])-c1c(-c3cc([2H])c([2H])c([2H])c3N(c3c([2H])c([2H])c(-c4c([2H])c([2H])c([2H])c([2H])c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(c1c([2H])c([2H])c([2H])c([2H])c1[2H])c1c([2H])c([2H])c([2H])c([2H])c1[2H]]

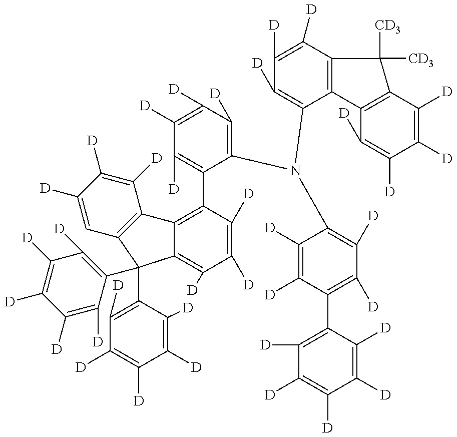 [SMILES: [2H]c1cc2c(c([2H])c1[2H])-c1c(-c3c([2H])c([2H])c([2H])c([2H])c3N(c3c([2H])c([2H])c(-c4c([2H])c([2H])c([2H])c([2H])c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c1C2(c1c([2H])c([2H])c([2H])c([2H])c1[2H])c1c([2H])c([2H])c([2H])c([2H])c1[2H]]

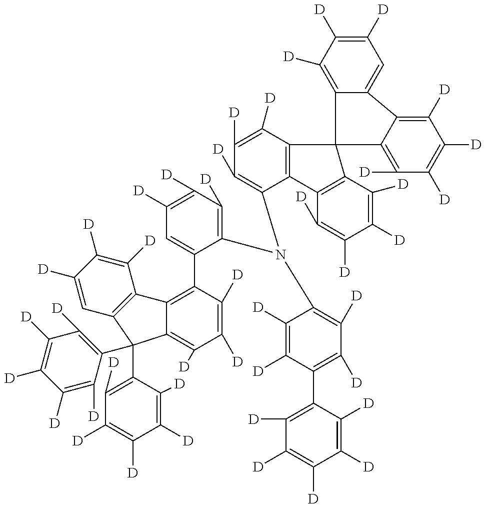 [SMILES: [2H]c1cc2c(c([2H])c1[2H])-c1c(-c3cc([2H])c([2H])c([2H])c3N(c3c([2H])c([2H])c(-c4c([2H])c([2H])c([2H])c([2H])c4[2H])c([2H])c3[2H])c3c([2H])c([2H])c([2H])c4c3-c3c([2H])c([2H])c([2H])c([2H])c3C43c4c(cc([2H])c([2H])c4[2H])-c4c([2H])c([2H])c([2H])c([2H])c43)c([2H])c([2H])c([2H])c1C2(c1c([2H])c([2H])c([2H])c([2H])c1[2H])c1c([2H])c([2H])c([2H])c([2H])c1[2H]]

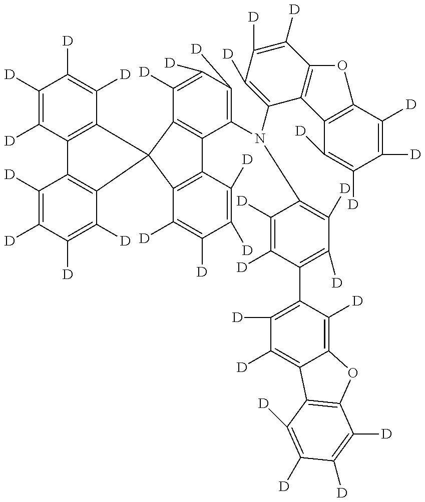 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])c5c(oc6c([2H])c([2H])c([2H])c([2H])c65)c4[2H])c([2H])c3[2H])c3c([2H])c([2H])c([2H])c4oc5c([2H])c([2H])c([2H])c([2H])c5c34)c([2H])c([2H])c([2H])c21]

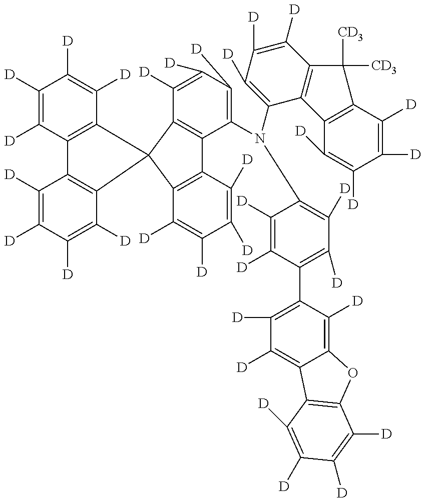 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])c5c(oc6c([2H])c([2H])c([2H])c([2H])c65)c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

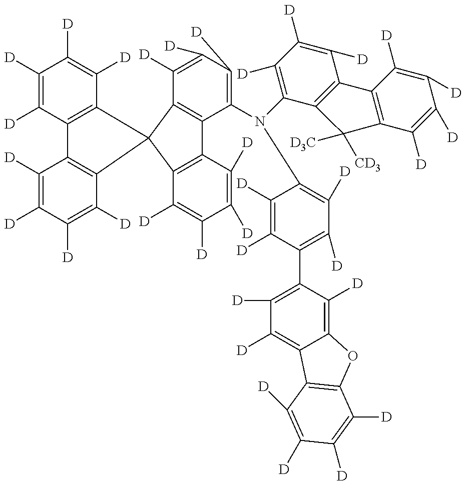 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])c5c(oc6c([2H])c([2H])c([2H])c([2H])c65)c4[2H])c([2H])c3[2H])c3c([2H])c([2H])c([2H])c4c3C(C([2H])([2H])[2H])(C([2H])([2H])[2H])c3c([2H])c([2H])c([2H])c([2H])c3-4)c([2H])c([2H])c([2H])c21]

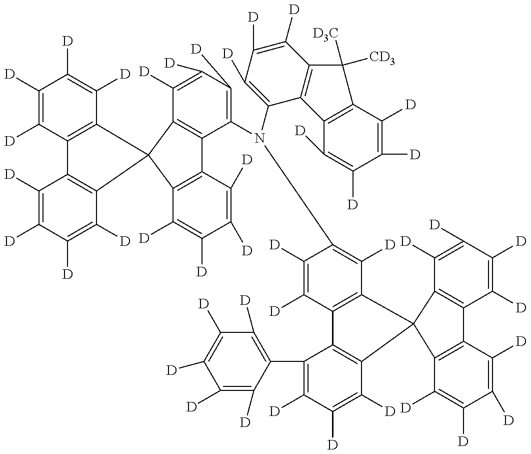 [SMILES: [2H]c1c([2H])c([2H])c(-c2c([2H])c([2H])c([2H])c3c2-c2c([2H])c([2H])c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c([2H])c([2H])c4C5(C([2H])([2H])[2H])C([2H])([2H])[2H])c([2H])c2C32c3c([2H])c([2H])c([2H])c([2H])c3-c3c([2H])c([2H])c([2H])c([2H])c32)c([2H])c1[2H]]

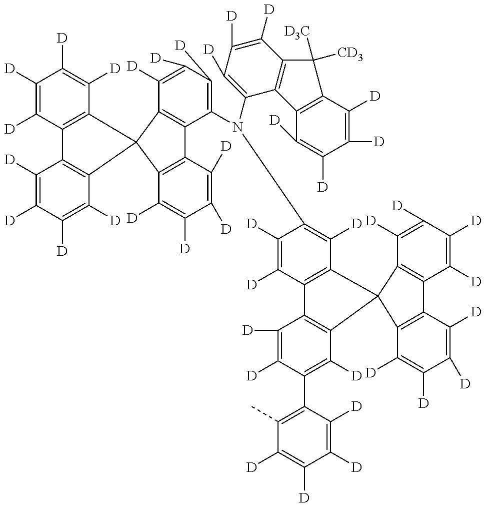

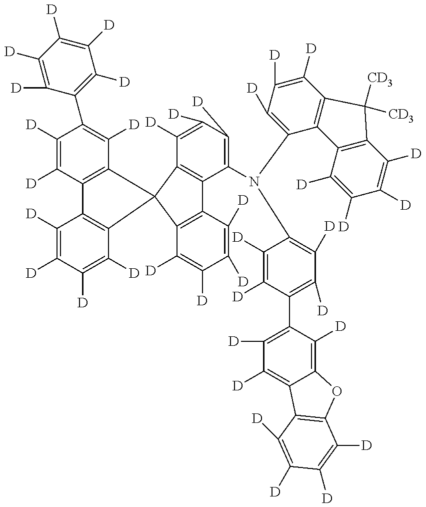 [SMILES: [2H]c1c([2H])c([2H])c(-c2c([2H])c([2H])c3c(c2[2H])C2(c4c([2H])c([2H])c([2H])c([2H])c4-3)c3c([2H])c([2H])c([2H])c([2H])c3-c3c(N(c4c([2H])c([2H])c(-c5c([2H])c([2H])c6c(oc7c([2H])c([2H])c([2H])c([2H])c76)c5[2H])c([2H])c4[2H])c4c([2H])c([2H])c([2H])c5c4-c4c([2H])c([2H])c([2H])c([2H])c4C5(C([2H])([2H])[2H])C([2H])([2H])[2H])c([2H])c([2H])c([2H])c32)c([2H])c1[2H]]

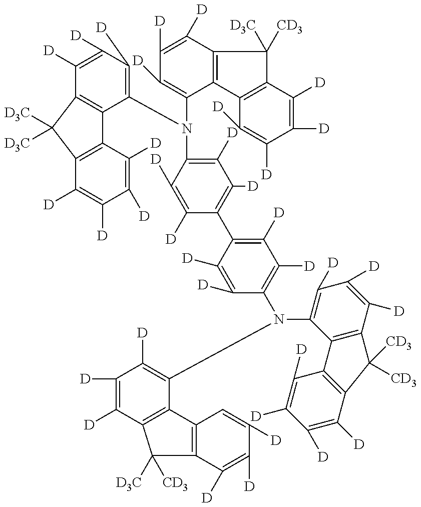 [SMILES: [2H]c1cc2c(c([2H])c1[2H])C(C([2H])([2H])[2H])(C([2H])([2H])[2H])c1c([2H])c([2H])c([2H])c(N(c3c([2H])c([2H])c(-c4c([2H])c([2H])c(N(c5c([2H])c([2H])c([2H])c6c5-c5c([2H])c([2H])c([2H])c([2H])c5C6(C([2H])([2H])[2H])C([2H])([2H])[2H])c5c([2H])c([2H])c([2H])c6c5-c5c([2H])c([2H])c([2H])c([2H])c5C6(C([2H])([2H])[2H])C([2H])([2H])[2H])c([2H])c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c1-2]

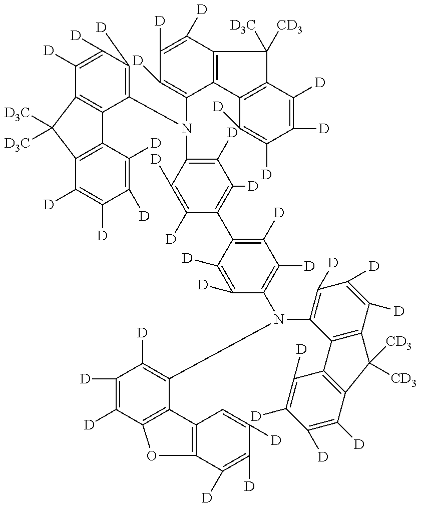 [SMILES: [2H]c1cc2c(oc3c([2H])c([2H])c([2H])c(N(c4c([2H])c([2H])c(-c5c([2H])c([2H])c(N(c6c([2H])c([2H])c([2H])c7c6-c6c([2H])c([2H])c([2H])c([2H])c6C7(C([2H])([2H])[2H])C([2H])([2H])[2H])c6c([2H])c([2H])c([2H])c7c6-c6c([2H])c([2H])c([2H])c([2H])c6C7(C([2H])([2H])[2H])C([2H])([2H])[2H])c([2H])c5[2H])c([2H])c4[2H])c4c([2H])c([2H])c([2H])c5c4-c4c([2H])c([2H])c([2H])c([2H])c4C5(C([2H])([2H])[2H])C([2H])([2H])[2H])c32)c([2H])c1[2H]]

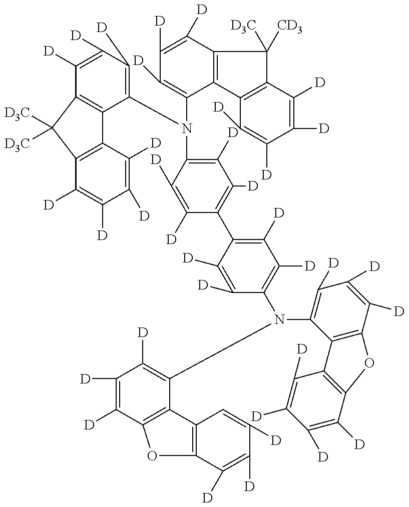 [SMILES: [2H]c1cc2c(oc3c([2H])c([2H])c([2H])c(N(c4c([2H])c([2H])c(-c5c([2H])c([2H])c(N(c6c([2H])c([2H])c([2H])c7c6-c6c([2H])c([2H])c([2H])c([2H])c6C7(C([2H])([2H])[2H])C([2H])([2H])[2H])c6c([2H])c([2H])c([2H])c7c6-c6c([2H])c([2H])c([2H])c([2H])c6C7(C([2H])([2H])[2H])C([2H])([2H])[2H])c([2H])c5[2H])c([2H])c4[2H])c4c([2H])c([2H])c([2H])c5oc6c([2H])c([2H])c([2H])c([2H])c6c45)c32)c([2H])c1[2H]]

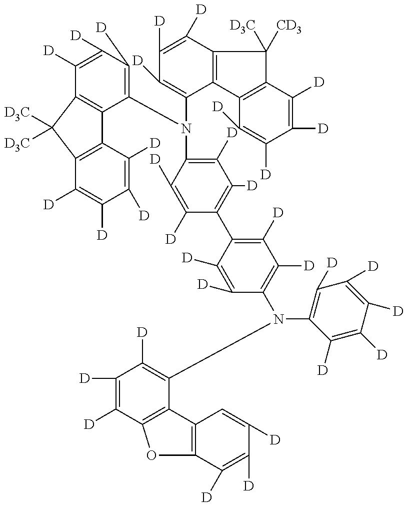 [SMILES: [2H]c1cc2c(oc3c([2H])c([2H])c([2H])c(N(c4c([2H])c([2H])c([2H])c([2H])c4[2H])c4c([2H])c([2H])c(-c5c([2H])c([2H])c(N(c6c([2H])c([2H])c([2H])c7c6-c6c([2H])c([2H])c([2H])c([2H])c6C7(C([2H])([2H])[2H])C([2H])([2H])[2H])c6c([2H])c([2H])c([2H])c7c6-c6c([2H])c([2H])c([2H])c([2H])c6C7(C([2H])([2H])[2H])C([2H])([2H])[2H])c([2H])c5[2H])c([2H])c4[2H])c32)c([2H])c1[2H]]

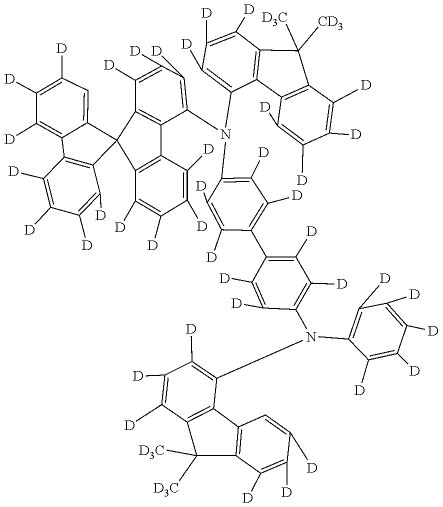 [SMILES: [2H]c1cc2c(c([2H])c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])c(N(c5c([2H])c([2H])c([2H])c([2H])c5[2H])c5c([2H])c([2H])c([2H])c6c5-c5cc([2H])c([2H])c([2H])c5C6(C([2H])([2H])[2H])C([2H])([2H])[2H])c([2H])c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

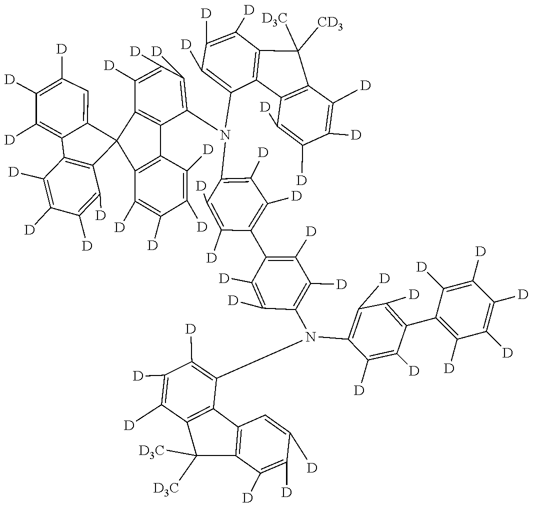 [SMILES: [2H]c1cc2c(c([2H])c1[2H])-c1c([2H])c([2H])c([2H])c([2H])c1C21c2c([2H])c([2H])c([2H])c([2H])c2-c2c(N(c3c([2H])c([2H])c(-c4c([2H])c([2H])c(N(c5c([2H])c([2H])c(-c6c([2H])c([2H])c([2H])c([2H])c6[2H])c([2H])c5[2H])c5c([2H])c([2H])c([2H])c6c5-c5cc([2H])c([2H])c([2H])c5C6(C([2H])([2H])[2H])C([2H])([2H])[2H])c([2H])c4[2H])c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]

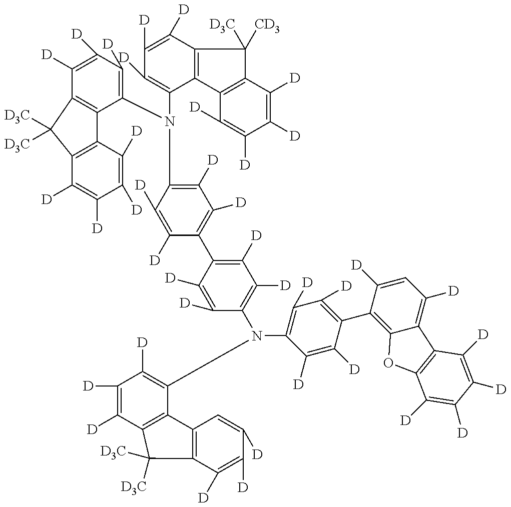 [SMILES: [2H]c1cc2c(c([2H])c1[2H])C(C([2H])([2H])[2H])(C([2H])([2H])[2H])c1c([2H])c([2H])c([2H])c(N(c3c([2H])c([2H])c(-c4c([2H])c([2H])c(N(c5c([2H])c([2H])c([2H])c6c5-c5c([2H])c([2H])c([2H])c([2H])c5C6(C([2H])([2H])[2H])C([2H])([2H])[2H])c5c([2H])c([2H])c([2H])c6c5-c5c([2H])c([2H])c([2H])c([2H])c5C6(C([2H])([2H])[2H])C([2H])([2H])[2H])c([2H])c4[2H])c([2H])c3[2H])c3c([2H])c([2H])c(-c4c([2H])cc([2H])c5c4oc4c([2H])c([2H])c([2H])c([2H])c45)c([2H])c3[2H])c1-2]

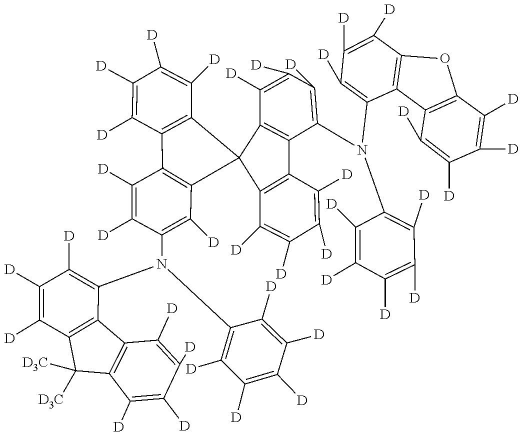 [SMILES: [2H]c1c([2H])c([2H])c(N(c2c([2H])c([2H])c3c(c2[2H])C2(c4c([2H])c([2H])c([2H])c([2H])c4-3)c3c([2H])c([2H])c([2H])c([2H])c3-c3c(N(c4c([2H])c([2H])c([2H])c([2H])c4[2H])c4c([2H])c([2H])c([2H])c5oc6c([2H])c([2H])c([2H])c([2H])c6c45)c([2H])c([2H])c([2H])c32)c2c([2H])c([2H])c([2H])c3c2-c2c([2H])c([2H])c([2H])c([2H])c2C3(C([2H])([2H])[2H])C([2H])([2H])[2H])c([2H])c1[2H]]

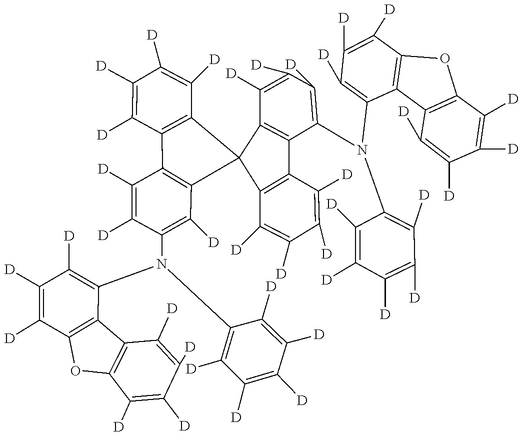 [SMILES: [2H]c1c([2H])c([2H])c(N(c2c([2H])c([2H])c3c(c2[2H])C2(c4c([2H])c([2H])c([2H])c([2H])c4-3)c3c([2H])c([2H])c([2H])c([2H])c3-c3c(N(c4c([2H])c([2H])c([2H])c([2H])c4[2H])c4c([2H])c([2H])c([2H])c5oc6c([2H])c([2H])c([2H])c([2H])c6c45)c([2H])c([2H])c([2H])c32)c2c([2H])c([2H])c([2H])c3oc4c([2H])c([2H])c([2H])c([2H])c4c23)c([2H])c1[2H]]

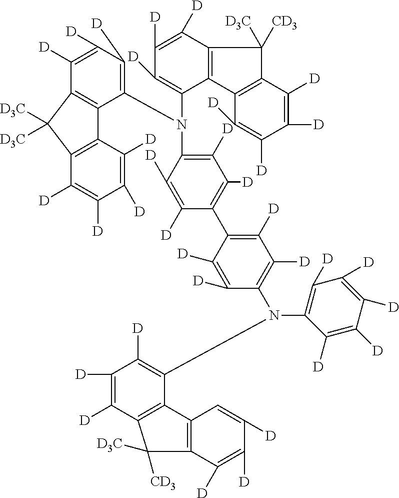 [SMILES: [2H]c1cc2c(c([2H])c1[2H])C(C([2H])([2H])[2H])(C([2H])([2H])[2H])c1c([2H])c([2H])c([2H])c(N(c3c([2H])c([2H])c([2H])c([2H])c3[2H])c3c([2H])c([2H])c(-c4c([2H])c([2H])c(N(c5c([2H])c([2H])c([2H])c6c5-c5c([2H])c([2H])c([2H])c([2H])c5C6(C([2H])([2H])[2H])C([2H])([2H])[2H])c5c([2H])c([2H])c([2H])c6c5-c5c([2H])c([2H])c([2H])c([2H])c5C6(C([2H])([2H])[2H])C([2H])([2H])[2H])c([2H])c4[2H])c([2H])c3[2H])c1-2]

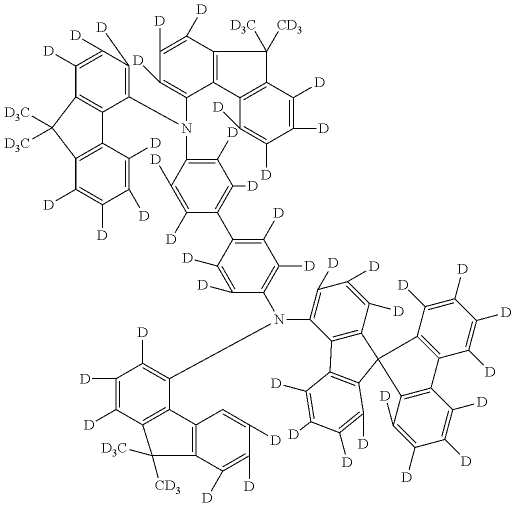 [SMILES: [2H]c1cc2c(c([2H])c1[2H])C(C([2H])([2H])[2H])(C([2H])([2H])[2H])c1c([2H])c([2H])c([2H])c(N(c3c([2H])c([2H])c(-c4c([2H])c([2H])c(N(c5c([2H])c([2H])c([2H])c6c5-c5c([2H])c([2H])c([2H])c([2H])c5C6(C([2H])([2H])[2H])C([2H])([2H])[2H])c5c([2H])c([2H])c([2H])c6c5-c5c([2H])c([2H])c([2H])c([2H])c5C6(C([2H])([2H])[2H])C([2H])([2H])[2H])c([2H])c4[2H])c([2H])c3[2H])c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c1-2]

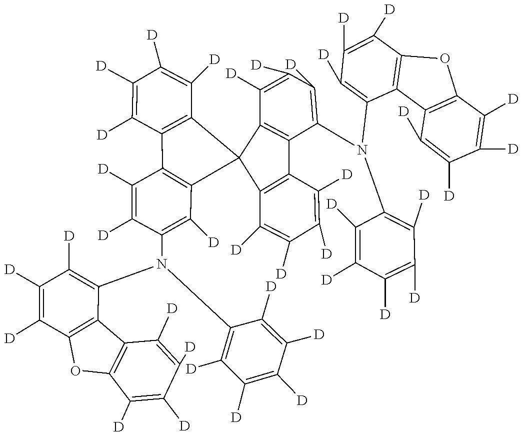 [SMILES: [2H]c1c([2H])c([2H])c(N(c2c([2H])c([2H])c3c(c2[2H])C2(c4c([2H])c([2H])c([2H])c([2H])c4-3)c3c([2H])c([2H])c([2H])c([2H])c3-c3c(N(c4c([2H])c([2H])c([2H])c([2H])c4[2H])c4c([2H])c([2H])c([2H])c5oc6c([2H])c([2H])c([2H])c([2H])c6c45)c([2H])c([2H])c([2H])c32)c2c([2H])c([2H])c([2H])c3oc4c([2H])c([2H])c([2H])c([2H])c4c23)c([2H])c1[2H]]

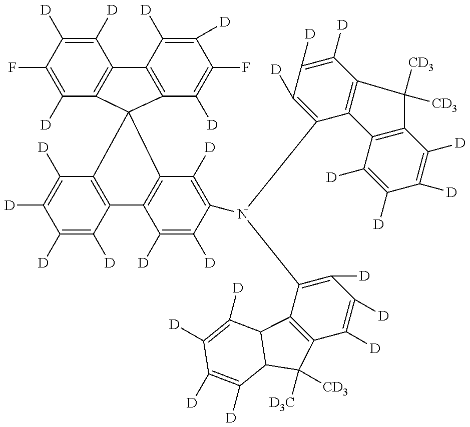 [SMILES: [2H]C1=C([2H])C2c3c(N(c4c([2H])c([2H])c5c(c4[2H])C4(c6c([2H])c([2H])c([2H])c([2H])c6-5)c5c([2H])c(F)c([2H])c([2H])c5-c5c([2H])c([2H])c(F)c([2H])c54)c4c([2H])c([2H])c([2H])c5c4-c4c([2H])c([2H])c([2H])c([2H])c4C5(C([2H])([2H])[2H])C([2H])([2H])[2H])c([2H])c([2H])c([2H])c3C(C([2H])([2H])[2H])(C([2H])([2H])[2H])C2C([2H])=C1[2H]]

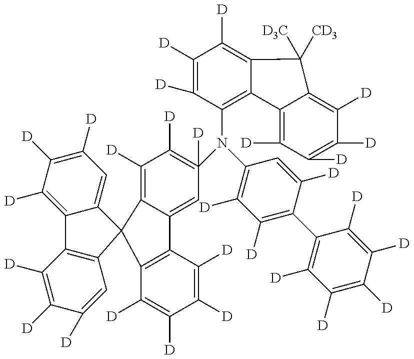

Particularly suitable compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) that are selected in accordance with the invention and are preferably used in combination with at least one compound of the formula (1) in the electroluminescent device of the invention are the compounds H1 to H15 in table 4.

TABLE 4 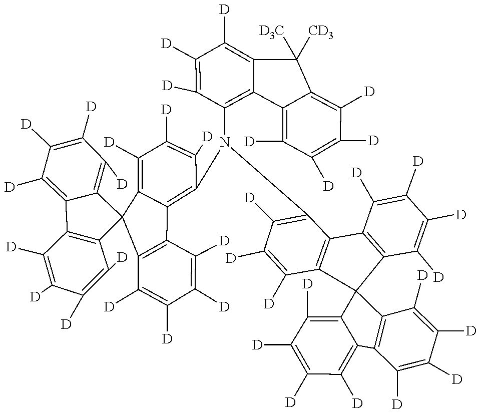 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]
H1 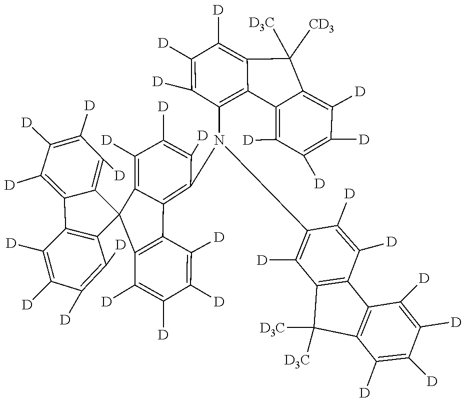 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21]
H2 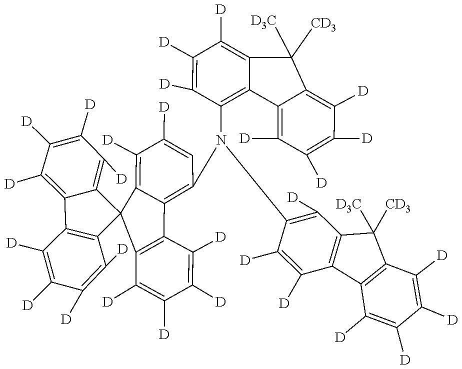 [SMILES: [2H]c1cc(N(c2c([2H])c([2H])c3c(c2[2H])C(C([2H])([2H])[2H])(C([2H])([2H])[2H])c2c([2H])c([2H])c([2H])c([2H])c2-3)c2c([2H])c([2H])c([2H])c3c2-c2c([2H])c([2H])c([2H])c([2H])c2C3(C([2H])([2H])[2H])C([2H])([2H])[2H])c2c(c1[2H])C1(c3c([2H])c([2H])c([2H])c([2H])c3-2)c2c([2H])c([2H])c([2H])c([2H])c2-c2c([2H])c([2H])c([2H])c([2H])c21]
H3 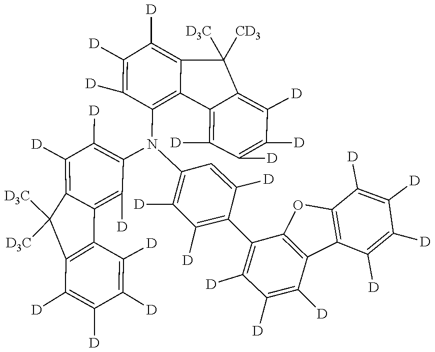 [SMILES: [2H]c1cc(N(c2c([2H])c([2H])c3c(c2[2H])-c2c([2H])c([2H])c([2H])c([2H])c2C3(C([2H])([2H])[2H])C([2H])([2H])[2H])c2c([2H])c([2H])c([2H])c3c2-c2c([2H])c([2H])c([2H])c([2H])c2C3(C([2H])([2H])[2H])C([2H])([2H])[2H])c([2H])c([2H])c1-c1c([2H])c([2H])c([2H])c2c1oc1c([2H])c([2H])c([2H])c([2H])c12]
H4 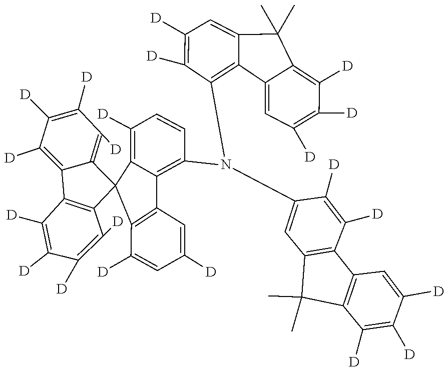 [SMILES: [2H]C([2H])=C([2H])/C([2H])=C1\C(=C)C2(c3c([2H])cc([2H])cc3-c3c(N(c4cc5c(c([2H])c4[2H])-c4cc([2H])c([2H])c([2H])c4C5(C)C)c4c([2H])c([2H])cc5c4-c4cc([2H])c([2H])c([2H])c4C5(C)C)ccc([2H])c32)c2c([2H])c([2H])c([2H])c([2H])c21]
H5 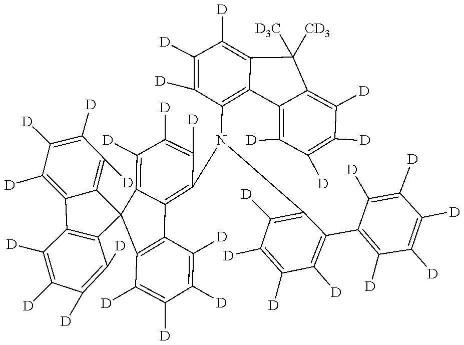 [SMILES: [2H]c1c([2H])c([2H])c(-c2c([2H])c([2H])c([2H])c([2H])c2N(c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c2c([2H])c([2H])c([2H])c3c2-c2c([2H])c([2H])c([2H])c([2H])c2C3(C([2H])([2H])[2H])C([2H])([2H])[2H])c([2H])c1[2H]]
H6 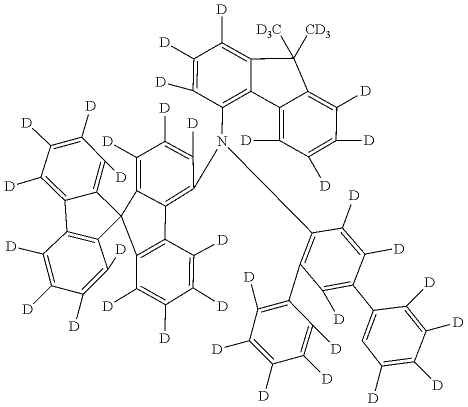 [SMILES: [2H]c1cc(-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c(-c3c([2H])c([2H])c([2H])c([2H])c3[2H])c2[2H])c([2H])c([2H])c1[2H]]
H7 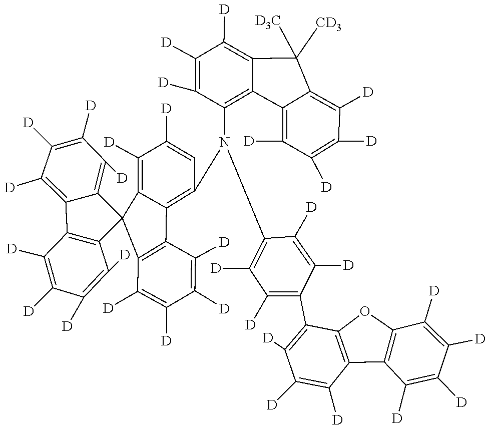 [SMILES: [2H]c1cc(N(c2c([2H])c([2H])c(-c3c([2H])c([2H])c([2H])c4c3oc3c([2H])c([2H])c([2H])c([2H])c34)c([2H])c2[2H])c2c([2H])c([2H])c([2H])c3c2-c2c([2H])c([2H])c([2H])c([2H])c2C3(C([2H])([2H])[2H])C([2H])([2H])[2H])c2c(c1[2H])C1(c3c([2H])c([2H])c([2H])c([2H])c3-2)c2c([2H])c([2H])c([2H])c([2H])c2-c2c([2H])c([2H])c([2H])c([2H])c21]
H8 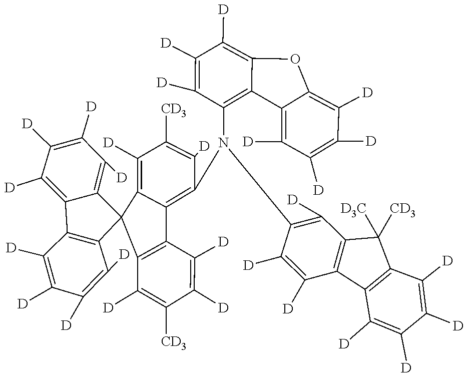 [SMILES: [2H]c1c([2H])c([2H])c2c(c1[2H])-c1c([2H])c([2H])c([2H])c([2H])c1C21c2c([2H])c(C([2H])([2H])[2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4oc5c([2H])c([2H])c([2H])c([2H])c5c34)c([2H])c(C([2H])([2H])[2H])c([2H])c21]
H9 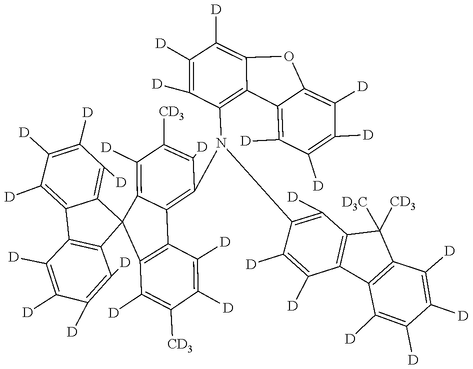 [SMILES: [2H]c1c([2H])c([2H])c2c(c1[2H])-c1c([2H])c([2H])c([2H])c([2H])c1C21c2c([2H])c(C([2H])([2H])[2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4oc5c([2H])c([2H])c([2H])c([2H])c5c34)c([2H])c(C([2H])([2H])[2H])c([2H])c21]
H10 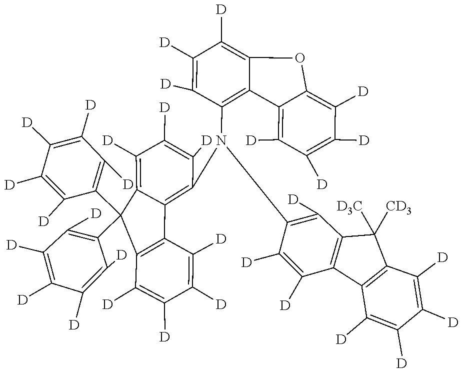 [SMILES: [2H]c1c([2H])c([2H])c(C2(c3c([2H])c([2H])c([2H])c([2H])c3[2H])c3c([2H])c([2H])c([2H])c([2H])c3-c3c(N(c4c([2H])c([2H])c5c(c4[2H])C(C([2H])([2H])[2H])(C([2H])([2H])[2H])c4c([2H])c([2H])c([2H])c([2H])c4-5)c4c([2H])c([2H])c([2H])c5oc6c([2H])c([2H])c([2H])c([2H])c6c45)c([2H])c([2H])c([2H])c32)c([2H])c1[2H]]
H11 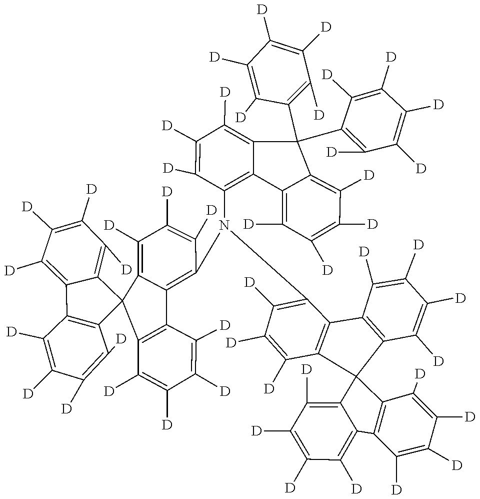 [SMILES: [2H]c1c([2H])c([2H])c(C2(c3c([2H])c([2H])c([2H])c([2H])c3[2H])c3c([2H])c([2H])c([2H])c([2H])c3-c3c(N(c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c4c([2H])c([2H])c([2H])c5c4-c4c([2H])c([2H])c([2H])c([2H])c4C54c5c([2H])c([2H])c([2H])c([2H])c5-c5c([2H])c([2H])c([2H])c([2H])c54)c([2H])c([2H])c([2H])c32)c([2H])c1[2H]]
H12 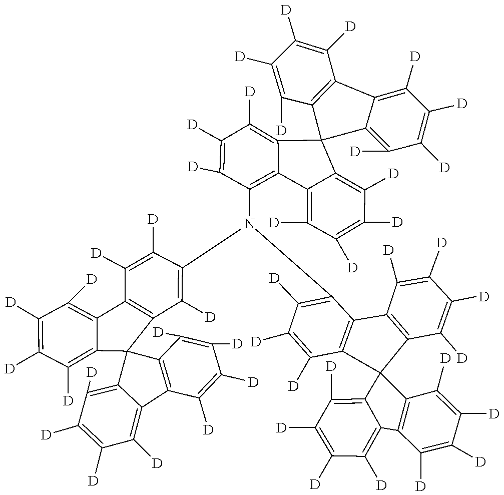 [SMILES: [2H]c1c([2H])c([2H])c2c(c1[2H])-c1c([2H])c([2H])c([2H])c([2H])c1C21c2c([2H])c([2H])c([2H])c([2H])c2-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c([2H])c21]
H13 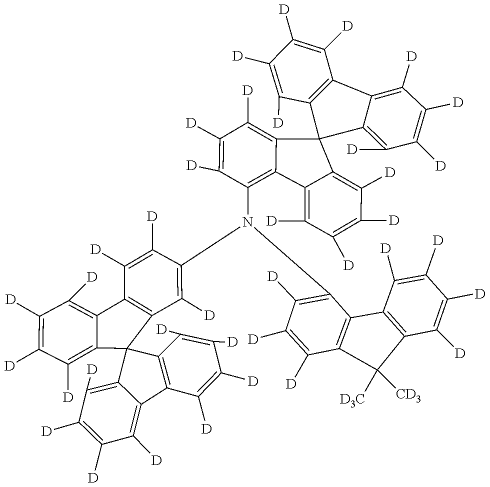 [SMILES: [2H]c1c([2H])c([2H])c2c(c1[2H])-c1c([2H])c([2H])c([2H])c([2H])c1C21c2c([2H])c([2H])c([2H])c([2H])c2-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c21]
H14 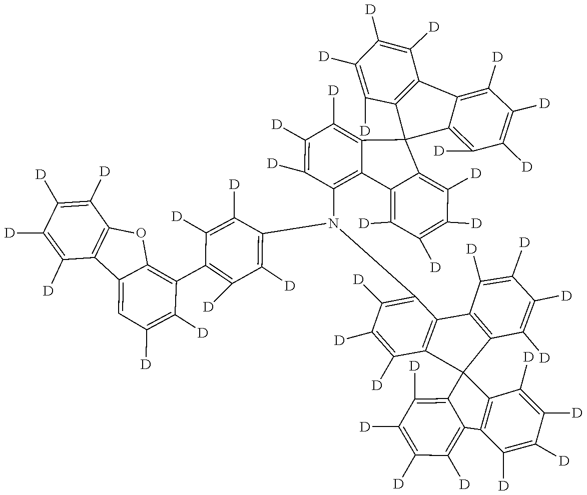 [SMILES: [2H]c1cc2c(oc3c([2H])c([2H])c([2H])c([2H])c32)c(-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c([2H])c2[2H])c1[2H]]
H15.

The preparation of the compounds of the formula (2) or preferred compounds of the formulae (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) and of the compounds from table 3 and compounds H1 to H15 is known to the person skilled in the art. The compounds can be prepared by synthesis steps known to those skilled in the art, for example bromination, Suzuki coupling, addition and cyclization reactions, etc. The partly deuterated or fully deuterated substituents can be introduced successively during the synthesis of the compounds of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9), or, alternatively, the non-deuterated compound can first be prepared and then a deuteration can be conducted, which leads to partly deuterated or fully deuterated compounds. Reaction conditions are sufficiently well known to the person skilled in the art. A suitable synthesis method for preparation of spirobifluorenyl compounds as host material 2 is shown in scheme 4, where the symbols and indices used are chosen representatively for the synthesis of the base skeleton. The person skilled in the art will be able to appropriately adapt this scheme, scheme 4, to the synthesis of the host material 2 as described above.

The synthesis of these host materials 2 in scheme 4 proceeds from biphenyl derivatives having halogen groups in the two ortho positions to the bond between the phenyl groups (X). These can be prepared by Suzuki reaction. The biphenyl derivatives are representatively substituted by at least one organic radical R which can be adjusted in accordance with the description. In a subsequent step, in an addition reaction and subsequent cyclization reaction, they are reacted with a fluorenone derivative to give a spirobifluorene having a halogen atom in the 4 position (Scheme 3). X is a halogen atom, preferably Cl, Br or I, more preferably Cl or Br, and Y is I.

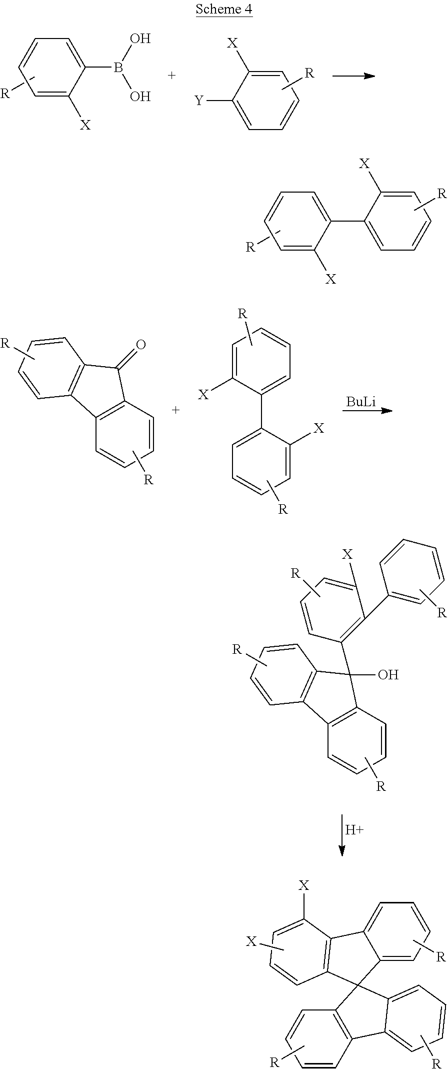

In a subsequent step, the intermediates obtained in scheme 4 can be reacted a) with a secondary amine in a Buchwald coupling, or b) with a triarylamine in a Suzuki coupling, or c) in a two-step process, firstly with an aromatic or heteroaromatic in a Suzuki coupling and then with a secondary amine in a Buchwald coupling.

Suitable reaction conditions for deuterations are specified in schemes 5 to 11 below, in each case with citation of the literature or patent literature in which details are described. The cited literature or patent literature is thus incorporated into the description by reference. Further details of deuteration are described in the examples.

A suitable method of deuterating an arylamine or a heteroarylamine by exchange of one or more hydrogen atoms for deuterium atoms is a treatment of the arylamine or a heteroarylamine to be deuterated in the presence of a platinum catalyst or palladium catalyst and a deuterium source. The term “deuterium source” means any compound that contains one or more deuterium atoms and is able to release them under suitable conditions.

The platinum catalyst is preferably dry platinum on charcoal, preferably 5% dry platinum on charcoal. The palladium catalyst is preferably dry palladium on charcoal, preferably 5% dry palladium on charcoal. A suitable deuterium source is D₂O, benzene-d6, chloroform-d, acetonitrile-d3, acetone-d6, acetic acid-d4, methanol-d4, toluene-d8. A preferred deuterium source is D₂O or a combination of D₂O and a fully deuterated organic solvent. A particularly preferred deuterium source is the combination of D₂O with a fully deuterated organic solvent, where the fully deuterated solvent here is not restricted. Particularly suitable fully deuterated solvents are benzene-d6 and toluene-d8. A particularly preferred deuterium source is a combination of D₂O and toluene-d8. The reaction is preferably conducted with heating, more preferably with heating to temperatures between 100° C. and 200° C. In addition, the reaction is preferably conducted under pressure.

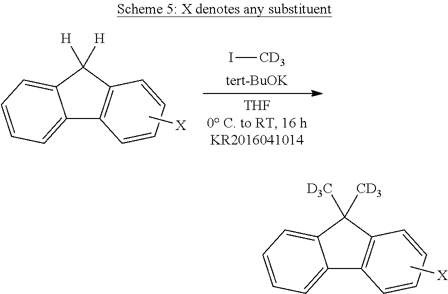

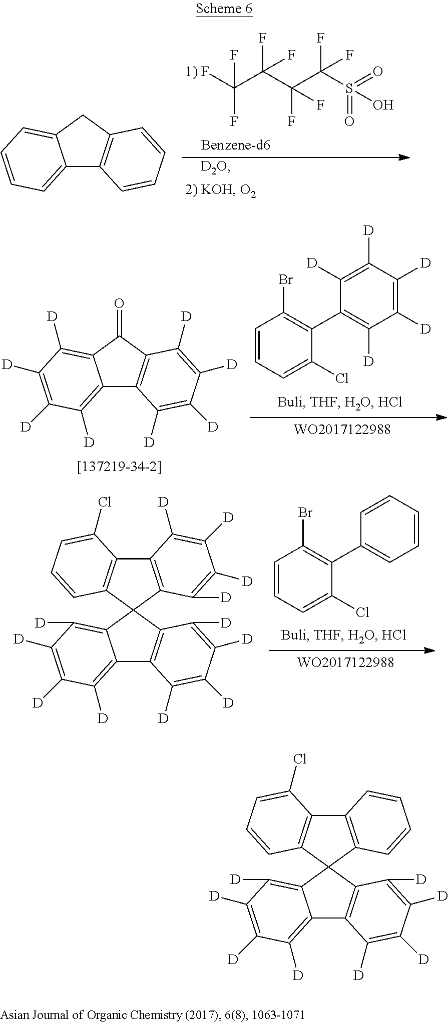

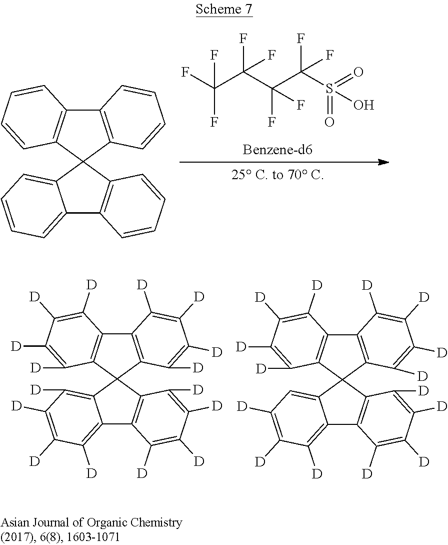

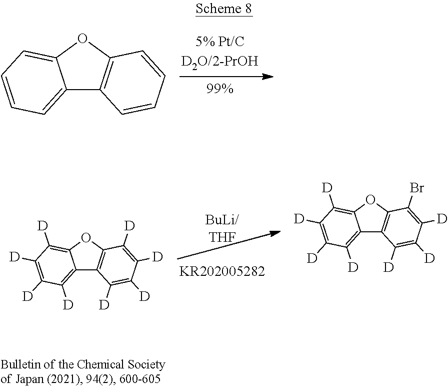

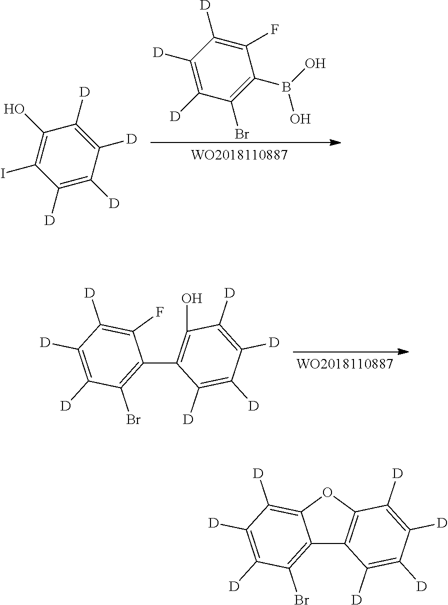 [SMILES: [2H]c1c([2H])c([2H])c(I)c(O)c1[2H] ; [2H]c1c([2H])c(F)c(B(O)O)c(Br)c1[2H] ; [2H]c1c([2H])c([2H])c(-c2c(F)c([2H])c([2H])c([2H])c2Br)c(O)c1[2H] ; [2H]c1c([2H])c([2H])c2c(oc3c([2H])c([2H])c([2H])c(Br)c32)c1[2H]]

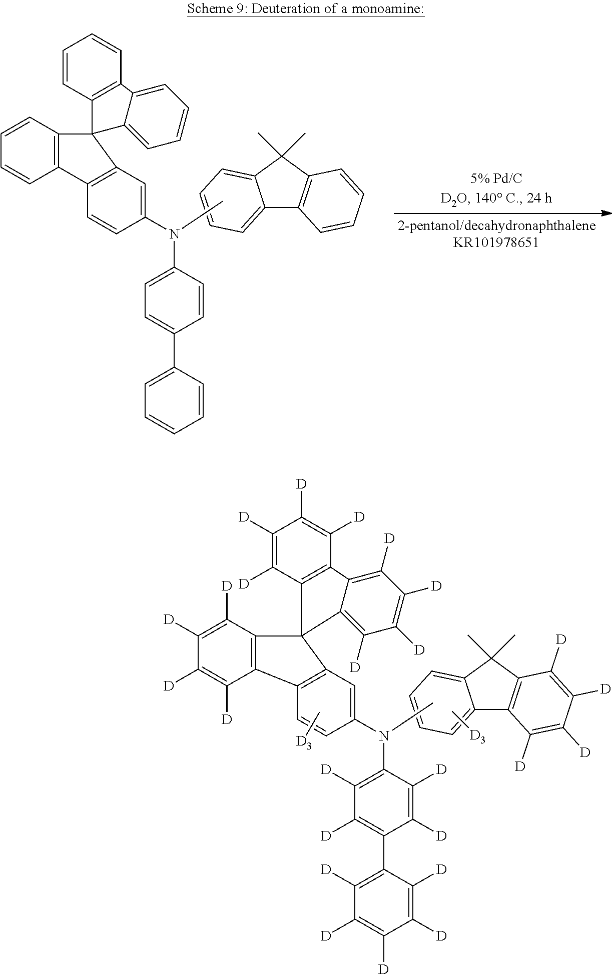

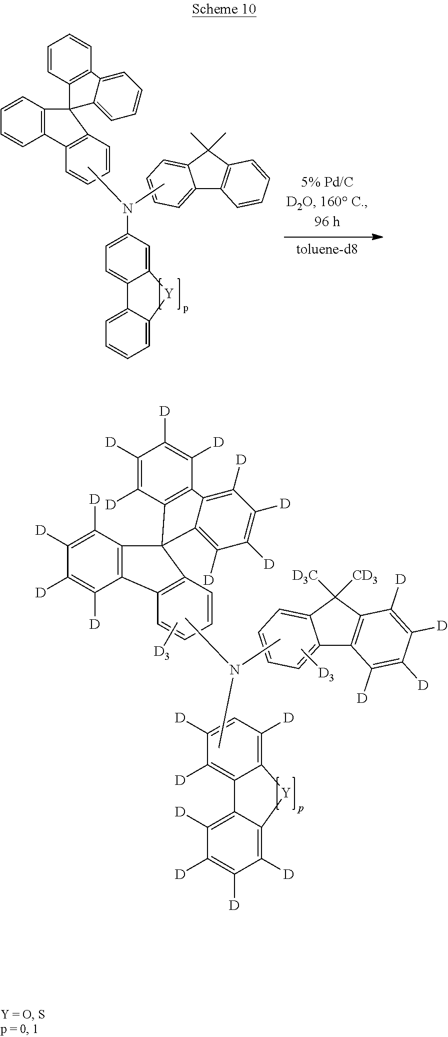

Scheme 11: n and m indicate the degree of deuteration, where at least one D is present per N-bonded substituent

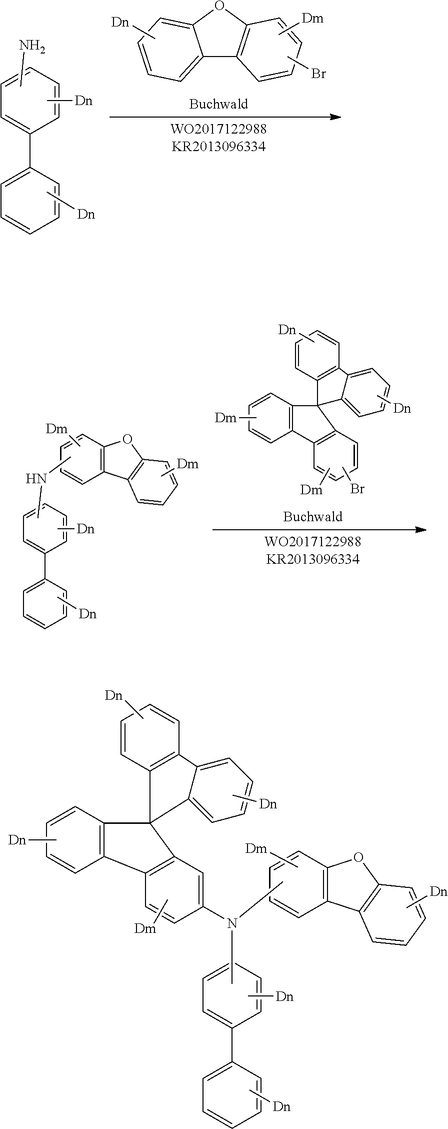

The aforementioned host materials of the formula (1) and the embodiments thereof that are described as preferred or the compounds from table 1 and the compounds E1 to E51 can be combined as desired in the device of the invention with the host materials of the formulae (2), (2a), (2b), (2c), (2d), (2e), (3), (3a), (3b), (3c), (3d), (3e), (3f), (3g), (3h), (3i), (3j), (3k), (3l), (3m), (3n), (3o), (4), (5), (6), (7), (8) and (9) mentioned and the embodiments thereof that are described as preferred or the compounds from table 3 or the compounds H1 to H15.

The invention likewise further provides mixtures comprising at least one compound of the formula (1) as host material 1 and at least one compound of the formula (2) as host material 2:

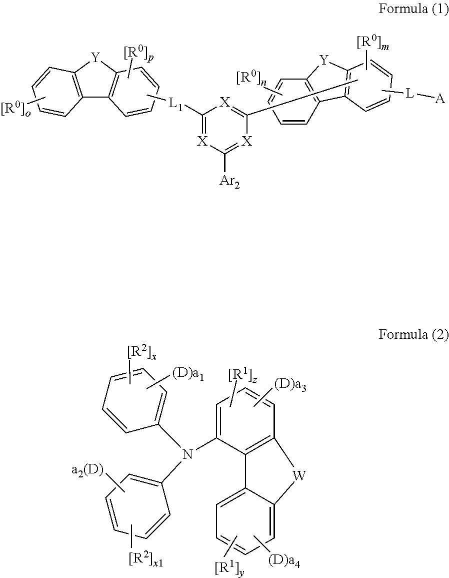

where the symbols and indices used are as follows:
A is

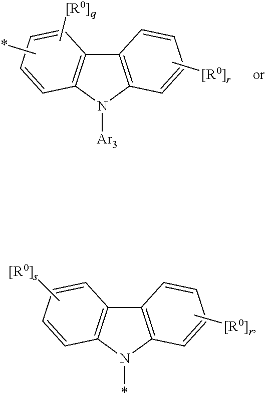

X is the same or different at each instance and is CR⁰ or N, where at least one symbol X is N;
Y is the same or different at each instance and is selected from O and S;
* indicates the binding site to the formula (1);
L and L₁ are the same or different at each instance and are a single bond or an aromatic or heteroaromatic ring system having 5 to 30 aromatic ring atoms;
W is O, S, C(R)₂;
R is in each case independently a straight-chain or branched alkyl group which has 1 to 4 carbon atoms and may be partly or fully deuterated, or an unsubstituted or partly or fully deuterated aromatic ring system having 6 to 18 carbon atoms, where two substituents R together with the carbon atom to which they are bonded may form a mono- or polycyclic, aliphatic or aromatic or heteroaromatic, unsubstituted, partly deuterated or fully deuterated ring system which may be substituted by one or more substituents R³, with the condition that the ring system and substituents bonded thereto do not contain a carbazole group;
R⁰ at each instance is independently D, an unsubstituted or partly or fully deuterated aromatic ring system having 6 to 18 carbon atoms or an unsubstituted or partly or fully deuterated dibenzofuran, dibenzothiophene or C-bonded N-arylcarbazole;
Ar₁ is the same or different at each instance and is an aromatic or heteroaromatic ring system which has 5 to 30 aromatic ring atoms and may be substituted by one or more nonaromatic R³ radicals; at the same time, two Ar₁ radicals bonded to the same nitrogen atom, phosphorus atom or boron atom may also be bridged to one another by a single bond or a bridge selected from C(R³)₂, O and S;
Ar₂ at each instance is independently an aryl or heteroaryl group which has 5 to 40 aromatic ring atoms and may be substituted by one or more R′ radicals;
Ar₃ at each instance is independently an aromatic ring system having 6 to 40 aromatic ring atoms or a heteroaromatic ring system having 5 to 40 aromatic ring atoms, which may be substituted by one or more R′ radicals;
aryl is the same or different at each instance and is an aromatic or heteroaromatic ring system which has 5 to 30 aromatic ring atoms and may be substituted by one or more nonaromatic R radicals;
R′ is the same or different at each instance and is selected from the group consisting of D, F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R′ to form a monocyclic or polycyclic, aliphatic, aromatic or heteroaromatic ring system which may be substituted by one or more R³ radicals;
R¹ is the same or different at each instance and is selected from the group consisting of F, Cl, Br, I, CN, NO₂, C(═O)R′, P(═O)(Ar₁)₂, P(Ar₁)₂, B(Ar₁)₂, Si(Ar₁) 3, Si(R′)₃, a straight-chain alkyl, alkoxy or thioalkyl group having 1 to 20 carbon atoms and a branched or cyclic alkyl, alkoxy or thioalkyl group having 3 to 20 carbon atoms and an alkenyl group having 2 to 20 carbon atoms, each of which may be substituted by one or more R′ radicals, where one or more nonadjacent CH₂ groups may be replaced by R′C═CR′, Si(R′)₂, C═O, C═S, C═NR′, P(═O)(R′), SO, SO₂, NR′, O, S or CONR′ and where one or more hydrogen atoms may be replaced by D, F, Cl, Br, I, CN or NO₂;
R² is the same or different at each instance and is selected from the group consisting of F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R² to form a monocyclic or polycyclic, aliphatic, aromatic or heteroaromatic ring system which may be substituted by one or more R³ radicals, with the condition that R² and substituents bonded thereto do not contain a carbazole group;
R³ is the same or different at each instance and is selected from the group consisting of D, F, CN, an aliphatic hydrocarbyl radical having 1 to 20 carbon atoms, and an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, it is possible for two or more adjacent R³ substituents together to form a mono- or polycyclic, aliphatic ring system;
n, m, p, q are each independently 0, 1, 2 or 3;
o, r, s are each independently 0, 1, 2, 3 or 4;
x, x1 at each instance are independently 0, 1, 2, 3 or 4;
y, z are each independently 0, 1 or 2;
a1, a2 are each independently 1, 2, 3, 4 or 5;
a3 is 0, 1, 2 or 3;
a4 is 0, 1, 2, 3 or 4; and
a1+a2+a3+a4 is 3, 4, 5, 6, 7, 8, 9, 10, 11, 12, 13, 14, 15, 16 or 17.

The details with regard to the host materials of the formulae (1) and (2) and the preferred embodiments thereof are correspondingly also applicable to the mixture of the invention.

Particularly preferred mixtures of the host materials of the formula (1) with the host materials of the formula (2) for the device of the invention are obtained by combination of the compounds E1 to E51 with the compounds from table 3.

Very particularly preferred mixtures of the host materials of the formula (1) with the host materials of the formula (2) for the device of the invention are obtained by combination of the compounds E1 to E51 with the compounds H1 to H15 as shown hereinafter in table 5.

TABLE 5

| | | | | | | | | |
|---|---|---|---|---|---|---|---|---|
| M1 | E1 | H1 | M2 | E2 | H1 | M3 | E3 | H1 |
| M4 | E4 | H1 | M5 | E5 | H1 | M6 | E6 | H1 |
| M7 | E7 | H1 | M8 | E8 | H1 | M9 | E9 | H1 |
| M10 | E10 | H1 | M11 | E11 | H1 | M12 | E12 | H1 |
| M13 | E13 | H1 | M14 | E14 | H1 | M15 | E15 | H1 |
| M16 | E16 | H1 | M17 | E17 | H1 | M18 | E18 | H1 |
| M19 | E19 | H1 | M20 | E20 | H1 | M21 | E21 | H1 |
| M22 | E22 | H1 | M23 | E23 | H1 | M24 | E24 | H1 |
| M25 | E25 | H1 | M26 | E26 | H1 | M27 | E27 | H1 |
| M28 | E28 | H1 | M29 | E29 | H1 | M30 | E30 | H1 |
| M31 | E31 | H1 | M32 | E32 | H1 | M33 | E33 | H1 |
| M34 | E34 | H1 | M35 | E35 | H1 | M36 | E36 | H1 |
| M37 | E37 | H1 | M38 | E38 | H1 | M39 | E39 | H1 |
| M40 | E40 | H1 | M41 | E41 | H1 | M42 | E42 | H1 |
| M43 | E43 | H1 | M44 | E44 | H1 | M45 | E45 | H1 |
| M46 | E46 | H1 | M47 | E47 | H1 | M48 | E48 | H1 |
| M49 | E49 | H1 | M50 | E50 | H1 | M51 | E51 | H1 |
| M52 | E1 | H2 | M53 | E2 | H2 | M54 | E3 | H2 |
| M55 | E4 | H2 | M56 | E5 | H2 | M57 | E6 | H2 |
| M58 | E7 | H2 | M59 | E8 | H2 | M60 | E9 | H2 |
| M61 | E10 | H2 | M62 | E11 | H2 | M63 | E12 | H2 |
| M64 | E13 | H2 | M65 | E14 | H2 | M66 | E15 | H2 |
| M67 | E16 | H2 | M68 | E17 | H2 | M69 | E18 | H2 |
| M70 | E19 | H2 | M71 | E20 | H2 | M72 | E21 | H2 |
| M73 | E22 | H2 | M74 | E23 | H2 | M75 | E24 | H2 |
| M76 | E25 | H2 | M77 | E26 | H2 | M78 | E27 | H2 |
| M79 | E28 | H2 | M80 | E29 | H2 | M81 | E30 | H2 |
| M82 | E31 | H2 | M83 | E32 | H2 | M84 | E33 | H2 |
| M85 | E34 | H2 | M86 | E35 | H2 | M87 | E36 | H2 |
| M88 | E37 | H2 | M89 | E38 | H2 | M90 | E39 | H2 |
| M91 | E40 | H2 | M92 | E41 | H2 | M93 | E42 | H2 |
| M94 | E43 | H2 | M95 | E44 | H2 | M96 | E45 | H2 |
| M97 | E46 | H2 | M98 | E47 | H2 | M99 | E48 | H2 |
| M100 | E49 | H2 | M101 | E50 | H2 | M102 | E51 | H2 |
| M103 | E1 | H3 | M104 | E2 | H3 | M105 | E3 | H3 |
| M106 | E4 | H3 | M107 | E5 | H3 | M108 | E6 | H3 |
| M109 | E7 | H3 | M110 | E8 | H3 | M111 | E9 | H3 |
| M112 | E10 | H3 | M113 | E11 | H3 | M114 | E12 | H3 |
| M115 | E13 | H3 | M116 | E14 | H3 | M117 | E15 | H3 |
| M118 | E16 | H3 | M119 | E17 | H3 | M120 | E18 | H3 |
| M121 | E19 | H3 | M122 | E20 | H3 | M123 | E21 | H3 |
| M124 | E22 | H3 | M125 | E23 | H3 | M126 | E24 | H3 |
| M127 | E25 | H3 | M128 | E26 | H3 | M129 | E27 | H3 |
| M130 | E28 | H3 | M131 | E29 | H3 | M132 | E30 | H3 |
| M133 | E31 | H3 | M134 | E32 | H3 | M135 | E33 | H3 |
| M136 | E34 | H3 | M137 | E35 | H3 | M138 | E36 | H3 |
| M139 | E37 | H3 | M140 | E38 | H3 | M141 | E39 | H3 |
| M142 | E40 | H3 | M143 | E41 | H3 | M144 | E42 | H3 |
| M145 | E43 | H3 | M146 | E44 | H3 | M147 | E45 | H3 |
| M148 | E46 | H3 | M149 | E47 | H3 | M150 | E48 | H3 |
| M151 | E49 | H3 | M152 | E50 | H3 | M153 | E51 | H3 |
| M154 | E1 | H4 | M155 | E2 | H4 | M156 | E3 | H4 |
| M157 | E4 | H4 | M158 | E5 | H4 | M159 | E6 | H4 |
| M160 | E7 | H4 | M161 | E8 | H4 | M162 | E9 | H4 |
| M163 | E10 | H4 | M164 | E11 | H4 | M165 | E12 | H4 |
| M166 | E13 | H4 | M167 | E14 | H4 | M168 | E15 | H4 |
| M169 | E16 | H4 | M170 | E17 | H4 | M171 | E18 | H4 |
| M172 | E19 | H4 | M173 | E20 | H4 | M174 | E21 | H4 |
| M175 | E22 | H4 | M176 | E23 | H4 | M177 | E24 | H4 |
| M178 | E25 | H4 | M179 | E26 | H4 | M180 | E27 | H4 |
| M181 | E28 | H4 | M182 | E29 | H4 | M183 | E30 | H4 |
| M184 | E31 | H4 | M185 | E32 | H4 | M186 | E33 | H4 |
| M187 | E34 | H4 | M188 | E35 | H4 | M189 | E36 | H4 |
| M190 | E37 | H4 | M191 | E38 | H4 | M192 | E39 | H4 |
| M193 | E40 | H4 | M194 | E41 | H4 | M195 | E42 | H4 |
| M196 | E43 | H4 | M197 | E44 | H4 | M198 | E45 | H4 |
| M199 | E46 | H4 | M200 | E47 | H4 | M201 | E48 | H4 |
| M202 | E49 | H4 | M203 | E50 | H4 | M204 | E51 | H4 |
| M205 | E1 | H5 | M206 | E2 | H5 | M207 | E3 | H5 |
| M208 | E4 | H5 | M209 | E5 | H5 | M210 | E6 | H5 |
| M211 | E7 | H5 | M212 | E8 | H5 | M213 | E9 | H5 |
| M214 | E10 | H5 | M215 | E11 | H5 | M216 | E12 | H5 |
| M217 | E13 | H5 | M218 | E14 | H5 | M219 | E15 | H5 |
| M220 | E16 | H5 | M221 | E17 | H5 | M222 | E18 | H5 |
| M223 | E19 | H5 | M224 | E20 | H5 | M225 | E21 | H5 |
| M226 | E22 | H5 | M227 | E23 | H5 | M228 | E24 | H5 |
| M229 | E25 | H5 | M230 | E26 | H5 | M231 | E27 | H5 |
| M232 | E28 | H5 | M233 | E29 | H5 | M234 | E30 | H5 |
| M235 | E31 | H5 | M236 | E32 | H5 | M237 | E33 | H5 |
| M238 | E34 | H5 | M239 | E35 | H5 | M240 | E36 | H5 |
| M241 | E37 | H5 | M242 | E38 | H5 | M243 | E39 | H5 |
| M244 | E40 | H5 | M245 | E41 | H5 | M246 | E42 | H5 |
| M247 | E43 | H5 | M248 | E44 | H5 | M249 | E45 | H5 |
| M250 | E46 | H5 | M251 | E47 | H5 | M252 | E48 | H5 |
| M253 | E49 | H5 | M254 | E50 | H5 | M255 | E51 | H5 |
| M256 | E1 | H6 | M257 | E2 | H6 | M258 | E3 | H6 |
| M259 | E4 | H6 | M260 | E5 | H6 | M261 | E6 | H6 |
| M262 | E7 | H6 | M263 | E8 | H6 | M264 | E9 | H6 |
| M265 | E10 | H6 | M266 | E11 | H6 | M267 | E12 | H6 |
| M268 | E13 | H6 | M269 | E14 | H6 | M270 | E15 | H6 |
| M271 | E16 | H6 | M272 | E17 | H6 | M273 | E18 | H6 |
| M274 | E19 | H6 | M275 | E20 | H6 | M276 | E21 | H6 |
| M277 | E22 | H6 | M278 | E23 | H6 | M279 | E24 | H6 |
| M280 | E25 | H6 | M281 | E26 | H6 | M282 | E27 | H6 |
| M283 | E28 | H6 | M284 | E29 | H6 | M285 | E30 | H6 |
| M286 | E31 | H6 | M287 | E32 | H6 | M288 | E33 | H6 |
| M289 | E34 | H6 | M290 | E35 | H6 | M291 | E36 | H6 |
| M292 | E37 | H6 | M293 | E38 | H6 | M294 | E39 | H6 |
| M295 | E40 | H6 | M296 | E41 | H6 | M297 | E42 | H6 |
| M298 | E43 | H6 | M299 | E44 | H6 | M300 | E45 | H6 |
| M301 | E46 | H6 | M302 | E47 | H6 | M303 | E48 | H6 |
| M304 | E49 | H6 | M305 | E50 | H6 | M306 | E51 | H6 |
| M307 | E1 | H7 | M308 | E2 | H7 | M309 | E3 | H7 |
| M310 | E4 | H7 | M311 | E5 | H7 | M312 | E6 | H7 |
| M313 | E7 | H7 | M314 | E8 | H7 | M315 | E9 | H7 |
| M316 | E10 | H7 | M317 | E11 | H7 | M318 | E12 | H7 |
| M319 | E13 | H7 | M320 | E14 | H7 | M321 | E15 | H7 |
| M322 | E16 | H7 | M323 | E17 | H7 | M324 | E18 | H7 |
| M325 | E19 | H7 | M326 | E20 | H7 | M327 | E21 | H7 |
| M328 | E22 | H7 | M329 | E23 | H7 | M330 | E24 | H7 |
| M331 | E25 | H7 | M332 | E26 | H7 | M333 | E27 | H7 |
| M334 | E28 | H7 | M335 | E29 | H7 | M336 | E30 | H7 |
| M337 | E31 | H7 | M338 | E32 | H7 | M339 | E33 | H7 |
| M340 | E34 | H7 | M341 | E35 | H7 | M342 | E36 | H7 |
| M343 | E37 | H7 | M344 | E38 | H7 | M345 | E39 | H7 |
| M346 | E40 | H7 | M347 | E41 | H7 | M348 | E42 | H7 |
| M349 | E43 | H7 | M350 | E44 | H7 | M351 | E45 | H7 |
| M352 | E46 | H7 | M353 | E47 | H7 | M354 | E48 | H7 |
| M355 | E49 | H7 | M356 | E50 | H7 | M357 | E51 | H7 |
| M358 | E1 | H8 | M359 | E2 | H8 | M360 | E3 | H8 |
| M361 | E4 | H8 | M362 | E5 | H8 | M363 | E6 | H8 |
| M364 | E7 | H8 | M365 | E8 | H8 | M366 | E9 | H8 |
| M367 | E10 | H8 | M368 | E11 | H8 | M369 | E12 | H8 |
| M370 | E13 | H8 | M371 | E14 | H8 | M372 | E15 | H8 |
| M373 | E16 | H8 | M374 | E17 | H8 | M375 | E18 | H8 |
| M376 | E19 | H8 | M377 | E20 | H8 | M378 | E21 | H8 |
| M379 | E22 | H8 | M380 | E23 | H8 | M381 | E24 | H8 |
| M382 | E25 | H8 | M383 | E26 | H8 | M384 | E27 | H8 |
| M385 | E28 | H8 | M386 | E29 | H8 | M387 | E30 | H8 |
| M388 | E31 | H8 | M389 | E32 | H8 | M390 | E33 | H8 |
| M391 | E34 | H8 | M392 | E35 | H8 | M393 | E36 | H8 |
| M394 | E37 | H8 | M395 | E38 | H8 | M396 | E39 | H8 |
| M397 | E40 | H8 | M398 | E41 | H8 | M399 | E42 | H8 |
| M400 | E43 | H8 | M401 | E44 | H8 | M402 | E45 | H8 |
| M403 | E46 | H8 | M404 | E47 | H8 | M405 | E48 | H8 |
| M406 | E49 | H8 | M407 | E50 | H8 | M408 | E51 | H8 |
| M409 | E1 | H9 | M410 | E2 | H9 | M411 | E3 | H9 |
| M412 | E4 | H9 | M413 | E5 | H9 | M414 | E6 | H9 |
| M415 | E7 | H9 | M416 | E8 | H9 | M417 | E9 | H9 |
| M418 | E10 | H9 | M419 | E11 | H9 | M420 | E12 | H9 |
| M421 | E13 | H9 | M422 | E14 | H9 | M423 | E15 | H9 |
| M424 | E16 | H9 | M425 | E17 | H9 | M426 | E18 | H9 |
| M427 | E19 | H9 | M428 | E20 | H9 | M429 | E21 | H9 |
| M430 | E22 | H9 | M431 | E23 | H9 | M432 | E24 | H9 |
| M433 | E25 | H9 | M434 | E26 | H9 | M435 | E27 | H9 |
| M436 | E28 | H9 | M437 | E29 | H9 | M438 | E30 | H9 |
| M439 | E31 | H9 | M440 | E32 | H9 | M441 | E33 | H9 |
| M442 | E34 | H9 | M443 | E35 | H9 | M444 | E36 | H9 |
| M445 | E37 | H9 | M446 | E38 | H9 | M447 | E39 | H9 |
| M448 | E40 | H9 | M449 | E41 | H9 | M450 | E42 | H9 |
| M451 | E43 | H9 | M452 | E44 | H9 | M453 | E45 | H9 |
| M454 | E46 | H9 | M455 | E47 | H9 | M456 | E48 | H9 |
| M457 | E49 | H9 | M458 | E50 | H9 | M459 | E51 | H9 |
| M460 | E1 | H10 | M461 | E2 | H10 | M462 | E3 | H10 |
| M463 | E4 | H10 | M464 | E5 | H10 | M465 | E6 | H10 |
| M466 | E7 | H10 | M467 | E8 | H10 | M468 | E9 | H10 |
| M469 | E10 | H10 | M470 | E11 | H10 | M471 | E12 | H10 |
| M472 | E13 | H10 | M473 | E14 | H10 | M474 | E15 | H10 |
| M475 | E16 | H10 | M476 | E17 | H10 | M477 | E18 | H10 |
| M478 | E19 | H10 | M479 | E20 | H10 | M480 | E21 | H10 |
| M481 | E22 | H10 | M482 | E23 | H10 | M483 | E24 | H10 |
| M484 | E25 | H10 | M485 | E26 | H10 | M486 | E27 | H10 |
| M487 | E28 | H10 | M488 | E29 | H10 | M489 | E30 | H10 |
| M490 | E31 | H10 | M491 | E32 | H10 | M492 | E33 | H10 |
| M493 | E34 | H10 | M494 | E35 | H10 | M495 | E36 | H10 |
| M496 | E37 | H10 | M497 | E38 | H10 | M498 | E39 | H10 |
| M499 | E40 | H10 | M500 | E41 | H10 | M501 | E42 | H10 |
| M502 | E43 | H10 | M503 | E44 | H10 | M504 | E45 | H10 |
| M505 | E46 | H10 | M506 | E47 | H10 | M507 | E48 | H10 |
| M508 | E49 | H10 | M509 | E50 | H10 | M510 | E51 | H10 |
| M511 | E1 | H11 | M512 | E2 | H11 | M513 | E3 | H11 |
| M514 | E4 | H11 | M515 | E5 | H11 | M516 | E6 | H11 |
| M517 | E7 | H11 | M518 | E8 | H11 | M519 | E9 | H11 |
| M520 | E10 | H11 | M521 | E11 | H11 | M522 | E12 | H11 |
| M523 | E13 | H11 | M524 | E14 | H11 | M525 | E15 | H11 |
| M526 | E16 | H11 | M527 | E17 | H11 | M528 | E18 | H11 |
| M529 | E19 | H11 | M530 | E20 | H11 | M531 | E21 | H11 |
| M532 | E22 | H11 | M533 | E23 | H11 | M534 | E24 | H11 |
| M535 | E25 | H11 | M536 | E26 | H11 | M537 | E27 | H11 |
| M538 | E28 | H11 | M539 | E29 | H11 | M540 | E30 | H11 |
| M541 | E31 | H11 | M542 | E32 | H11 | M543 | E33 | H11 |
| M544 | E34 | H11 | M545 | E35 | H11 | M546 | E36 | H11 |
| M547 | E37 | H11 | M548 | E38 | H11 | M549 | E39 | H11 |
| M550 | E40 | H11 | M551 | E41 | H11 | M552 | E42 | H11 |
| M553 | E43 | H11 | M554 | E44 | H11 | M555 | E45 | H11 |
| M556 | E46 | H11 | M557 | E47 | H11 | M558 | E48 | H11 |
| M559 | E49 | H11 | M560 | E50 | H11 | M561 | E51 | H11 |
| M562 | E1 | H12 | M563 | E2 | H12 | M564 | E3 | H12 |
| M565 | E4 | H12 | M566 | E5 | H12 | M567 | E6 | H12 |
| M568 | E7 | H12 | M569 | E8 | H12 | M570 | E9 | H12 |
| M571 | E10 | H12 | M572 | E11 | H12 | M573 | E12 | H12 |
| M574 | E13 | H12 | M575 | E14 | H12 | M576 | E15 | H12 |
| M577 | E16 | H12 | M578 | E17 | H12 | M579 | E18 | H12 |
| M580 | E19 | H12 | M581 | E20 | H12 | M582 | E21 | H12 |
| M583 | E22 | H12 | M584 | E23 | H12 | M585 | E24 | H12 |
| M586 | E25 | H12 | M587 | E26 | H12 | M588 | E27 | H12 |
| M589 | E28 | H12 | M590 | E29 | H12 | M591 | E30 | H12 |
| M592 | E31 | H12 | M593 | E32 | H12 | M594 | E33 | H12 |
| M595 | E34 | H12 | M596 | E35 | H12 | M597 | E36 | H12 |
| M598 | E37 | H12 | M599 | E38 | H12 | M600 | E39 | H12 |
| M601 | E40 | H12 | M602 | E41 | H12 | M603 | E42 | H12 |
| M604 | E43 | H12 | M605 | E44 | H12 | M606 | E45 | H12 |
| M607 | E46 | H12 | M608 | E47 | H12 | M609 | E48 | H12 |
| M610 | E49 | H12 | M611 | E50 | H12 | M612 | E51 | H12 |
| M613 | E1 | H13 | M614 | E2 | H13 | M615 | E3 | H13 |
| M616 | E4 | H13 | M617 | E5 | H13 | M618 | E6 | H13 |
| M619 | E7 | H13 | M620 | E8 | H13 | M621 | E9 | H13 |
| M622 | E10 | H13 | M623 | E11 | H13 | M624 | E12 | H13 |
| M625 | E13 | H13 | M626 | E14 | H13 | M627 | E15 | H13 |
| M628 | E16 | H13 | M629 | E17 | H13 | M630 | E18 | H13 |
| M631 | E19 | H13 | M632 | E20 | H13 | M633 | E21 | H13 |
| M634 | E22 | H13 | M635 | E23 | H13 | M636 | E24 | H13 |
| M637 | E25 | H13 | M638 | E26 | H13 | M639 | E27 | H13 |
| M640 | E28 | H13 | M641 | E29 | H13 | M642 | E30 | H13 |
| M643 | E31 | H13 | M644 | E32 | H13 | M645 | E33 | H13 |
| M646 | E34 | H13 | M647 | E35 | H13 | M648 | E36 | H13 |
| M649 | E37 | H13 | M650 | E38 | H13 | M651 | E39 | H13 |
| M652 | E40 | H13 | M653 | E41 | H13 | M654 | E42 | H13 |
| M655 | E43 | H13 | M656 | E44 | H13 | M657 | E45 | H13 |
| M658 | E46 | H13 | M659 | E47 | H13 | M660 | E48 | H13 |
| M661 | E49 | H13 | M662 | E50 | H13 | M663 | E51 | H13 |
| M664 | E1 | H14 | M665 | E2 | H14 | M666 | E3 | H14 |
| M667 | E4 | H14 | M668 | E5 | H14 | M669 | E6 | H14 |
| M670 | E7 | H14 | M671 | E8 | H14 | M672 | E9 | H14 |
| M673 | E10 | H14 | M674 | E11 | H14 | M675 | E12 | H14 |
| M676 | E13 | H14 | M677 | E14 | H14 | M678 | E15 | H14 |
| M679 | E16 | H14 | M680 | E17 | H14 | M681 | E18 | H14 |
| M682 | E19 | H14 | M683 | E20 | H14 | M684 | E21 | H14 |
| M685 | E22 | H14 | M686 | E23 | H14 | M687 | E24 | H14 |
| M688 | E25 | H14 | M689 | E26 | H14 | M690 | E27 | H14 |
| M691 | E28 | H14 | M692 | E29 | H14 | M693 | E30 | H14 |
| M694 | E31 | H14 | M695 | E32 | H14 | M696 | E33 | H14 |
| M697 | E34 | H14 | M698 | E35 | H14 | M699 | E36 | H14 |
| M700 | E37 | H14 | M701 | E38 | H14 | M702 | E39 | H14 |
| M703 | E40 | H14 | M704 | E41 | H14 | M705 | E42 | H14 |
| M706 | E43 | H14 | M707 | E44 | H14 | M708 | E45 | H14 |
| M709 | E46 | H14 | M710 | E47 | H14 | M711 | E48 | H14 |
| M712 | E49 | H14 | M713 | E50 | H14 | M714 | E51 | H14 |
| M715 | E1 | H15 | M716 | E2 | H15 | M717 | E3 | H15 |
| M718 | E4 | H15 | M719 | E5 | H15 | M720 | E6 | H15 |
| M721 | E7 | H15 | M722 | E8 | H15 | M723 | E9 | H15 |
| M724 | E10 | H15 | M725 | E11 | H15 | M726 | E12 | H15 |
| M727 | E13 | H15 | M728 | E14 | H15 | M729 | E15 | H15 |
| M730 | E16 | H15 | M731 | E17 | H15 | M732 | E18 | H15 |
| M733 | E19 | H15 | M734 | E20 | H15 | M735 | E21 | H15 |
| M736 | E22 | H15 | M737 | E23 | H15 | M738 | E24 | H15 |
| M739 | E25 | H15 | M740 | E26 | H15 | M741 | E27 | H15 |
| M742 | E28 | H15 | M743 | E29 | H15 | M744 | E30 | H15 |
| M745 | E31 | H15 | M746 | E32 | H15 | M747 | E33 | H15 |
| M748 | E34 | H15 | M749 | E35 | H15 | M750 | E36 | H15 |
| M751 | E37 | H15 | M752 | E38 | H15 | M753 | E39 | H15 |
| M754 | E40 | H15 | M755 | E41 | H15 | M756 | E42 | H15 |
| M757 | E43 | H15 | M758 | E44 | H15 | M759 | E45 | H15 |
| M760 | E46 | H15 | M761 | E47 | H15 | M762 | E48 | H15 |
| M763 | E49 | H15 | M764 | E50 | H15 | M765 | E51 | H15 |

The concentration of the electron-transporting host material of the formula (1) as described above or described as preferred in the mixture of the invention or in the light-emitting layer of the device of the invention is in the range from 5% by weight to 90% by weight, preferably in the range from 10% by weight to 85% by weight, more preferably in the range from 20% by weight to 85% by weight, even more preferably in the range from 30% by weight to 80% by weight, very especially preferably in the range from 20% by weight to 60% by weight and most preferably in the range from 30% by weight to 50% by weight, based on the overall mixture or based on the overall composition of the light-emitting layer.

The concentration of the hole-transporting host material of the formula (2) as described above or described as preferred in the mixture of the invention or in the light-emitting layer of the device of the invention is in the range from 10% by weight to 95% by weight, preferably in the range from 15% by weight to 90% by weight, more preferably in the range from 15% by weight to 80% by weight, even more preferably in the range from 20% by weight to 70% by weight, very especially preferably in the range from 40% by weight to 80% by weight and most preferably in the range from 50% by weight to 70% by weight, based on the overall mixture or based on the overall composition of the light-emitting layer.

The present invention also relates to a mixture which, as well as the aforementioned host materials 1 and 2 as described above or described as preferred, especially mixtures M1 to M765, also contains at least one phosphorescent emitter.

The present invention also relates to an organic electroluminescent device as described above or described as preferred, wherein the light-emitting layer, as well as the aforementioned host materials 1 and 2 as described above or described as preferred, especially the material combinations M1 to M765, also comprises at least one phosphorescent emitter.

The term “phosphorescent emitters” typically encompasses compounds where the light is emitted through a spin-forbidden transition from an excited state having higher spin multiplicity, i.e. a spin state>1, for example through a transition from a triplet state or a state having an even higher spin quantum number, for example a quintet state. This is preferably understood to mean a transition from a triplet state.

Suitable phosphorescent emitters (=triplet emitters) are especially compounds which, when suitably excited, emit light, preferably in the visible region, and also contain at least one atom of atomic number greater than 20, preferably greater than 38 and less than 84, more preferably greater than 56 and less than 80, especially a metal having this atomic number. Preferred phosphorescence emitters used are compounds containing copper, molybdenum, tungsten, rhenium, ruthenium, osmium, rhodium, iridium, palladium, platinum, silver, gold or europium, especially compounds containing iridium or platinum. In the context of the present invention, all luminescent compounds containing the abovementioned metals are regarded as phosphorescent emitters.

In general, all phosphorescent complexes as used for phosphorescent OLEDs according to the prior art and as known to those skilled in the art in the field of organic electroluminescent devices are suitable.

Preferred phosphorescent emitters according to the present invention conform to the formula (IIIa)

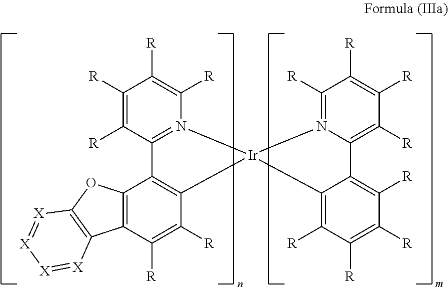

where the symbols and indices for this formula (IIIa) are defined as follows:
n+m is 3, n is 1 or 2, m is 2 or 1,
X is N or CR,
R is H, D, or a branched or linear alkyl group having 1 to 10 carbon atoms or a partly or fully deuterated branched or linear alkyl group having 1 to 10 carbon atoms or a cycloalkyl group which has 4 to 7 carbon atoms and may be partly or fully substituted by deuterium.

The invention accordingly further provides an organic electroluminescent device as described above or described as preferred, characterized in that the light-emitting layer, as well as the host materials 1 and 2, comprises at least one phosphorescent emitter conforming to the formula (IIIa) as described above.

In emitters of the formula (IIIa), n is preferably 1 and m is preferably 2.

In emitters of the formula (IIIa), preferably one X is selected from N and the other X are CR.

In emitters of the formula (IIIa), at least one R is preferably different from H. In emitters of the formula (IIIa), preferably two R are different from H and have one of the other definitions given above for the emitters of the formula (IIIa).

Preferred phosphorescent emitters according to the present invention conform to the formulae (I), (II), (III), (IV) or (V)

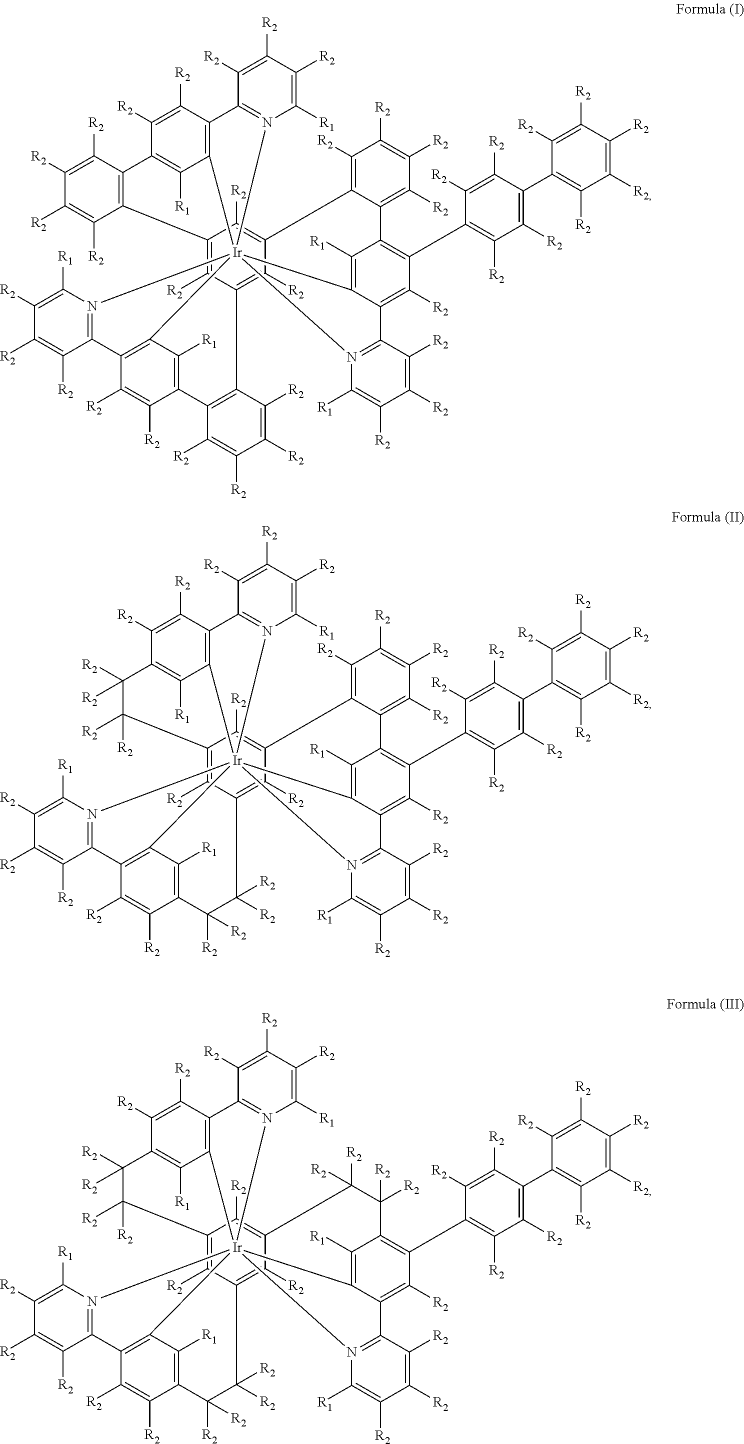

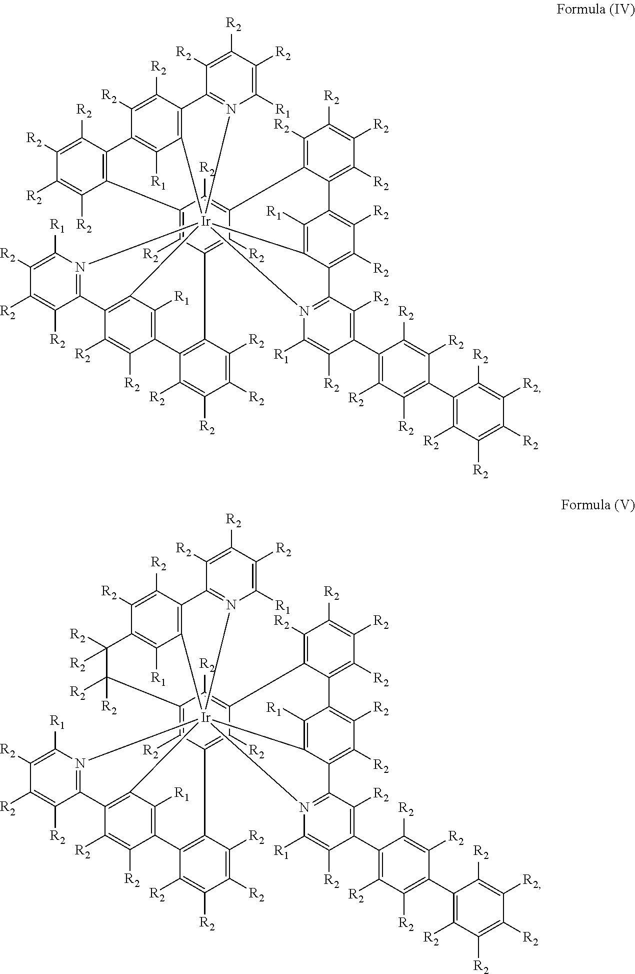

where the symbols and indices for these formulae (I), (II), (III), (IV) and (V) are defined as follows:
R₁ is H or D, R₂ is H, D, or a branched or linear alkyl group having 1 to 10 carbon atoms or a partly or fully deuterated branched or linear alkyl group having 1 to 10 carbon atoms or a cycloalkyl group which has 4 to 10 carbon atoms and may be partly or fully substituted by deuterium.

Preferred phosphorescent emitters according to the present invention conform to the formulae (VI), (VII) or (VIII)

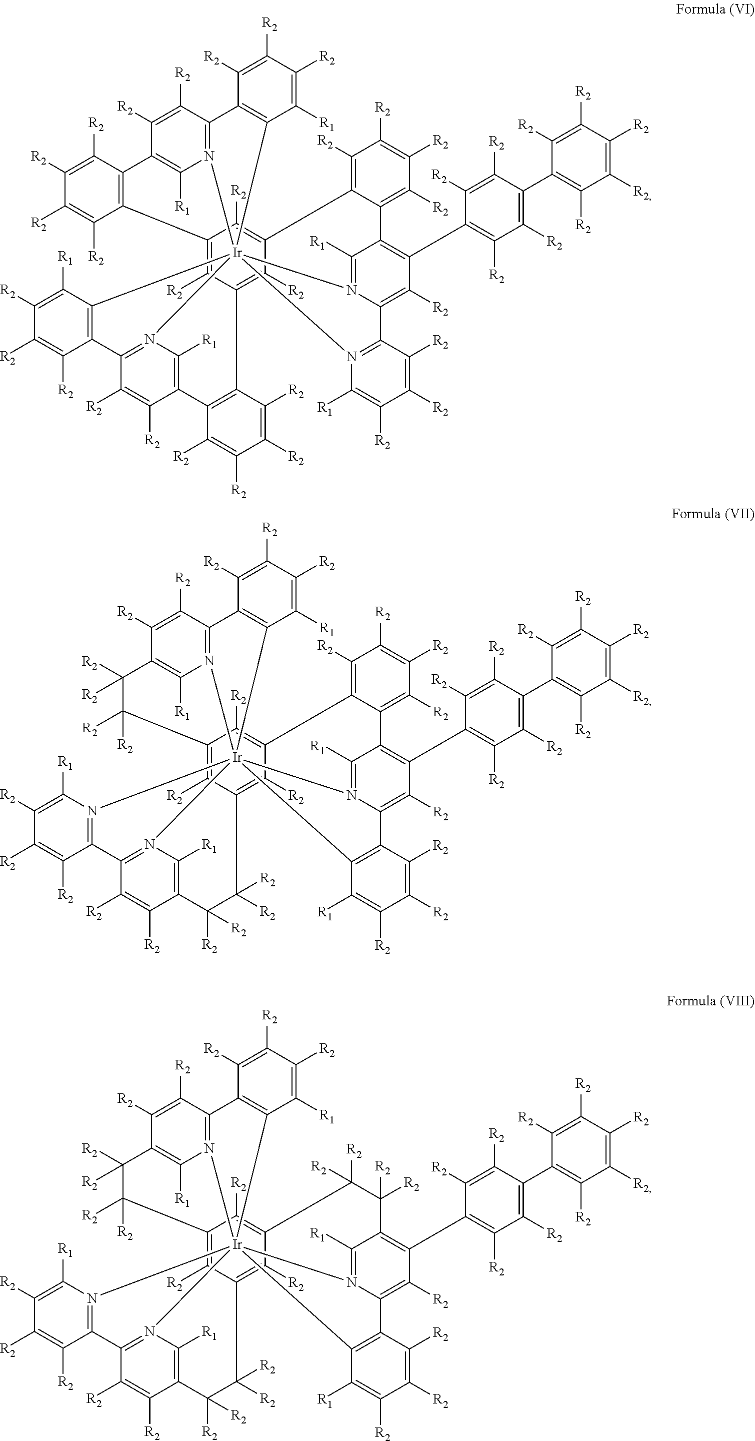

where the symbols and indices for these formulae (VI), (VII) and (VIII) are defined as follows:

R₁ is H or D, R₂ is H, D, F or a branched or linear alkyl group having 1 to 10 carbon atoms or a partly or fully deuterated branched or linear alkyl group having 1 to 10 carbon atoms or a cycloalkyl group which has 4 to 10 carbon atoms and may be partly or fully substituted by deuterium.

Preferred examples of phosphorescent emitters are described in WO2019007867 on pages 120 to 126 in table 5, and on pages 127 to 129 in table 6. The emitters are incorporated into description by this reference.

Particularly preferred examples of phosphorescent emitters are listed in table 6 below.

TABLE 6

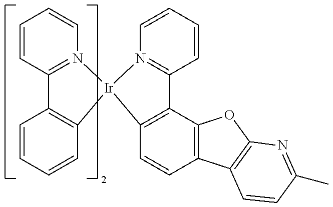

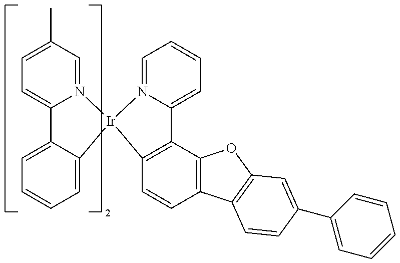

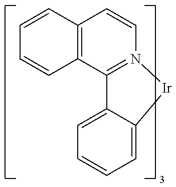

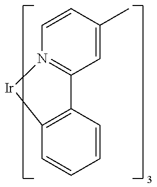

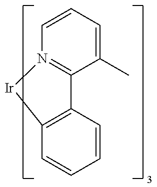

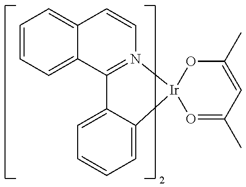

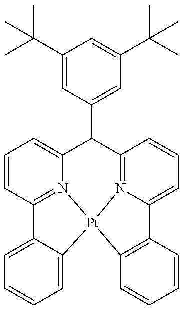

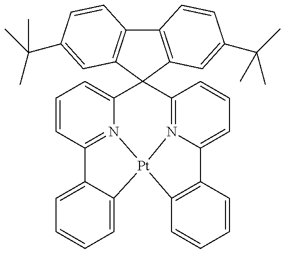

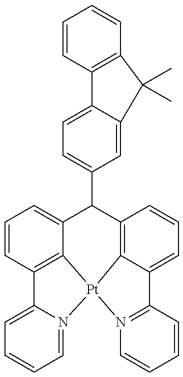

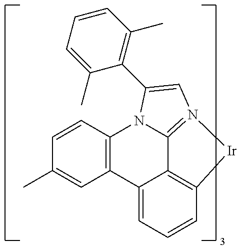

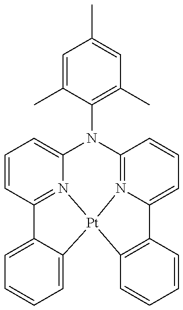

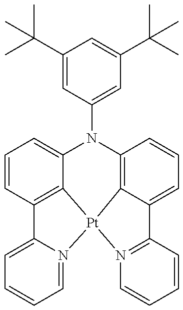

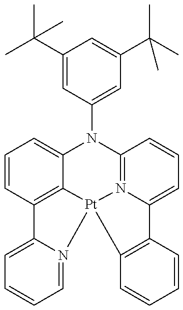

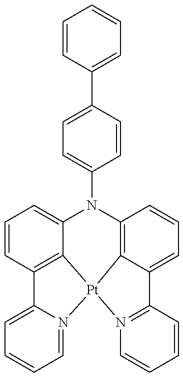

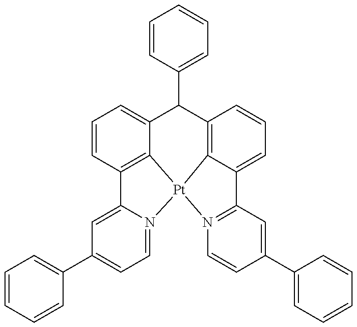

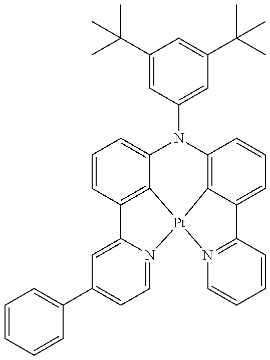

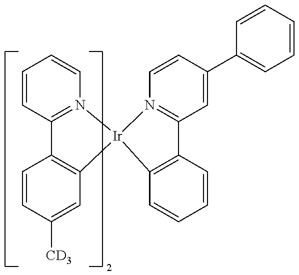

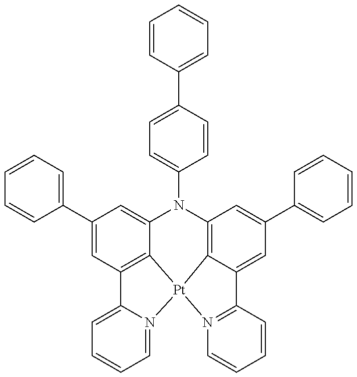

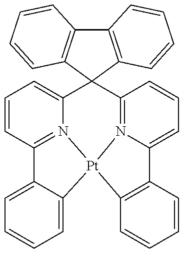

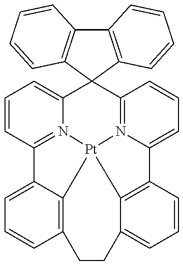

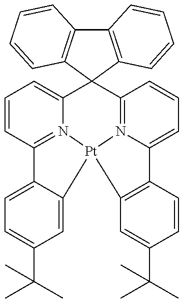

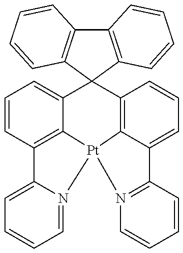

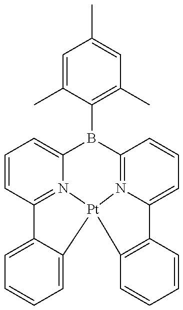

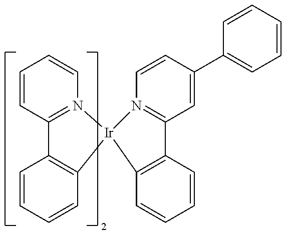

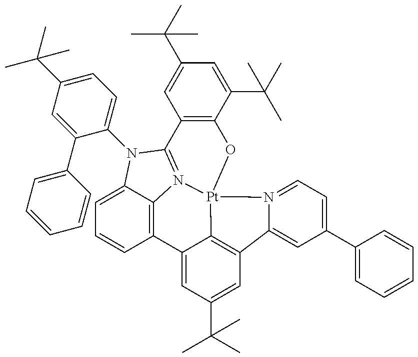

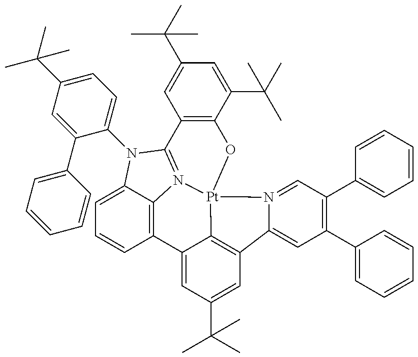

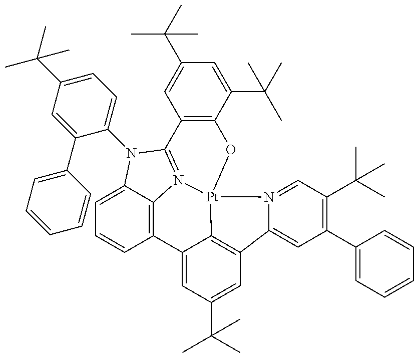

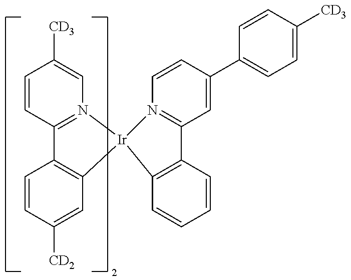

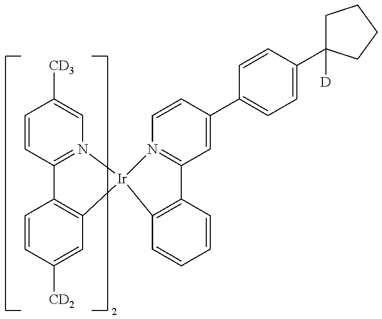

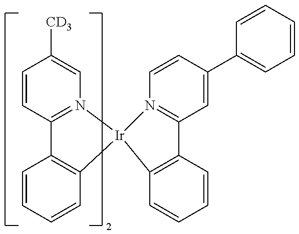

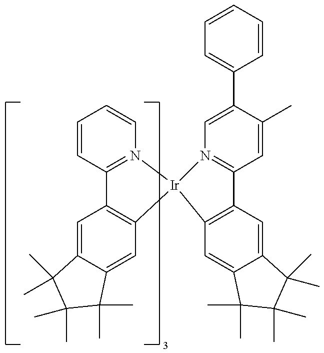

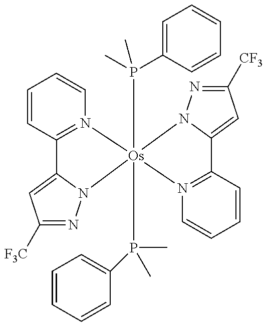

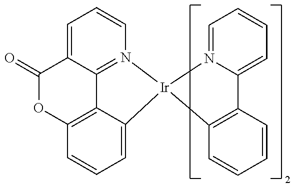

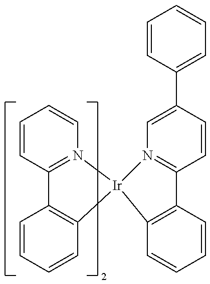

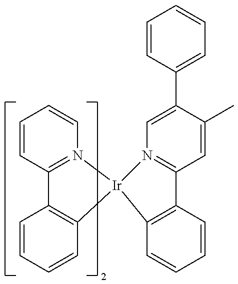

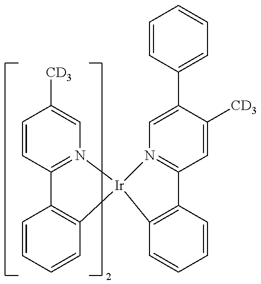

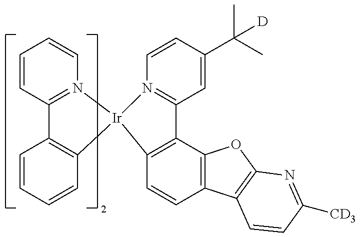

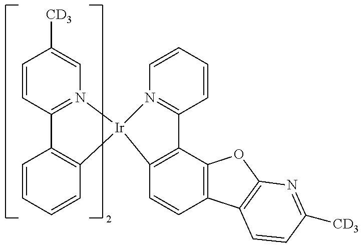

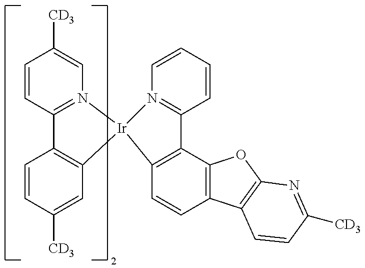

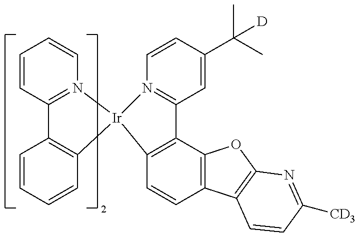

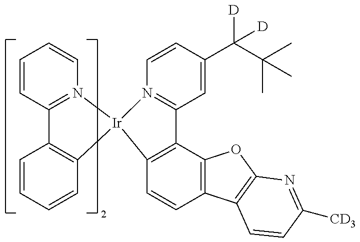

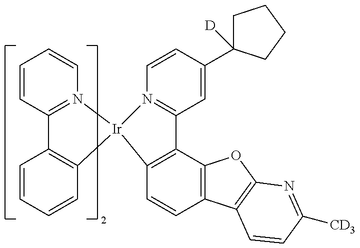

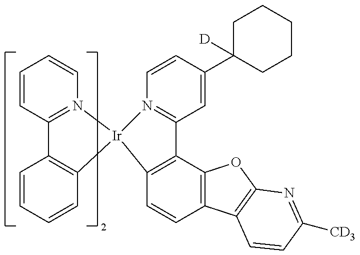

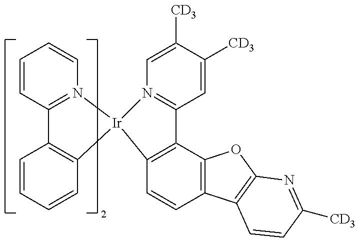

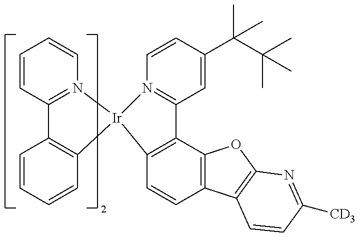

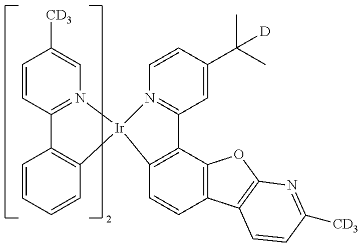

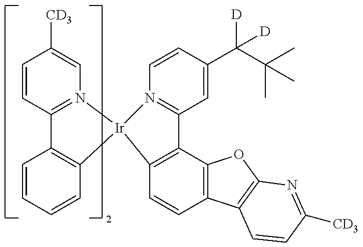

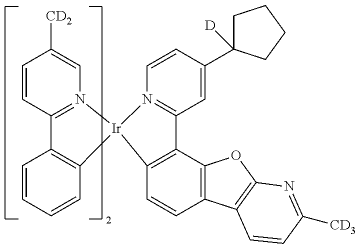

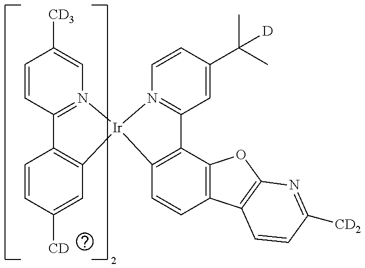

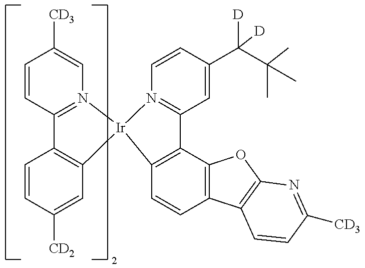

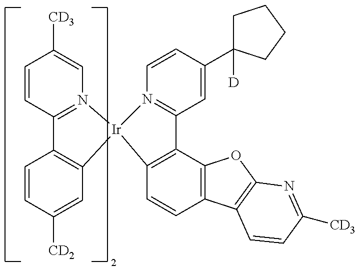

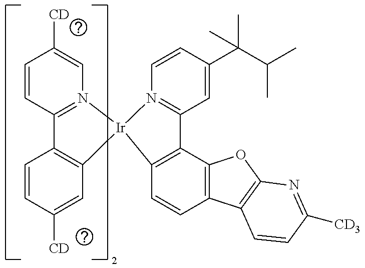

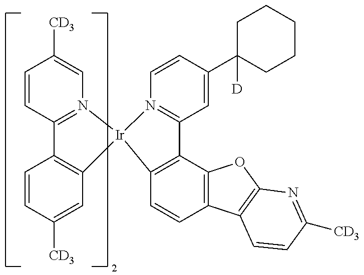

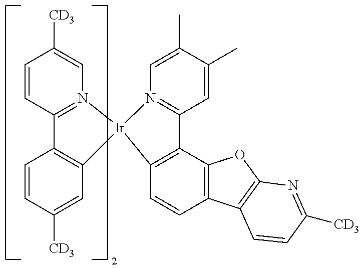

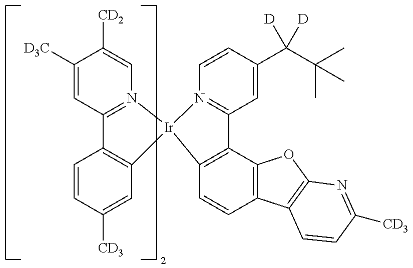

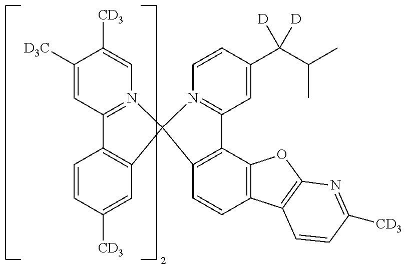

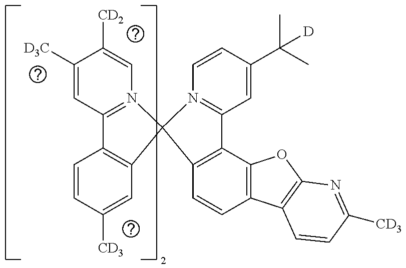

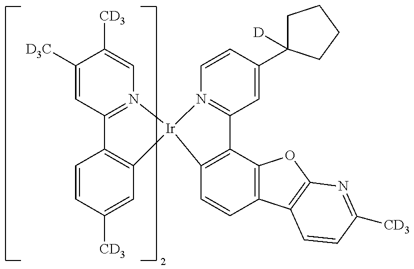

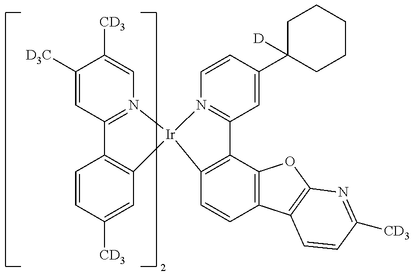

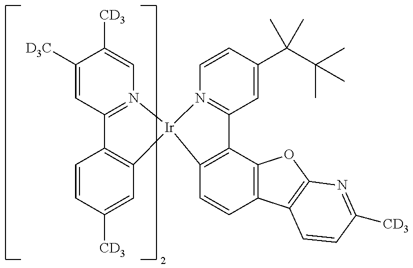

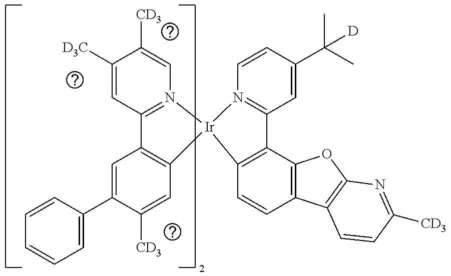

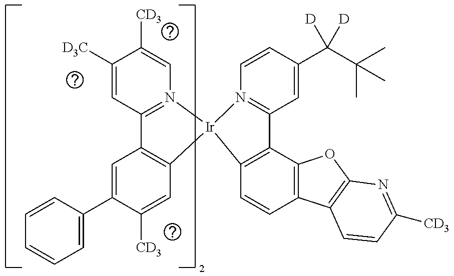

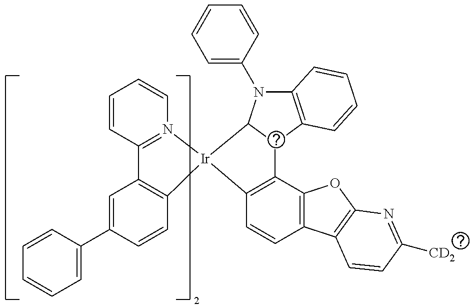

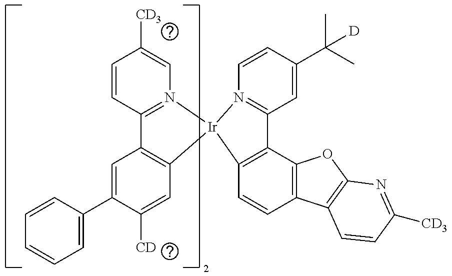

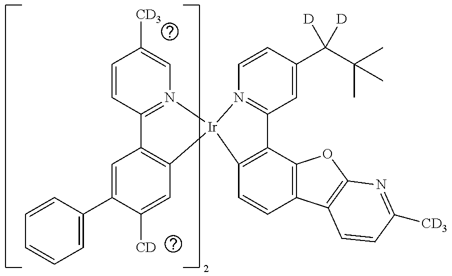

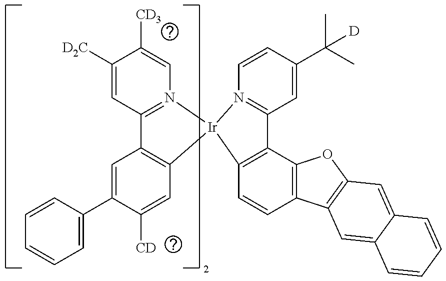

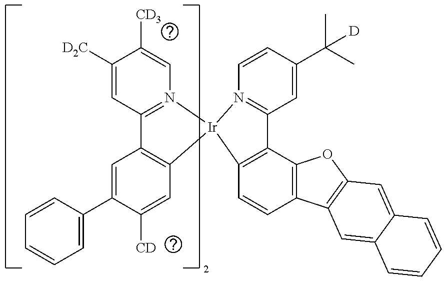

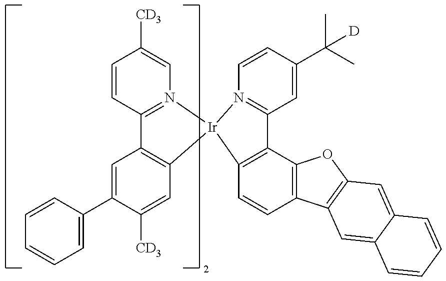

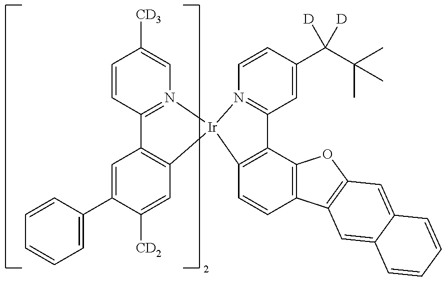

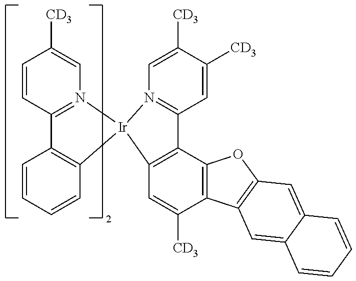

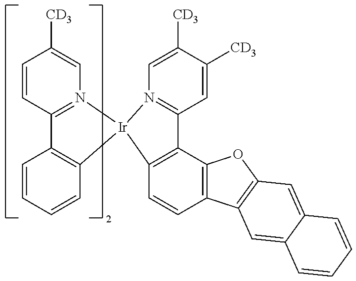

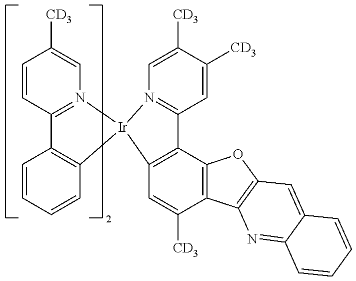

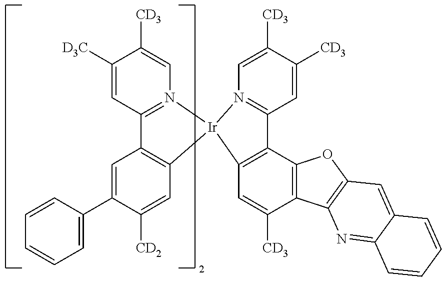

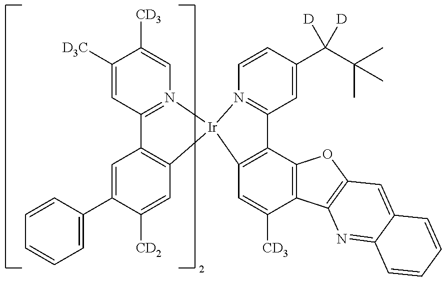

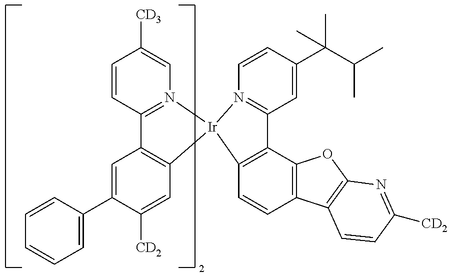

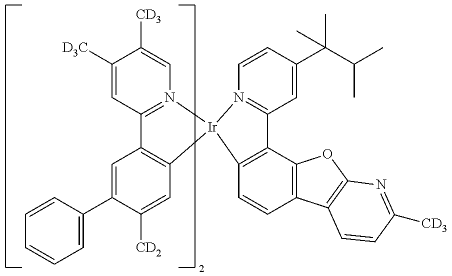

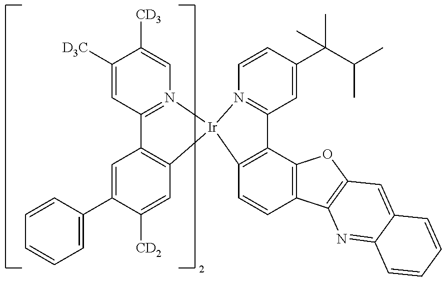

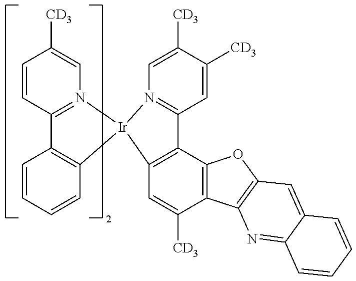

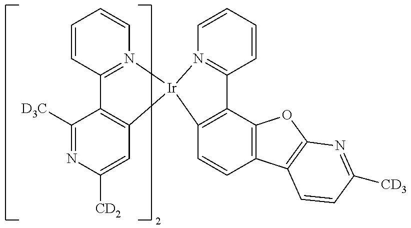

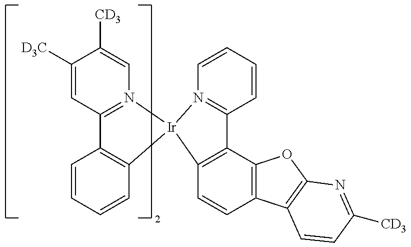

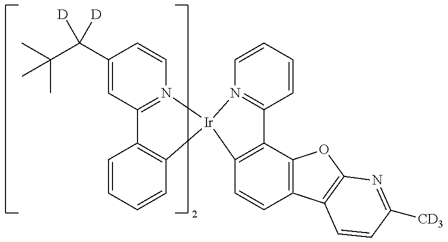

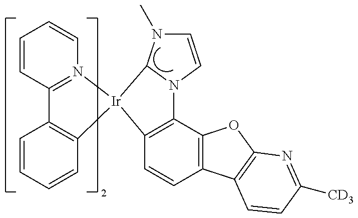

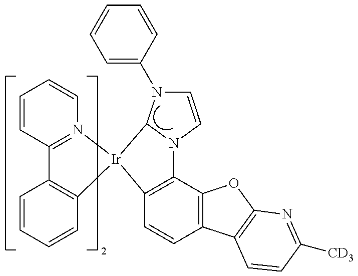

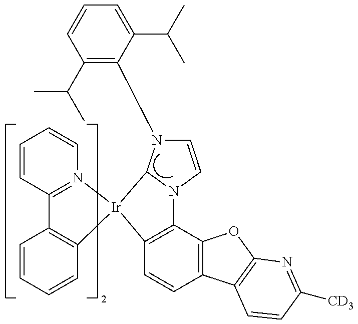

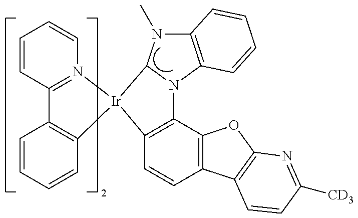

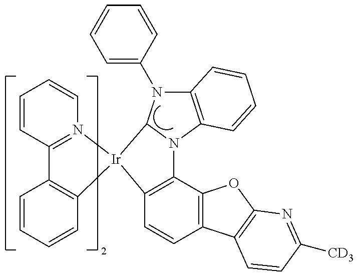

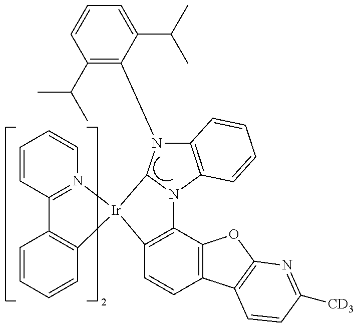

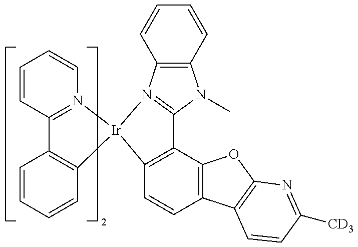

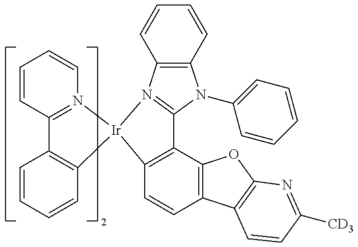

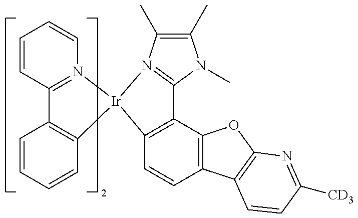

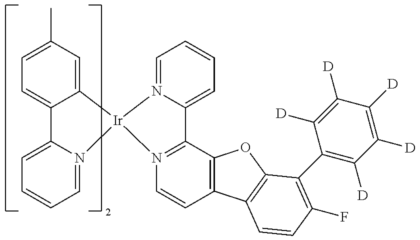

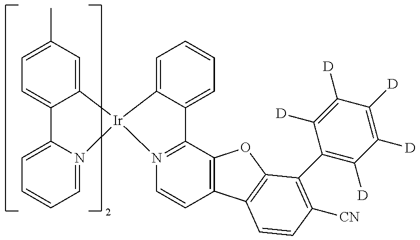

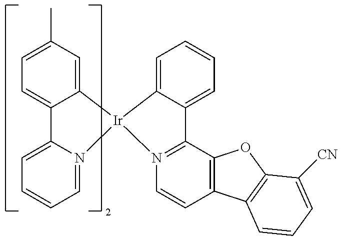

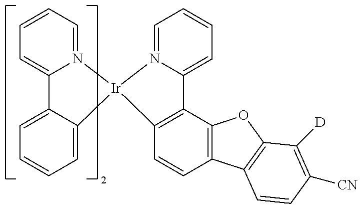

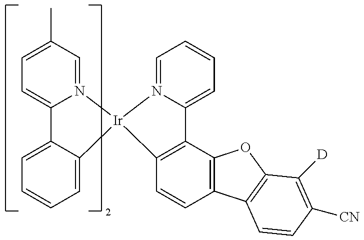

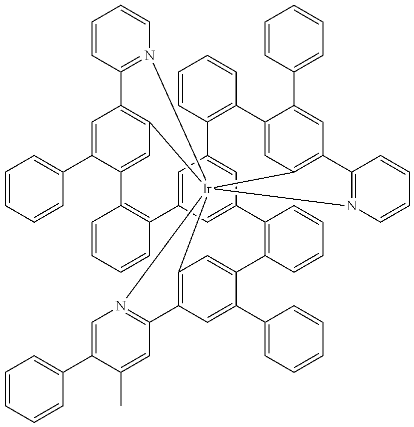

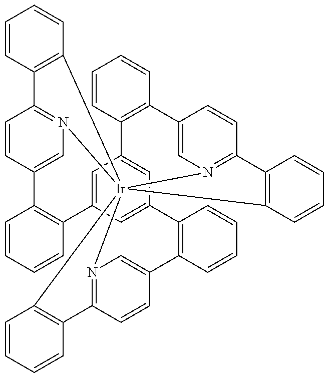

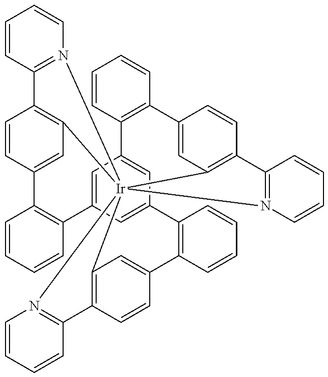

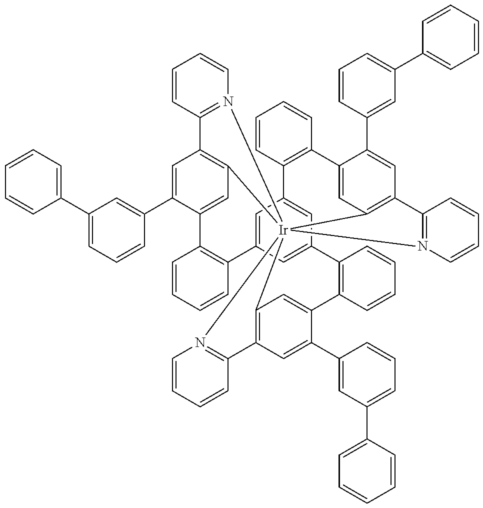

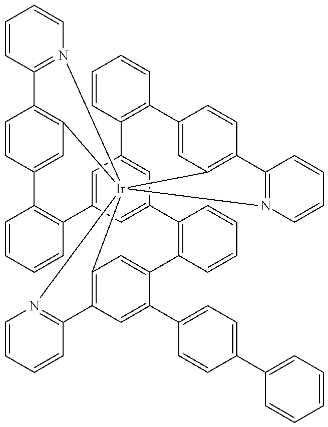

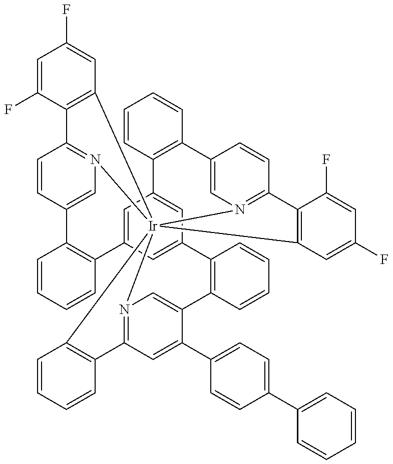

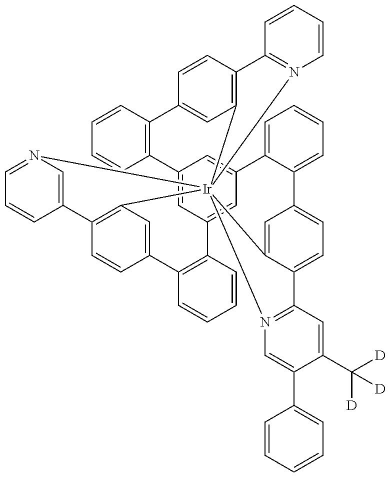

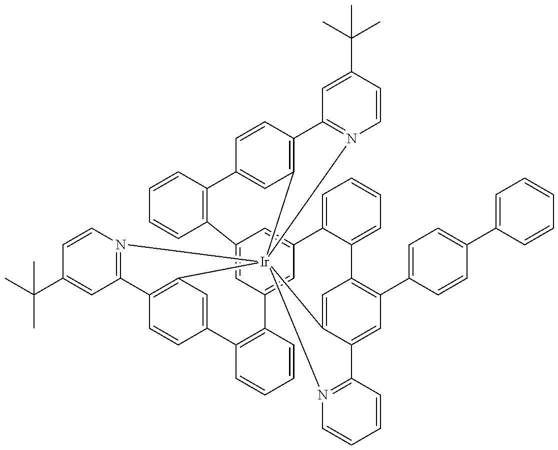

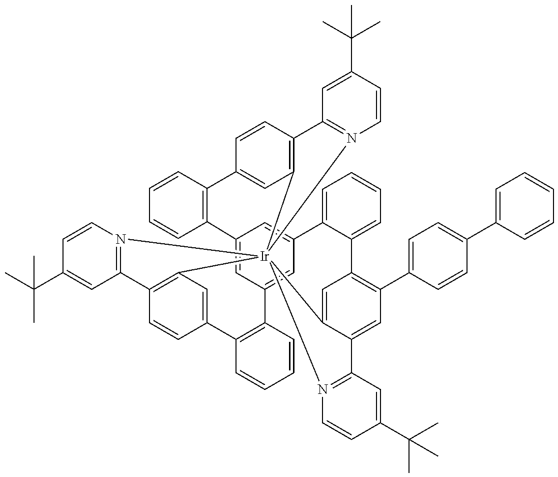

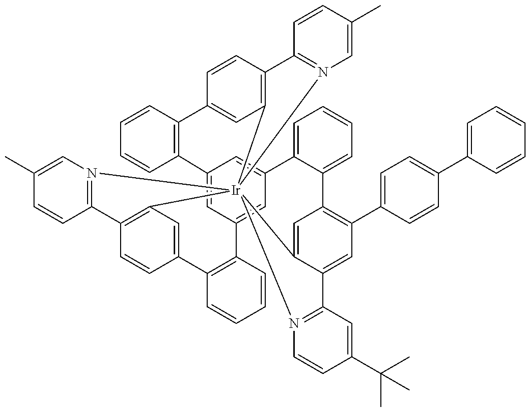

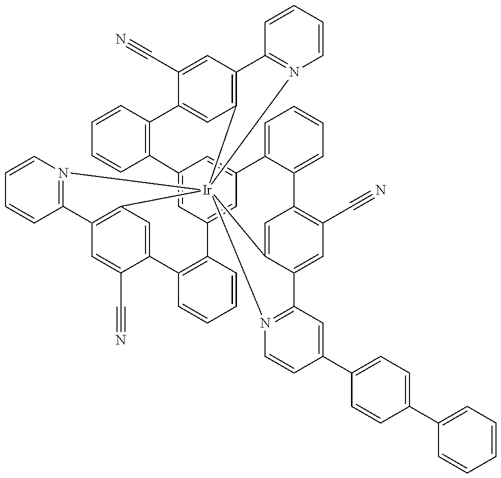

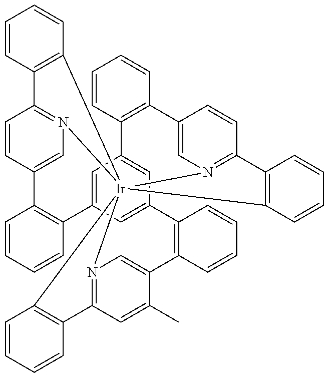

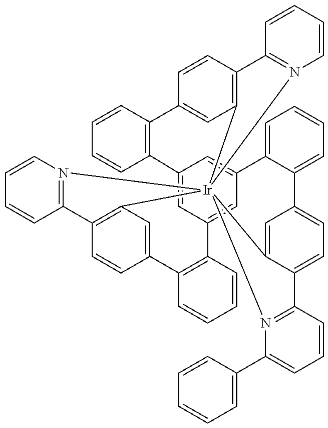

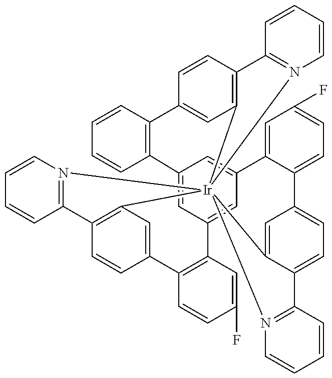

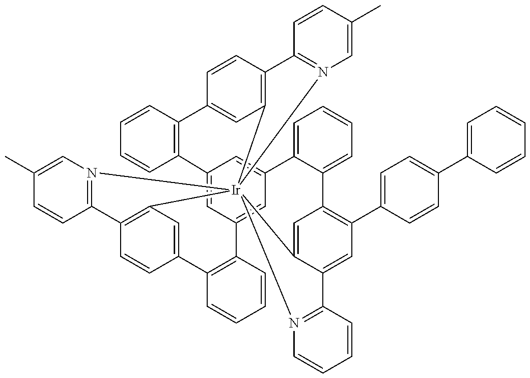

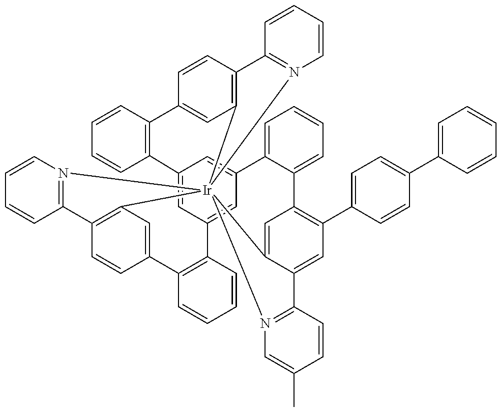

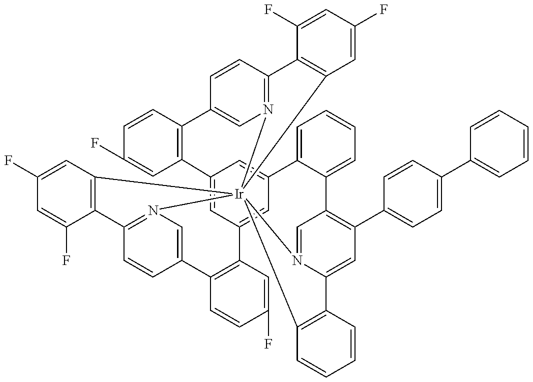

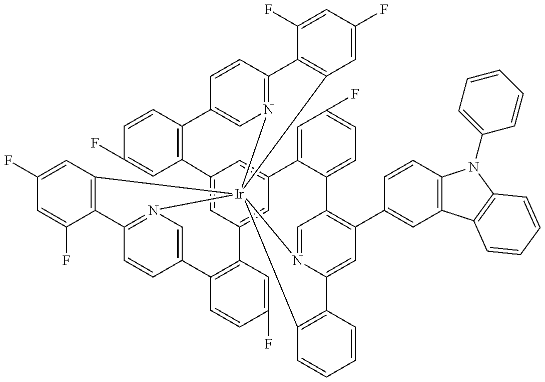

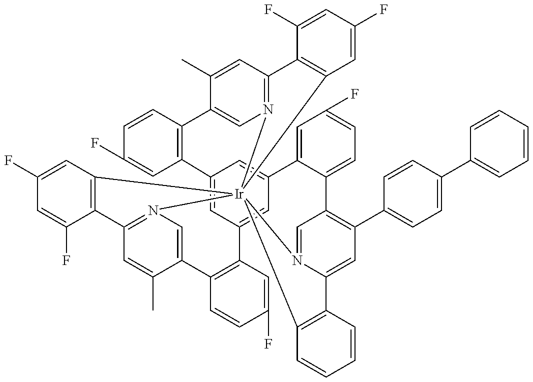

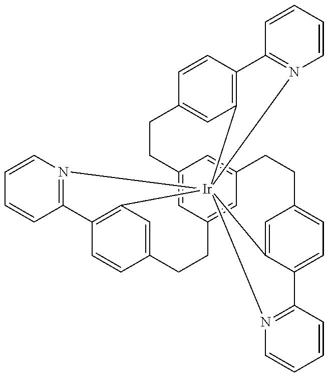

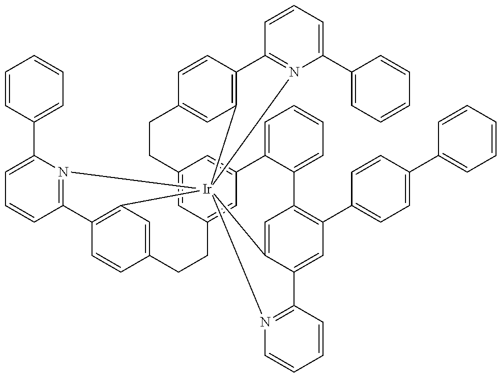

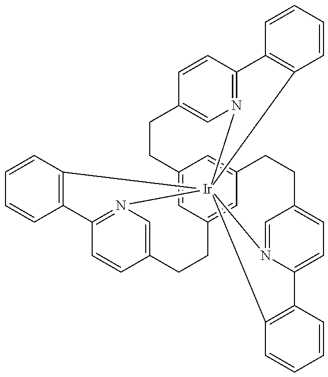

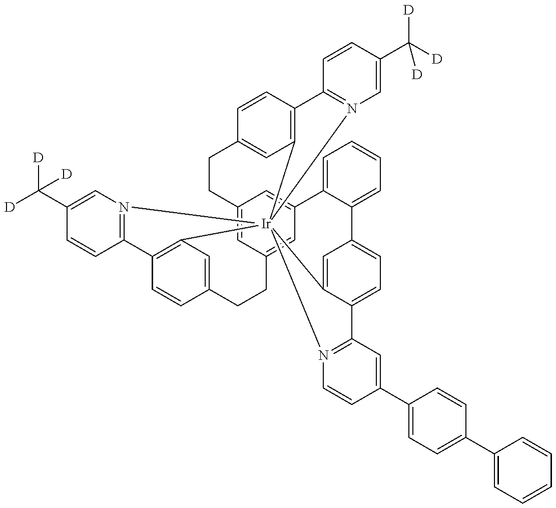

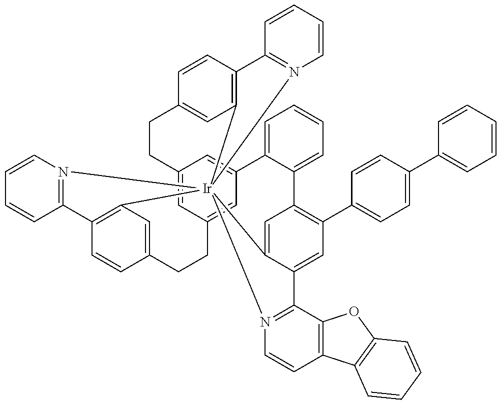

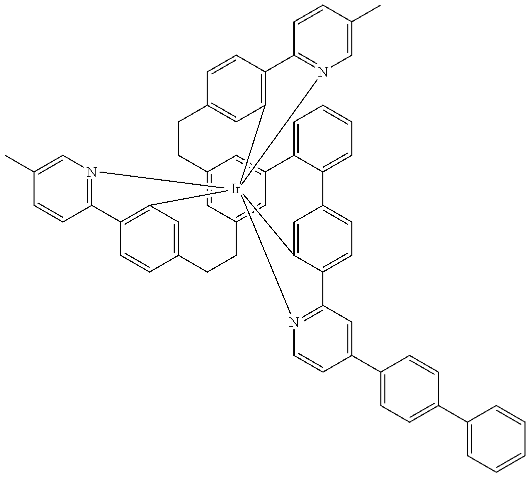

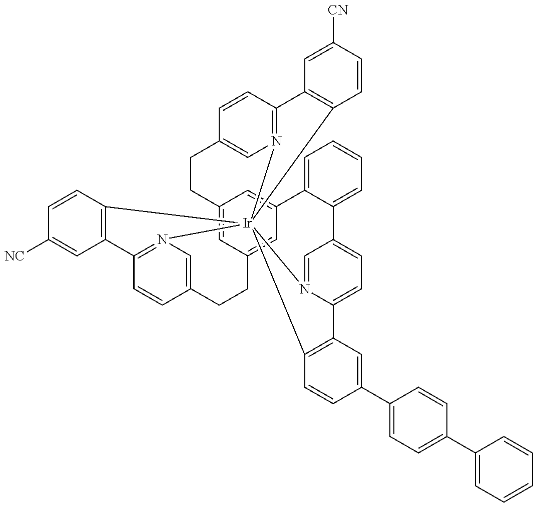

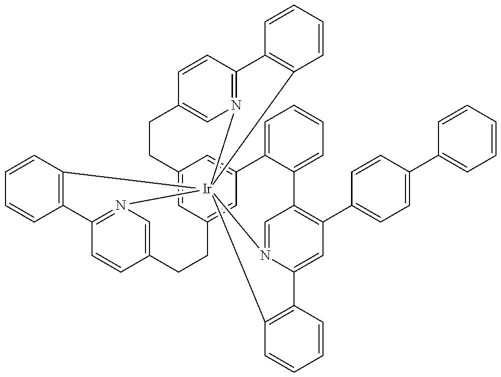

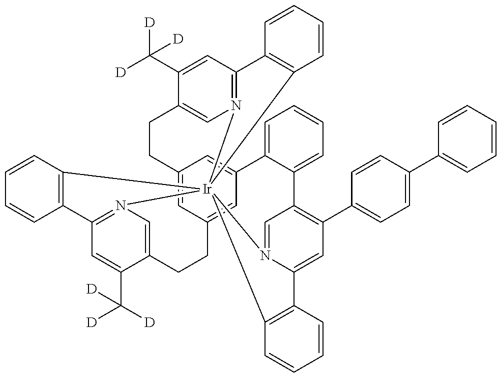

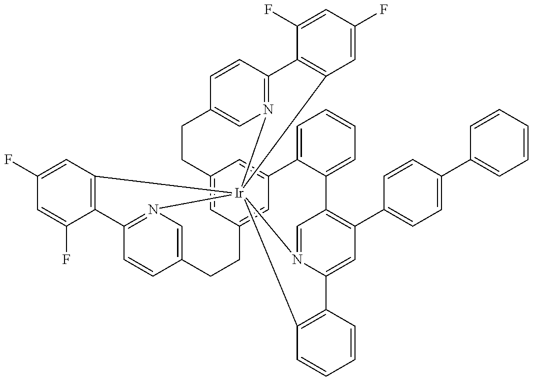

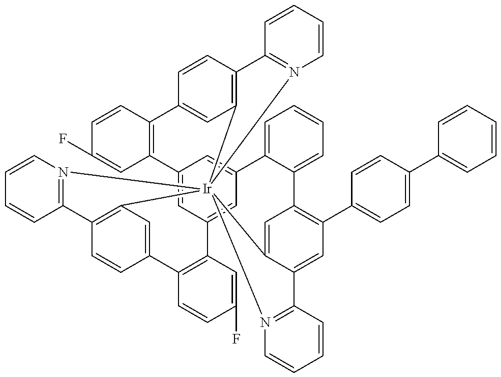

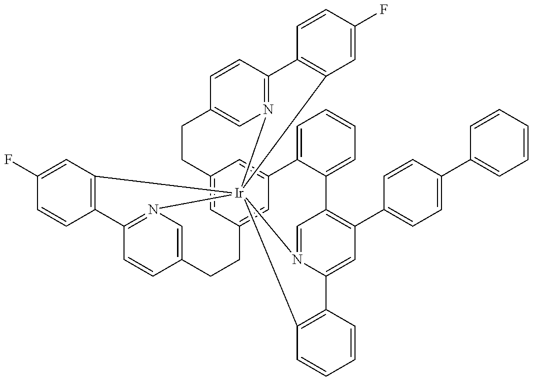

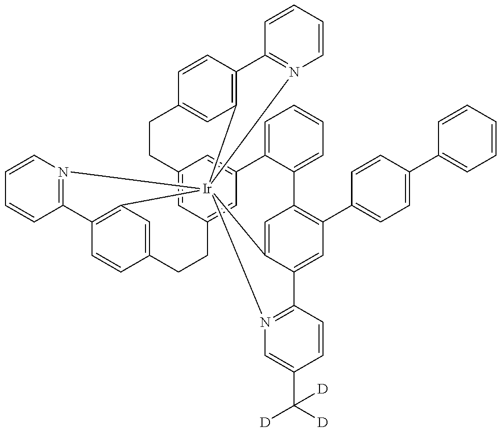

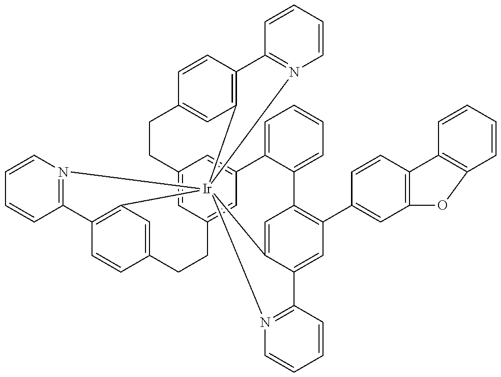

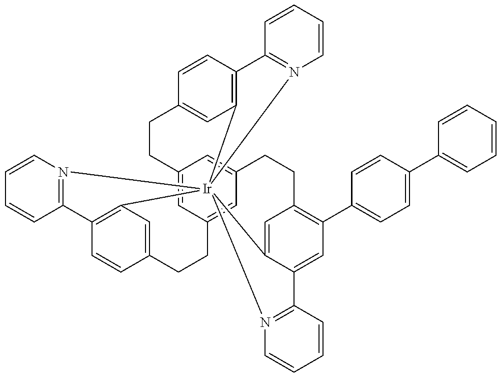

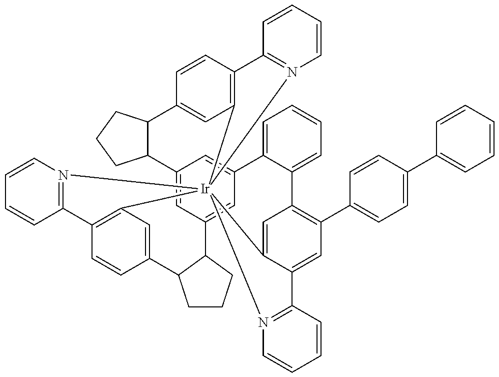

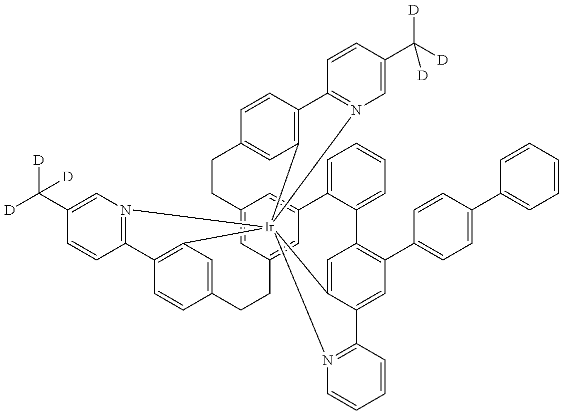

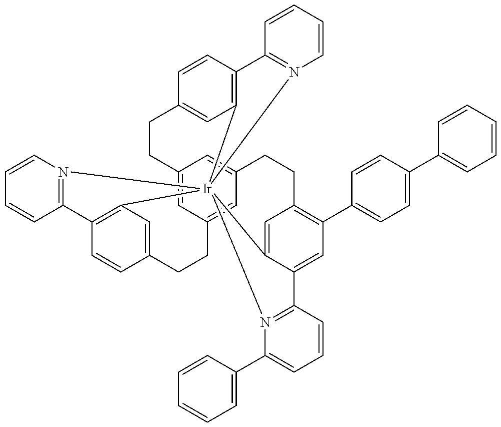

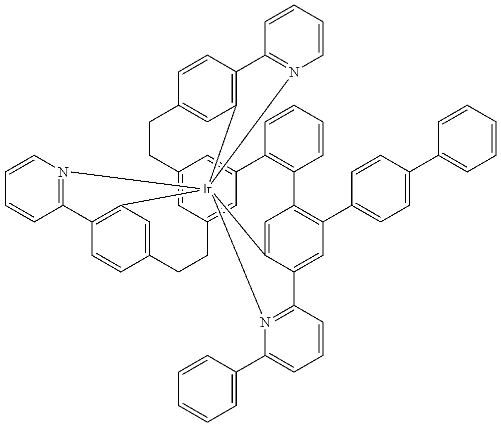

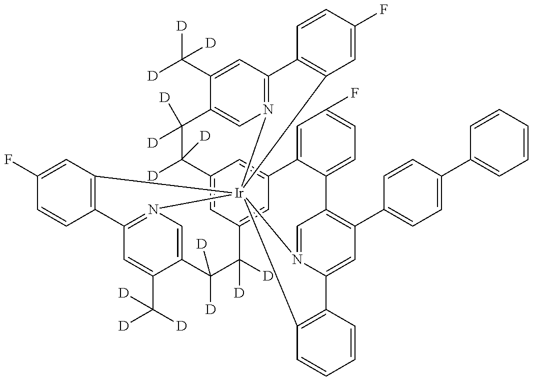

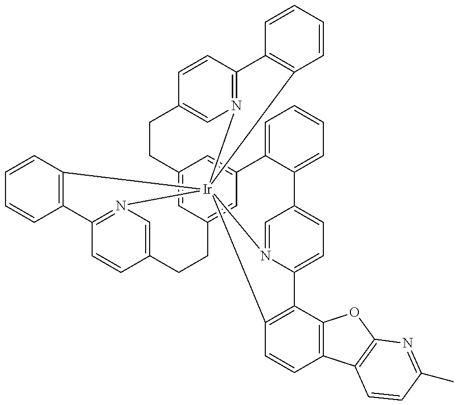

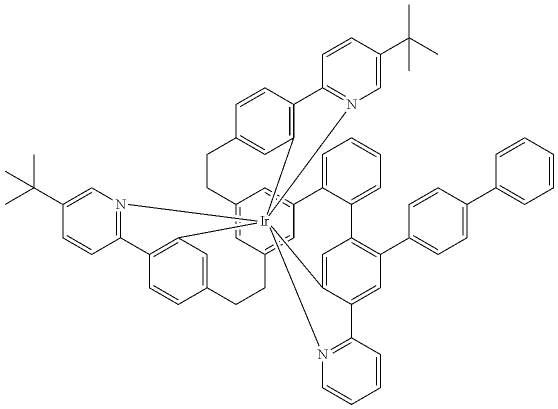

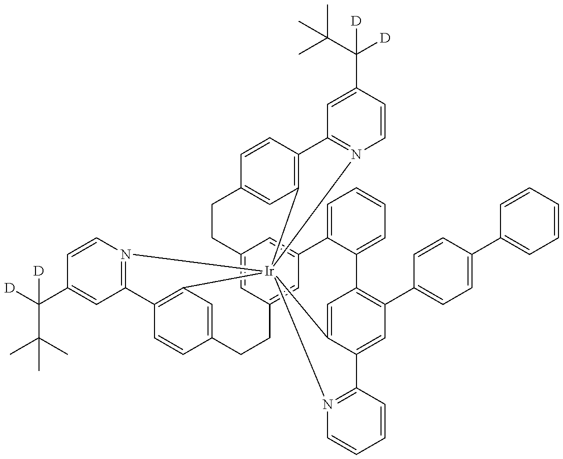

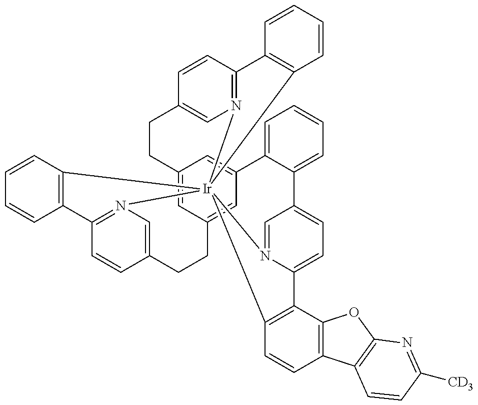

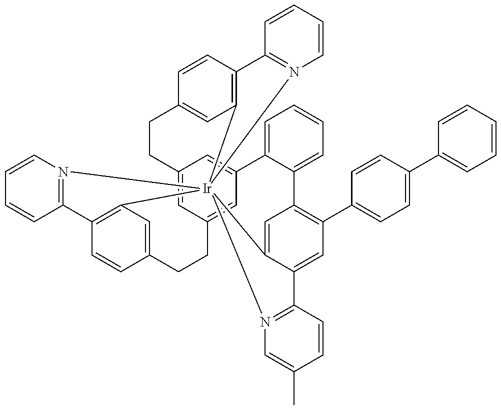

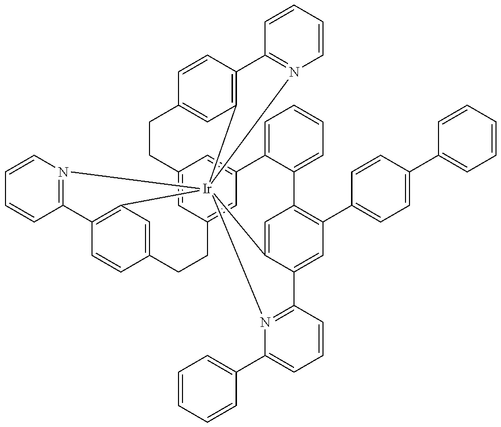

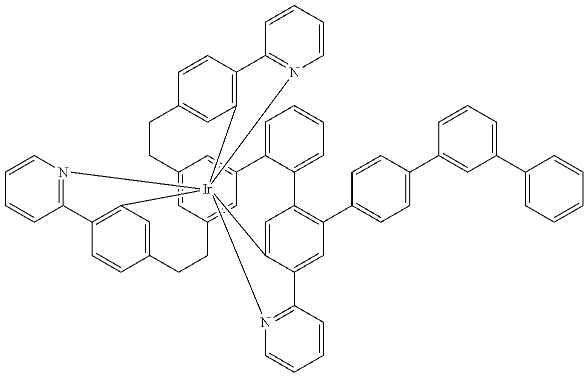

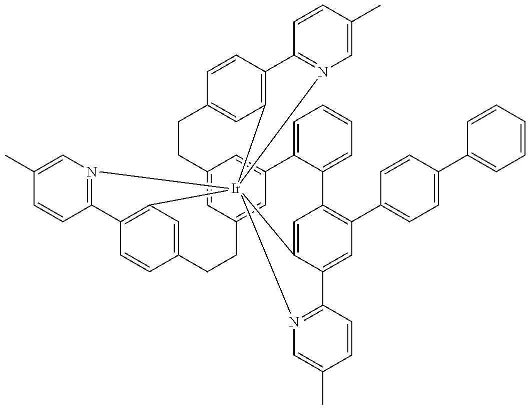

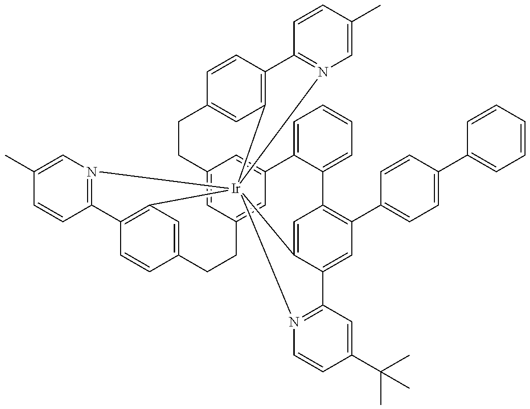

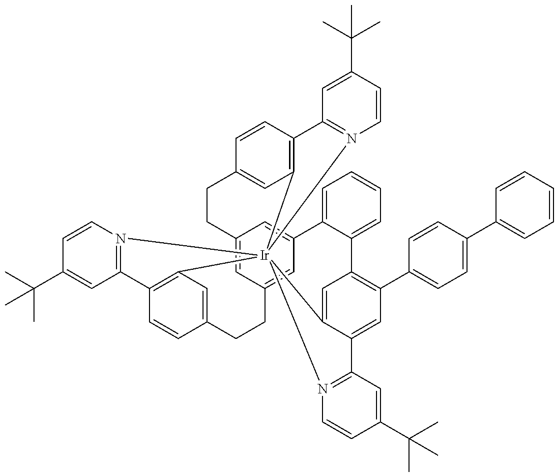

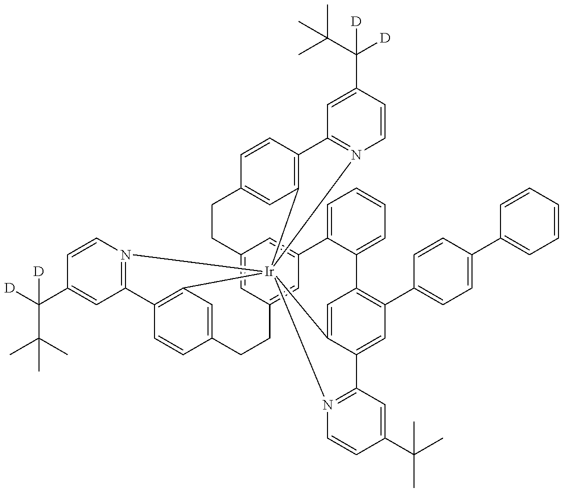

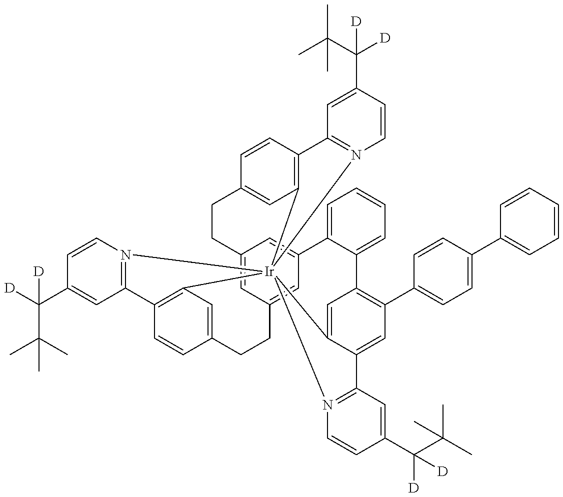

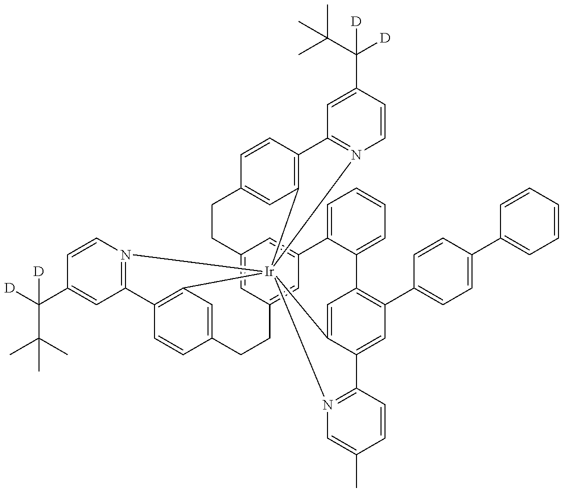

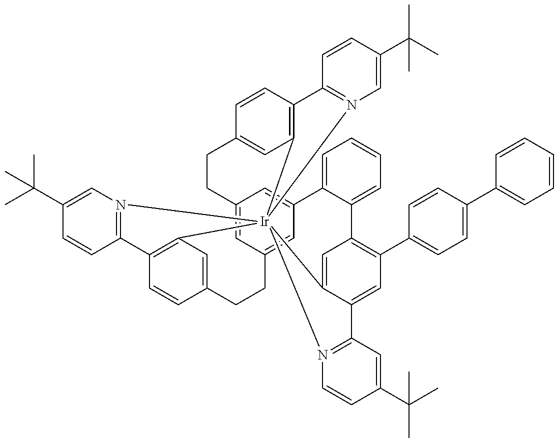

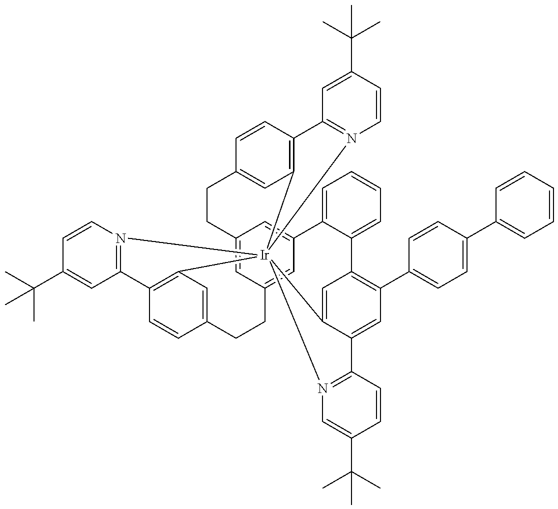

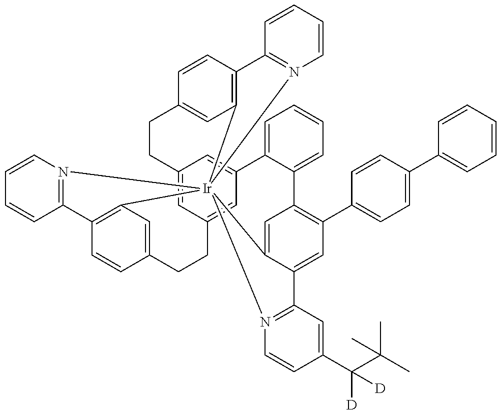

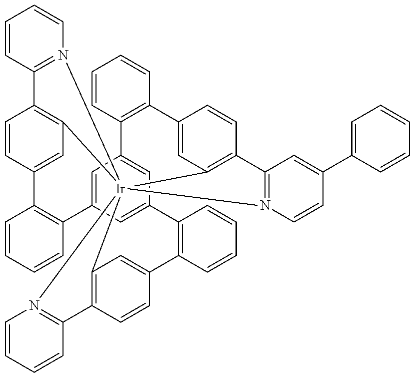

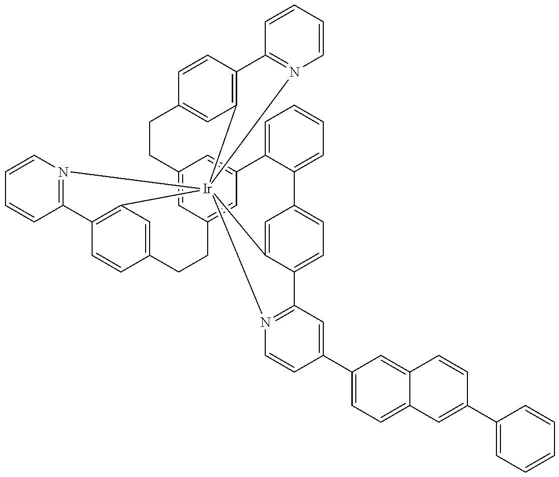

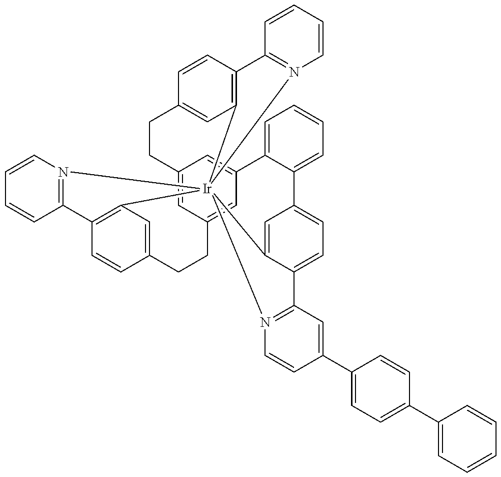

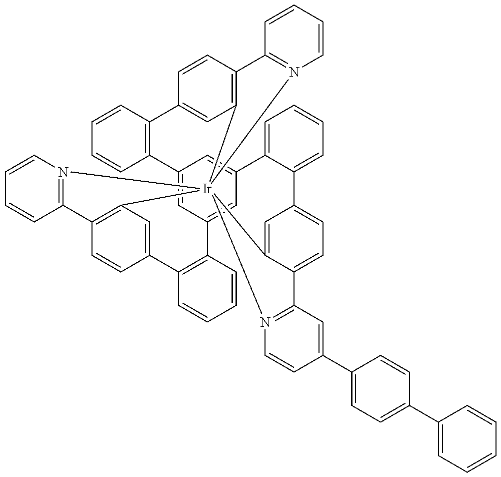

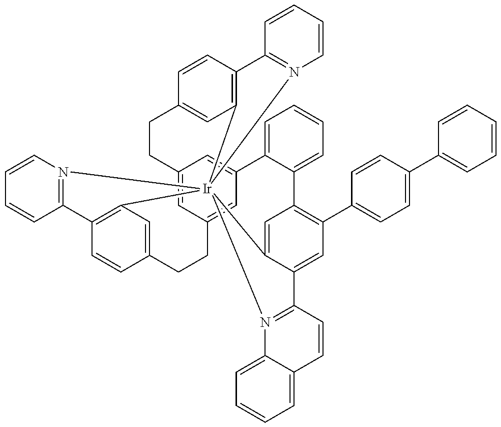

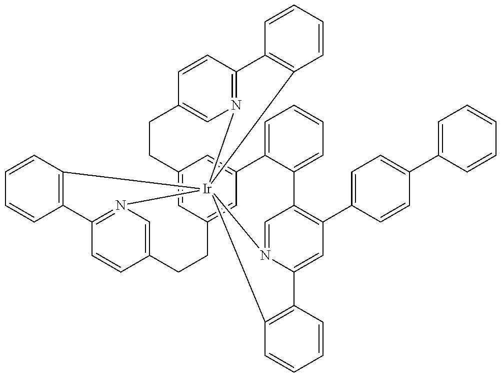

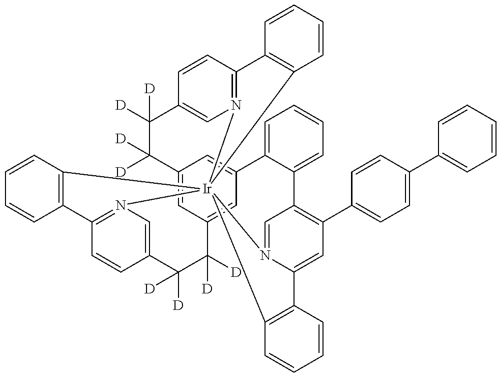

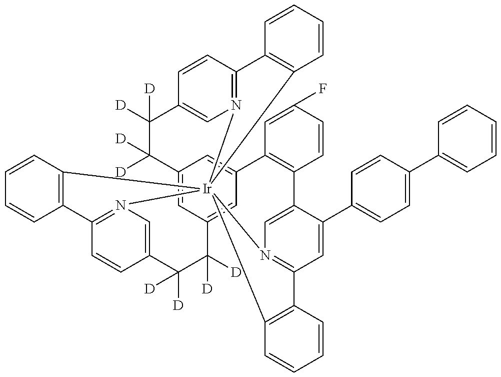

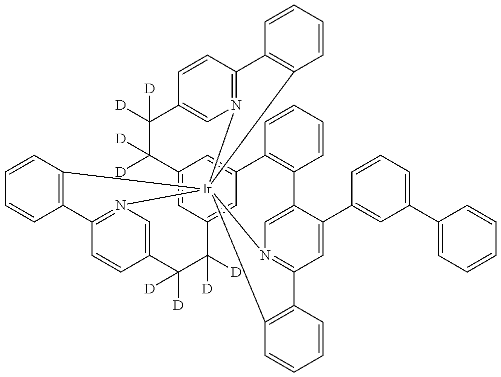

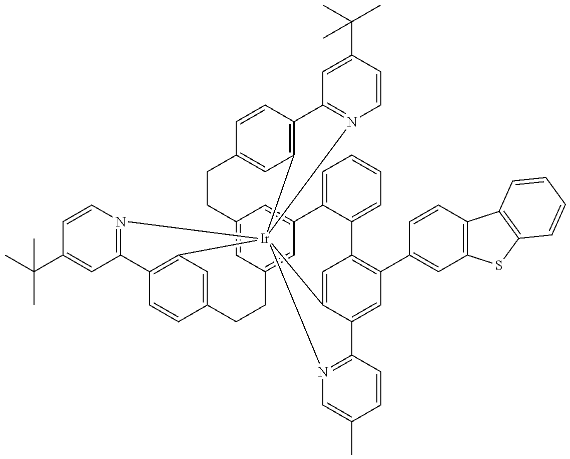

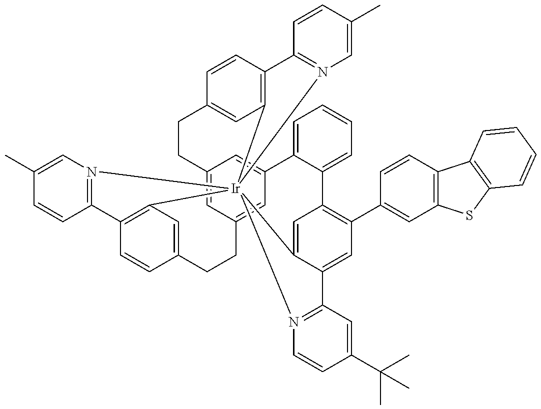

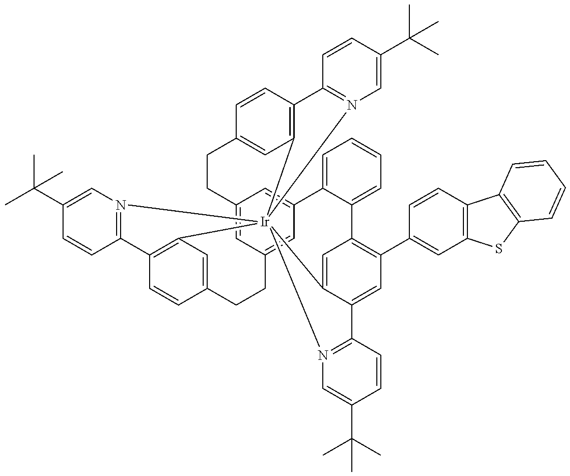

In the mixtures of the invention or in the light-emitting layer of the device of the invention, any mixture selected from the sum of the mixtures M1 to M765 is preferably combined with a compound of the formula (IIIa) or a compound of the formulae (I) to (VIII) or a compound from table 6.

The light-emitting layer in the organic electroluminescent device of the invention, comprising at least one phosphorescent emitter, is preferably an infrared-emitting or yellow-, orange-, red-, green-, blue- or ultraviolet-emitting layer, more preferably a yellow- or green-emitting layer and most preferably a green-emitting layer.

A yellow-emitting layer is understood here to mean a layer having a photoluminescence maximum within the range from 540 to 570 nm. An orange-emitting layer is understood to mean a layer having a photoluminescence maximum within the range from 570 to 600 nm. A red-emitting layer is understood to mean a layer having a photoluminescence maximum within the range from 600 to 750 nm. A green-emitting layer is understood to mean a layer having a photoluminescence maximum within the range from 490 to 540 nm. A blue-emitting layer is understood to mean a layer having a photoluminescence maximum within the range from 440 to 490 nm. The photoluminescence maximum of the layer is determined here by measuring the photoluminescence spectrum of the layer having a layer thickness of 50 nm at room temperature, said layer having the inventive combination of the host materials of the formulae (1) and (2) and the appropriate emitter.

The photoluminescence spectrum of the layer is recorded, for example, with a commercial photoluminescence spectrometer.

The photoluminescence spectrum of the emitter chosen is generally measured in oxygen-free solution, 10⁻⁵ molar, at room temperature, a suitable solvent being any in which the chosen emitter dissolves in the concentration mentioned. Particularly suitable solvents are typically toluene or 2-methyl-THF, but also dichloromethane. Measurement is effected with a commercial photoluminescence spectrometer. The triplet energy T1 in eV is determined from the photoluminescence spectra of the emitters. Initially the peak maximum Plmax. (in nm) of the photoluminescence spectrum is determined. The peak maximum Plmax. (in nm) is then converted into eV according to: E(T₁ in eV)=1240/E(T₁ in nm)=1240/PLmax. (in nm).

Preferred phosphorescent emitters are accordingly yellow emitters, preferably of the formula (IIIa), of the formulae (I) to (VIII) or from table 6, the triplet energy T₁ of which is preferably ˜2.3 eV to ˜2.1 eV.

Preferred phosphorescent emitters are accordingly green emitters, preferably of the formula (IIIa), of the formulae (I) to (VIII) or from table 6, the triplet energy T₁ of which is preferably ˜2.5 eV to ˜2.3 eV.

Particularly preferred phosphorescent emitters are accordingly green emitters, preferably of the formula (IIIa), of the formulae (I) to (VIII) or from table 6 as described above, the triplet energy T₁ of which is preferably ˜2.5 eV to ˜2.3 eV.

Most preferably, green emitters, preferably of the formula (IIIa), of the formulae (I) to (VIII) or from table 6, as described above, are selected for the mixture of the invention or emitting layer of the invention.

It is also possible for fluorescent emitters to be present in the light-emitting layer of the device of the invention.

Preferred fluorescent emitting compounds are selected from the class of the arylamines, where preferably at least one of the aromatic or heteroaromatic ring systems of the arylamine is a fused ring system, more preferably having at least 14 aromatic ring atoms.

Preferred examples of these are aromatic anthraceneamines, aromatic anthracenediamines, aromatic pyreneamines, aromatic pyrenediamines, aromatic chryseneamines or aromatic chrysenediamines. An aromatic anthraceneamine is understood to mean a compound in which a diarylamino group is bonded directly to an anthracene group, preferably in the 9 position. An aromatic anthracenediamine is understood to mean a compound in which two diarylamino groups are bonded directly to an anthracene group, preferably in the 9,10 positions. Aromatic pyreneamines, pyrenediamines, chryseneamines and chrysenediamines are defined analogously, where the diarylamino groups are bonded to the pyrene preferably in the 1 position or 1,6 positions. Further preferred emitting compounds are indenofluoreneamines or -diamines, benzoindenofluoreneamines or -diamines, and dibenzoindenofluoreneamines or -diamines, and indenofluorene derivatives having fused aryl groups. Likewise preferred are pyrenearylamines. Likewise preferred are benzoindenofluoreneamines, benzofluoreneamines, extended benzoindenofluorenes, phenoxazines, and fluorene derivatives joined to furan units or to thiophene units.

In a further preferred embodiment of the invention, the at least one light-emitting layer of the organic electroluminescent device, as well as the host materials 1 and 2 as described above or described as preferred, may comprise further host materials or matrix materials, called mixed matrix systems. The mixed matrix systems preferably comprise three or four different matrix materials, more preferably three different matrix materials (in other words, one further matrix component in addition to the host materials 1 and 2 as described above). Particularly suitable matrix materials which can be used in combination as matrix component in a mixed matrix system are selected from wide-band gap materials, bipolar host materials, electron transport materials (ETM) and hole transport materials (HTM).

A wide-band gap material is understood herein to mean a material within the scope of the disclosure of U.S. Pat. No. 7,294,849 which is characterized by a band gap of at least 3.5 eV, the band gap being understood to mean the gap between the HOMO and LUMO energy of a material.

Preferably, the mixed matrix system is optimized for an emitter of the formula (IIIa), the formulae (I) to (VIII), or from table 6.

In one embodiment of the present invention, the mixture does not comprise any further constituents, i.e. functional materials, aside from the constituents of electron-transporting host material of the formula (1) and hole-transporting host material of the formula (2).

These are material mixtures that are used as such for production of the light-emitting layer. These mixtures are also referred to as premix systems that are used as the sole material source in the vapor deposition of the host materials for the light-emitting layer and have a constant mixing ratio in the vapor deposition. In this way, it is possible in a simple and rapid manner to achieve the vapor deposition of a layer with homogeneous distribution of the components without the need for precise actuation of a multitude of material sources.

In an alternative embodiment of the present invention, the mixture also comprises the phosphorescent emitter as described above, in addition to the constituents of electron-transporting host material of the formula (1) and hole-transporting host material of the formula (2). In the case of a suitable mixing ratio in the vapor deposition, this mixture may also be used as the sole material source as described above.

The components or constituents of the light-emitting layer of the device of the invention may thus be processed by vapor deposition or from solution. The material combination of host materials 1 and 2 as described above or described as preferred, optionally with the phosphorescent emitter as described above or described as preferred, are provided for that purpose in a formulation containing at least one solvent. These formulations may, for example, be solutions, dispersions or emulsions. For this purpose, it may be preferable to use mixtures of two or more solvents.

The present invention therefore further provides a formulation comprising an inventive mixture of host materials 1 and 2 as described above, optionally in combination with a phosphorescent emitter as described above or described as preferred, and at least one solvent.

Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane or mixtures of these solvents.

The formulation here may also comprise at least one further organic or inorganic compound which is likewise used in the light-emitting layer of the device of the invention, especially a further emitting compound and/or a further matrix material. Suitable emitting compounds and further matrix materials have already been detailed above.

The light-emitting layer in the device of the invention, according to the preferred embodiments and the emitting compound, contains preferably between 99.9% and 1% by volume, further preferably between 99% and 10% by volume, especially preferably between 98% and 60% by volume, very especially preferably between 97% and 80% by volume, of matrix material composed of at least one compound of the formula (1) and at least one compound of the formula (2) according to the preferred embodiments, based on the overall composition of emitter and matrix material. Correspondingly, the light-emitting layer in the device of the invention preferably contains between 0.1% and 99% by volume, further preferably between 1% and 90% by volume, more preferably between 2% and 40% by volume, most preferably between 3% and 20% by volume, of the emitter based on the overall composition of the light-emitting layer composed of emitter and matrix material. If the compounds are processed from solution, preference is given to using the corresponding amounts in % by weight rather than the above-specified amounts in % by volume.

The light-emitting layer in the device of the invention, according to the preferred embodiments and the emitting compound, preferably contains the matrix material of the formula (1) and the matrix material of the formula (2) in a percentage by volume ratio between 3:1 and 1:3, preferably between 1:2.5 and 1:1, more preferably between 1:2 and 1:1. If the compounds are processed from solution, preference is given to using the corresponding ratio in % by weight rather than the above-specified ratio in % by volume.

The present invention also relates to an organic electroluminescent device as described above or described as preferred, wherein the organic layer comprises a hole injection layer (HIL) and/or a hole transport layer (HTL), the hole-injecting material and hole-transporting material of which belongs to the class of the arylamines. Preferred compounds with hole transport function that do not conform to one of the formulae for the host material 2, preferably for use in a hole injection layer, a hole transport layer, an electron blocker layer and/or as additional matrix material in the emitting layer of the invention, are shown in table 7 below. The compounds in table 7, as the structures show, are non-deuterated compounds.

TABLE 7 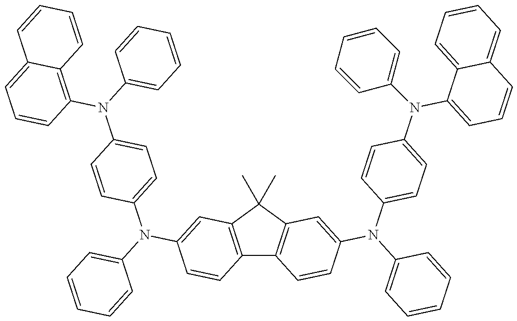 [SMILES: CC1(C)c2cc(N(c3ccccc3)c3ccc(N(c4ccccc4)c4cccc5ccccc45)cc3)ccc2-c2ccc(N(c3ccccc3)c3ccc(N(c4ccccc4)c4cccc5ccccc45)cc3)cc21]
HT-1 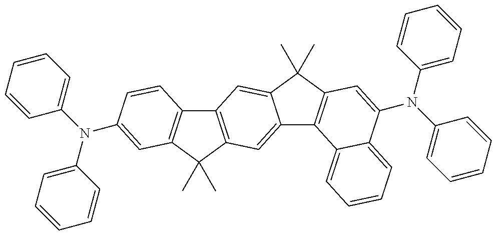 [SMILES: CC1(C)c2cc(N(c3ccccc3)c3ccccc3)ccc2-c2cc3c(cc21)-c1c(cc(N(c2ccccc2)c2ccccc2)c2ccccc12)C3(C)C]
HT-2 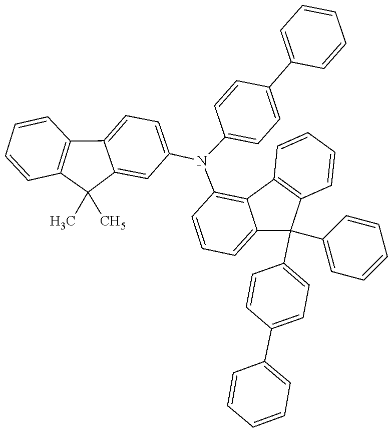
HT-3 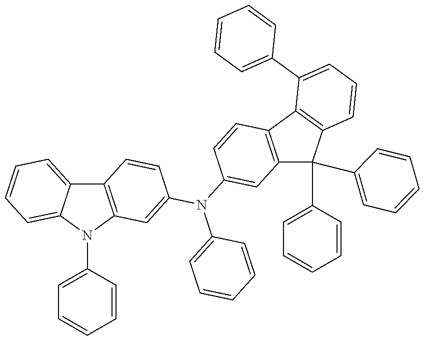 [SMILES: c1ccc(-c2cccc3c2-c2ccc(N(c4ccccc4)c4ccc5c6ccccc6n(-c6ccccc6)c5c4)cc2C3(c2ccccc2)c2ccccc2)cc1]
HT-4 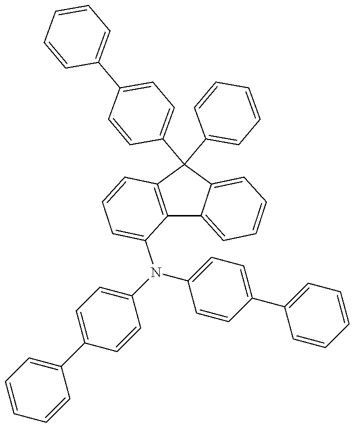 [SMILES: c1ccc(-c2ccc(N(c3ccc(-c4ccccc4)cc3)c3cccc4c3-c3ccccc3C4(c3ccccc3)c3ccc(-c4ccccc4)cc3)cc2)cc1]
HT-5 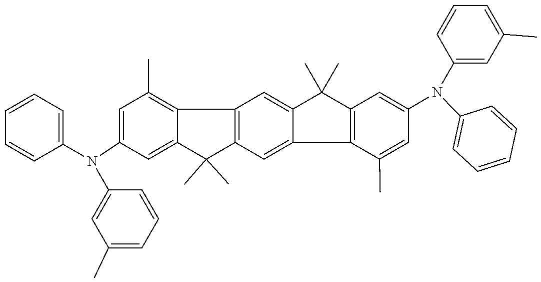 [SMILES: Cc1cccc(N(c2ccccc2)c2cc(C)c3c(c2)C(C)(C)c2cc4c(cc2-3)C(C)(C)c2cc(N(c3ccccc3)c3cccc(C)c3)cc(C)c2-4)c1]
HT-6 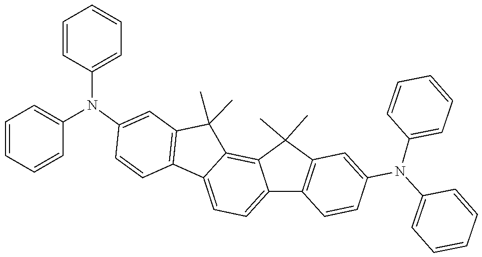 [SMILES: CC1(C)c2cc(N(c3ccccc3)c3ccccc3)ccc2-c2ccc3c(c21)C(C)(C)c1cc(N(c2ccccc2)c2ccccc2)ccc1-3]
HT-7 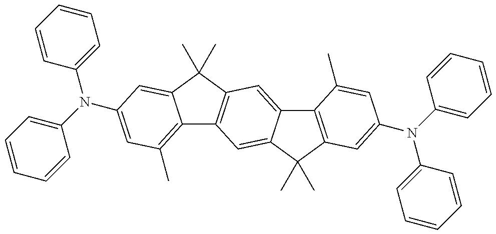 [SMILES: Cc1cc(N(c2ccccc2)c2ccccc2)cc2c1-c1cc3c(cc1C2(C)C)-c1c(C)cc(N(c2ccccc2)c2ccccc2)cc1C3(C)C]
HT-8 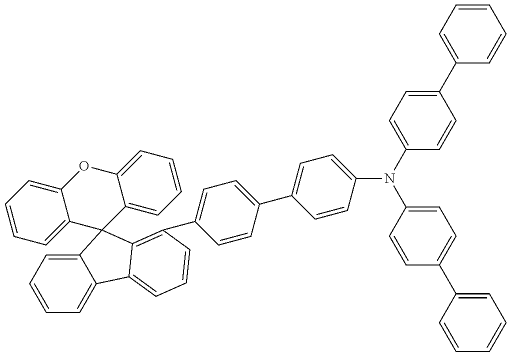 [SMILES: c1ccc(-c2ccc(N(c3ccc(-c4ccccc4)cc3)c3ccc(-c4ccc(-c5cccc6c5C5(c7ccccc7Oc7ccccc75)c5ccccc5-6)cc4)cc3)cc2)cc1]
HT-9 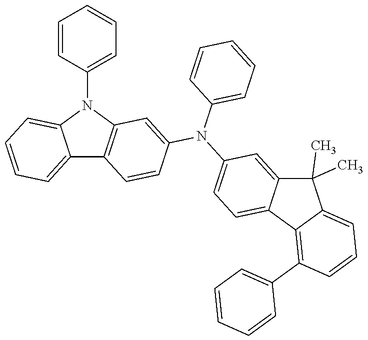 [SMILES: CC1(C)c2cc(N(c3ccccc3)c3ccc4c5ccccc5n(-c5ccccc5)c4c3)ccc2-c2c(-c3ccccc3)cccc21]
HT-10 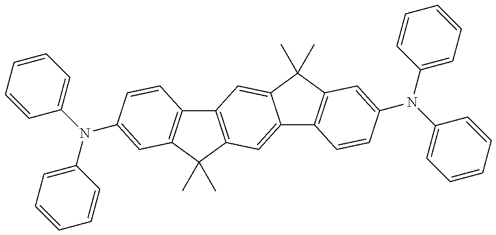 [SMILES: CC1(C)c2cc(N(c3ccccc3)c3ccccc3)ccc2-c2cc3c(cc21)-c1ccc(N(c2ccccc2)c2ccccc2)cc1C3(C)C]
HT-11 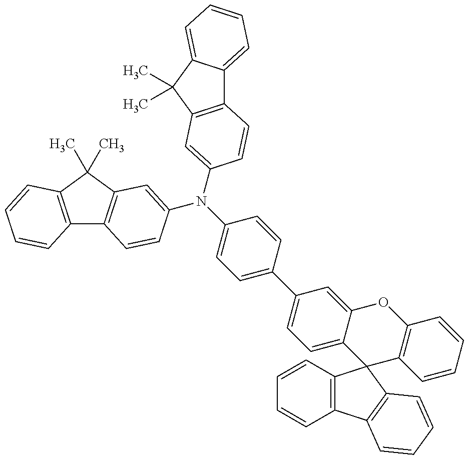 [SMILES: CC1(C)c2ccccc2-c2ccc(N(c3ccc(-c4ccc5c(c4)Oc4ccccc4C54c5ccccc5-c5ccccc54)cc3)c3ccc4c(c3)C(C)(C)c3ccccc3-4)cc21]
HT-12 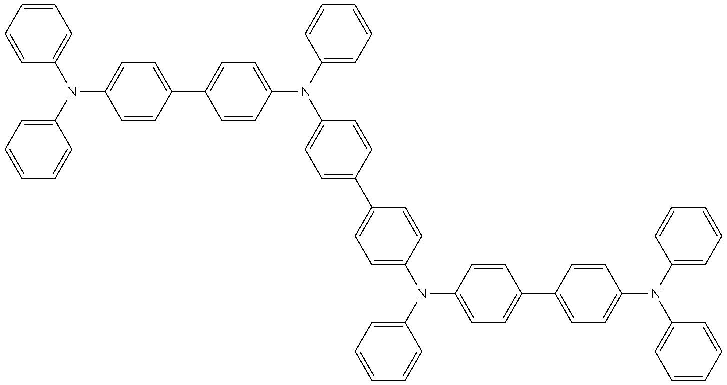 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]
HT-13 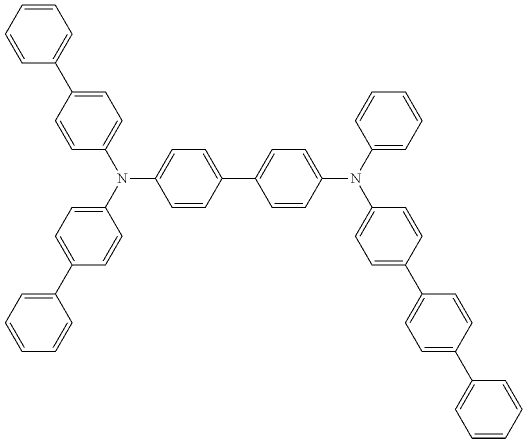 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]
HT-14 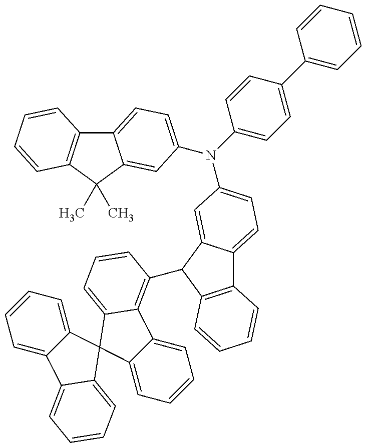 [SMILES: CC1(C)c2ccccc2-c2ccc(N(c3ccc(-c4ccccc4)cc3)c3ccc4c(c3)C(c3cccc5c3-c3ccccc3C53c5ccccc5-c5ccccc53)c3ccccc3-4)cc21]
HT-15 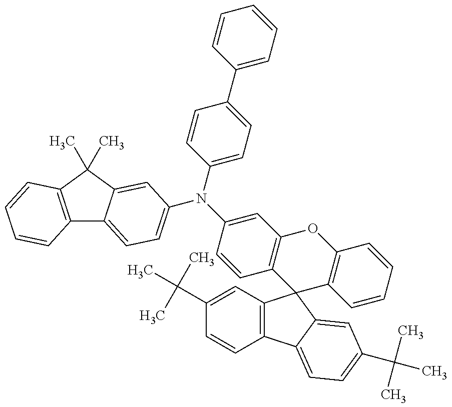 [SMILES: CC(C)(C)c1ccc2c(c1)C1(c3ccccc3Oc3cc(N(c4ccc(-c5ccccc5)cc4)c4ccc5c(c4)C(C)(C)c4ccccc4-5)ccc31)c1cc(C(C)(C)C)ccc1-2]
HT-16 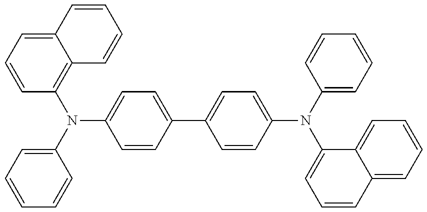 [SMILES: c1ccc(N(c2ccc(-c3ccc(N(c4ccccc4)c4cccc5ccccc45)cc3)cc2)c2cccc3ccccc23)cc1]
HT-17 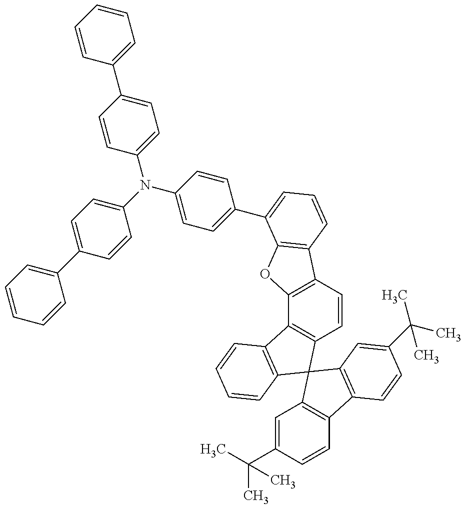 [SMILES: CC(C)(C)c1ccc2c(c1)C1(c3cc(C(C)(C)C)ccc3-2)c2ccccc2-c2c1ccc1c2oc2c(-c3ccc(N(c4ccc(-c5ccccc5)cc4)c4ccc(-c5ccccc5)cc4)cc3)cccc21]
HT-18 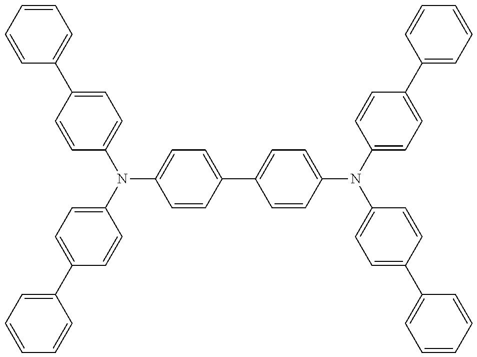 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]
HT-19 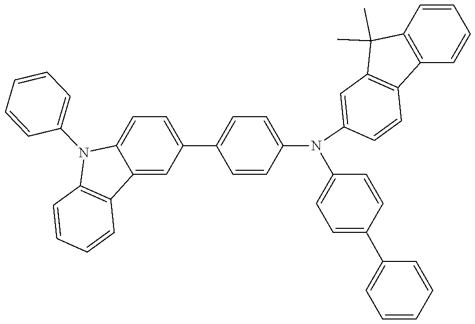 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]
HT-20 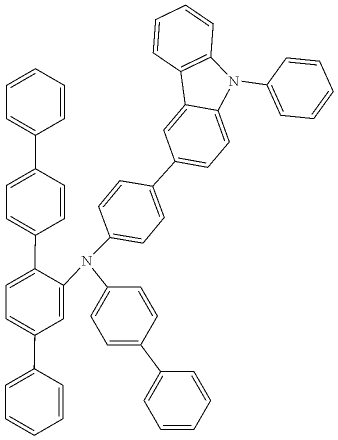 [SMILES: c1ccc(-c2ccc(-c3ccc(-c4ccccc4)cc3N(c3ccc(-c4ccccc4)cc3)c3ccc(-c4ccc5c(c4)c4ccccc4n5-c4ccccc4)cc3)cc2)cc1]
HT-21 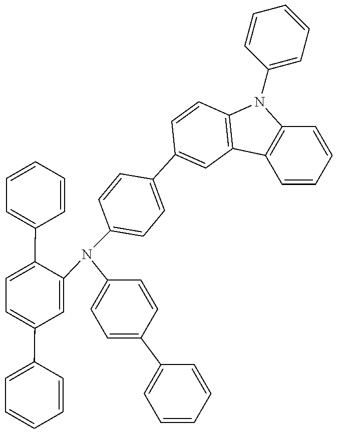 [SMILES: c1ccc(-c2ccc(N(c3ccc(-c4ccc5c(c4)c4ccccc4n5-c4ccccc4)cc3)c3cc(-c4ccccc4)ccc3-c3ccccc3)cc2)cc1]
HT-22 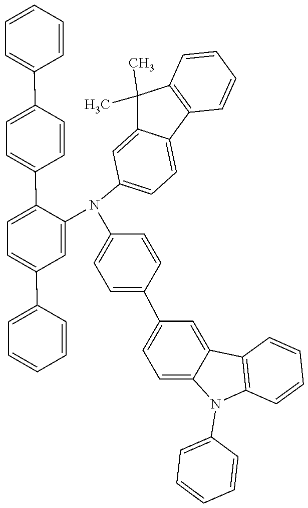 [SMILES: CC1(C)c2ccccc2-c2ccc(N(c3ccc(-c4ccc5c(c4)c4ccccc4n5-c4ccccc4)cc3)c3cc(-c4ccccc4)ccc3-c3ccc(-c4ccccc4)cc3)cc21]
HT-23 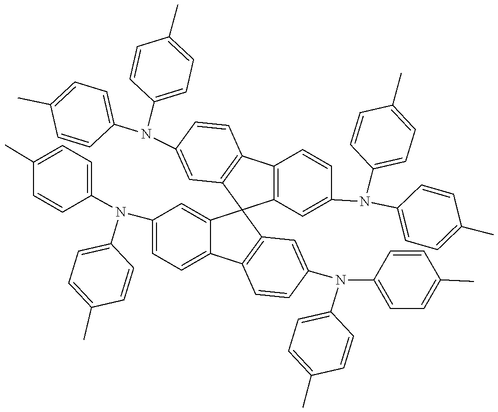
HT-24 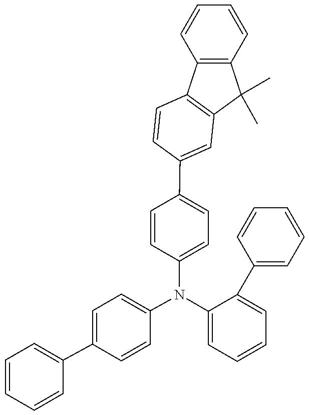 [SMILES: CC1(C)c2ccccc2-c2ccc(-c3ccc(N(c4ccc(-c5ccccc5)cc4)c4ccccc4-c4ccccc4)cc3)cc21]
HT-25 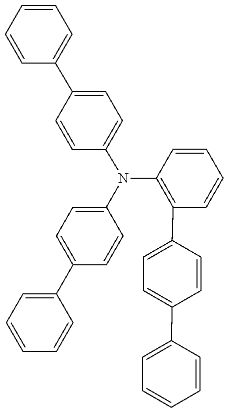 [SMILES: c1ccc(-c2ccc(-c3ccccc3N(c3ccc(-c4ccccc4)cc3)c3ccc(-c4ccccc4)cc3)cc2)cc1]
HT-26 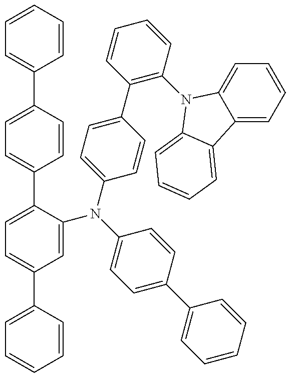 [SMILES: c1ccc(-c2ccc(-c3ccc(-c4ccccc4)cc3N(c3ccc(-c4ccccc4)cc3)c3ccc(-c4ccccc4-n4c5ccccc5c5ccccc54)cc3)cc2)cc1]
HT-27 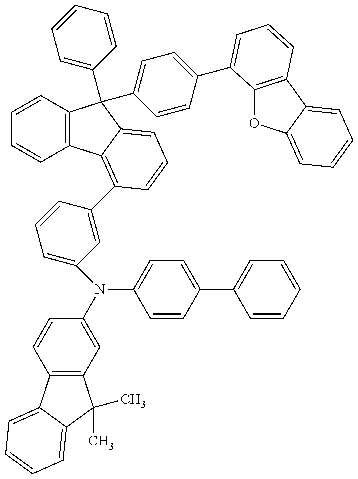 [SMILES: CC1(C)c2ccccc2-c2ccc(N(c3ccc(-c4ccccc4)cc3)c3cccc(-c4cccc5c4-c4ccccc4C5(c4ccccc4)c4ccc(-c5cccc6c5oc5ccccc56)cc4)c3)cc21]
HT-28 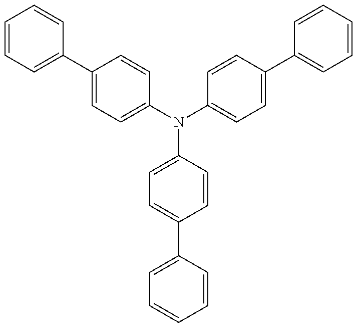 [SMILES: c1ccc(-c2ccc(N(c3ccc(-c4ccccc4)cc3)c3ccc(-c4ccccc4)cc3)cc2)cc1]
HT-29 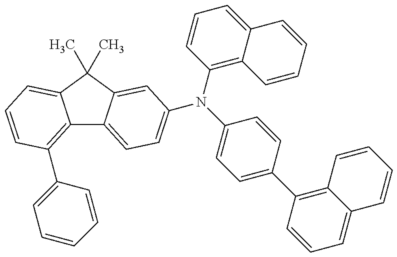 [SMILES: CC1(C)c2cc(N(c3ccc(-c4cccc5ccccc45)cc3)c3cccc4ccccc34)ccc2-c2c(-c3ccccc3)cccc21]
HT-30 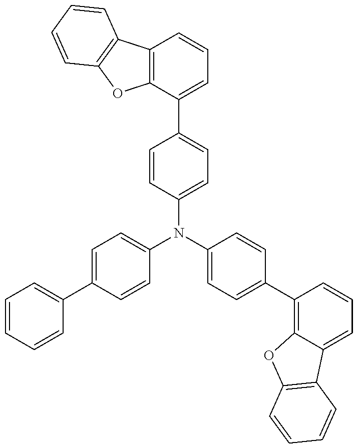 [SMILES: c1ccc(-c2ccc(N(c3ccc(-c4cccc5c4oc4ccccc45)cc3)c3ccc(-c4cccc5c4oc4ccccc45)cc3)cc2)cc1]
HT-31 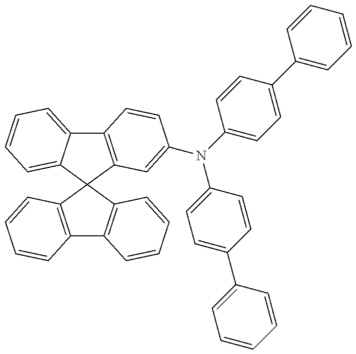 [SMILES: c1ccc(-c2ccc(N(c3ccc(-c4ccccc4)cc3)c3ccc4c(c3)C3(c5ccccc5-c5ccccc53)c3ccccc3-4)cc2)cc1]
HT-32 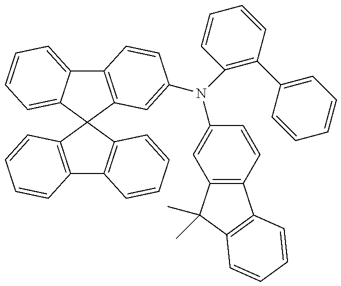 [SMILES: CC1(C)c2ccccc2-c2ccc(N(c3ccc4c(c3)C3(c5ccccc5-c5ccccc53)c3ccccc3-4)c3ccccc3-c3ccccc3)cc21]
HT-33 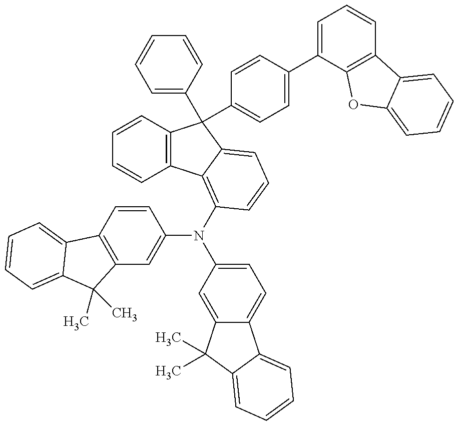 [SMILES: CC1(C)c2ccccc2-c2ccc(N(c3ccc4c(c3)C(C)(C)c3ccccc3-4)c3cccc4c3-c3ccccc3C4(c3ccccc3)c3ccc(-c4cccc5c4oc4ccccc45)cc3)cc21]
HT-34 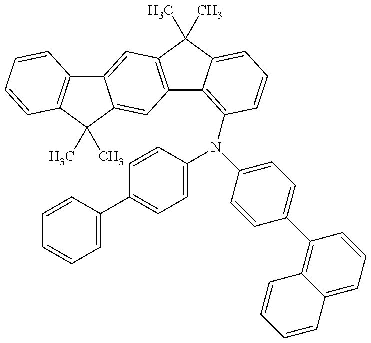 [SMILES: CC1(C)c2ccccc2-c2cc3c(cc21)-c1c(N(c2ccc(-c4ccccc4)cc2)c2ccc(-c4cccc5ccccc45)cc2)cccc1C3(C)C]
HT-35 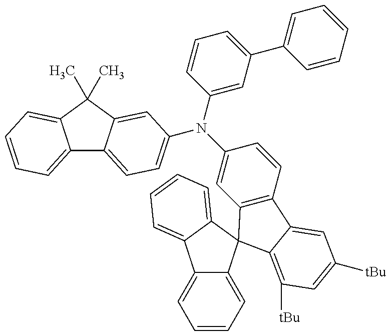 [SMILES: CC(C)(C)c1cc2c(c(C(C)(C)C)c1)C1(c3ccccc3-c3ccccc31)c1cc(N(c3cccc(-c4ccccc4)c3)c3ccc4c(c3)C(C)(C)c3ccccc3-4)ccc1-2]
HT-36 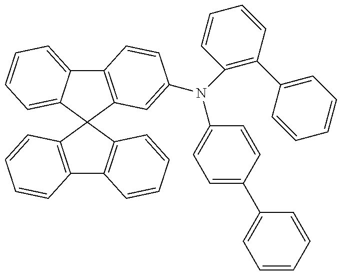 [SMILES: c1ccc(-c2ccc(N(c3ccc4c(c3)C3(c5ccccc5-c5ccccc53)c3ccccc3-4)c3ccccc3-c3ccccc3)cc2)cc1]
HT-37 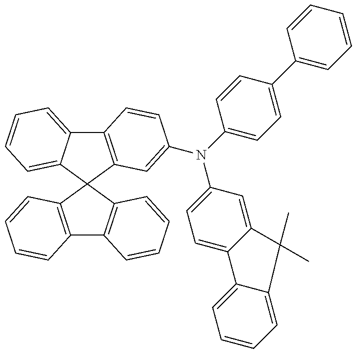 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21]
HT-38 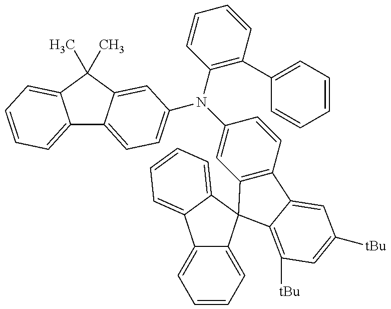 [SMILES: CC(C)(C)c1cc2c(c(C(C)(C)C)c1)C1(c3ccccc3-c3ccccc31)c1cc(N(c3ccc4c(c3)C(C)(C)c3ccccc3-4)c3ccccc3-c3ccccc3)ccc1-2]
HT-39 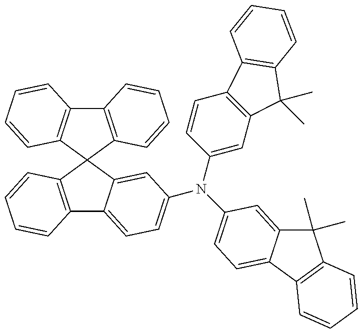 [SMILES: CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21]
HT-40 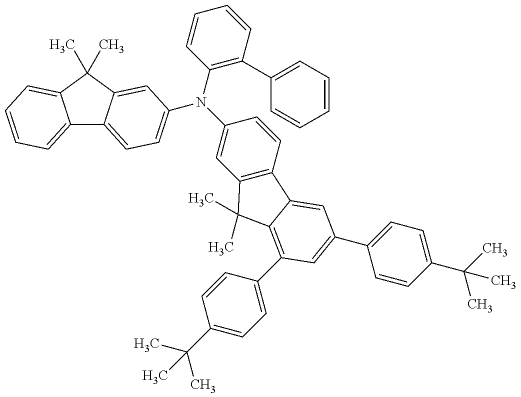 [SMILES: CC(C)(C)c1ccc(-c2cc(-c3ccc(C(C)(C)C)cc3)c3c(c2)-c2ccc(N(c4ccc5c(c4)C(C)(C)c4ccccc4-5)c4ccccc4-c4ccccc4)cc2C3(C)C)cc1]
HT-41 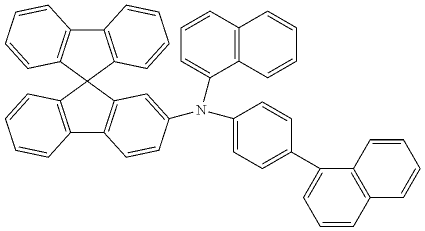 [SMILES: c1ccc2c(c1)-c1ccccc1C21c2ccccc2-c2ccc(N(c3ccc(-c4cccc5ccccc45)cc3)c3cccc4ccccc34)cc21]
HT-42 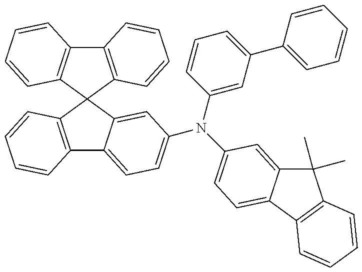 [SMILES: CC1(C)c2ccccc2-c2ccc(N(c3cccc(-c4ccccc4)c3)c3ccc4c(c3)C3(c5ccccc5-c5ccccc53)c3ccccc3-4)cc21]
HT-43 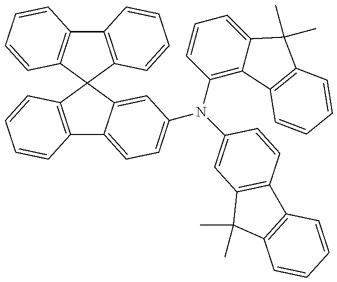 [SMILES: CC1(C)c2ccccc2-c2ccc(N(c3ccc4c(c3)C3(c5ccccc5-c5ccccc53)c3ccccc3-4)c3cccc4c3-c3ccccc3C4(C)C)cc21]
HT-44 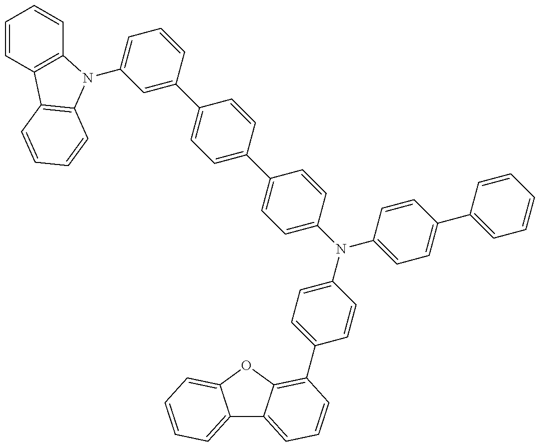 [SMILES: c1ccc(-c2ccc(N(c3ccc(-c4ccc(-c5cccc(-n6c7ccccc7c7ccccc76)c5)cc4)cc3)c3ccc(-c4cccc5c4oc4ccccc45)cc3)cc2)cc1]
HT-45 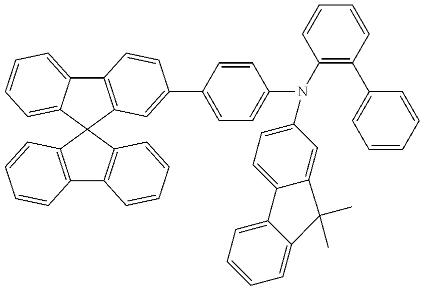 [SMILES: CC1(C)c2ccccc2-c2ccc(N(c3ccc(-c4ccc5c(c4)C4(c6ccccc6-c6ccccc64)c4ccccc4-5)cc3)c3ccccc3-c3ccccc3)cc21]
HT-46 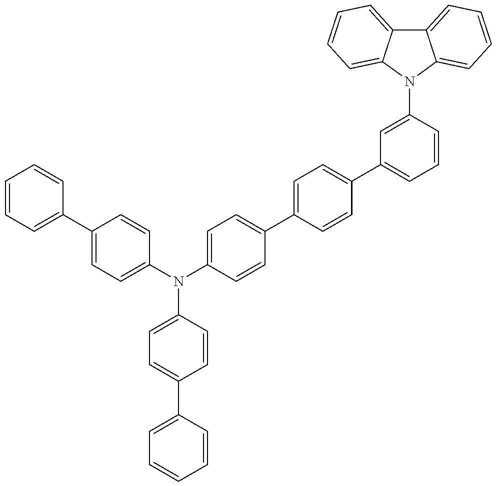 [SMILES: c1ccc(-c2ccc(N(c3ccc(-c4ccccc4)cc3)c3ccc(-c4ccc(-c5cccc(-n6c7ccccc7c7ccccc76)c5)cc4)cc3)cc2)cc1]
HT-47 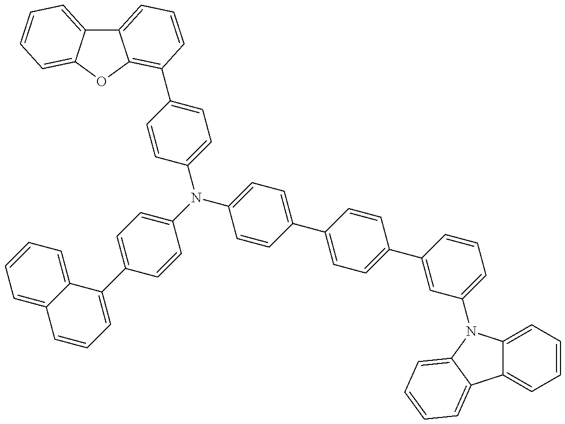 [SMILES: c1cc(-c2ccc(-c3ccc(N(c4ccc(-c5cccc6ccccc56)cc4)c4ccc(-c5cccc6c5oc5ccccc56)cc4)cc3)cc2)cc(-n2c3ccccc3c3ccccc32)c1]
HT-48 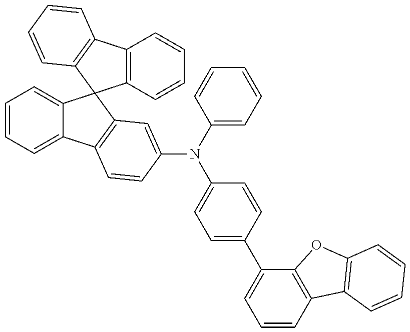 [SMILES: c1ccc(N(c2ccc(-c3cccc4c3oc3ccccc34)cc2)c2ccc3c(c2)C2(c4ccccc4-c4ccccc42)c2ccccc2-3)cc1]
HT-49 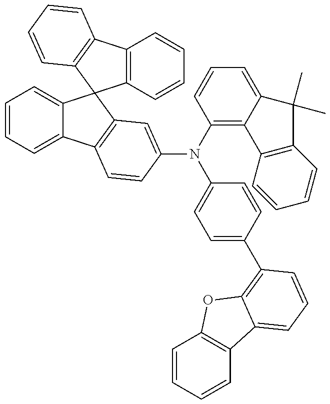 [SMILES: CC1(C)c2ccccc2-c2c(N(c3ccc(-c4cccc5c4oc4ccccc45)cc3)c3ccc4c(c3)C3(c5ccccc5-c5ccccc53)c3ccccc3-4)cccc21]
HT-50 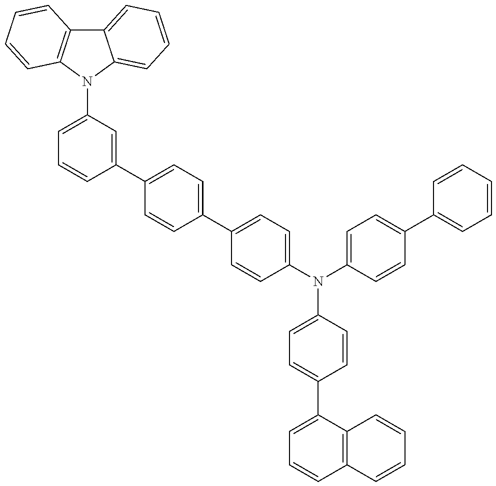 [SMILES: c1ccc(-c2ccc(N(c3ccc(-c4ccc(-c5cccc(-n6c7ccccc7c7ccccc76)c5)cc4)cc3)c3ccc(-c4cccc5ccccc45)cc3)cc2)cc1]
HT-51 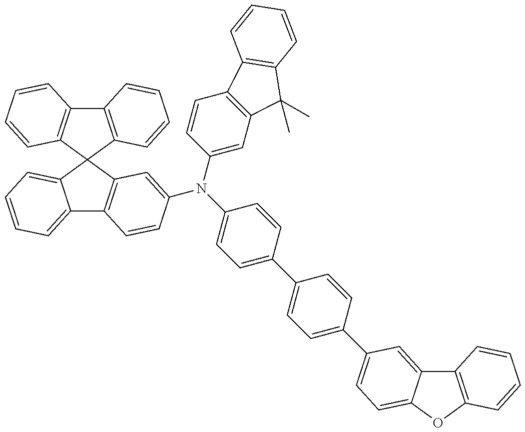 [SMILES: CC1(C)c2ccccc2-c2ccc(N(c3ccc(-c4ccc(-c5ccc6oc7ccccc7c6c5)cc4)cc3)c3ccc4c(c3)C3(c5ccccc5-c5ccccc53)c3ccccc3-4)cc21]
HT-52 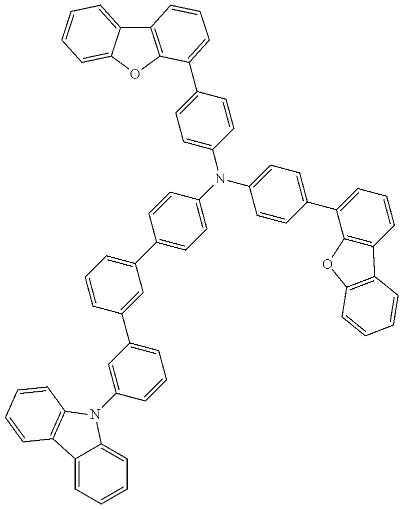 [SMILES: c1cc(-c2ccc(N(c3ccc(-c4cccc5c4oc4ccccc45)cc3)c3ccc(-c4cccc5c4oc4ccccc45)cc3)cc2)cc(-c2cccc(-n3c4ccccc4c4ccccc43)c2)c1]
HT-53 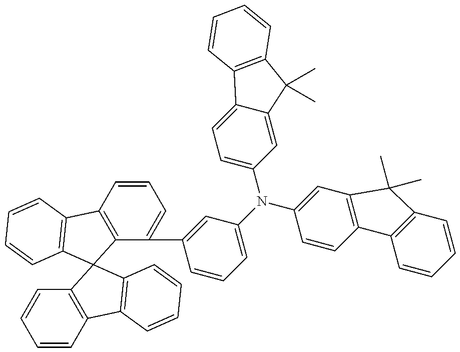 [SMILES: CC1(C)c2ccccc2-c2ccc(N(c3cccc(-c4cccc5c4C4(c6ccccc6-c6ccccc64)c4ccccc4-5)c3)c3ccc4c(c3)C(C)(C)c3ccccc3-4)cc21]
HT-54 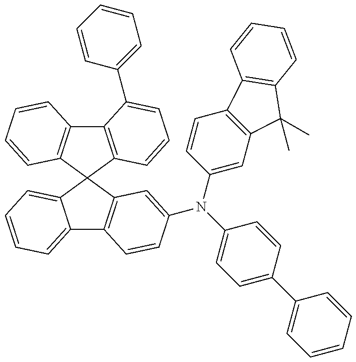 [SMILES: CC1(C)c2ccccc2-c2ccc(N(c3ccc(-c4ccccc4)cc3)c3ccc4c(c3)C3(c5ccccc5-4)c4ccccc4-c4c(-c5ccccc5)cccc43)cc21]
HT-55 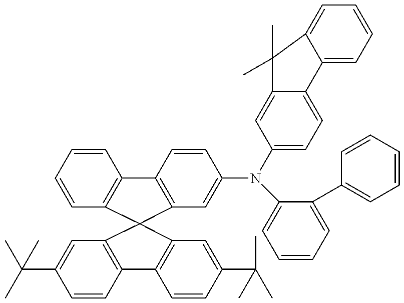 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]
HT-56 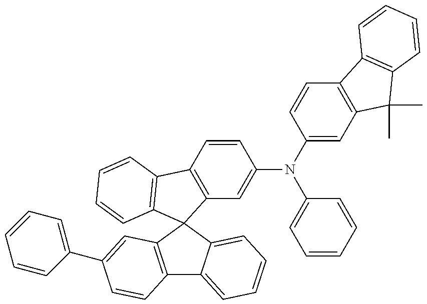 [SMILES: CC1(C)c2ccccc2-c2ccc(N(c3ccccc3)c3ccc4c(c3)C3(c5ccccc5-c5ccc(-c6ccccc6)cc53)c3ccccc3-4)cc21]
HT-57 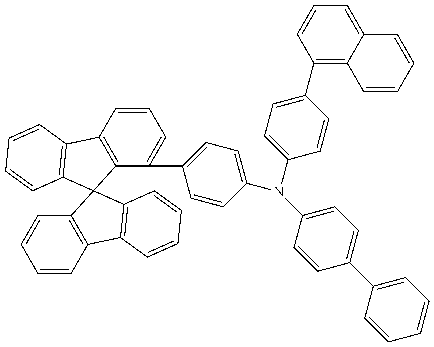 [SMILES: c1ccc(-c2ccc(N(c3ccc(-c4cccc5c4C4(c6ccccc6-c6ccccc64)c4ccccc4-5)cc3)c3ccc(-c4cccc5ccccc45)cc3)cc2)cc1]
HT-58 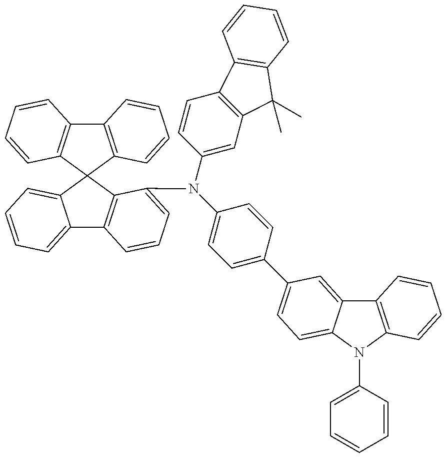 [SMILES: CC1(C)c2ccccc2-c2ccc(N(c3ccc(-c4ccc5c(c4)c4ccccc4n5-c4ccccc4)cc3)c3cccc4c3C3(c5ccccc5-c5ccccc53)c3ccccc3-4)cc21]
HT-59 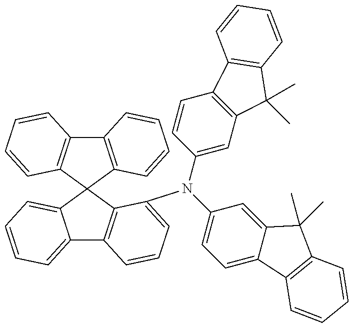 [SMILES: CC1(C)c2ccccc2-c2ccc(N(c3ccc4c(c3)C(C)(C)c3ccccc3-4)c3cccc4c3C3(c5ccccc5-c5ccccc53)c3ccccc3-4)cc21]
HT-60 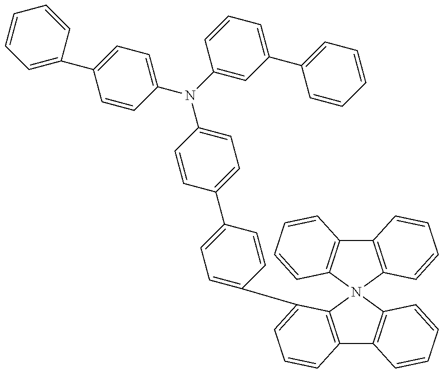
HT-61 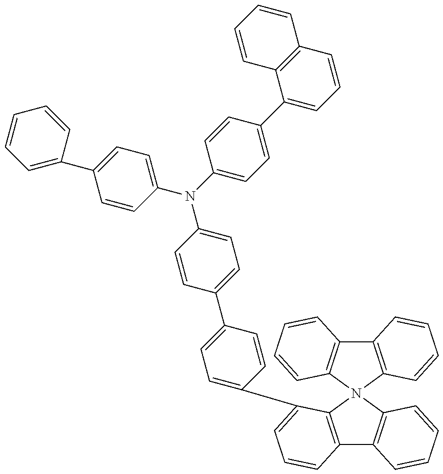
HT-62 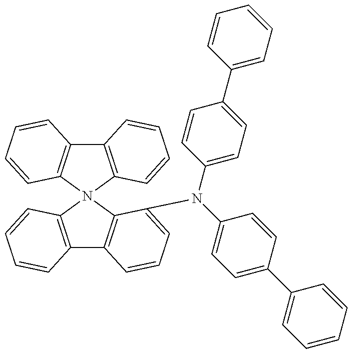
HT-63 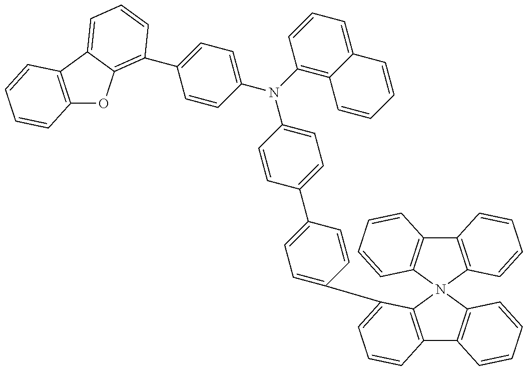
HT-64 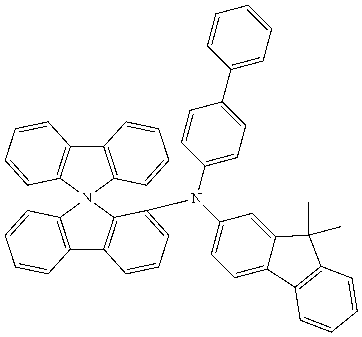
HT-65 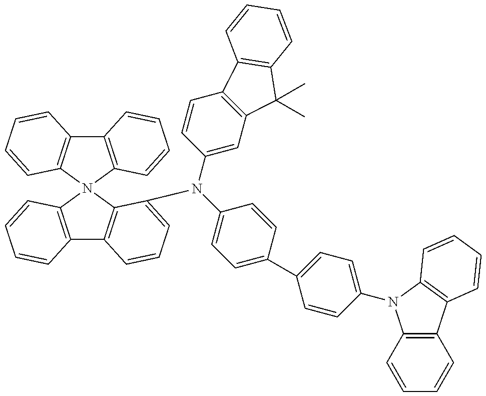
HT-66 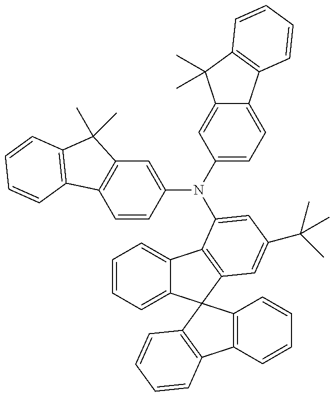 [SMILES: CC(C)(C)c1cc(N(c2ccc3c(c2)C(C)(C)c2ccccc2-3)c2ccc3c(c2)C(C)(C)c2ccccc2-3)c2c(c1)C1(c3ccccc3-c3ccccc31)c1ccccc1-2]
HT-67 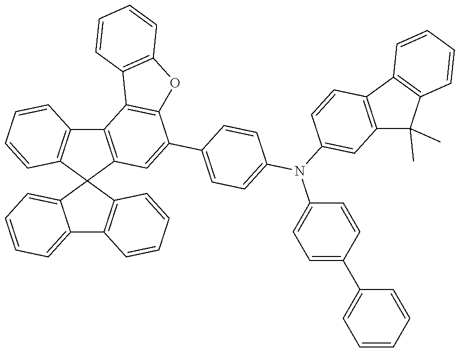 [SMILES: CC1(C)c2ccccc2-c2ccc(N(c3ccc(-c4ccccc4)cc3)c3ccc(-c4cc5c(c6c4oc4ccccc46)-c4ccccc4C54c5ccccc5-c5ccccc54)cc3)cc21]
HT-68 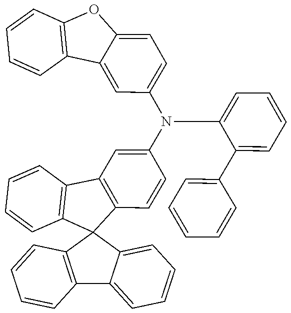 [SMILES: c1ccc(-c2ccccc2N(c2ccc3c(c2)-c2ccccc2C32c3ccccc3-c3ccccc32)c2ccc3oc4ccccc4c3c2)cc1]
HT-69 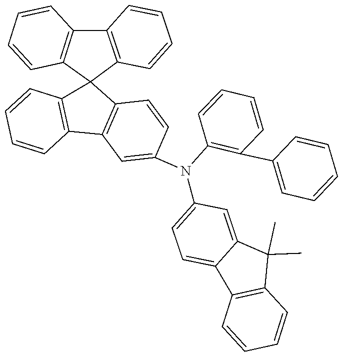 [SMILES: CC1(C)c2ccccc2-c2ccc(N(c3ccc4c(c3)-c3ccccc3C43c4ccccc4-c4ccccc43)c3ccccc3-c3ccccc3)cc21]
HT-70 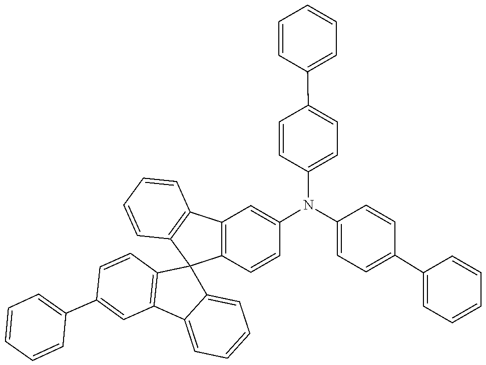 [SMILES: c1ccc(-c2ccc(N(c3ccc(-c4ccccc4)cc3)c3ccc4c(c3)-c3ccccc3C43c4ccccc4-c4cc(-c5ccccc5)ccc43)cc2)cc1]
HT-71 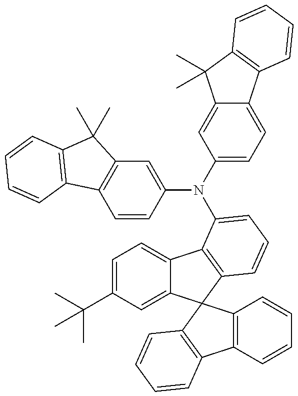 [SMILES: CC(C)(C)c1ccc2c(c1)C1(c3ccccc3-c3ccccc31)c1cccc(N(c3ccc4c(c3)C(C)(C)c3ccccc3-4)c3ccc4c(c3)C(C)(C)c3ccccc3-4)c1-2]
HT-72 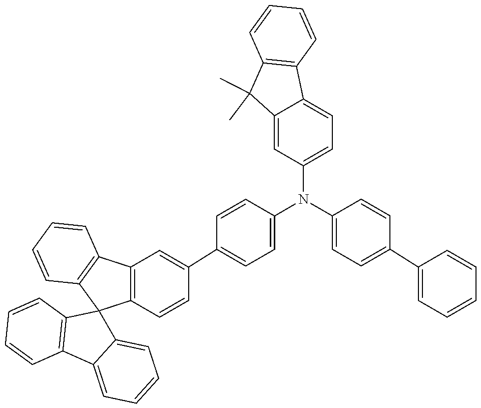 [SMILES: CC1(C)c2ccccc2-c2ccc(N(c3ccc(-c4ccccc4)cc3)c3ccc(-c4ccc5c(c4)-c4ccccc4C54c5ccccc5-c5ccccc54)cc3)cc21]
HT-73 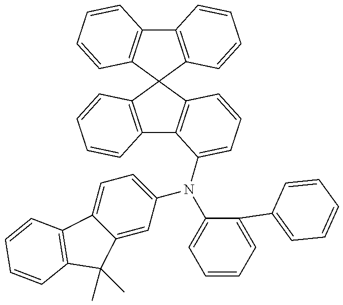 [SMILES: CC1(C)c2ccccc2-c2ccc(N(c3ccccc3-c3ccccc3)c3cccc4c3-c3ccccc3C43c4ccccc4-c4ccccc43)cc21]
HT-74 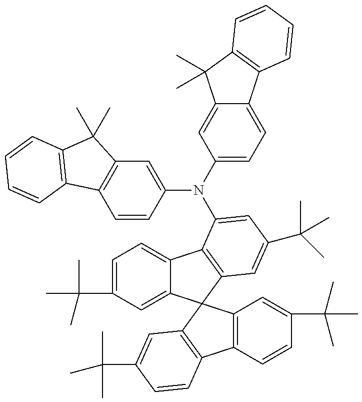 [SMILES: CC(C)(C)c1ccc2c(c1)C1(c3cc(C(C)(C)C)ccc3-2)c2cc(C(C)(C)C)ccc2-c2c(N(c3ccc4c(c3)C(C)(C)c3ccccc3-4)c3ccc4c(c3)C(C)(C)c3ccccc3-4)cc(C(C)(C)C)cc21]
HT-75 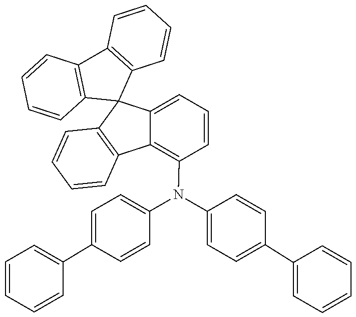 [SMILES: c1ccc(-c2ccc(N(c3ccc(-c4ccccc4)cc3)c3cccc4c3-c3ccccc3C43c4ccccc4-c4ccccc43)cc2)cc1]
HT-76 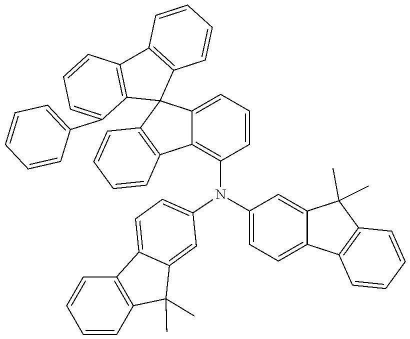 [SMILES: CC1(C)c2ccccc2-c2ccc(N(c3ccc4c(c3)C(C)(C)c3ccccc3-4)c3cccc4c3-c3ccccc3C43c4ccccc4-c4cccc(-c5ccccc5)c43)cc21]
HT-77 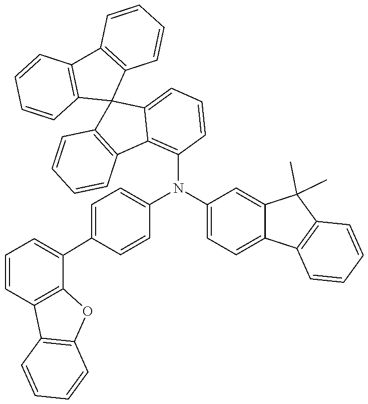 [SMILES: CC1(C)c2ccccc2-c2ccc(N(c3ccc(-c4cccc5c4oc4ccccc45)cc3)c3cccc4c3-c3ccccc3C43c4ccccc4-c4ccccc43)cc21]
HT-78 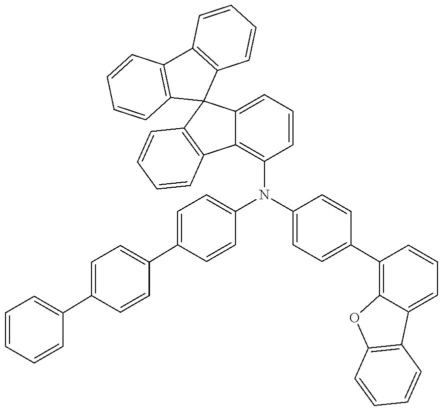 [SMILES: c1ccc(-c2ccc(-c3ccc(N(c4ccc(-c5cccc6c5oc5ccccc56)cc4)c4cccc5c4-c4ccccc4C54c5ccccc5-c5ccccc54)cc3)cc2)cc1]
HT-79 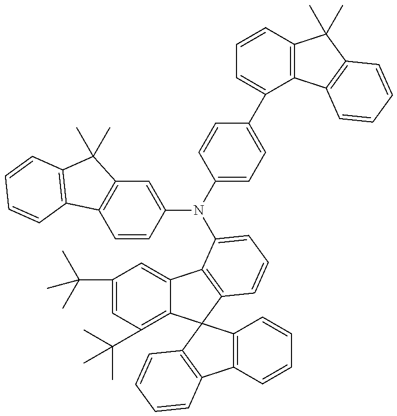 [SMILES: CC(C)(C)c1cc2c(c(C(C)(C)C)c1)C1(c3ccccc3-c3ccccc31)c1cccc(N(c3ccc(-c4cccc5c4-c4ccccc4C5(C)C)cc3)c3ccc4c(c3)C(C)(C)c3ccccc3-4)c1-2]
HT-80 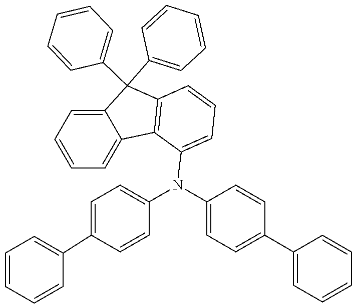 [SMILES: c1ccc(-c2ccc(N(c3ccc(-c4ccccc4)cc3)c3cccc4c3-c3ccccc3C4(c3ccccc3)c3ccccc3)cc2)cc1]
HT-81 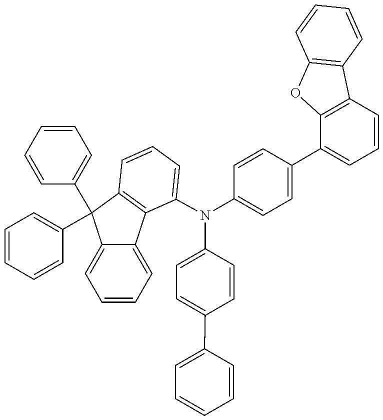 [SMILES: c1ccc(-c2ccc(N(c3ccc(-c4cccc5c4oc4ccccc45)cc3)c3cccc4c3-c3ccccc3C4(c3ccccc3)c3ccccc3)cc2)cc1]
HT-82 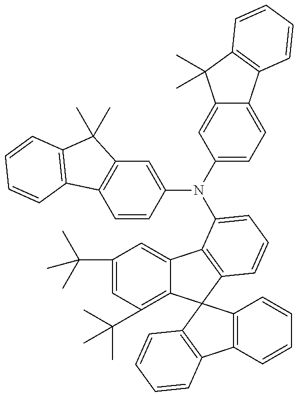 [SMILES: CC(C)(C)c1cc2c(c(C(C)(C)C)c1)C1(c3ccccc3-c3ccccc31)c1cccc(N(c3ccc4c(c3)C(C)(C)c3ccccc3-4)c3ccc4c(c3)C(C)(C)c3ccccc3-4)c1-2]
HT-83 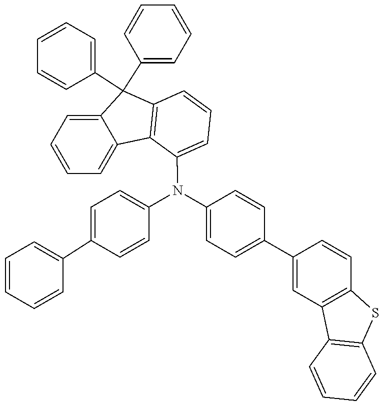 [SMILES: c1ccc(-c2ccc(N(c3ccc(-c4ccc5sc6ccccc6c5c4)cc3)c3cccc4c3-c3ccccc3C4(c3ccccc3)c3ccccc3)cc2)cc1]
HT-84 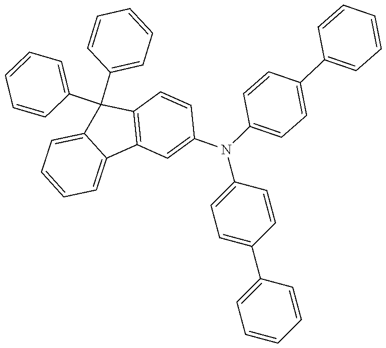 [SMILES: c1ccc(-c2ccc(N(c3ccc(-c4ccccc4)cc3)c3ccc4c(c3)-c3ccccc3C4(c3ccccc3)c3ccccc3)cc2)cc1]
HT-85 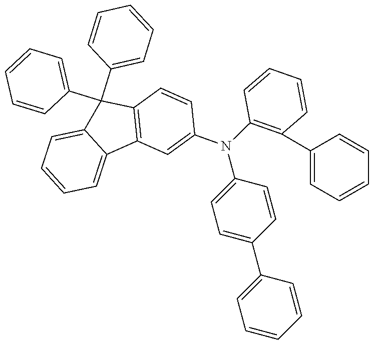 [SMILES: c1ccc(-c2ccc(N(c3ccc4c(c3)-c3ccccc3C4(c3ccccc3)c3ccccc3)c3ccccc3-c3ccccc3)cc2)cc1]
HT-86 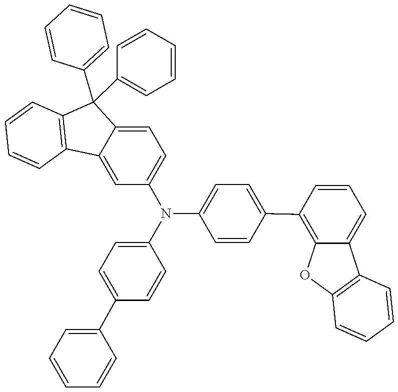 [SMILES: c1ccc(-c2ccc(N(c3ccc(-c4cccc5c4oc4ccccc45)cc3)c3ccc4c(c3)-c3ccccc3C4(c3ccccc3)c3ccccc3)cc2)cc1]
HT-87 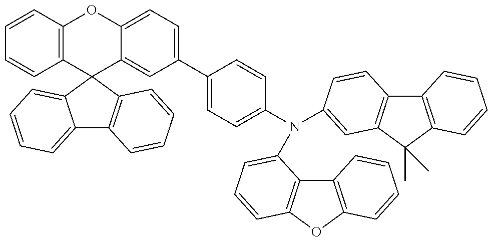 [SMILES: CC1(C)c2ccccc2-c2ccc(N(c3ccc(-c4ccc5c(c4)C4(c6ccccc6O5)c5ccccc5-c5ccccc54)cc3)c3cccc4oc5ccccc5c34)cc21]
HT-88 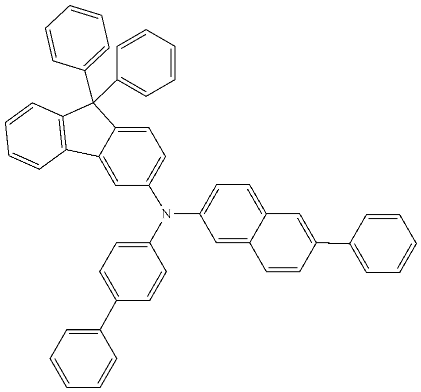 [SMILES: c1ccc(-c2ccc(N(c3ccc4c(c3)-c3ccccc3C4(c3ccccc3)c3ccccc3)c3ccc4cc(-c5ccccc5)ccc4c3)cc2)cc1]
HT-89 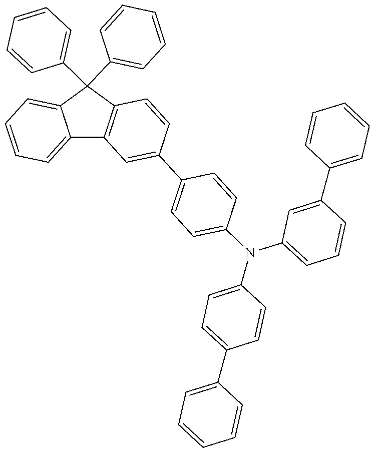 [SMILES: c1ccc(-c2ccc(N(c3ccc(-c4ccc5c(c4)-c4ccccc4C5(c4ccccc4)c4ccccc4)cc3)c3cccc(-c4ccccc4)c3)cc2)cc1]
HT-90 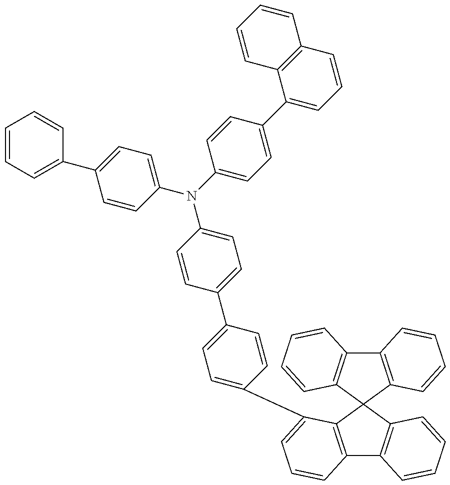 [SMILES: c1ccc(-c2ccc(N(c3ccc(-c4ccc(-c5cccc6c5C5(c7ccccc7-c7ccccc75)c5ccccc5-6)cc4)cc3)c3ccc(-c4cccc5ccccc45)cc3)cc2)cc1]
HT-91 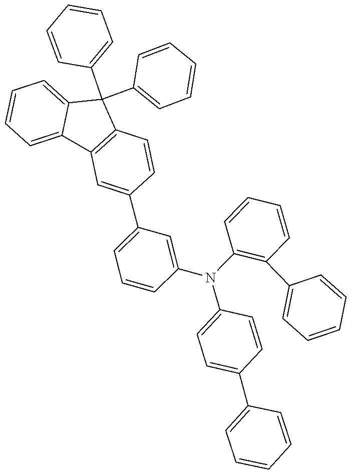 [SMILES: c1ccc(-c2ccc(N(c3cccc(-c4ccc5c(c4)-c4ccccc4C5(c4ccccc4)c4ccccc4)c3)c3ccccc3-c3ccccc3)cc2)cc1]
HT-92 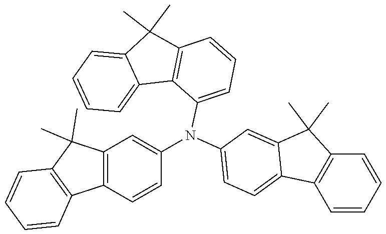 [SMILES: CC1(C)c2ccccc2-c2ccc(N(c3ccc4c(c3)C(C)(C)c3ccccc3-4)c3cccc4c3-c3ccccc3C4(C)C)cc21]
HT-93 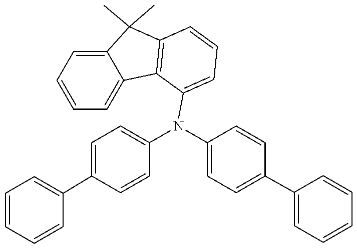 [SMILES: CC1(C)c2ccccc2-c2c(N(c3ccc(-c4ccccc4)cc3)c3ccc(-c4ccccc4)cc3)cccc21]
HT-94 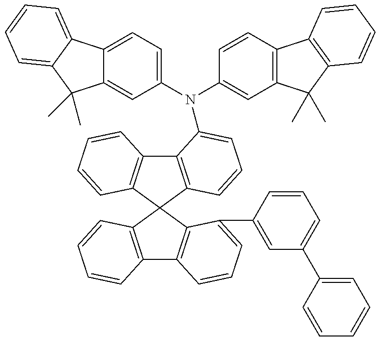 [SMILES: CC1(C)c2ccccc2-c2ccc(N(c3ccc4c(c3)C(C)(C)c3ccccc3-4)c3cccc4c3-c3ccccc3C43c4ccccc4-c4cccc(-c5cccc(-c6ccccc6)c5)c43)cc21]
HT-95 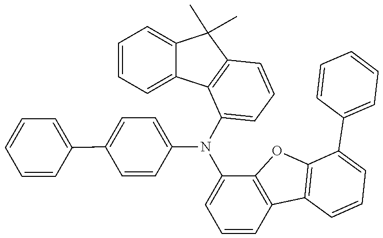 [SMILES: CC1(C)c2ccccc2-c2c(N(c3ccc(-c4ccccc4)cc3)c3cccc4c3oc3c(-c5ccccc5)cccc34)cccc21]
HT-96 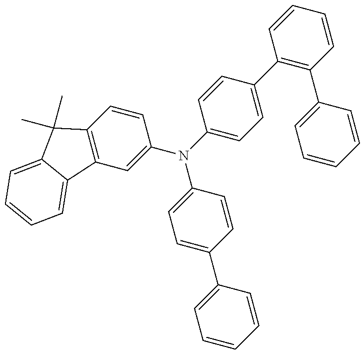 [SMILES: CC1(C)c2ccccc2-c2cc(N(c3ccc(-c4ccccc4)cc3)c3ccc(-c4ccccc4-c4ccccc4)cc3)ccc21]
HT-97 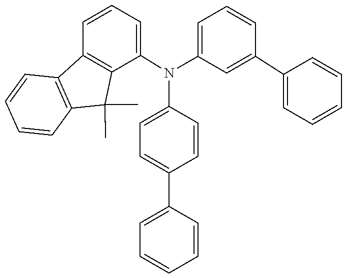 [SMILES: CC1(C)c2ccccc2-c2cccc(N(c3ccc(-c4ccccc4)cc3)c3cccc(-c4ccccc4)c3)c21]
HT-98 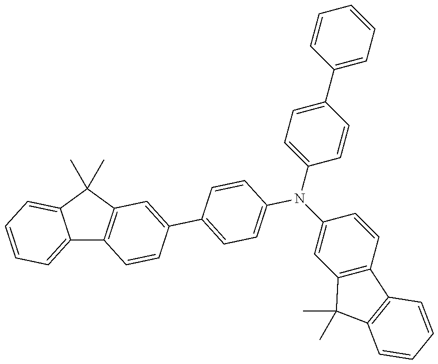 [SMILES: CC1(C)c2ccccc2-c2ccc(-c3ccc(N(c4ccc(-c5ccccc5)cc4)c4ccc5c(c4)C(C)(C)c4ccccc4-5)cc3)cc21]
HT-99 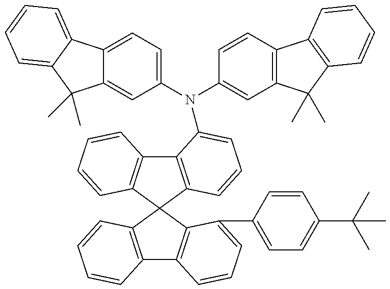 [SMILES: CC(C)(C)c1ccc(-c2cccc3c2C2(c4ccccc4-3)c3ccccc3-c3c(N(c4ccc5c(c4)C(C)(C)c4ccccc4-5)c4ccc5c(c4)C(C)(C)c4ccccc4-5)cccc32)cc1]
HT-100 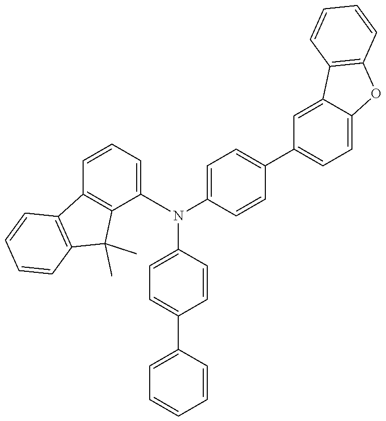 [SMILES: CC1(C)c2ccccc2-c2cccc(N(c3ccc(-c4ccccc4)cc3)c3ccc(-c4ccc5oc6ccccc6c5c4)cc3)c21]
HT-101 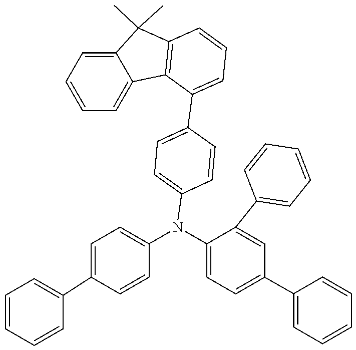 [SMILES: CC1(C)c2ccccc2-c2c(-c3ccc(N(c4ccc(-c5ccccc5)cc4)c4ccc(-c5ccccc5)cc4-c4ccccc4)cc3)cccc21]
HT-102 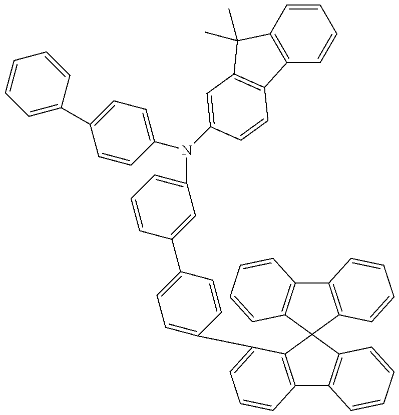 [SMILES: CC1(C)c2ccccc2-c2ccc(N(c3ccc(-c4ccccc4)cc3)c3cccc(-c4ccc(-c5cccc6c5C5(c7ccccc7-c7ccccc75)c5ccccc5-6)cc4)c3)cc21]
HT-103 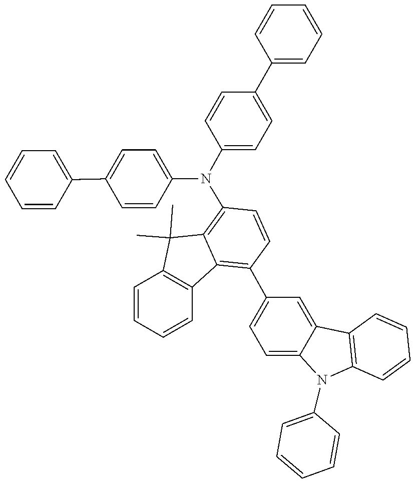 [SMILES: CC1(C)c2ccccc2-c2c(-c3ccc4c(c3)c3ccccc3n4-c3ccccc3)ccc(N(c3ccc(-c4ccccc4)cc3)c3ccc(-c4ccccc4)cc3)c21]
HT-104 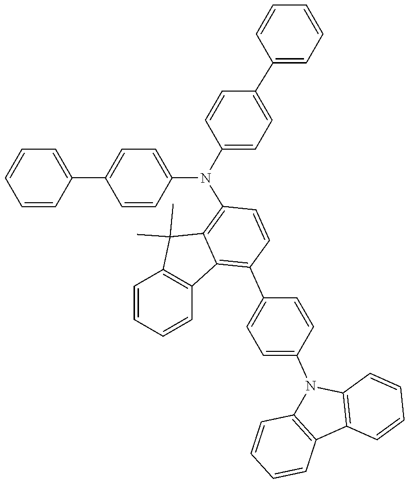 [SMILES: CC1(C)c2ccccc2-c2c(-c3ccc(-n4c5ccccc5c5ccccc54)cc3)ccc(N(c3ccc(-c4ccccc4)cc3)c3ccc(-c4ccccc4)cc3)c21]
HT-105 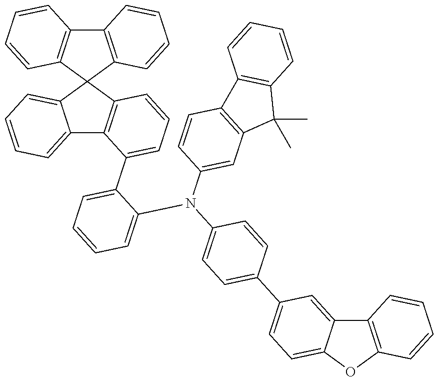 [SMILES: CC1(C)c2ccccc2-c2ccc(N(c3ccc(-c4ccc5oc6ccccc6c5c4)cc3)c3ccccc3-c3cccc4c3-c3ccccc3C43c4ccccc4-c4ccccc43)cc21]
HT-106 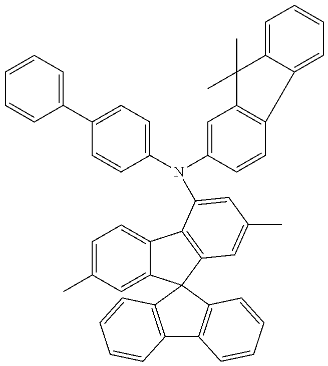 [SMILES: Cc1ccc2c(c1)C1(c3ccccc3-c3ccccc31)c1cc(C)cc(N(c3ccc(-c4ccccc4)cc3)c3ccc4c(c3)C(C)(C)c3ccccc3-4)c1-2]
HT-107 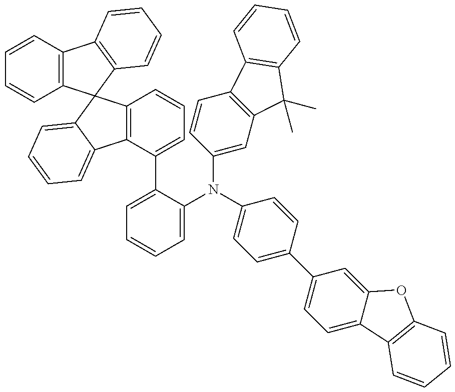 [SMILES: CC1(C)c2ccccc2-c2ccc(N(c3ccc(-c4ccc5c(c4)oc4ccccc45)cc3)c3ccccc3-c3cccc4c3-c3ccccc3C43c4ccccc4-c4ccccc43)cc21]
HT-108 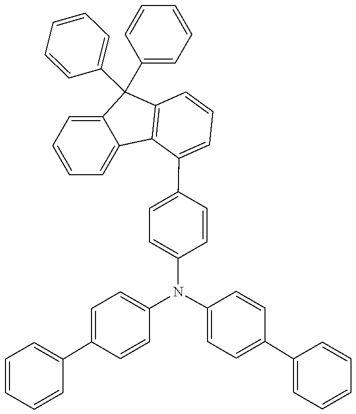 [SMILES: c1ccc(-c2ccc(N(c3ccc(-c4ccccc4)cc3)c3ccc(-c4cccc5c4-c4ccccc4C5(c4ccccc4)c4ccccc4)cc3)cc2)cc1]
HT-109 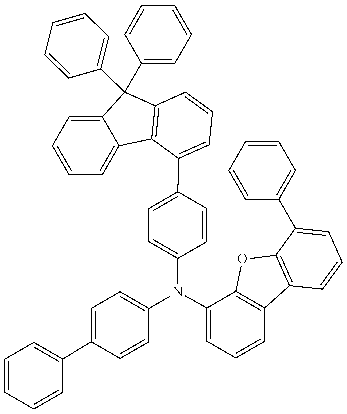 [SMILES: c1ccc(-c2ccc(N(c3ccc(-c4cccc5c4-c4ccccc4C5(c4ccccc4)c4ccccc4)cc3)c3cccc4c3oc3c(-c5ccccc5)cccc34)cc2)cc1]
HT-110

The sequence of layers in the organic electroluminescent device of the invention is preferably as follows:
anode/hole injection layer/hole transport layer/emitting layer/electron transport layer/electron injection layer/cathode.

This sequence of the layers is a preferred sequence.

At the same time, it should be pointed out again that not all the layers mentioned need be present and/or that further layers may additionally be present.

The organic electroluminescent device of the invention may contain two or more emitting layers. At least one of the emitting layers is the light-emitting layer of the invention containing at least one compound of the formula (1) as host material 1 and at least one compound of the formula (2) as host material 2 as described above or described as preferred. It is particularly preferable when these emission layers in this case altogether exhibit several emission maxima between 380 nm and 750 nm, so that the overall result is white emission.

Materials used for the electron transport layer may be any materials as used according to the prior art as electron transport materials in the electron transport layer. Especially suitable are aluminum complexes, for example Alq₃, zirconium complexes, for example Zrq₄, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives.

Suitable cathodes of the device of the invention are metals having a low work function, metal alloys or multilayer structures composed of various metals, for example alkaline earth metals, alkali metals, main group metals or lanthanoids (e.g. Ca, Ba, Mg, Al, In, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO).

Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

The organic electroluminescent device of the invention, in the course of production, is appropriately (according to the application) structured, contact-connected and finally sealed, since the lifetime of the devices of the invention is shortened in the presence of water and/or air.

The production of the device of the invention is not restricted here. It is possible that one or more organic layers, including the light-emitting layer, are coated by a sublimation method. In this case, the materials are applied by vapor deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

The organic electroluminescent device of the invention is preferably characterized in that one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and thus structured (for example M. S. Arnold et al., Appl. Phys. Lett. 2008, 92, 053301).

The organic electroluminescent device of the invention is further preferably characterized in that one or more organic layers comprising the composition of the invention are produced from solution, for example by spin-coating, or by any printing method, for example screen printing, flexographic printing, nozzle printing or offset printing, but more preferably LITI (light-induced thermal imaging, thermal transfer printing) or inkjet printing. For this purpose, soluble host materials 1 and 2 and phosphorescent emitters are needed. Processing from solution has the advantage that, for example, the light-emitting layer can be applied in a very simple and inexpensive manner. This technique is especially suitable for the mass production of organic electroluminescent devices.

In addition, hybrid methods are possible, in which, for example, one or more layers are applied from solution and one or more further layers are applied by vapor deposition. These methods are known in general terms to those skilled in the art and can be applied to organic electroluminescent devices.

The invention therefore further provides a process for producing the organic electroluminescent device of the invention as described above or described as preferred, characterized in that the organic layer, preferably the light-emitting layer, the hole injection layer and/or hole transport layer, is applied by gas phase deposition, especially by a sublimation method and/or by an OVPD (organic vapor phase deposition) method and/or with the aid of a carrier gas sublimation, or from solution, especially by spin-coating or by a printing method.

In the case of production by means of gas phase deposition, there are in principle two ways in which the organic layer, preferably the light-emitting layer, of the invention can be applied or vapor-deposited onto any substrate or the prior layer. Firstly, the materials used can each be initially charged in a material source and ultimately evaporated from the different material sources (“co-evaporation”). Secondly, the various materials can be premixed (premix systems) and the mixture can be initially charged in a single material source from which it is ultimately evaporated (“premix evaporation”). In this way, it is possible in a simple and rapid manner to achieve the vapor deposition of the light-emitting layer with homogeneous distribution of the components without the need for precise actuation of a multitude of material sources.

The invention accordingly further provides a process for producing the device of the invention, characterized in that the at least one compound of the formula (1) as described above or described as preferred and the at least one compound of the formula (2) as described above or described as preferred are deposited from the gas phase successively or simultaneously from at least two material sources, optionally with the at least one phosphorescent emitter as described above or described as preferred, and form the light-emitting layer.

In a preferred embodiment of the present invention, the light-emitting layer is applied by means of gas phase deposition, wherein the constituents of the composition are premixed and evaporated from a single material source.

The invention accordingly further provides a process for producing the device of the invention, characterized in that the at least one compound of the formula (1) and the at least one compound of the formula (2) are deposited from the gas phase as a mixture, successively or simultaneously with the at least one phosphorescent emitter, and form the light-emitting layer.

The invention further provides a process for producing the device of the invention as described above or described as preferred, characterized in that the at least one compound of the formula (1) and the at least one compound of the formula (2) as described above or described as preferred are applied from solution together with the at least one phosphorescent emitter in order to form the light-emitting layer.

The devices of the invention feature the following surprising advantages over the prior art:

The use of the described material combination of host materials 1 and 2 as described above especially leads to an increase in the lifetime of the devices.

It is known that the C-D bond is shorter than the C—H bond as a result of the anharmonicity of the bond stretch potential (M. L. Allinger and H. L. Flanagan, J. Computa nationale Chem. 1983, 4 (3), 399). This means that the chemical bond of carbon to deuterium is stronger, more stable and slower to react than the chemical carbon-hydrogen bond. When a deuterated organic system is used, by comparison with the non-deuterated organic system, the expectation is generally that thermal stability will be better and there will be a longer lifetime for the optoelectronic device. The replacement of labile C—H bonds by C-D bonds in an organic functional material increases the lifetime of the corresponding device generally by a factor of 1.5-3 without loss of efficiency.

As apparent in the example given hereinafter, it is possible to determine by comparison of the data for OLEDs with combinations from the prior art that the inventive combinations of matrix materials in the EML lead to devices having a significantly increased lifetime and/or luminance, irrespective of the emitter concentration, without such an increase in lifetime being expected by the person skilled in the art. At the same time, the devices of the invention are more thermally stable, and there is a distinct reduction in the unwanted side reaction of carbazole formation of the host material 2 by cyclization reaction in the light-emitting layer during the operation of the device.

Other reasons for the benefits of the combination of host materials 1 and 2 as described above are the specific structural selection of these host materials 1 and 2 from the prior art, especially the selection of the host material 2 or of the preferred embodiments of the host material 2, where the deuteration additionally enhances this effect.

It should be pointed out that variations of the embodiments described in the present invention are covered by the scope of this invention. Any feature disclosed in the present invention may, unless this is explicitly ruled out, be exchanged for alternative features which serve the same purpose or an equivalent or similar purpose. Any feature disclosed in the present invention, unless stated otherwise, should therefore be considered as an example from a generic series or as an equivalent or similar feature.

All features of the present invention may be combined with one another in any manner, unless particular features and/or steps are mutually exclusive. This is especially true of preferred features of the present invention. Equally, features of non-essential combinations may be used separately (and not in combination).

The technical teaching disclosed with the present invention may be abstracted and combined with other examples.

The invention is illustrated in detail by the examples which follow, without any intention of restricting it thereby.

### EXAMPLES

### General Methods

In all quantum-chemical calculations, the Gaussian16 (Rev. B.01) software package is used. The neutral singlet ground state is optimized at the B3LYP/6-31G (d) level. HOMO and LUMO values are determined at the B3LYP/6-31G (d) level for the B3LYP/6-31G (d)-optimized ground state energy. Then TD-DFT singlet and triplet excitations (vertical excitations) are calculated by the same method (B3LYP/6-31G (d)) and with the optimized ground state geometry. The standard settings for SCF and gradient convergence are used.

From the energy calculation, the HOMO is obtained as the last orbital occupied by two electrons (alpha occ. eigenvalues) and LUMO as the first unoccupied orbital (alpha virt. eigenvalues) in Hartree units, where HEh and LEh represent the HOMO energy in Hartree units and the LUMO energy in Hartree units respectively. This is used to determine the HOMO and LUMO value in electron volts, calibrated by cyclic voltammetry measurements, as follows:

HOMOcorr=0.90603*HOMO−0.84836

LUMOcorr=0.99687*LUMO−0.72445

The triplet level T1 of a material is defined as the relative excitation energy (in eV) of the triplet state having the lowest energy which is found by the quantum-chemical energy calculation.

The singlet level S1 of a material is defined as the relative excitation energy (in eV) of the singlet state having the second-lowest energy which is found by the quantum-chemical energy calculation.

The energetically lowest singlet state is referred to as SO.

The method described herein is independent of the software package used and always gives the same results. Examples of frequently utilized programs for this purpose are “Gaussian09” (Gaussian Inc.) and Q-Chem 4.1 (Q-Chem, Inc.). In the present case, the energies are calculated using the software package “Gaussian16 (Rev. B.01)”.

### Synthesis Examples

The syntheses which follow, unless stated otherwise, are conducted under a protective gas atmosphere in dried solvents. The solvents and reagents can be purchased, for example, from Sigma-ALDRICH or ABCR. The respective figures in square brackets or the numbers quoted for individual compounds relate to the CAS numbers of the compounds known from the literature.

### Synthesis Example 1

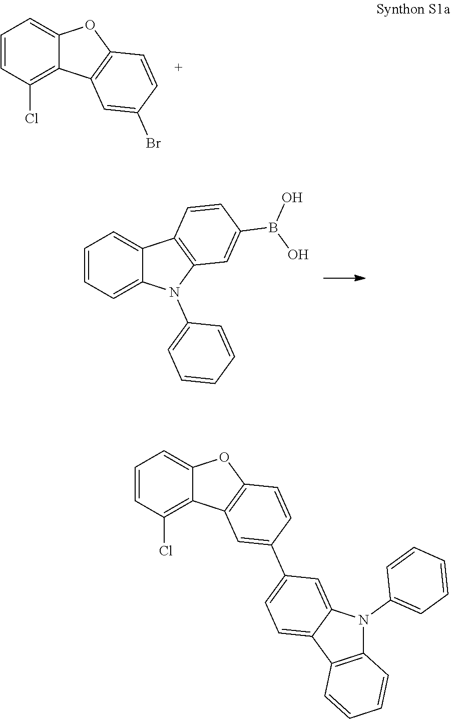 [SMILES: Clc1cccc2oc3ccc(Br)cc3c12 ; OB(O)c1ccc2c3ccccc3n(-c3ccccc3)c2c1 ; Clc1cccc2oc3ccc(-c4ccc5c6ccccc6n(-c6ccccc6)c5c4)cc3c12]

To an initial charge of 1-chloro-8-bromodibenzofuran (100 g, 353.6 mmol) [CAS-2225909-61-3] and B-(9-phenyl-9H-carbazol-2-yl)boronic acid (106.6 g, 371.3 mmol) [1001911-63-2] in toluene (800 ml), 1,4-dioxane (800 ml) and water (400 ml) under inert atmosphere are added Na₂CO₃ (74.95 g, 0.71 mol) and tetrakis(triphenylphosphine)palladium (0) (4.09 g, 3.54 mmol), and the mixture is stirred under reflux for 16 h. After cooling, the mixture is filtered with suction through a Celite-filled frit, and worked up by extraction with toluene and water. The aqueous phase is extracted twice with toluene (500 ml each time), and the combined organic phases are dried over Na₂SO₄. The solvent is removed on a rotary evaporator, and the crude product is converted to a slurry with ethanol (1200 ml) and stirred under reflux for 2 h. The solids are filtered off with suction, washed with ethanol and dried in a vacuum drying cabinet.

Yield: 138.5 g (312.2 mmol, 88%), 97% by 1H NMR

The following compounds can be prepared analogously: Purification can also be accomplished using column chromatography, or recrystallization or hot extraction using other standard solvents such as ethanol, butanol, acetone, ethyl acetate, acetonitrile, toluene, xylene, dichloromethane, methanol, tetrahydrofuran, n-butyl acetate, 1,4-dioxane, or recrystallization using high boilers such as dimethyl sulfoxide, N,N-dimethylformamide, N,N-dimethylacetamide, N-methylpyrrolidone, etc.

| Reactant 1 | Reactant 2 | Product | Yield |
|---|---|---|---|
| 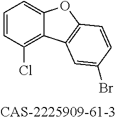 [SMILES: Clc1cccc2oc3ccc(Br)cc3c12] | 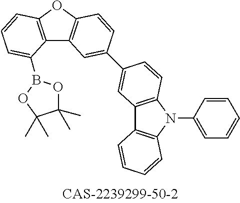 [SMILES: CC1(C)OB(c2cccc3oc4ccc(-c5ccc6c(c5)c5ccccc5n6-c5ccccc5)cc4c23)OC1(C)C] | 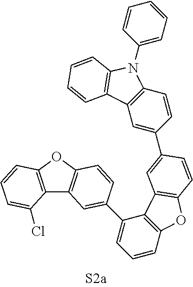 [SMILES: Clc1cccc2oc3ccc(-c4cccc5oc6ccc(-c7ccc8c(c7)c7ccccc7n8-c7ccccc7)cc6c45)cc3c12] | 63% |
| 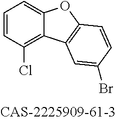 [SMILES: Clc1cccc2oc3ccc(Br)cc3c12] | 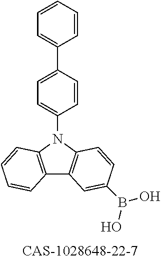 [SMILES: OB(O)c1ccc2c(c1)c1ccccc1n2-c1ccc(-c2ccccc2)cc1] | 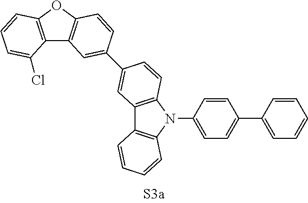 [SMILES: Clc1cccc2oc3ccc(-c4ccc5c(c4)c4ccccc4n5-c4ccc(-c5ccccc5)cc4)cc3c12] | 62% |
| 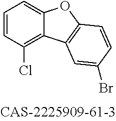 [SMILES: Clc1cccc2oc3ccc(Br)cc3c12] | 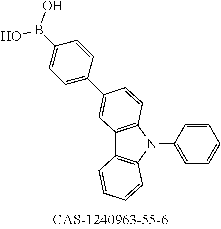 [SMILES: OB(O)c1ccc(-c2ccc3c(c2)c2ccccc2n3-c2ccccc2)cc1] | 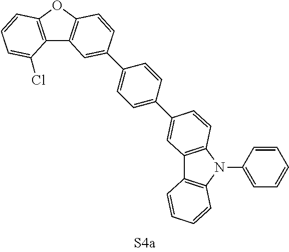 [SMILES: Clc1cccc2oc3ccc(-c4ccc(-c5ccc6c(c5)c5ccccc5n6-c5ccccc5)cc4)cc3c12] | 71% |
| 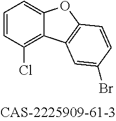 [SMILES: Clc1cccc2oc3ccc(Br)cc3c12] | 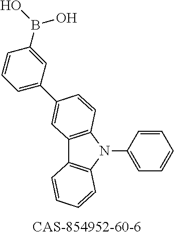 [SMILES: OB(O)c1cccc(-c2ccc3c(c2)c2ccccc2n3-c2ccccc2)c1] | 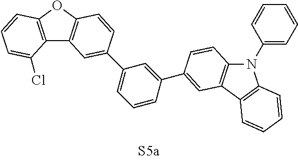 [SMILES: Clc1cccc2oc3ccc(-c4cccc(-c5ccc6c(c5)c5ccccc5n6-c5ccccc5)c4)cc3c12] | 77% |
| 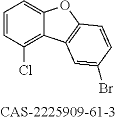 [SMILES: Clc1cccc2oc3ccc(Br)cc3c12] | 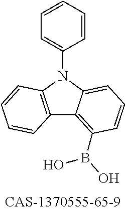 [SMILES: OB(O)c1cccc2c1c1ccccc1n2-c1ccccc1] | 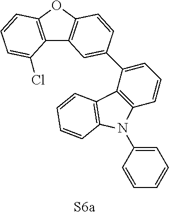 [SMILES: Clc1cccc2oc3ccc(-c4cccc5c4c4ccccc4n5-c4ccccc4)cc3c12] | 56% |
| 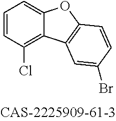 [SMILES: Clc1cccc2oc3ccc(Br)cc3c12] | 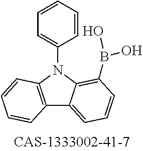 [SMILES: OB(O)c1cccc2c3ccccc3n(-c3ccccc3)c12] | 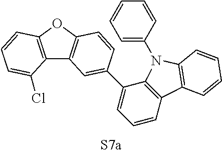 [SMILES: Clc1cccc2oc3ccc(-c4cccc5c6ccccc6n(-c6ccccc6)c45)cc3c12] | 52% |
| 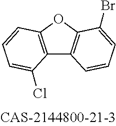 [SMILES: Clc1cccc2oc3c(Br)cccc3c12] | 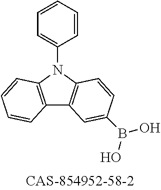 [SMILES: OB(O)c1ccc2c(c1)c1ccccc1n2-c1ccccc1] | 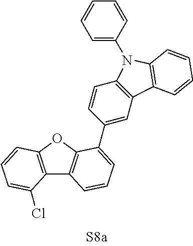 [SMILES: Clc1cccc2oc3c(-c4ccc5c(c4)c4ccccc4n5-c4ccccc4)cccc3c12] | 69% |
| 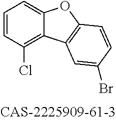 [SMILES: Clc1cccc2oc3ccc(Br)cc3c12] | 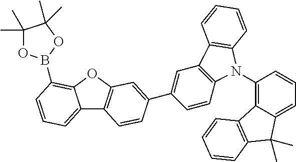 [SMILES: CC1(C)c2ccccc2-c2c(-n3c4ccccc4c4cc(-c5ccc6c(c5)oc5c(B7OC(C)(C)C(C)(C)O7)cccc56)ccc43)cccc21] | 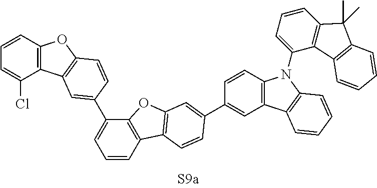 [SMILES: CC1(C)c2ccccc2-c2c(-n3c4ccccc4c4cc(-c5ccc6c(c5)oc5c(-c7ccc8oc9cccc(Cl)c9c8c7)cccc56)ccc43)cccc21] | 67% |
| 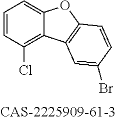 [SMILES: Clc1cccc2oc3ccc(Br)cc3c12] | 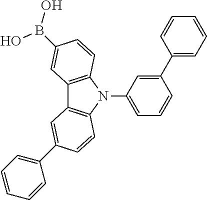 [SMILES: OB(O)c1ccc2c(c1)c1cc(-c3ccccc3)ccc1n2-c1cccc(-c2ccccc2)c1] | 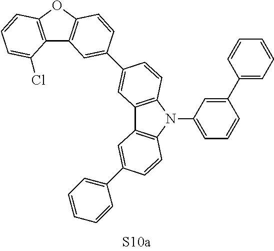 [SMILES: Clc1cccc2oc3ccc(-c4ccc5c(c4)c4cc(-c6ccccc6)ccc4n5-c4cccc(-c5ccccc5)c4)cc3c12] | 52% |
| 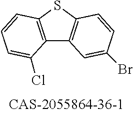 [SMILES: Clc1cccc2sc3ccc(Br)cc3c12] | 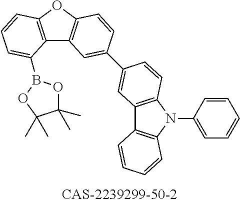 [SMILES: CC1(C)OB(c2cccc3oc4ccc(-c5ccc6c(c5)c5ccccc5n6-c5ccccc5)cc4c23)OC1(C)C] | 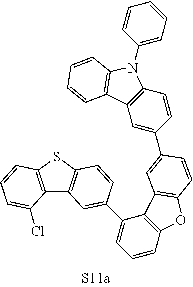 [SMILES: Clc1cccc2sc3ccc(-c4cccc5oc6ccc(-c7ccc8c(c7)c7ccccc7n8-c7ccccc7)cc6c45)cc3c12] | 72% |
| 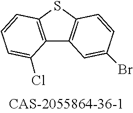 [SMILES: Clc1cccc2sc3ccc(Br)cc3c12] | 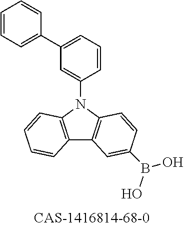 [SMILES: OB(O)c1ccc2c(c1)c1ccccc1n2-c1cccc(-c2ccccc2)c1] | 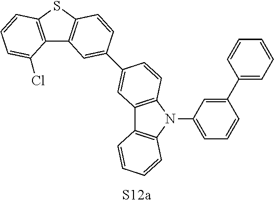 [SMILES: Clc1cccc2sc3ccc(-c4ccc5c(c4)c4ccccc4n5-c4cccc(-c5ccccc5)c4)cc3c12] | 80% |
| 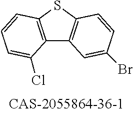 [SMILES: Clc1cccc2sc3ccc(Br)cc3c12] | 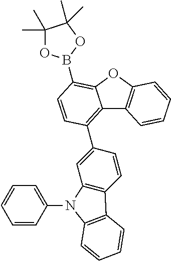 [SMILES: CC1(C)OB(c2ccc(-c3ccc4c5ccccc5n(-c5ccccc5)c4c3)c3c2oc2ccccc23)OC1(C)C] | 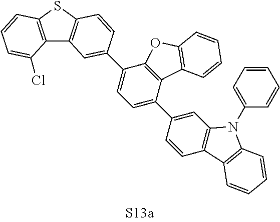 [SMILES: Clc1cccc2sc3ccc(-c4ccc(-c5ccc6c7ccccc7n(-c7ccccc7)c6c5)c5c4oc4ccccc45)cc3c12] | 73% |

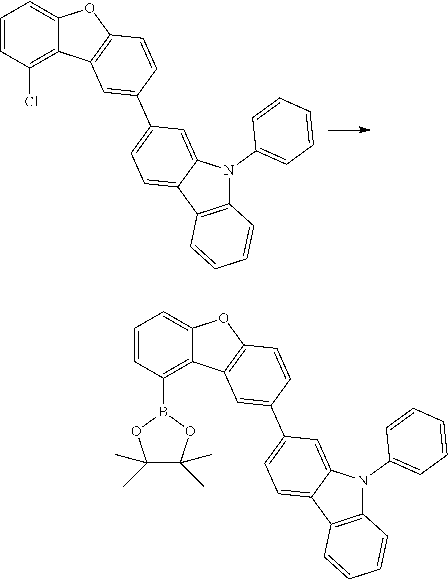 [SMILES: Clc1cccc2oc3ccc(-c4ccc5c6ccccc6n(-c6ccccc6)c5c4)cc3c12 ; CC1(C)OB(c2cccc3oc4ccc(-c5ccc6c7ccccc7n(-c7ccccc7)c6c5)cc4c23)OC1(C)C]

To an initial charge of S1a (124.30 g, 280 mmol) and 4,4,5,5-tetramethyl-2-(4,4,5,5-tetramethyl-1,3,2-dioxaborolan-2-yl)-1,3,2-dioxaborolane (76.20 g, 300 mmol) in 1,4-dioxane (2000 ml) under inert atmosphere are added potassium acetate (82.33 g, 1.40 mol) and trans-dichlorobis(tricyclohexylphosphine)palladium(II) (6.21 g, 83.9 mmol), and the mixture is stirred under reflux for 32 h. After cooling, the solvent is removed by rotary evaporation on a rotary evaporator, the residue is worked up by extraction with toluene/water, and the organic phase is dried over Na₂SO₄. The crude product is extracted by stirring under reflux with ethanol (1100 ml), and the solids are filtered off with suction after cooling and washed with ethanol.

Yield: 113.5 g (212.5 mmol, 76%), 95% by 1H NMR.

The following compounds can be prepared analogously: Purification can also be accomplished using column chromatography, or recrystallization or hot extraction using other standard solvents such as ethanol, butanol, acetone, ethyl acetate, acetonitrile, toluene, xylene, dichloromethane, methanol, tetrahydrofuran, n-butyl acetate, 1,4-dioxane, or recrystallization using high boilers such as dimethyl sulfoxide, N, N-dimethylformamide, N,N-dimethylacetamide. N-methylpyrrolidone, etc.

| Reactant 1 | Product | Yield |
|---|---|---|
| 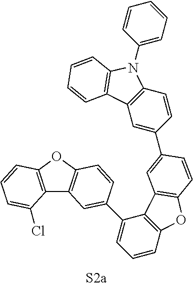 [SMILES: Clc1cccc2oc3ccc(-c4cccc5oc6ccc(-c7ccc8c(c7)c7ccccc7n8-c7ccccc7)cc6c45)cc3c12] | 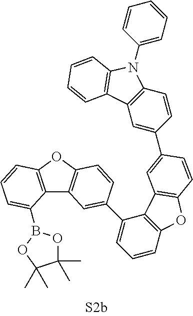 [SMILES: CC1(C)OB(c2cccc3oc4ccc(-c5cccc6oc7ccc(-c8ccc9c(c8)c8ccccc8n9-c8ccccc8)cc7c56)cc4c23)OC1(C)C] | 79% |
| 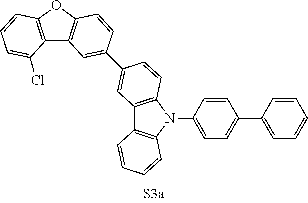 [SMILES: Clc1cccc2oc3ccc(-c4ccc5c(c4)c4ccccc4n5-c4ccc(-c5ccccc5)cc4)cc3c12] | 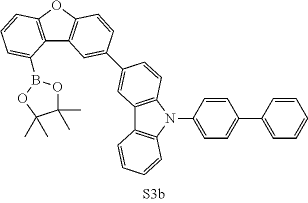 [SMILES: CC1(C)OB(c2cccc3oc4ccc(-c5ccc6c(c5)c5ccccc5n6-c5ccc(-c6ccccc6)cc5)cc4c23)OC1(C)C] | 70% |
| 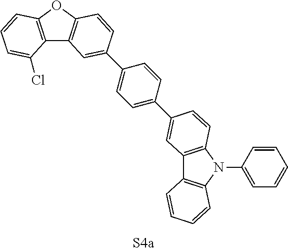 [SMILES: Clc1cccc2oc3ccc(-c4ccc(-c5ccc6c(c5)c5ccccc5n6-c5ccccc5)cc4)cc3c12] | 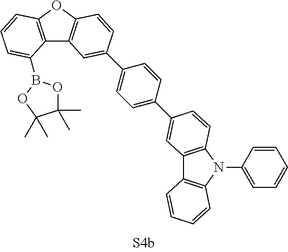 [SMILES: CC1(C)OB(c2cccc3oc4ccc(-c5ccc(-c6ccc7c(c6)c6ccccc6n7-c6ccccc6)cc5)cc4c23)OC1(C)C] | 66% |
| 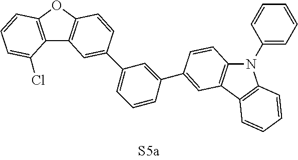 [SMILES: Clc1cccc2oc3ccc(-c4cccc(-c5ccc6c(c5)c5ccccc5n6-c5ccccc5)c4)cc3c12] | 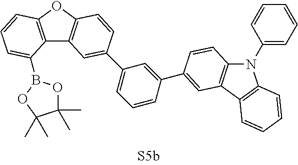 [SMILES: CC1(C)OB(c2cccc3oc4ccc(-c5cccc(-c6ccc7c(c6)c6ccccc6n7-c6ccccc6)c5)cc4c23)OC1(C)C] | 67% |
| 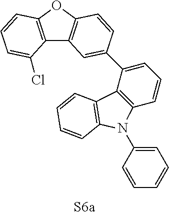 [SMILES: Clc1cccc2oc3ccc(-c4cccc5c4c4ccccc4n5-c4ccccc4)cc3c12] | 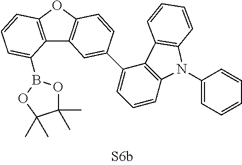 [SMILES: CC1(C)OB(c2cccc3oc4ccc(-c5cccc6c5c5ccccc5n6-c5ccccc5)cc4c23)OC1(C)C] | 72% |
| 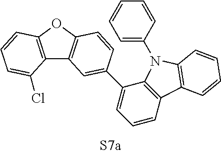 [SMILES: Clc1cccc2oc3ccc(-c4cccc5c6ccccc6n(-c6ccccc6)c45)cc3c12] | 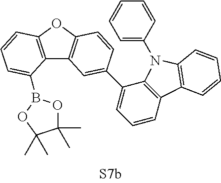 [SMILES: CC1(C)OB(c2cccc3oc4ccc(-c5cccc6c7ccccc7n(-c7ccccc7)c56)cc4c23)OC1(C)C] | 64% |
| 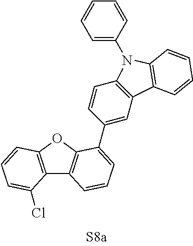 [SMILES: Clc1cccc2oc3c(-c4ccc5c(c4)c4ccccc4n5-c4ccccc4)cccc3c12] | 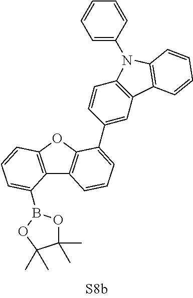 [SMILES: CC1(C)OB(c2cccc3oc4c(-c5ccc6c(c5)c5ccccc5n6-c5ccccc5)cccc4c23)OC1(C)C] | 78% |
| 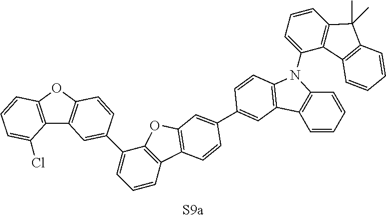 [SMILES: CC1(C)c2ccccc2-c2c(-n3c4ccccc4c4cc(-c5ccc6c(c5)oc5c(-c7ccc8oc9cccc(Cl)c9c8c7)cccc56)ccc43)cccc21] | 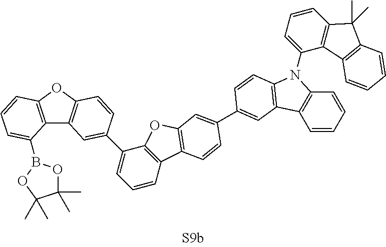 [SMILES: CC1(C)c2ccccc2-c2c(-n3c4ccccc4c4cc(-c5ccc6c(c5)oc5c(-c7ccc8oc9cccc(B%10OC(C)(C)C(C)(C)O%10)c9c8c7)cccc56)ccc43)cccc21] | 59% |
| 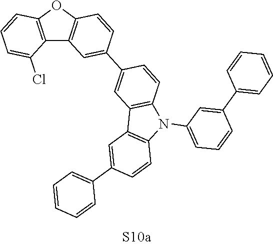 [SMILES: Clc1cccc2oc3ccc(-c4ccc5c(c4)c4cc(-c6ccccc6)ccc4n5-c4cccc(-c5ccccc5)c4)cc3c12] | 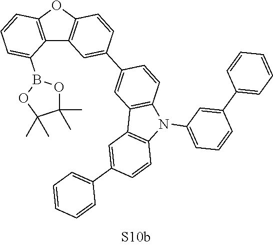 [SMILES: CC1(C)OB(c2cccc3oc4ccc(-c5ccc6c(c5)c5cc(-c7ccccc7)ccc5n6-c5cccc(-c6ccccc6)c5)cc4c23)OC1(C)C] | 71% |
| 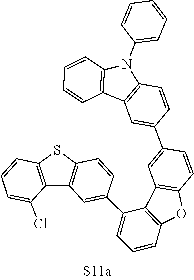 [SMILES: Clc1cccc2sc3ccc(-c4cccc5oc6ccc(-c7ccc8c(c7)c7ccccc7n8-c7ccccc7)cc6c45)cc3c12] | 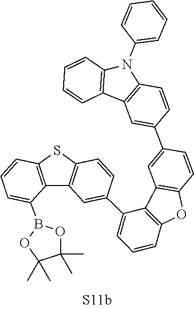 [SMILES: CC1(C)OB(c2cccc3sc4ccc(-c5cccc6oc7ccc(-c8ccc9c(c8)c8ccccc8n9-c8ccccc8)cc7c56)cc4c23)OC1(C)C] | 67% |
| 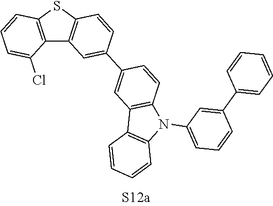 [SMILES: Clc1cccc2sc3ccc(-c4ccc5c(c4)c4ccccc4n5-c4cccc(-c5ccccc5)c4)cc3c12] | 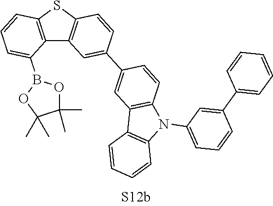 [SMILES: CC1(C)OB(c2cccc3sc4ccc(-c5ccc6c(c5)c5ccccc5n6-c5cccc(-c6ccccc6)c5)cc4c23)OC1(C)C] | 80% |
| 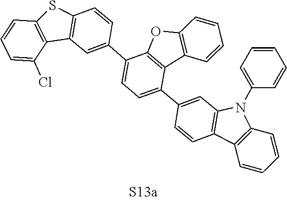 [SMILES: Clc1cccc2sc3ccc(-c4ccc(-c5ccc6c7ccccc7n(-c7ccccc7)c6c5)c5c4oc4ccccc45)cc3c12] | 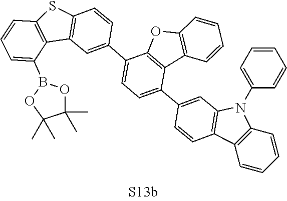 [SMILES: CC1(C)OB(c2cccc3sc4ccc(-c5ccc(-c6ccc7c8ccccc8n(-c8ccccc8)c7c6)c6c5oc5ccccc56)cc4c23)OC1(C)C] | 82% |

### E1

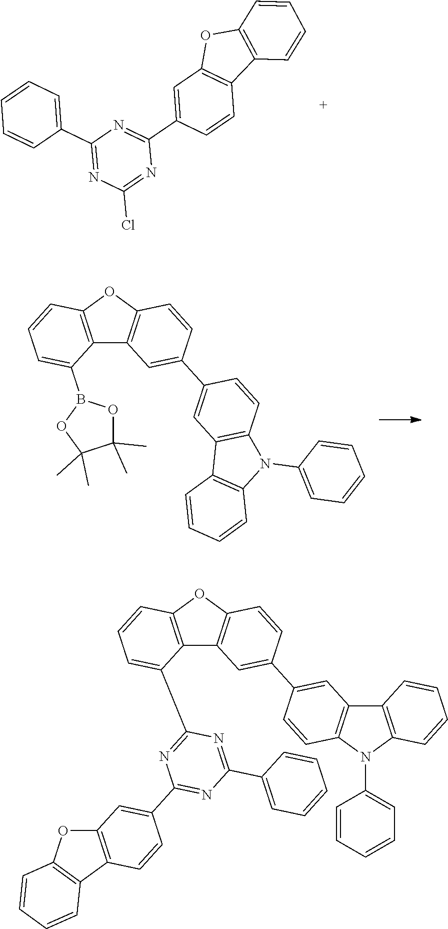 [SMILES: Clc1nc(-c2ccccc2)nc(-c2ccc3c(c2)oc2ccccc23)n1 ; CC1(C)OB(c2cccc3oc4ccc(-c5ccc6c(c5)c5ccccc5n6-c5ccccc5)cc4c23)OC1(C)C ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1]

To an initial charge of 9-phenyl-3-[9-(4,4,5,5-tetramethyl-[1,3,2]dioxaborolan-2-yl)-dibenzofuran-2-yl]-9H-carbazole (22.00 g, 41.1 mmol) [2239299-50-2], 2-chloro-4-{8-oxatricyclo[7.4.0.0²,7]trideca-1(13),2(7),3,5,9,11-hexaen-5-yl}-6-phenyl-1,3,5-triazine (14.70 g, 41.1 mmol) [CAS-2142681-84-1] in THF (650 ml) and water (250 ml) under inert atmosphere are added Na₂CO₃ (9.58 g, 90.4 mmol) and tetrakis(triphenylphosphine)palladium (0) (710 mg, 0.62 mmol), and the mixture is stirred under reflux for 16 h. After cooling, the mixture is worked up by extraction with toluene/water, the aqueous phase is extracted three times with toluene (250 ml each time), and the combined organic phases are dried over Na₂SO₄. The crude product is subjected to extraction with hot heptane/toluene twice, recrystallized from n-butyl acetate twice and finally sublimed under high vacuum.

Yield: 15.5 g (21.2 mmol, 52%); purity: >99.9% by HPLC.

It is possible in an analogous manner to prepare further compounds in which S1b to S13b, or commercially available compounds such as the compounds having CAS numbers CAS-2239299-50-2, CAS-2299272-36-7, are reacted with triazine derivatives in a corresponding manner to give the compounds E2 to E38.

Further triazine derivatives and dibenzofuran derivatives that can be used for these syntheses are shown, for example, in the table below.

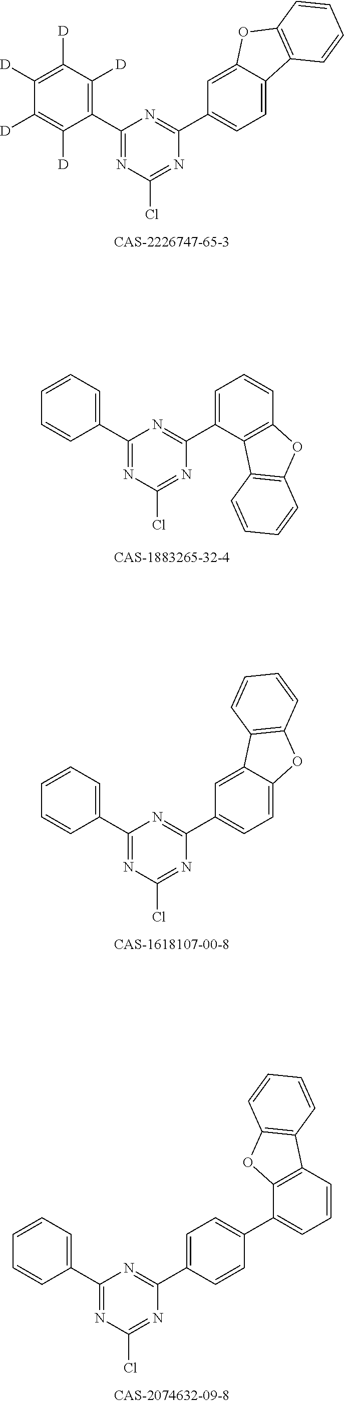 [SMILES: [2H]c1c([2H])c([2H])c(-c2nc(Cl)nc(-c3ccc4c(c3)oc3ccccc34)n2)c([2H])c1[2H] ; Clc1nc(-c2ccccc2)nc(-c2cccc3oc4ccccc4c23)n1 ; Clc1nc(-c2ccccc2)nc(-c2ccc3oc4ccccc4c3c2)n1 ; Clc1nc(-c2ccccc2)nc(-c2ccc(-c3cccc4c3oc3ccccc34)cc2)n1]

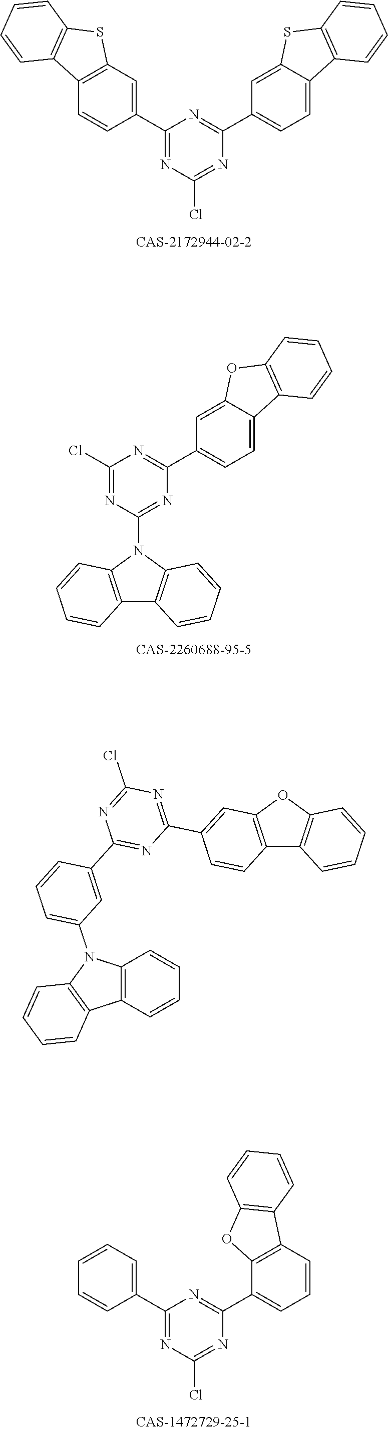 [SMILES: Clc1nc(-c2ccc3c(c2)sc2ccccc23)nc(-c2ccc3c(c2)sc2ccccc23)n1 ; Clc1nc(-c2ccc3c(c2)oc2ccccc23)nc(-n2c3ccccc3c3ccccc32)n1 ; Clc1nc(-c2cccc(-n3c4ccccc4c4ccccc43)c2)nc(-c2ccc3c(c2)oc2ccccc23)n1 ; Clc1nc(-c2ccccc2)nc(-c2cccc3c2oc2ccccc23)n1]

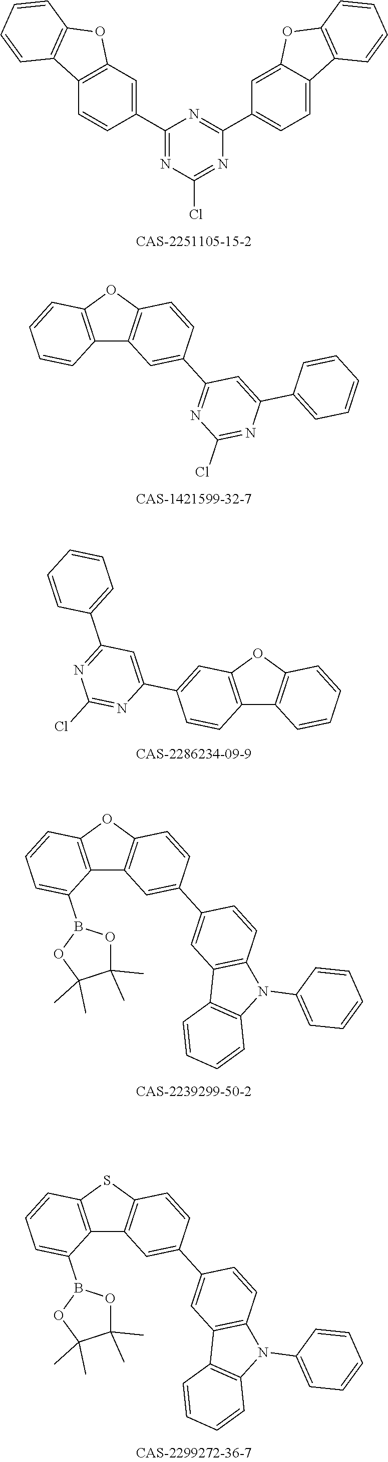 [SMILES: Clc1nc(-c2ccc3c(c2)oc2ccccc23)nc(-c2ccc3c(c2)oc2ccccc23)n1 ; Clc1nc(-c2ccccc2)cc(-c2ccc3oc4ccccc4c3c2)n1 ; Clc1nc(-c2ccccc2)cc(-c2ccc3c(c2)oc2ccccc23)n1 ; CC1(C)OB(c2cccc3oc4ccc(-c5ccc6c(c5)c5ccccc5n6-c5ccccc5)cc4c23)OC1(C)C ; CC1(C)OB(c2cccc3sc4ccc(-c5ccc6c(c5)c5ccccc5n6-c5ccccc5)cc4c23)OC1(C)C]

The catalyst system used here (palladium source and ligand) may also be Pd₂(dba)₃ with SPhos [657408-07-6] or bis(triphenylphosphine)palladium(II) chloride [13965-03-2]. Purification can also be accomplished using column chromatography, or recrystallization or hot extraction using other standard solvents such as ethanol, butanol, acetone, ethyl acetate, acetonitrile, toluene, xylene, dichloromethane, methanol, tetrahydrofuran, n-butyl acetate, 1,4-dioxane, or recrystallization using high boilers such as dimethyl sulfoxide, N,N-dimethylformamide, N,N-dimethylacetamide, N-methylpyrrolidone, etc.

### Synthesis Example 2

### a) 1-Bromo-8-iododibenzofuran

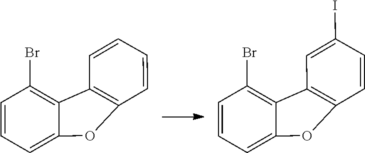 [SMILES: Brc1cccc2oc3ccccc3c12 ; Brc1cccc2oc3ccc(I)cc3c12]

20 g (80 mmol) of dibenzofuran-1-boronic acid, 2.06 g (40.1 mmol) of iodine, 3.13 g (17.8 mmol) of iodic acid, 80 ml of acetic acid and 5 ml of sulfuric acid and 5 ml of water and 2 ml of chloroform are stirred at 65° for 3 hours. The mixture is cooled, then water is added, and the precipitated solids are filtered off with suction and washed three times with water.

The residue is recrystallized from toluene and from dichloromethane/heptane. The yield is 25.6 g (68 mmol), corresponding to 85% of theory.

### b) 9-9-Bromodibenzofuran-2-yl)-3-phenylcarbazole

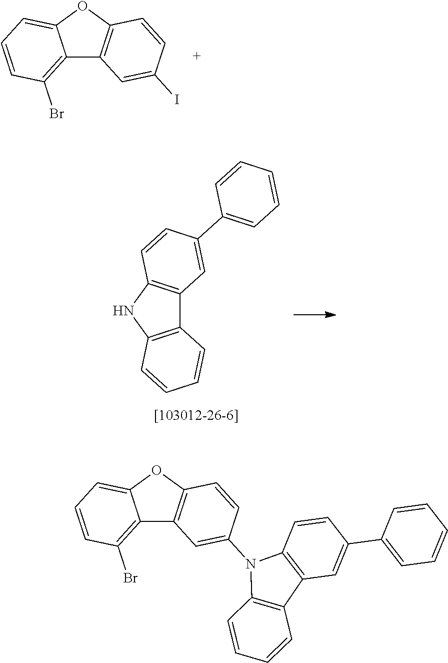 [SMILES: Brc1cccc2oc3ccc(I)cc3c12 ; c1ccc(-c2ccc3[nH]c4ccccc4c3c2)cc1 ; Brc1cccc2oc3ccc(-n4c5ccccc5c5cc(-c6ccccc6)ccc54)cc3c12]

37 g (100 mmol) of 3-phenylcarbazole, 48.5 g (200 mmol) of 1-bromo-8-iododibenzofuran and 2.3 g (20 mmol) of L-proline are stirred in 100 ml at 150° C. for 30 h. The solution is diluted with water and extracted twice with ethyl acetate, and the combined organic phases are dried over Na₂SO₄ and concentrated by rotary evaporation. The residue is purified by chromatography (EtOAc/hexane: 2/3). The yield is 29 g (60 mmol), 60% of theory.

The following compounds are prepared in an analogous manner.

| | Reactant 1 | Reactant 2 | Product | Yield |
|---|---|---|---|---|
| 1b | 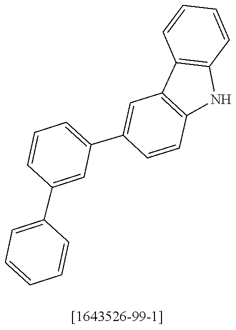 [SMILES: c1ccc(-c2cccc(-c3ccc4[nH]c5ccccc5c4c3)c2)cc1] | 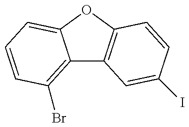 [SMILES: Brc1cccc2oc3ccc(I)cc3c12] | 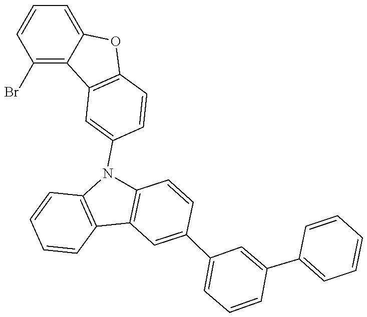 [SMILES: Brc1cccc2oc3ccc(-n4c5ccccc5c5cc(-c6cccc(-c7ccccc7)c6)ccc54)cc3c12] | 57% |
| 2b | 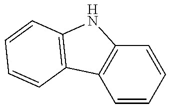 [SMILES: c1ccc2c(c1)[nH]c1ccccc12] | 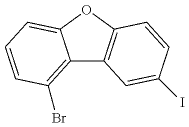 [SMILES: Brc1cccc2oc3ccc(I)cc3c12] | 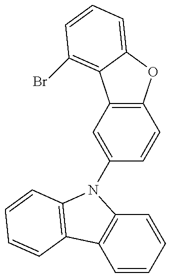 [SMILES: Brc1cccc2oc3ccc(-n4c5ccccc5c5ccccc54)cc3c12] | 61% |

### c) 8-(3-Phenylcarbazol-9-yl)dibenzofuran-1-yl]boronic acid

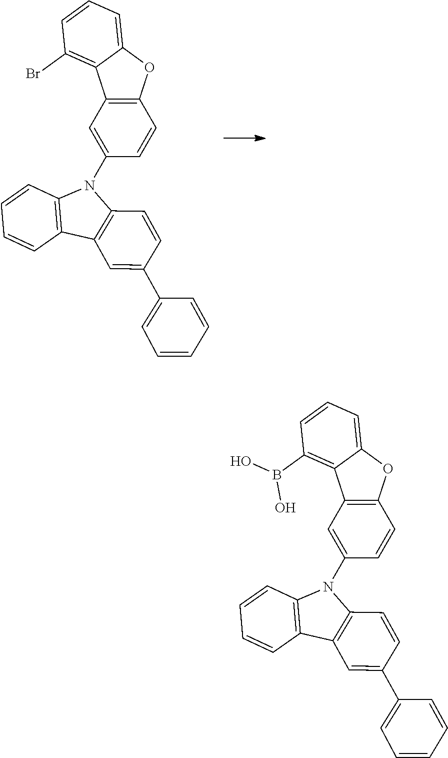 [SMILES: Brc1cccc2oc3ccc(-n4c5ccccc5c5cc(-c6ccccc6)ccc54)cc3c12 ; OB(O)c1cccc2oc3ccc(-n4c5ccccc5c5cc(-c6ccccc6)ccc54)cc3c12]

35 g (73 mol) of 9-(9-bromodibenzofuran-2-yl)-3-phenylcarbazole is dissolved in 150 ml of dry THF and cooled to −78° C. At this temperature, 30 ml (76 mmol/2.5 M in hexane) of n-butyllithium is added within about 5 min and then the mixture is stirred at −78° C. for a further 2.5 h. At this temperature, 15 g (146 mmol) of trimethyl borate is added, and the reaction is allowed to come gradually to room temperature (about 18 h). The reaction solution is washed with water and the precipitated solids and the organic phase are subjected to azeotropic drying with toluene. The crude product is extracted while stirring from toluene/methylene chloride at about 40° C. and filtered off with suction. Yield: 29 g (64 mmol), 90% of theory.

The following compounds are prepared in an analogous manner:

| | Reactant 1 | Product | Yield |
|---|---|---|---|
| 1c | 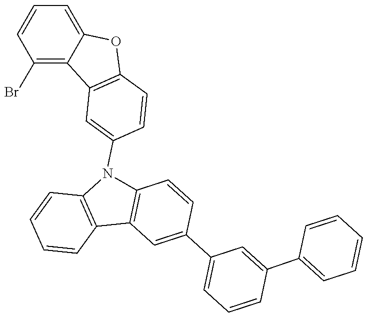 [SMILES: Brc1cccc2oc3ccc(-n4c5ccccc5c5cc(-c6cccc(-c7ccccc7)c6)ccc54)cc3c12] | 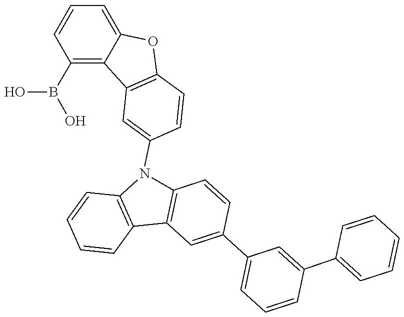 [SMILES: OB(O)c1cccc2oc3ccc(-n4c5ccccc5c5cc(-c6cccc(-c7ccccc7)c6)ccc54)cc3c12] | 95% |
| 2c | 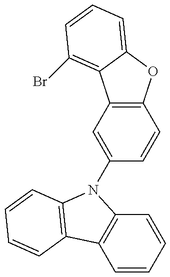 [SMILES: Brc1cccc2oc3ccc(-n4c5ccccc5c5ccccc54)cc3c12] | 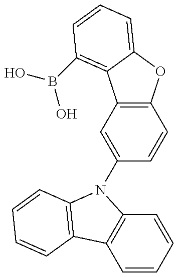 [SMILES: OB(O)c1cccc2oc3ccc(-n4c5ccccc5c5ccccc54)cc3c12] | 89% |

### d) 9-[9-(4-Dibenzofuran-3-yl-6-phenyl-1,3,5-triazin-2-yl)dibenzofuran-2-yl]-3-phenylcarbazole

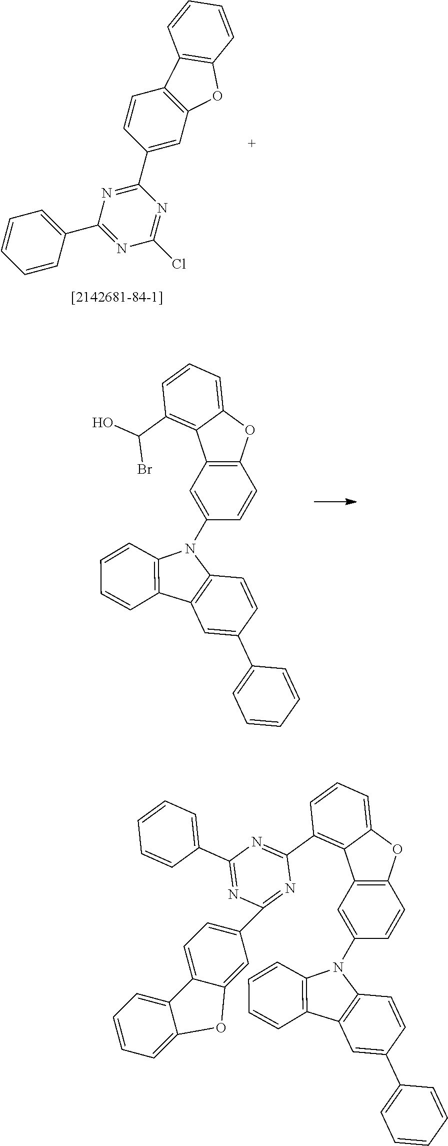 [SMILES: Clc1nc(-c2ccccc2)nc(-c2ccc3c(c2)oc2ccccc23)n1 ; OC(Br)c1cccc2oc3ccc(-n4c5ccccc5c5cc(-c6ccccc6)ccc54)cc3c12 ; c1ccc(-c2ccc3c(c2)c2ccccc2n3-c2ccc3oc4cccc(-c5nc(-c6ccccc6)nc(-c6ccc7c(c6)oc6ccccc67)n5)c4c3c2)cc1]

39.3 g (110 mmol) of 8-(3-phenylcarbazol-9-yl)dibenzofuran-1-yl]boronic acid, 29.5 g (110.0 mmol) of 2-chloro-4,6-diphenyl-1,3,5-triazine and 21 g (210.0 mmol) of sodium carbonate are suspended in 500 ml of ethylene glycol diamine ether and 500 ml of water. To this suspension are added 913 mg (3.0 mmol) of tri-o-tolylphosphine and then 112 mg (0.5 mmol) of palladium(II)acetate, and the reaction mixture is heated under reflux for 16 h. After cooling, the organic phase is removed, filtered through silica gel, washed three times with 200 ml of water and then concentrated to dryness. The residue is recrystallized from toluene and from dichloromethane/heptane. The yield is 71 g (98 mmol), corresponding to 89% of theory.

The following compounds are prepared in an analogous manner:

| | Reactant 1 | Reactant 2 | Product | Yield |
|---|---|---|---|---|
| 1d | 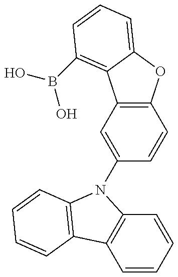 [SMILES: OB(O)c1cccc2oc3ccc(-n4c5ccccc5c5ccccc54)cc3c12] | 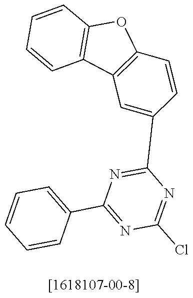 [SMILES: Clc1nc(-c2ccccc2)nc(-c2ccc3oc4ccccc4c3c2)n1] | 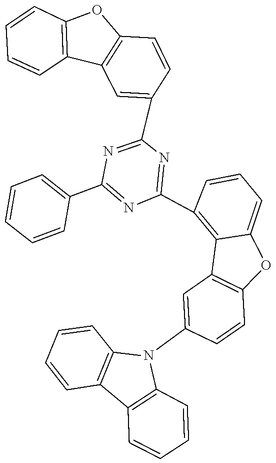 [SMILES: c1ccc(-c2nc(-c3ccc4oc5ccccc5c4c3)nc(-c3cccc4oc5ccc(-n6c7ccccc7c7ccccc76)cc5c34)n2)cc1] | 75% |
| 2d | 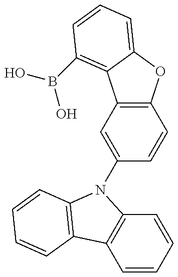 [SMILES: OB(O)c1cccc2oc3ccc(-n4c5ccccc5c5ccccc54)cc3c12] | 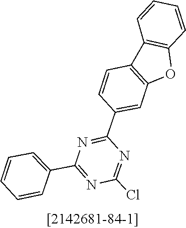 [SMILES: Clc1nc(-c2ccccc2)nc(-c2ccc3c(c2)oc2ccccc23)n1] | 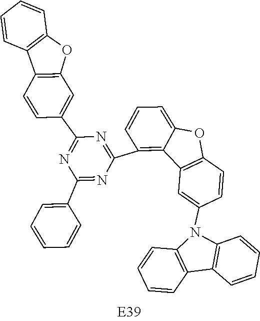 [SMILES: c1ccc(-c2nc(-c3ccc4c(c3)oc3ccccc34)nc(-c3cccc4oc5ccc(-n6c7ccccc7c7ccccc76)cc5c34)n2)cc1] | 71% |
| 3d | 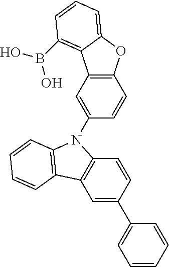 [SMILES: OB(O)c1cccc2oc3ccc(-n4c5ccccc5c5cc(-c6ccccc6)ccc54)cc3c12] | 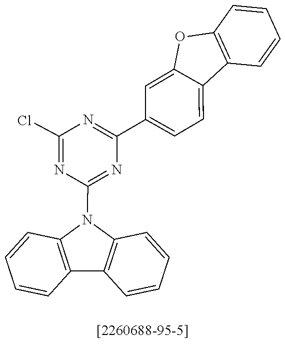 [SMILES: Clc1nc(-c2ccc3c(c2)oc2ccccc23)nc(-n2c3ccccc3c3ccccc32)n1] | 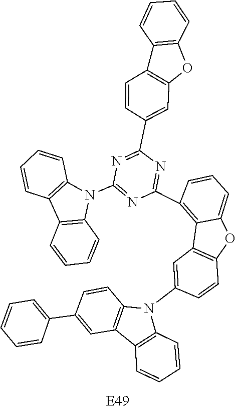 [SMILES: c1ccc(-c2ccc3c(c2)c2ccccc2n3-c2ccc3oc4cccc(-c5nc(-c6ccc7c(c6)oc6ccccc67)nc(-n6c7ccccc7c7ccccc76)n5)c4c3c2)cc1] | 63% |
| 4d | 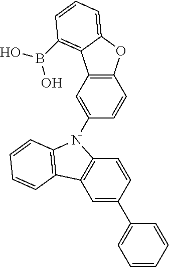 [SMILES: OB(O)c1cccc2oc3ccc(-n4c5ccccc5c5cc(-c6ccccc6)ccc54)cc3c12] | 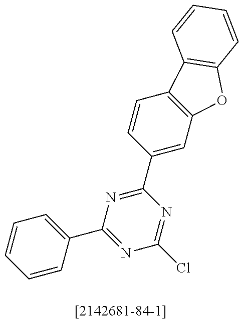 [SMILES: Clc1nc(-c2ccccc2)nc(-c2ccc3c(c2)oc2ccccc23)n1] | 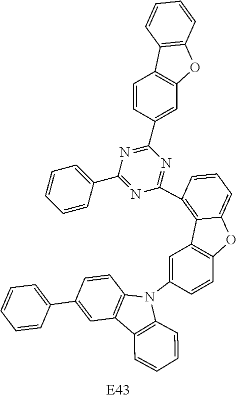 [SMILES: c1ccc(-c2ccc3c(c2)c2ccccc2n3-c2ccc3oc4cccc(-c5nc(-c6ccccc6)nc(-c6ccc7c(c6)oc6ccccc67)n5)c4c3c2)cc1] | 67% |
| 5d | 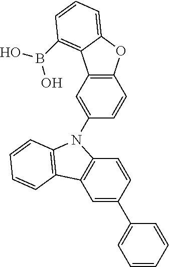 [SMILES: OB(O)c1cccc2oc3ccc(-n4c5ccccc5c5cc(-c6ccccc6)ccc54)cc3c12] | 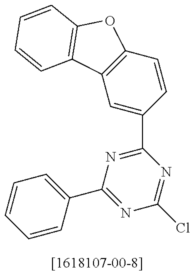 [SMILES: Clc1nc(-c2ccccc2)nc(-c2ccc3oc4ccccc4c3c2)n1] | 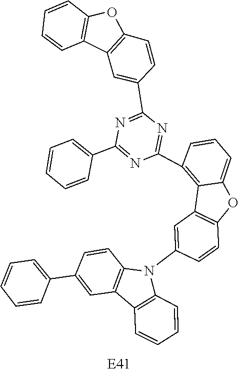 [SMILES: c1ccc(-c2ccc3c(c2)c2ccccc2n3-c2ccc3oc4cccc(-c5nc(-c6ccccc6)nc(-c6ccc7oc8ccccc8c7c6)n5)c4c3c2)cc1] | 80% |
| 6d | 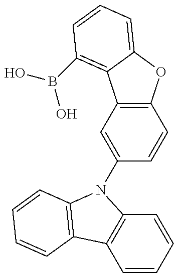 [SMILES: OB(O)c1cccc2oc3ccc(-n4c5ccccc5c5ccccc54)cc3c12] | 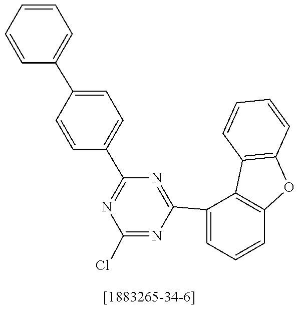 [SMILES: Clc1nc(-c2ccc(-c3ccccc3)cc2)nc(-c2cccc3oc4ccccc4c23)n1] | 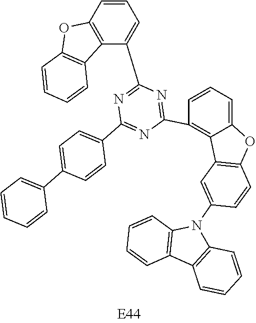 [SMILES: c1ccc(-c2ccc(-c3nc(-c4cccc5oc6ccccc6c45)nc(-c4cccc5oc6ccc(-n7c8ccccc8c8ccccc87)cc6c45)n3)cc2)cc1] | 77% |
| 7d | 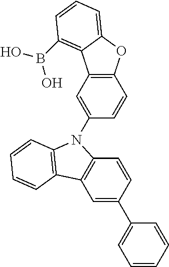 [SMILES: OB(O)c1cccc2oc3ccc(-n4c5ccccc5c5cc(-c6ccccc6)ccc54)cc3c12] | 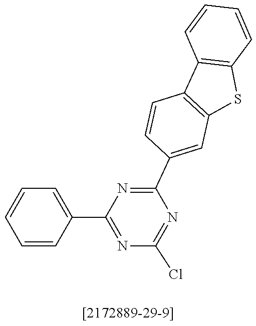 [SMILES: Clc1nc(-c2ccccc2)nc(-c2ccc3c(c2)sc2ccccc23)n1] | 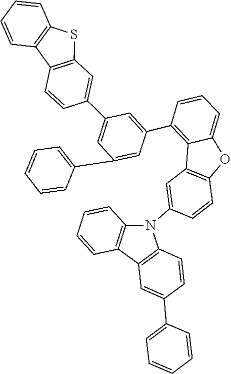 [SMILES: c1ccc(-c2cc(-c3ccc4c(c3)sc3ccccc34)cc(-c3cccc4oc5ccc(-n6c7ccccc7c7cc(-c8ccccc8)ccc76)cc5c34)c2)cc1] | 79% |
| 8d | 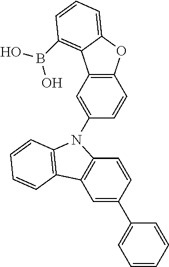 [SMILES: OB(O)c1cccc2oc3ccc(-n4c5ccccc5c5cc(-c6ccccc6)ccc54)cc3c12] | 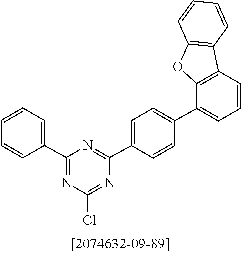 [SMILES: Clc1nc(-c2ccccc2)nc(-c2ccc(-c3cccc4c3oc3ccccc34)cc2)n1] | 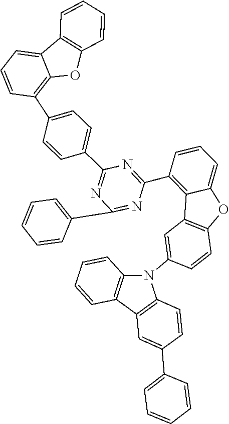 [SMILES: c1ccc(-c2ccc3c(c2)c2ccccc2n3-c2ccc3oc4cccc(-c5nc(-c6ccccc6)nc(-c6ccc(-c7cccc8c7oc7ccccc78)cc6)n5)c4c3c2)cc1] | 76% |

### Synthesis Example 3

### General Deuteration

The starting compound is dissolved in a mixture of deuterated water (99% deuterium atom) and toluene-d8 (99% deuterium atom) and heated to 160° C. under pressure in the presence of dry platinum on charcoal (5%) as catalyst for 96 hours. After the reaction mixture has been cooled down, the phases are separated, and the aqueous phase is extracted twice with the tetrahydrofuran-toluene mixture. The recombined organic phases are washed with a sodium chloride solution, dried over sodium sulfate and filtered. The solvent is removed under reduced pressure in order to provide the crude deuterated compound in solid form. The compound is purified further by extraction, crystallization and sublimation.

### Example A: 1,1′,2′,3′,4′,5′,6,6′,7′,8,8′-Undecadeuterio-N-(2,3,6,7,8-pentadeuterio-9,9-dimethylfluoren-4-yl)-N-(3,4,6,7,8-pentadeuterio-9,9-dimethylfluoren-2-yl)-9,9′-spirobi[fluorene]-4-amine

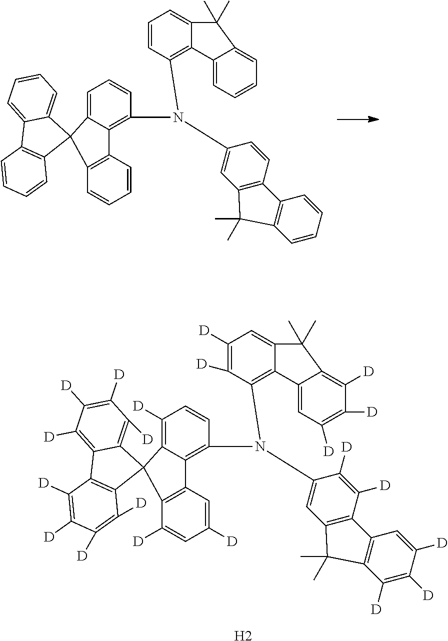 [SMILES: CC1(C)c2ccccc2-c2ccc(N(c3cccc4c3-c3ccccc3C4(C)C)c3cccc4c3-c3ccccc3C43c4ccccc4-c4ccccc43)cc21 ; [2H]c1cc([2H])c2c(c1)-c1c(N(c3cc4c(c([2H])c3[2H])-c3cc([2H])c([2H])c([2H])c3C4(C)C)c3c([2H])c([2H])cc4c3-c3cc([2H])c([2H])c([2H])c3C4(C)C)ccc([2H])c1C21c2c([2H])c([2H])c([2H])c([2H])c2-c2c([2H])c([2H])c([2H])c([2H])c21 ; "H2"]

N-(9,9-Dimethylfluoren-2-yl)-N-(9,9-dimethylfluoren-4-yl)-9,9′-spirobi[fluorene]-4′-amine (22.8 g, 32 mmol), toluene-d8 (231 g, 2.31 mol), deuterated water (1300 g, 64.9 mol) and dry platinum on charcoal (5%) (30 g) are stirred at 130° C. for 24 h. The crude product is purified further by extracting twice with a mixture of heptane and toluene (4:1) and subliming twice.

Yield: 21.2 g (28 mmol, 90%) with a purity of >99.9%. Identity is demonstrated by HPLC-MS and 1H NMR.

### Example B: 1,2,3,5,6,7,8-Heptadeuterio-N-[1,2,3,5,6,7,8-heptadeuterio-9,9-bis(trideuteriomethyl)fluoren-4-yl]-9,9-bis(trideuteriomethyl)-N-[2,3,5-trideuterio-4-(2,3,4,5,6-pentadeuteriophenyl)phenyl]fluorene-4-amine

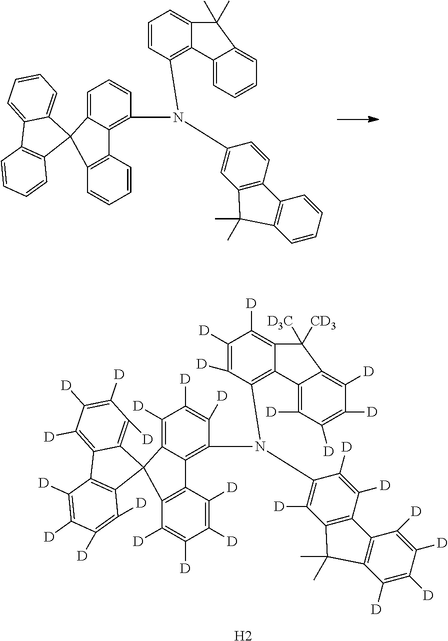 [SMILES: CC1(C)c2ccccc2-c2ccc(N(c3cccc4c3-c3ccccc3C4(C)C)c3cccc4c3-c3ccccc3C43c4ccccc4-c4ccccc43)cc21 ; [2H]c1c([2H])c([2H])c2c(c1[2H])-c1c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c1C2(C)C ; "H2"]

N-(9,9-Dimethylfluoren-2-yl)-N-(9,9-dimethylfluoren-4-yl)-9,9′-spirobi[fluorene]-4′-amine (22.8 g, 31.8 mmol), toluene-d8 (231 g, 2.31 mol), deuterated water (1300 g, 64.9 mol) and dry platinum on charcoal (5%) (30 g) are stirred at 160° C. for 96 h. The crude product is purified further by extracting twice with a mixture of heptane and toluene (4:1) and subliming twice.

Yield: 21.9 g (28.9 mmol, 95%) with a purity of >99.9%. Identity is demonstrated by HPLC-MS.

The following compounds can be prepared in an analogous manner: The yield in all cases is between 40% and 90%.

| | Reactant | Product |
|---|---|---|
| 1 | 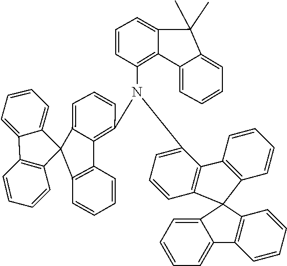 [SMILES: CC1(C)c2ccccc2-c2c(N(c3cccc4c3-c3ccccc3C43c4ccccc4-c4ccccc43)c3cccc4c3-c3ccccc3C43c4ccccc4-c4ccccc43)cccc21] | 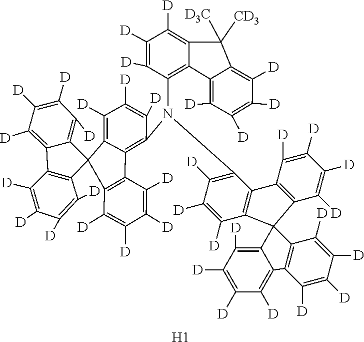 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c([2H])c([2H])c21 ; "H1"] |
| 2 | 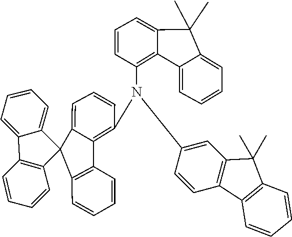 [SMILES: CC1(C)c2ccccc2-c2ccc(N(c3cccc4c3-c3ccccc3C4(C)C)c3cccc4c3-c3ccccc3C43c4ccccc4-c4ccccc43)cc21] | 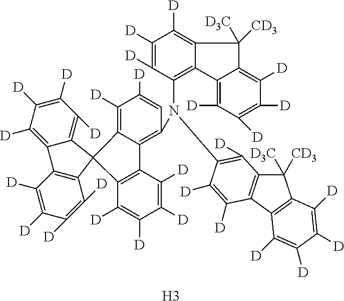 [SMILES: [2H]c1cc(N(c2c([2H])c([2H])c3c(c2[2H])C(C([2H])([2H])[2H])(C([2H])([2H])[2H])c2c([2H])c([2H])c([2H])c([2H])c2-3)c2c([2H])c([2H])c([2H])c3c2-c2c([2H])c([2H])c([2H])c([2H])c2C(C([2H])([2H])[2H])(C([2H])([2H])[2H])C3)c2c(c1[2H])C1(c3c([2H])c([2H])c([2H])c([2H])c3-2)c2c([2H])c([2H])c([2H])c([2H])c2-c2c([2H])c([2H])c([2H])c([2H])c21 ; "H3"] |
| 3 | 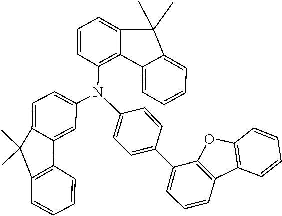 | 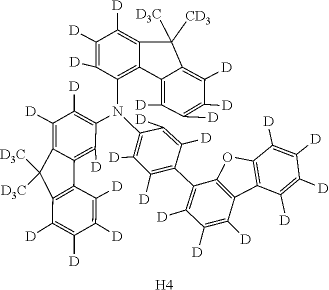 [SMILES: [2H]c1c([2H])c([2H])c2c(c1[2H])-c1c([2H])c(N(c3c([2H])c([2H])c(-c4c([2H])c([2H])c([2H])c5c4oc4c([2H])c([2H])c([2H])c([2H])c45)c([2H])c3[2H])c3c([2H])c([2H])c([2H])c4c3-c3c([2H])c([2H])c([2H])c([2H])c3C4(C([2H])([2H])[2H])C([2H])([2H])[2H])c([2H])c([2H])c1C2(C([2H])([2H])[2H])C([2H])([2H])[2H] ; "H4"] |
| 4 | 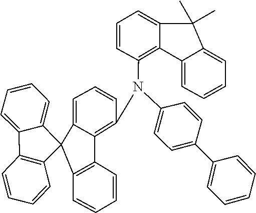 [SMILES: CC1(C)c2ccccc2-c2c(N(c3ccc(-c4ccccc4)cc3)c3cccc4c3-c3ccccc3C43c4ccccc4-c4ccccc43)cccc21] | 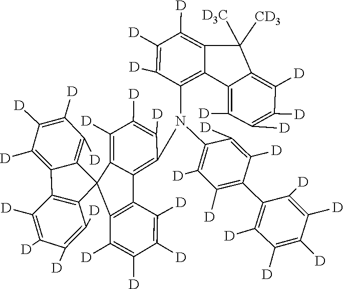 [SMILES: [2H]c1c([2H])c([2H])c(-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c2[2H])c([2H])c1[2H]] |
| 5 | 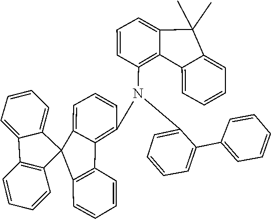 [SMILES: CC1(C)c2ccccc2-c2c(N(c3ccccc3-c3ccccc3)c3cccc4c3-c3ccccc3C43c4ccccc4-c4ccccc43)cccc21] | 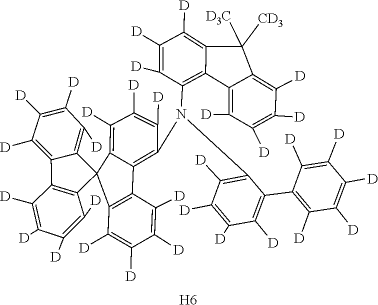 [SMILES: [2H]c1c([2H])c([2H])c(-c2c([2H])c([2H])c([2H])c([2H])c2N(c2c([2H])c([2H])c([2H])c3c2-c2c([2H])c([2H])c([2H])c([2H])c2C32c3c([2H])c([2H])c([2H])c([2H])c3-c3c([2H])c([2H])c([2H])c([2H])c32)c2c([2H])c([2H])c([2H])c3c2-c2c([2H])c([2H])c([2H])c([2H])c2C3(C([2H])([2H])[2H])C([2H])([2H])[2H])c([2H])c1[2H] ; "H6"] |
| 6 | 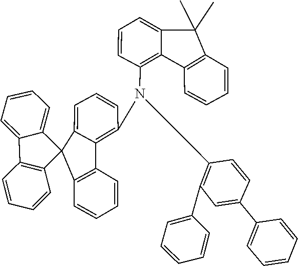 [SMILES: CC1(C)c2ccccc2-c2c(N(c3ccc(-c4ccccc4)cc3-c3ccccc3)c3cccc4c3-c3ccccc3C43c4ccccc4-c4ccccc43)cccc21] | 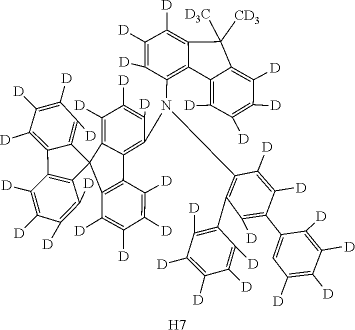 |
| 7 | 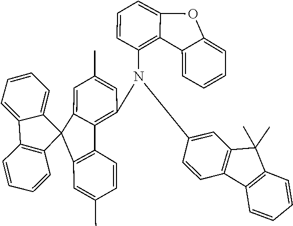 [SMILES: Cc1ccc2c(c1)C1(c3ccccc3-c3ccccc31)c1cc(C)cc(N(c3ccc4c(c3)C(C)(C)c3ccccc3-4)c3cccc4oc5ccccc5c34)c1-2] | 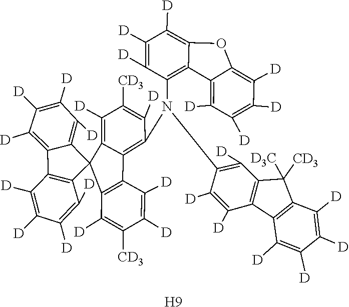 [SMILES: [2H]c1c([2H])c([2H])c2c(c1[2H])-c1c([2H])c([2H])c([2H])c([2H])c1C21c2c([2H])c(C([2H])([2H])[2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4oc5c([2H])c([2H])c([2H])c([2H])c5c34)c([2H])c(C([2H])([2H])[2H])c([2H])c21 ; "H9"] |
| 8 | 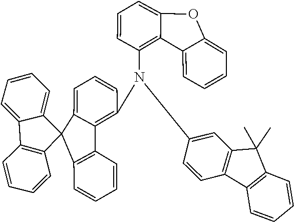 [SMILES: CC1(C)c2ccccc2-c2ccc(N(c3cccc4c3-c3ccccc3C43c4ccccc4-c4ccccc43)c3cccc4oc5ccccc5c34)cc21] | 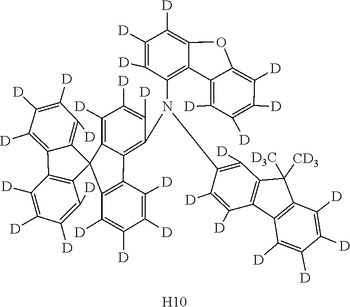 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3c([2H])c([2H])c4c(c3[2H])C(C([2H])([2H])[2H])(C([2H])([2H])[2H])c3c([2H])c([2H])c([2H])c([2H])c3-4)c3c([2H])c([2H])c([2H])c4oc5c([2H])c([2H])c([2H])c([2H])c5c34)c([2H])c([2H])c([2H])c21 ; "H10"] |
| 9 | 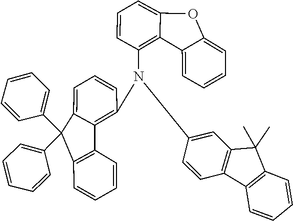 [SMILES: CC1(C)c2ccccc2-c2ccc(N(c3cccc4c3-c3ccccc3C4(c3ccccc3)c3ccccc3)c3cccc4oc5ccccc5c34)cc21] | 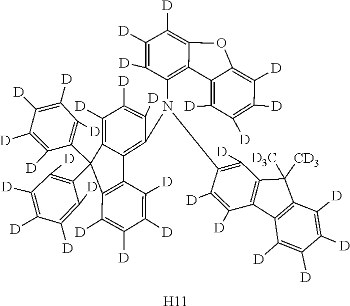 [SMILES: [2H]c1c([2H])c([2H])c(C2(c3c([2H])c([2H])c([2H])c([2H])c3[2H])c3c([2H])c([2H])c([2H])c([2H])c3-c3c(N(c4c([2H])c([2H])c5c(c4[2H])C(C([2H])([2H])[2H])(C([2H])([2H])[2H])c4c([2H])c([2H])c([2H])c([2H])c4-5)c4c([2H])c([2H])c([2H])c5oc6c([2H])c([2H])c([2H])c([2H])c6c45)c([2H])c([2H])c([2H])c32)c([2H])c1[2H] ; "H11"] |
| 10 | 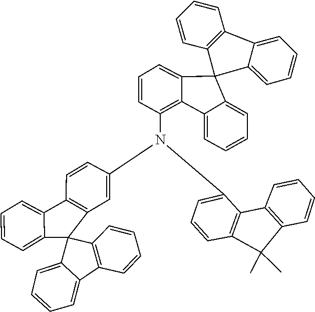 [SMILES: CC1(C)c2ccccc2-c2c(N(c3ccc4c(c3)C3(c5ccccc5-c5ccccc53)c3ccccc3-4)c3cccc4c3-c3ccccc3C43c4ccccc4-c4ccccc43)cccc21] | 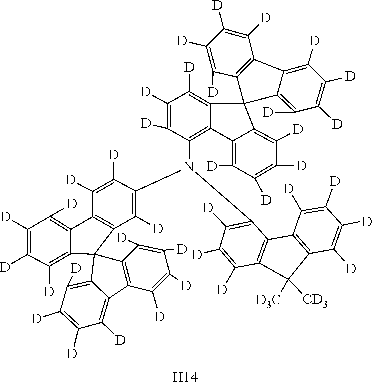 [SMILES: [2H]c1c([2H])c([2H])c2c(c1[2H])-c1c([2H])c([2H])c([2H])c([2H])c1C21c2c([2H])c([2H])c([2H])c([2H])c2-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C4(C([2H])([2H])[2H])C([2H])([2H])[2H])c([2H])c21 ; "H14"] |
| 11 | 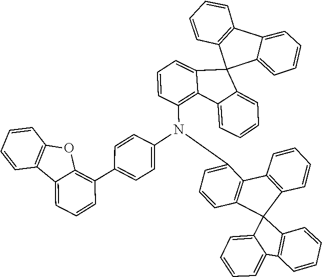 [SMILES: c1ccc2c(c1)-c1ccccc1C21c2ccccc2-c2c(N(c3ccc(-c4cccc5c4oc4ccccc45)cc3)c3cccc4c3-c3ccccc3C43c4ccccc4-c4ccccc43)cccc21] | 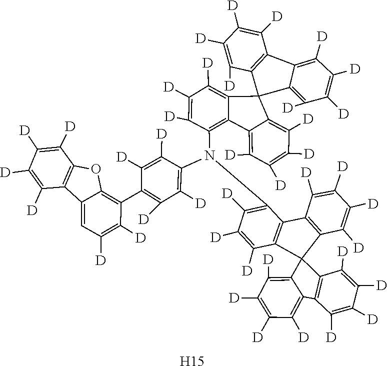 [SMILES: [2H]c1cc2c(oc3c([2H])c([2H])c([2H])c([2H])c32)c(-c2c([2H])c([2H])c(N(c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c3c([2H])c([2H])c([2H])c4c3-c3c([2H])c([2H])c([2H])c([2H])c3C43c4c([2H])c([2H])c([2H])c([2H])c4-c4c([2H])c([2H])c([2H])c([2H])c43)c([2H])c2[2H])c1[2H] ; "H15"] |
| 12 | 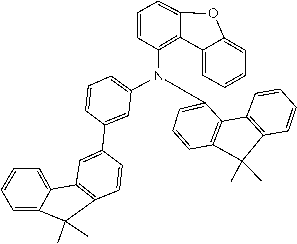 [SMILES: CC1(C)c2ccccc2-c2cc(-c3cccc(N(c4cccc5c4-c4ccccc4C5(C)C)c4cccc5oc6ccccc6c45)c3)ccc21] | 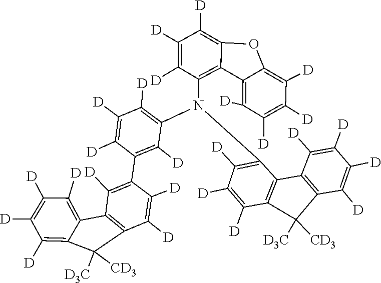 [SMILES: [2H]c1c([2H])c([2H])c2c(c1[2H])-c1c([2H])c(-c3c([2H])c([2H])c([2H])c(N(c4c([2H])c([2H])c([2H])c5c4-c4c([2H])c([2H])c([2H])c([2H])c4C5(C([2H])([2H])[2H])C([2H])([2H])[2H])c4c([2H])c([2H])c([2H])c5oc6c([2H])c([2H])c([2H])c([2H])c6c45)c3[2H])c([2H])c([2H])c1C2(C([2H])([2H])[2H])C([2H])([2H])[2H]] |

### Production of the OLEDs

In examples V1 to V4 and B1 to B15 which follow (see tables 8 and 9), the data of various OLEDs are presented.

Pretreatment for examples V1-B15: Glass plates coated with structured ITO (indium tin oxide) of thickness 50 nm are treated prior to coating with an oxygen plasma, followed by an argon plasma. These plasma-treated glass plates form the substrates to which the OLEDs are applied.

The OLEDs basically have the following layer structure: substrate/hole injection layer (HIL)/hole transport layer (HTL)/electron blocker layer (EBL)/emission layer (EML)/optional hole blocker layer (HBL)/electron transport layer (ETL)/optional electron injection layer (EIL) and finally a cathode. The cathode is formed by an aluminum layer of thickness 100 nm. The exact structure of the OLEDs can be found in table 8. The materials required for production of the OLEDs are shown in table 10 if not described above.

All materials are applied by thermal vapor deposition in a vacuum chamber. In this case, the emission layer always consists of at least one matrix material (host material) and an emitting dopant (emitter) which is added to the matrix material(s) in a particular proportion by volume by co-evaporation. Details given in such a form as E1:SdT1:TEG1 (32%:60%:8%) mean here that the material E1 is present in the layer in a proportion by volume of 32%, SdT1 in a proportion of 60% and TEG1 in a proportion of 8%. Analogously, the electron transport layer may also consist of a mixture of two materials.

The OLEDs are characterized in a standard manner. For this purpose, the electroluminescence spectra, the voltage and the external quantum efficiency (EQE, measured in percent) are determined as a function of luminance, calculated from current-voltage-luminance characteristics (IUL characteristics) assuming Lambertian radiation characteristics, and the lifetime. Electroluminescence spectra are determined at a luminance of 1000 cd/m², and these are used to calculate the CIE 1931 x and y color coordinates. The parameter U1000 in Table 9 refers here to the voltage which is required for a luminance of 1000 cd/m². CE1000 denotes the current efficiency which is achieved at 1000 cd/m². Finally, EQE1000 refers to the external quantum efficiency at an operating luminance of 1000 cd/m². The lifetime LT is defined as the time after which the luminance drops from the starting luminance to a certain proportion L1 in the course of operation with constant current density j₀. A figure of L1=80% in table 9 means that the lifetime reported in the LT column corresponds to the time after which the luminance falls to 80% of its starting value. The data for the various OLEDs are collated in Table 9. Examples V1 to V4 are comparative examples according to the prior art; Examples B1-B15 show data of OLEDs of the invention.

Some of the examples are elucidated in detail hereinafter, in order to illustrate the advantages of the OLEDs of the invention.

### Use of Mixtures of the Invention in the Emission Layer of Phosphorescent OLEDs

The materials of the invention, when used as matrix material in combination with deuterated monoamines in the emission layer (EML) in phosphorescent OLEDs, result in significant improvements over the prior art, particularly in relation to the lifetime and external quantum efficiency of the OLEDs. Through use of the material combinations of the invention, it is possible to observe an improvement in the EQE by about 5-10% compared to the prior art compounds SdT1, and an increase in lifetime by 30-100% (comparison of example V2 with example B2 and comparison of V4 with B6).

TABLE 8
Structure of the OLEDs

| | HIL | HTL | EBL | EML | HBL | ETL | EIL |
|---|---|---|---|---|---|---|---|
| Ex. | thickness | thickness | thickness | thickness | thickness | thickness | thickness |
| V1 | SpMA1:P | SpMA | SpMA3 | E1:SdT1:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| V1 | SpMA1:P | SpMA | SpMA3 | E1:SdT2:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B1 | SpMA1:P | SpMA | SpMA3 | E1:H5:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B2 | SpMA1:P | SpMA | SpMA3 | E1:H2:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B3 | SpMA1:P | SpMA | SpMA3 | E1:H1:TEG2 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B4 | SpMA1:P | SpMA | SpMA3 | E1:H2:TEG2 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| V3 | SpMA1:P | SpMA | SpMA3 | E39:SdT1:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| V4 | SpMA1:P | SpMA | SpMA3 | E39:SdT2:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B5 | SpMA1:P | SpMA | SpMA3 | E39:H5;TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B6 | SpMA1:P | SpMA | SpMA3 | E39:H2:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B7 | SpMA1:P | SpMA | SpMA3 | E39:H2:TEG2 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B8 | SpMA1:P | SpMA | SpMA3 | E39:H1:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B9 | SpMA1:P | SpMA | SpMA3 | E2: H2:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B10 | SpMA1:P | SpMA | SpMA3 | E3: H4:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B11 | SpMA1:P | SpMA | SpMA3 | E26: H10:TEG1 | ST2 | ST2:LiQ | LiQ |
| | D1 | 1 | 20 nm | (32%:60%:8%) | 5 nm | (50%:50%) | 1 nm |
| | (95%:5%) | 240 nm | | 40 nm | | 40 nm | |
| | 20 nm | | | | | | |
| B12 | SpMA1:P | SpMA | SpMA3 | E35: H11:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B13 | SpMA1:P | SpMA | SpMA3 | E40: H2:TEG1 | ST2 | ST2:LiQ | LiQ |
| | D1 | 1 | 20 nm | (32%:60%:8%) | 5 nm | (50%:50%) | 1 nm |
| | (95%:5%) | 230 nm | | 40 nm | | 40 nm | |
| | 20 nm | | | | | | |
| B14 | SpMA1:P | SpMA | SpMA3 | E40: H1:TEG1 | ST2 | ST2:LiQ | LiQ |
| | D1 | 1 | 20 nm | (32%:60%:8%) | 5 nm | (50%:50%) | 1 nm |
| | (95%:5%) | 240 nm | | 40 nm | | 40 nm | |
| | 20 nm | | | | | | |
| B15 | SpMA1:P | SpMA | SpMA3 | E46: H1:TEG1 | ST2 | ST2:LiQ | LiQ |
| | D1 | 1 | 20 nm | (32%:60%:8%) | 5 nm | (50%:50%) | 1 nm |
| | (95%:5%) | 240 nm | | 40 nm | | 40 nm | |
| | 20 nm | | | | | | |

TABLE 9
Data of the OLEDs

| | U1000 | EQE1000 | CIE x/y at | j0 | L1 | LT |
|---|---|---|---|---|---|---|
| Ex. | (V) | (%) | 1000 cd/m² | (mA/cm²) | (%) | (h) |
| V1 | 4.4 | 19.1 | 0.33/0.63 | 40 | 80 | 350 |
| V2 | 4.2 | 21.9 | 0.33/0.63 | 40 | 80 | 630 |
| B1 | 4.1 | 21.4 | 0.34/0.62 | 40 | 80 | 980 |
| B2 | 4.0 | 23.0 | 0.35/0.63 | 40 | 80 | 1270 |
| B3 | 4.0 | 20.8 | 0.34/0.63 | 40 | 80 | 1212 |
| B4 | 4.1 | 22.7 | 0.35/0.63 | 40 | 80 | 1189 |
| V3 | 4.6 | 18.0 | 0.34/0.63 | 40 | 80 | 340 |
| V4 | 4.2 | 20.7 | 0.34/0.63 | 40 | 80 | 620 |
| B5 | 4.3 | 21.3 | 0.35/0.63 | 40 | 80 | 965 |
| B6 | 4.1 | 23.0 | 0.34/0.63 | 40 | 80 | 1244 |
| B7 | 4.0 | 20.3 | 0.33/0.63 | 40 | 80 | 1214 |
| B8 | 4.0 | 22.5 | 0.34/0.63 | 40 | 80 | 1202 |
| B9 | 4.2 | 22.8 | 0.35/0.63 | 40 | 80 | 1100 |
| B10 | 4.1 | 22.1 | 0.34/0.63 | 40 | 80 | 1067 |
| B11 | 4.2 | 22.3 | 0.34/0.62 | 40 | 80 | 1190 |
| B12 | 4.2 | 23.0 | 0.34/0.62 | 40 | 80 | 1022 |
| B13 | 4.0 | 23.3 | 0.34/0.63 | 40 | 80 | 1130 |
| B14 | 4.1 | 22.1 | 0.35/0.62 | 40 | 80 | 1007 |
| B15 | 4.1 | 23.2 | 0.33/0.63 | 40 | 80 | 1201 |

TABLE 10
Structural formulae of the materials for the OLEDs

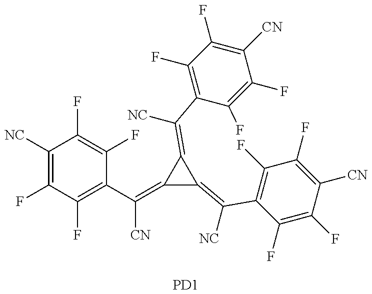 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; "PD1"]

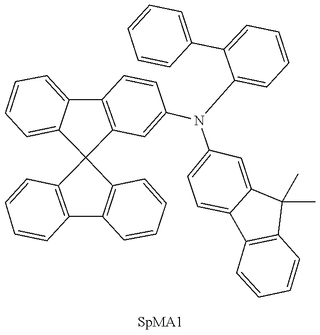 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

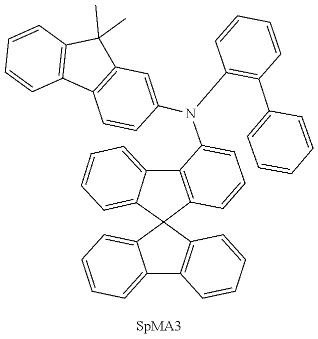 [SMILES: CC1(C)c2ccccc2-c2ccc(N(c3ccccc3-c3ccccc3)c3cccc4c3-c3ccccc3C43c4ccccc4-c4ccccc43)cc21]

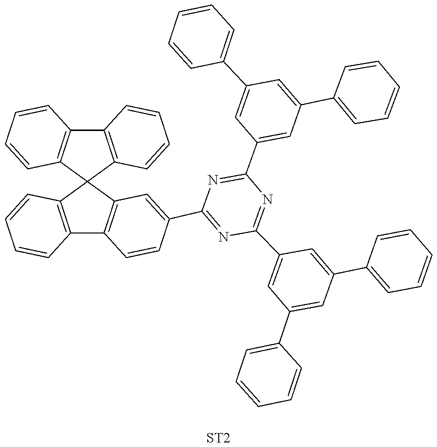 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1 ; "ST2"]

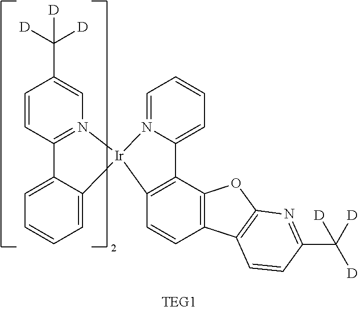

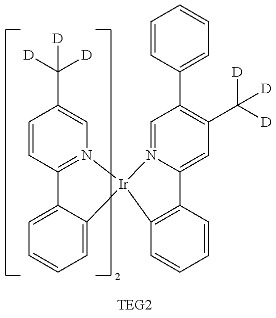

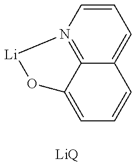

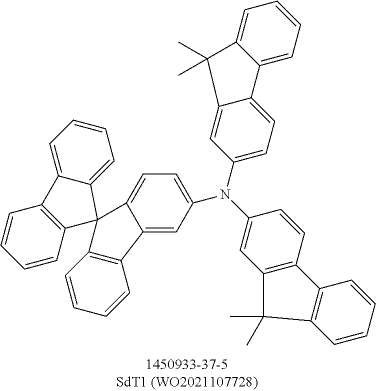 [SMILES: CC1(C)c2ccccc2-c2ccc(N(c3ccc4c(c3)-c3ccccc3C43c4ccccc4-c4ccccc43)c3ccc4c(c3)C(C)(C)c3ccccc3-4)cc21]

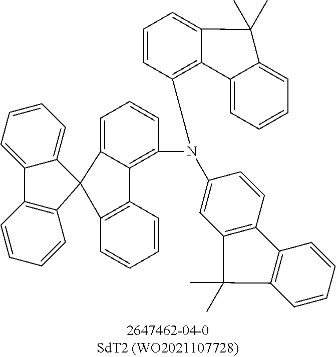 [SMILES: CC1(C)c2ccccc2-c2ccc(N(c3cccc4c3-c3ccccc3C4(C)C)c3cccc4c3-c3ccccc3C43c4ccccc4-c4ccccc43)cc21]

1.-15. (canceled)

16. An organic electroluminescent device comprising an anode, a cathode and at least one organic layer containing at least one light-emitting layer, wherein the at least one light-emitting layer contains at least one compound of the formula (1) as host material 1 and at least one compound of the formula (2) as host material 2: 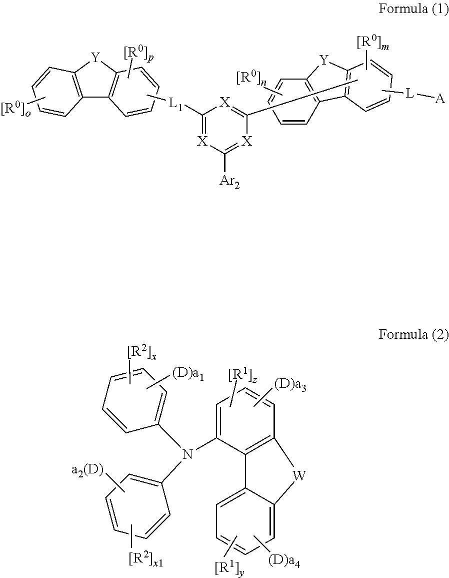
where the symbols and indices used are as follows:
A is 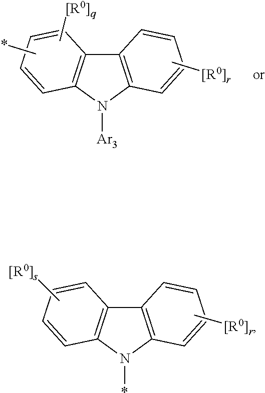
X is the same or different at each instance and is CR⁰ or N, where at least one symbol X is N;
Y is the same or different at each instance and is selected from O and S;
* indicates the binding site to the formula (1);
L and L₁ are the same or different at each instance and are a single bond or an aromatic or heteroaromatic ring system having 5 to 30 aromatic ring atoms;
W is O, S, C(R)₂;
R is in each case independently a straight-chain or branched alkyl group which has 1 to 4 carbon atoms and may be partly or fully deuterated, or an unsubstituted or partly or fully deuterated aromatic ring system having 6 to 18 carbon atoms, where two substituents R together with the carbon atom to which they are bonded may form a mono- or polycyclic, aliphatic or aromatic or heteroaromatic, unsubstituted, partly deuterated or fully deuterated ring system which may be substituted by one or more substituents R³, with the condition that the ring system and substituents bonded thereto do not contain a carbazole group;
R⁰ at each instance is independently D, an unsubstituted or partly or fully deuterated aromatic ring system having 6 to 18 carbon atoms or an unsubstituted or partly or fully deuterated dibenzofuran, dibenzothiophene or C-bonded N-arylcarbazole;
Ar₁ is the same or different at each instance and is an aromatic or heteroaromatic ring system which has 5 to 30 aromatic ring atoms and may be substituted by one or more nonaromatic R³ radicals; at the same time, two Ar₁ radicals bonded to the same nitrogen atom, phosphorus atom or boron atom may also be bridged to one another by a single bond or a bridge selected from C(R³)₂, O and S;
Ar₂ at each instance is independently an aryl or heteroaryl group which has 5 to 40 aromatic ring atoms and may be substituted by one or more R′ radicals;
Ar₃ at each instance is independently an aromatic ring system having 6 to 40 aromatic ring atoms or a heteroaromatic ring system having 5 to 40 aromatic ring atoms, which may be substituted by one or more R′ radicals;
aryl is the same or different at each instance and is an aromatic or heteroaromatic ring system which has 5 to 30 aromatic ring atoms and may be substituted by one or more nonaromatic R′ radicals;
R′ is the same or different at each instance and is selected from the group consisting of D, F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C—S, C═Se, C═NR³, P(═O)(R³), SO, SO₂, NH, NR³, O, S, CONH or CONR³ and where one or more hydrogen atoms may be replaced by F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R′ to form a monocyclic or polycyclic, aliphatic, aromatic or heteroaromatic ring system which may be substituted by one or more R³ radicals;
R¹ is the same or different at each instance and is selected from the group consisting of F, Cl, Br, I, CN, NO₂, C(═O)R′, P(═O)(Ar₁)₂, P(Ar₁)₂, B(Ar₁)₂, Si(Ar₁)₃, Si(R′)₃, a straight-chain alkyl, alkoxy or thioalkyl group having 1 to 20 carbon atoms and a branched or cyclic alkyl, alkoxy or thioalkyl group having 3 to 20 carbon atoms and an alkenyl group having 2 to 20 carbon atoms, each of which may be substituted by one or more R′ radicals, where one or more nonadjacent CH₂ groups may be replaced by R′C═CR′, Si(R′)₂, C═O, C═S, C═NR′, P(═O)(R′), SO, SO₂, NR′, O, S or CONR′ and where one or more hydrogen atoms may be replaced by D, F, Cl, Br, I, CN or NO₂;
R² is the same or different at each instance and is selected from the group consisting of F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R² to form a monocyclic or polycyclic, aliphatic, aromatic or heteroaromatic ring system which may be substituted by one or more R³ radicals, with the condition that R² and substituents bonded thereto do not contain a carbazole group;
R³ is the same or different at each instance and is selected from the group consisting of d, F, CN, an aliphatic hydrocarbyl radical having 1 to 20 carbon atoms, and an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, it is possible for two or more adjacent R³ substituents together to form a mono- or polycyclic, aliphatic ring system;
n, m, p, q are each independently 0, 1, 2 or 3;
o, r, s are each independently 0, 1, 2, 3 or 4;
x, x1 at each instance are independently 0, 1, 2, 3 or 4;
y, z are each independently 0, 1 or 2;
a1, a2 are each independently 1, 2, 3, 4 or 5;
a3 is 0, 1, 2 or 3;
a4 is 0, 1, 2, 3 or 4; and
a1+a2+a3+a4 is 3, 4, 5, 6, 7, 8, 9, 10, 11, 12, 13, 14, 15, 16 or 17.

17. The organic electroluminescent device as claimed in claim 16, wherein L in host material 1 is selected from a bond or the linkers from the group of L-1 to L-33 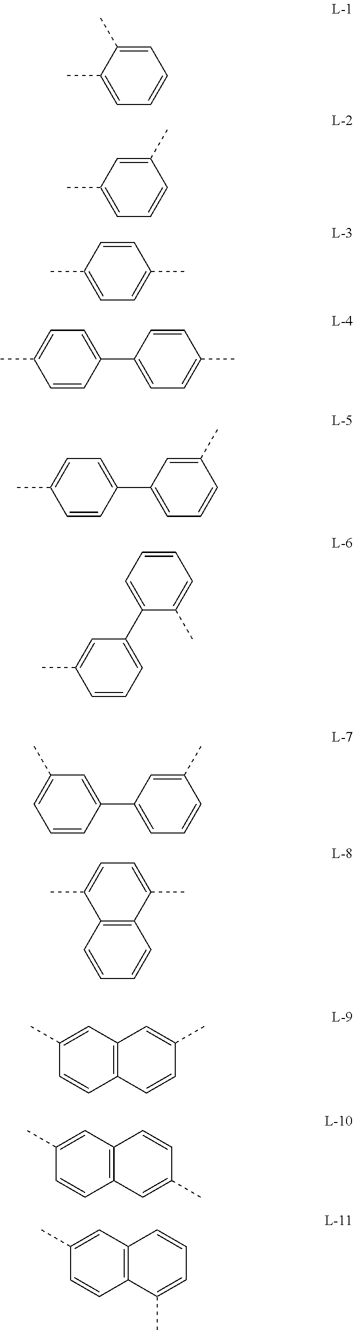 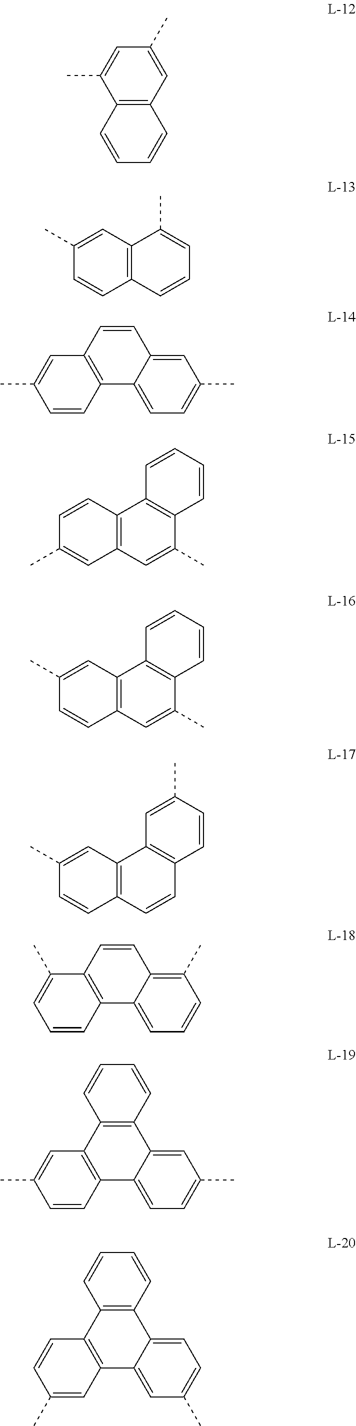 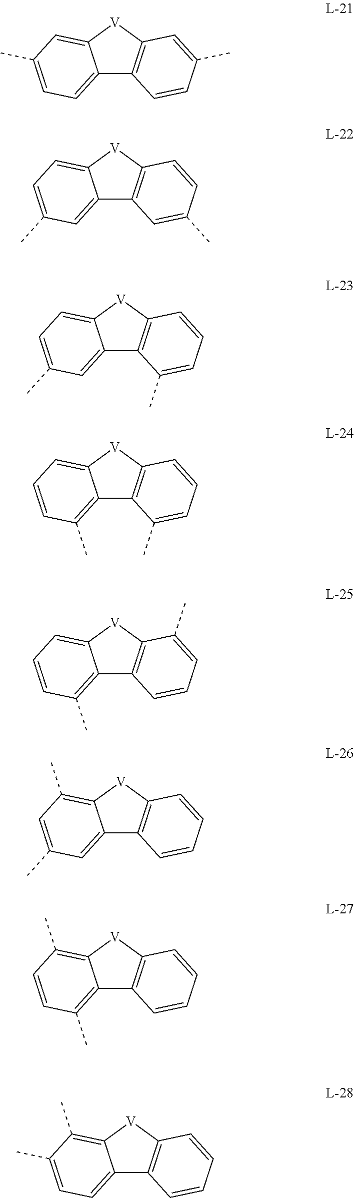 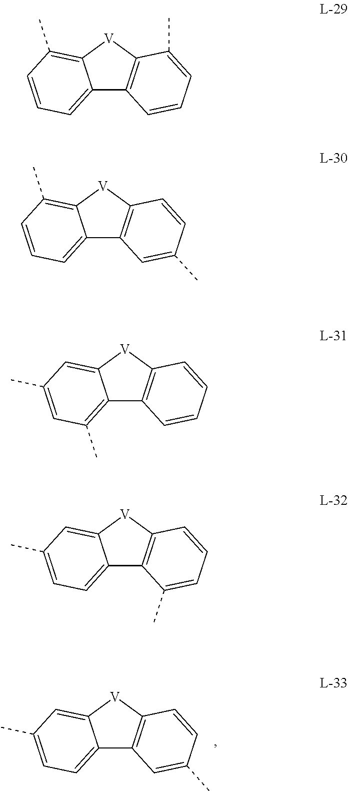
where V is in each case independently O or S.

18. The organic electroluminescent device as claimed in claim 16, wherein the host material 2 conforms to the formula (3) 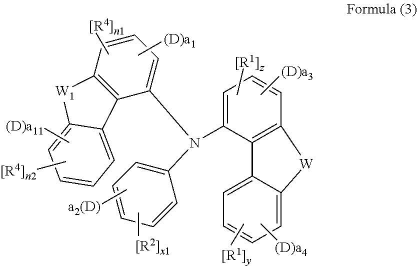
where W, R1, R2, a1, a2, a3, a4, x, y and z have a definition given in claim 16 and the symbols and indices used are as follows:
W₁ is O, S or C(R)₂, where R has a definition given in claim 16;
R⁴ is the same or different at each instance and is selected from the group consisting of F, Cl, Br, I, C(═O)Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br or I, an aromatic or heteroaromatic ring system which has 5 to 60 aromatic ring atoms and may be substituted in each case by one or more R³ radicals, where it is optionally possible for two or more adjacent substituents R⁴ to form a monocyclic or polycyclic, aliphatic, aromatic or heteroaromatic ring system which may be substituted by one or more R³ radicals, with the condition that R⁴ and substituents bonded thereto do not contain a carbazole group;
a₁₁ is 0, 1, 2, 3 or 4;
n1 is 0, 1 or 2; and
n2 is 0, 1, 2, 3 or 4.

19. The organic electroluminescent device as claimed in claim 16, wherein L₁ in host material 1 is a single bond.

20. The organic electroluminescent device as claimed in claim 16, wherein the host material 2 is fully deuterated.

21. The organic electroluminescent device as claimed in claim 16, wherein the device is an electroluminescent device selected from organic light-emitting transistors (OLETs), organic field quench devices (OFQDs), organic light-emitting electrochemical cells (OLECs, LECs, LEECs), organic laser diodes (O-lasers) and organic light-emitting diodes (OLEDs).

22. The organic electroluminescent device as claimed in claim 16, wherein the device comprises, in addition to the light-emitting layer (EML), a hole injection layer (HIL), a hole transport layer (HTL), an electron transport layer (ETL), an electron injection layer (EIL) and/or a hole blocker layer (HBL).

23. The organic electroluminescent device as claimed in claim 16, wherein the light-emitting layer, as well as the at least one host material 1 and the at least one host material 2, contains at least one phosphorescent emitter.

24. A process for producing a device as claimed in claim 16, wherein the light-emitting layer is applied by gas phase deposition or from solution.

25. The process as claimed in claim 24, wherein the at least one compound of the formula (1) and the at least one compound of the formula (2) are deposited from the gas phase successively or simultaneously from at least two material sources, optionally with the at least one phosphorescent emitter, and form the light-emitting layer.

26. The process as claimed in claim 24, wherein the at least one compound of the formula (1) and the at least one compound of the formula (2) are deposited from the gas phase as a mixture, successively or simultaneously with the at least one phosphorescent emitter, and form the light-emitting layer.

27. The process as claimed in claim 24, wherein the at least one compound of the formula (1) and the at least one compound of the formula (2) are applied from a solution together with the at least one phosphorescent emitter to form the light-emitting layer.

28. A mixture comprising at least one compound of the formula (1) as host material 1 and at least one compound of the formula (2) as host material 2 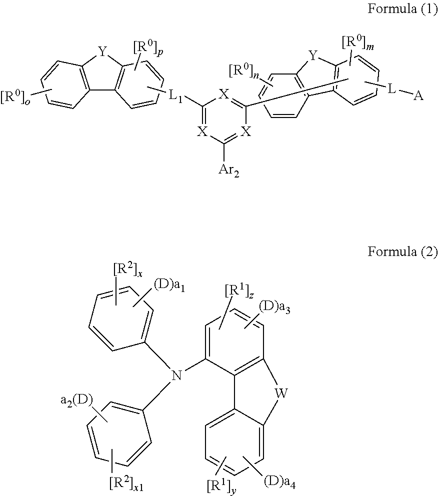
where the symbols and indices used are as follows:
A is 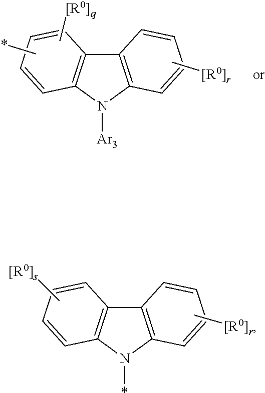
X is the same or different at each instance and is CR⁰ or N, where at least one symbol X is N;
Y is the same or different at each instance and is selected from O and S;
* indicates the binding site to the formula (1);
L and L₁ are the same or different at each instance and are a single bond or an aromatic or heteroaromatic ring system having 5 to 30 aromatic ring atoms;
W is O, S, C(R)₂;
R is in each case independently a straight-chain or branched alkyl group which has 1 to 4 carbon atoms and may be partly or fully deuterated, or an unsubstituted or partly or fully deuterated aromatic ring system having 6 to 18 carbon atoms, where two substituents R together with the carbon atom to which they are bonded may form a mono- or polycyclic, aliphatic or aromatic or heteroaromatic, unsubstituted, partly deuterated or fully deuterated ring system which may be substituted by one or more substituents R³, with the condition that the ring system and substituents bonded thereto do not contain a carbazole group;
R⁰ at each instance is independently D, an unsubstituted or partly or fully deuterated aromatic ring system having 6 to 18 carbon atoms or an unsubstituted or partly or fully deuterated dibenzofuran, dibenzothiophene or C-bonded N-arylcarbazole;
Ar₁ is the same or different at each instance and is an aromatic or heteroaromatic ring system which has 5 to 30 aromatic ring atoms and may be substituted by one or more nonaromatic R³ radicals; at the same time, two Ar₁ radicals bonded to the same nitrogen atom, phosphorus atom or boron atom may also be bridged to one another by a single bond or a bridge selected from C(R³)₂, O and S;
Ar₂ at each instance is independently an aryl or heteroaryl group which has 5 to 40 aromatic ring atoms and may be substituted by one or more R′ radicals;
Ar₃ at each instance is independently an aromatic ring system having 6 to 40 aromatic ring atoms or a heteroaromatic ring system having 5 to 40 aromatic ring atoms, which may be substituted by one or more R′ radicals;
aryl is the same or different at each instance and is an aromatic or heteroaromatic ring system which has 5 to 30 aromatic ring atoms and may be substituted by one or more nonaromatic R radicals;
R′ is the same or different at each instance and is selected from the group consisting of D, F, Cl, Br, I, CN, NO₂, N(Ar₁)₂, NH₂, N(R³)₂, C(═O)Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R′ to form a monocyclic or polycyclic, aliphatic, aromatic or heteroaromatic ring system which may be substituted by one or more R³ radicals;
R¹ is the same or different at each instance and is selected from the group consisting of F, Cl, Br, I, CN, NO₂, C(═O)R′, P(═O)(Ar₁)₂, P(Ar₁)₂, B(Ar₁)₂, Si(Ar₁) 3, Si(R′)₃, a straight-chain alkyl, alkoxy or thioalkyl group having 1 to 20 carbon atoms and a branched or cyclic alkyl, alkoxy or thioalkyl group having 3 to 20 carbon atoms and an alkenyl group having 2 to 20 carbon atoms, each of which may be substituted by one or more R′ radicals, where one or more nonadjacent CH₂ groups may be replaced by R′C═CR′, Si(R′)₂, C═O, C═S, C═NR′, P(═O)(R′), SO, SO₂, NR′, O, S or CONR′ and where one or more hydrogen atoms may be replaced by D, F, Cl, Br, I, CN or NO₂;
R² is the same or different at each instance and is selected from the group consisting of F, Cl, Br, I, CN, NO₂, N(Ar₁)₂, NH₂, N(R³)₂, C(═O) Ar₁, C(═O)H, C(═O)R³, P(═O)(Ar₁)₂, a straight-chain alkyl, alkoxy or thioalkyl group having 1 to 40 carbon atoms and a branched or cyclic alkyl, alkoxy or thioalkyl group having 3 to 40 carbon atoms and an alkenyl or alkynyl group having 2 to 40 carbon atoms, each of which may be substituted by one or more R³ radicals, where one or more nonadjacent CH₂ groups may be replaced by HC═CH, R³C═CR³, C≡C, Si(R³)₂, Ge(R³)₂, Sn(R³)₂, C═O, C═S, C═Se, C═NR³, P(═O)(R³), SO, SO₂, NH, NR³, O, S, CONH or CONR³ and where one or more hydrogen atoms may be replaced by D, F, Cl, Br, I, CN or NO₂, an aromatic or heteroaromatic ring system which has 5 to 60 aromatic ring atoms and may be substituted in each case by one or more R³ radicals, an aryloxy or heteroaryloxy group which has 5 to 60 aromatic ring atoms and may be substituted by one or more R³ radicals, or a combination of these systems, where it is optionally possible for two or more adjacent substituents R² to form a monocyclic or polycyclic, aliphatic, aromatic or heteroaromatic ring system which may be substituted by one or more R³ radicals, with the condition that R² and substituents bonded thereto do not contain a carbazole group;
R³ is the same or different at each instance and is selected from the group consisting of D, F, CN, an aliphatic hydrocarbyl radical having 1 to 20 carbon atoms, and an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, it is possible for two or more adjacent R³ substituents together to form a mono- or polycyclic, aliphatic ring system;
n, m, p, q are each independently 0, 1, 2 or 3;
o, r, s are each independently 0, 1, 2, 3 or 4;
x, x1 at each instance are independently 0, 1, 2, 3 or 4;
y, z are each independently 0, 1 or 2;
a1, a2 are each independently 1, 2, 3, 4 or 5;
a3 is 0, 1, 2 or 3;
a4 is 0, 1, 2, 3 or 4; and
a1+a2+a3+a4 is 3, 4, 5, 6, 7, 8, 9, 10, 11, 12, 13, 14, 15, 16 or 17.

29. The mixture as claimed in claim 28, wherein the mixture consists of at least one compound of the formula (1), at least one compound of the formula (2) and a phosphorescent emitter.

30. A formulation comprising a mixture as claimed in claim 28 and at least one solvent.
